(19) United States
(12) Patent Application Publication
(10) Pub. No.: US 2024/0260289 A1
(43) Pub. Date: Aug. 1, 2024

(54) ORGANIC ELECTROLUMINESCENT DEVICE

(71) Applicant: BEIJING SUMMER SPROUT TECHNOLOGY CO., LTD., Beijing (CN)

(72) Inventors: Jing Wang, Beijing (CN); Menglan Xie, Beijing (CN); Huiqing Pang, Beijing (CN); Zhihao Cui, Beijing (CN); Hualong Ding, Beijing (CN); Renjie Zheng, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/396,172

(22) Filed: Dec. 26, 2023

(30) Foreign Application Priority Data
Dec. 30, 2022 (CN) 202211717388.8
Mar. 8, 2023 (CN) 202310218088.3

(51) Int. Cl. H10K 50/11; H10K 50/18; H10K 85/30; H10K 85/60

(52) U.S. Cl. CPC H10K 50/11; H10K 50/181; H10K 85/342; H10K 85/633; H10K 85/655; H10K 85/6572; H10K 85/6574

(57) ABSTRACT

Provided is an organic electroluminescent device. The organic electroluminescent device comprises: an anode, a cathode, an emissive layer disposed between the anode and the cathode, and an electron blocking layer disposed between the anode and the emissive layer, wherein the electron blocking layer comprises an electron blocking material; the capacitance of the organic electroluminescent device satisfies the following condition: at 500 Hz, a maximum capacitance value of the organic electroluminescent device is Cₘₐₓ, and ΔC=C₀−Cₘₐₓ≥0.4 nF; the electron blocking material has a hole mobility μₕ≤65×10⁻⁵ cm²/(V·s); a hole-only device of the emissive layer has a drive voltage V_{HOD}@J10≤8.0 V at a current density of 10 mA/cm², and an electron-only device of the emissive layer has a drive voltage V_{EOD}@J10≤8.0 V at a current density of 10 mA/cm². The organic electroluminescent device can greatly reduce device capacitance and further reduce a device voltage and improve device efficiency so that the device has better performance. Further provided is a display assembly comprising the organic electroluminescent device.

### CROSS-REFERENCE TO RELATED APPLICATION(S)

This application claims priority to Chinese Patent Application No. 202211717388.8 filed on Dec. 30, 2022 and Chinese Patent Application No. 202310218088.3 filed on Mar. 8, 2023, the disclosure of which are incorporated herein by reference in their entireties.

### TECHNICAL FIELD

The present disclosure relates to organic electronic devices, for example, organic electroluminescent devices. More particularly, the present disclosure relates to an organic electroluminescent device capable of effectively reducing device capacitance.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

An organic electroluminescent device converts electrical energy into light by applying a voltage across the device. Generally, the organic electroluminescent device includes an anode, a cathode, and an organic layer between the anode and the cathode. The organic layer of the electroluminescent device includes a hole injection layer, a hole transporting layer, an electron blocking layer, an emissive layer (including a host material and a doping material), a hole blocking layer, an electron transporting layer, an electron injection layer, and the like. According to different functions of materials, the materials that constitute the organic layer may be divided into a hole injection material, a hole transporting material, an electron blocking material, a host material, an emissive material, a hole blocking material, an electron transporting material, an electron injection material, and the like. When a bias voltage is applied to the device, holes are injected into the emissive layer from the anode, and electrons are injected into the emissive layer from the cathode. The holes and the electrons meet each other to form excitons, and the excitons are recombined to emit light. The electron blocking layer and the emissive layer are important function layers affecting the performance of the organic electroluminescent device, and the selection and matching of materials of the electron blocking layer and the emissive layer seriously affect the drive voltage, efficiency, capacitance, and the like of the organic electroluminescent device.

An OLED includes a series of organic semiconductor films and thus has a capacitance property, especially before the device is turned on (that is, lit). As shown in FIG. 1, an equivalent circuit of a pixel may be simplified into a light-emitting diode and a capacitor connected in parallel, wherein the capacitor here is not an actual capacitor device but the internal capacitance of the OLED, the capacity of which varies according to the device structure and the selection and matching of different materials.

With the development of the OLED industry, people further pursue a higher refresh rate and a higher resolution. The higher refresh rate means a shorter charging time of the capacitor corresponding to each pixel, and the higher resolution means the simultaneous charging of more pixels. However, when the OLED device has a relatively high internal capacitance, a display response speed becomes slower, especially at a high refresh rate. Therefore, how to reduce the internal capacitance of the device (pixel) is a key point of great concern.

At present, to reduce an effect of the internal capacitance of the device, a method commonly used by researchers in the art is to develop some compounds having particular structures to reduce device capacitance from the aspect of materials. For example, an emissive doping material has a great effect on the device capacitance; thus, an emissive doping material with the characteristic of a low capacitance may be developed. However, this method faces a huge challenge: the device capacitance needs to be further reduced while a material with higher efficiency, a better lifetime, and better thermal stability and crystallinity is obtained, which greatly increases the difficulty of material development.

Therefore, how to reduce the effect of the internal capacitance of the device in another manner so that the device has greatly reduced capacitance and good performance in aspects of voltage, efficiency, etc. to obtain higher display quality is a problem to be solved by the researchers in the art.

### SUMMARY

The present disclosure aims to provide an organic electroluminescent device capable of efficiently reducing capacitance to solve at least part of the preceding problems. An emissive layer of the electroluminescent device has relatively good hole transporting performance (for example, V_{HOD}@J10≤8.00 V) and relatively good electron transporting performance (for example, V_{EOD}@J10≤8.00 V) and when matched with an electron blocking material having a relatively low hole mobility, can greatly reduce device capacitance and further reduce a device voltage and improve device efficiency so that the device has better performance.

According to an embodiment of the present disclosure, an organic electroluminescent device is disclosed. The organic electroluminescent device comprises:
an anode,
a cathode,
an emissive layer disposed between the anode and the cathode, and
an electron blocking layer disposed between the anode and the emissive layer, wherein the electron blocking layer comprises an electron blocking material with a hole mobility μₕ≤65×10⁻⁵ cm²/(V·s);
capacitance of the organic electroluminescent device satisfies the following condition:
at 500 Hz, a maximum capacitance value of the organic electroluminescent device is Cₘₐₓ, and ΔC=C₀−Cₘₐₓ≥0.4 nF;
wherein C₀ denotes a maximum capacitance value of an organic electroluminescent device A at 500 Hz, and the organic electroluminescent device A is the same as the organic electroluminescent device except that the electron blocking material in the electron blocking layer of the organic electroluminescent device is replaced with Compound HT;
the Compound HT has the following structure:

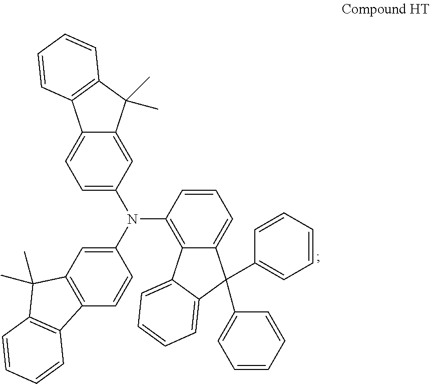 [SMILES: CC1(C)c2ccccc2-c2ccc(N(c3ccc4c(c3)C(C)(C)c3ccccc3-4)c3cccc4c3-c3ccccc3C4(c3ccccc3)c3ccccc3)cc21]

wherein the emissive layer satisfies the following conditions: a hole-only device comprising the emissive layer with a thickness of 400 Å has a drive voltage V_{HOD}@J10≤8.0 V at a current density of 10 mA/cm², and an electron-only device comprising the emissive layer with a thickness of 400 Å has a drive voltage V_{EOD}@J10≤8.0 V at a current density of 10 mA/cm²;
the hole-only device comprising the emissive layer with a thickness of 400 Å has the following structure:
ITO (1200 Å)/HTM:PD (with a weight ratio of 97:3, 100 Å)/HTM (400 Å)/HT-2 (50 Å)/the emissive layer (400 Å)/HTM (400 Å)/HTM:PD (with a weight ratio of 97:3, 100 Å)/Al (1200 Å);
the Compound HTM, the Compound PD, and the Compound HT-2 have the following structures:

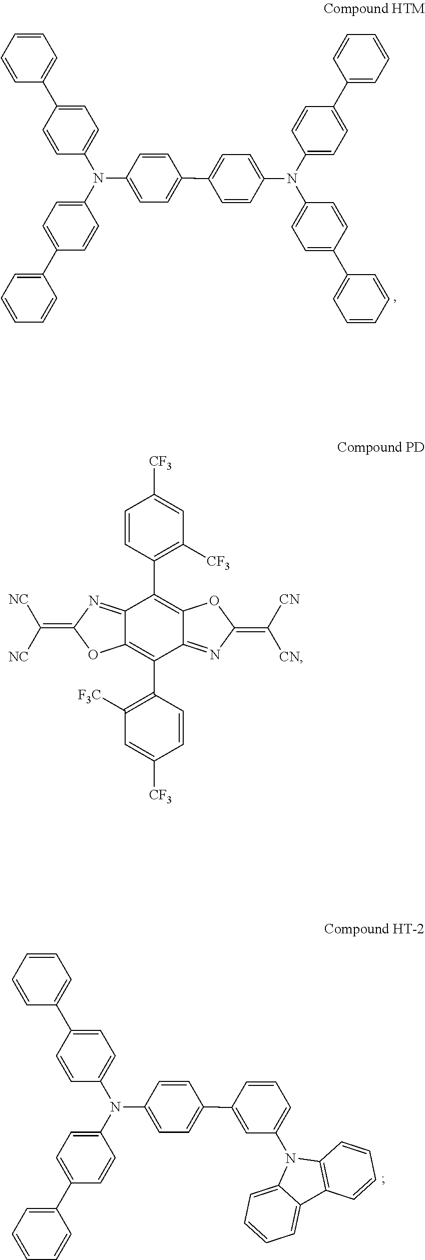 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2ccc(N(c3ccc(-c4ccccc4)cc3)c3ccc(-c4cccc(-n5c6ccccc6c6ccccc65)c4)cc3)cc2)cc1]

the electron-only device comprising the emissive layer with a thickness of 400 Å has the following structure:
ITO (1200 Å)/Liq (10 Å)/the emissive layer (400 Å)/ET:Liq (with a weight ratio of 40:60, 300 Å)/Liq (10 Å)/Al (1200 Å); and
the Compound ET and Liq have the following structures:

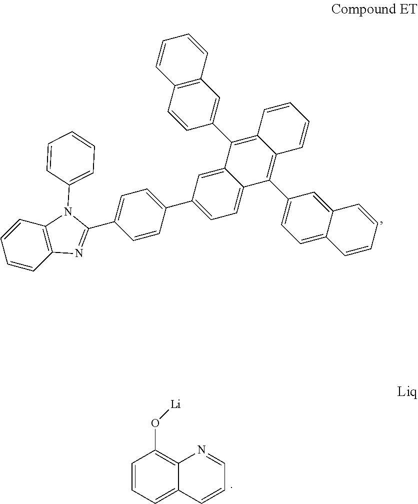

According to another embodiment of the present disclosure, a display assembly is disclosed. The display assembly comprises an organic electroluminescent device, wherein the specific structure of the organic electroluminescent device is shown in the preceding embodiment.

The present disclosure discloses a new organic electroluminescent device, where an emissive layer of the electroluminescent device has relatively good hole transporting performance (for example, V_{HOD}@J10≤8.00 V) and relatively good electron transporting performance (for example, V_{EOD}@J10≤8.00 V) and when matched with an electron blocking material having a relatively low hole mobility, can greatly reduce device capacitance and further reduce a device voltage and improve device efficiency so that the device has better performance.

### BRIEF DESCRIPTION OF DRAWINGS

FIG. 1 is a schematic diagram of an equivalent circuit of an organic electroluminescent device.

FIG. 2 is a schematic diagram of an organic light-emitting apparatus that may include an electroluminescent device disclosed herein.

FIG. 3 is a schematic diagram of another organic light-emitting apparatus that may include an electroluminescent device disclosed herein.

FIG. 4 is a structural diagram of a typical top-emitting OLED that may include an electroluminescent device disclosed herein.

FIG. 5 is a schematic diagram of a capacitance-voltage (C-V) property curve of an electroluminescent device.

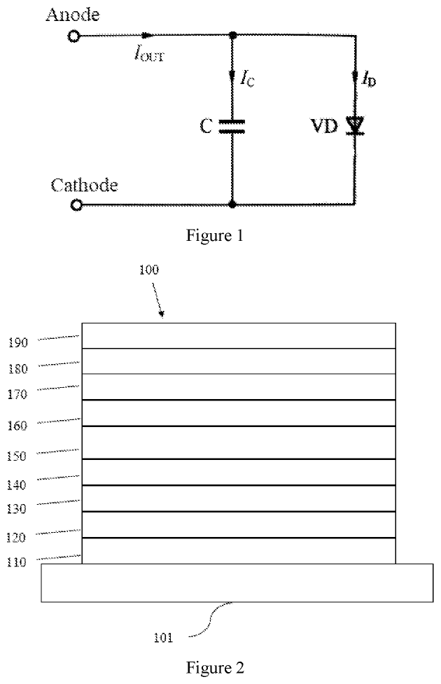

### DETAILED DESCRIPTION

OLEDs can be fabricated on various types of substrates such as glass, plastic, and metal foil. FIG. 2 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may comprise a single layer or multiple layers.

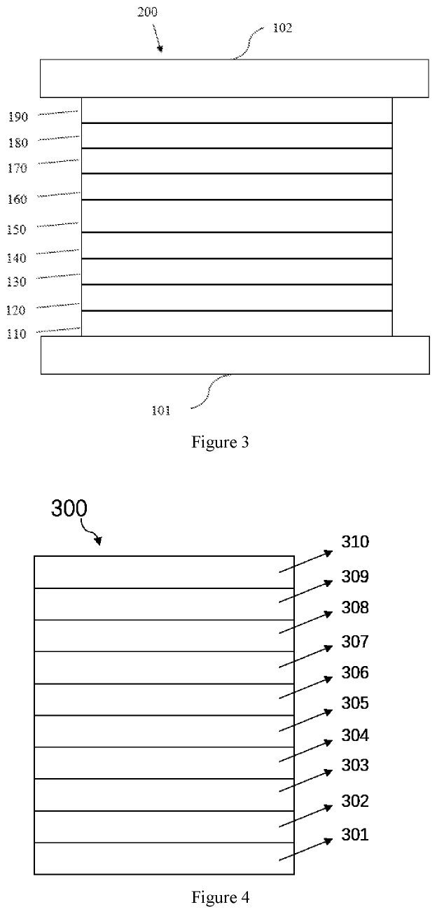

An OLED can be encapsulated by a barrier layer. FIG. 3 schematically shows an organic light emitting device 200 without limitation. FIG. 3 differs from FIG. 2 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

An “OLED device” may be bottom-emitting, that is, emitting light from the side of the substrate, top-emitting, that is, emitting light from the side of an encapsulation layer, or may be a transparent device, that is, emitting light from the side of the substrate and the side of the encapsulation layer at the same time.

The structure of a typical top-emitting OLED device is shown in FIG. 4. An OLED device 300 comprises an anode layer 301, a hole injection layer (HIL) 302, a hole transporting layer (HTL) 303, an electron blocking layer (EBL) 304 (also referred to as an emissive auxiliary layer or a prime layer), an emissive layer (EML) 305, a hole blocking layer (HBL) 306 (optional), an electron transporting layer (ETL) 307, an electron injection layer (EIL) 308, a cathode layer 309, and a capping layer 310. The anode layer 301 is a material or a material combination having a high reflectivity, including, but not limited to, Ag, Al, Ti, Cr, Pt, Ni, TiN, and a combination of the above materials with ITO and/or MoOx (molybdenum oxide). Generally, the reflectivity of the anode is greater than 50%; preferably, the reflectivity of the anode is greater than 70%; more preferably, the reflectivity of the anode is greater than 80%. The cathode layer 309 should be a translucent or transparent conductive material, including, but not limited to, a MgAg alloy, MoOx, Yb, Ca, ITO, IZO, or a combination thereof, and the average transmittance of the cathode layer for light having a wavelength in a visible light region is greater than 15%; preferably, the average transmittance of the cathode layer for light having a wavelength in the visible light region is greater than 20%; more preferably, the average transmittance of the cathode layer for light having a wavelength in the visible light region is greater than 25%.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

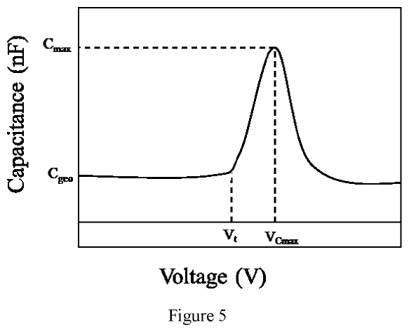

As used herein, unless otherwise specified, “capacitance” refers to the maximum internal capacitance of a device, that is, the maximum capacitance. Generally, the display industry pays more attention to the capacitance of an OLED device within a range of 100-1000 Hz. Capacitance data at 500 Hz is most commonly used. Therefore, the capacitance at 500 Hz is used herein. The “maximum capacitance” refers to a peak value which the device capacitance can reach as a test voltage increases at a particular frequency, as shown in FIG. 5.

As used herein, the term “effective emissive area” refers to an “effective emissive area” of a substrate X fabricated into a non-emissive device. The “effective emissive area” is equal to an emissive area of the same substrate X fabricated into an emissive device.

As used herein, an “emissive area” refers to a corresponding area in an organic electroluminescent device where the anode is in direct contact with organic layers and meanwhile the organic layers are in direct contact with the cathode in a direction perpendicular to the light emission surface. Herein, the emissive area in examples and comparative examples is 0.04 cm².

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small AES-T. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, t-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, a substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, a heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted alkylgermanyl having 3 to 20 carbon atoms, unsubstituted arylgermanyl having 6 to 20 carbon atoms, unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitution, up to the maximum available substitutions. When substitution in the compounds mentioned in the present disclosure represents multiple substitutions (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

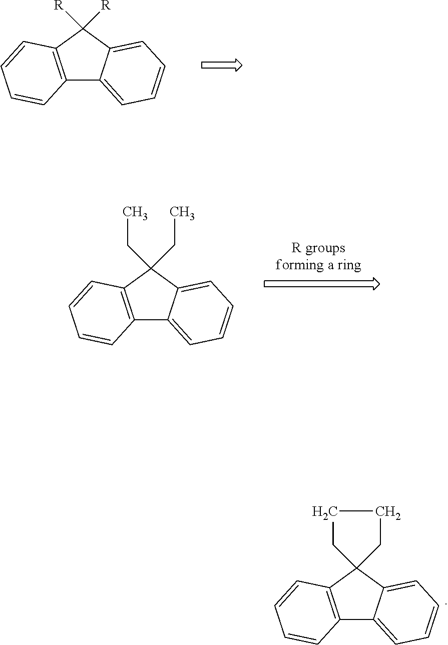

The expression that adjacent substituents can be optionally joined to form a ring is also intended to mean that two substituents bonded to carbon atoms which are directly bonded to each other are joined to each other via a chemical bond to form a ring, which can be exemplified by the following formula:

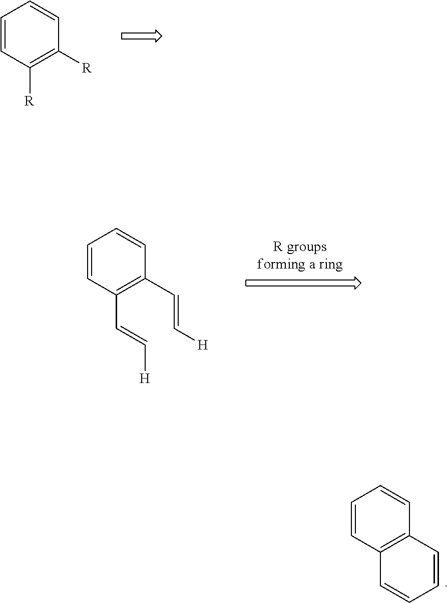

The expression that adjacent substituents can be optionally joined to form a ring is also intended to mean that two substituents bonded to further distant carbon atoms are joined to each other via a chemical bond to form a ring, which can be exemplified by the following formula:

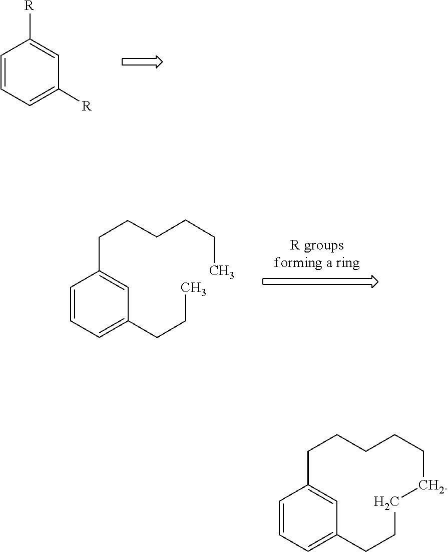

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

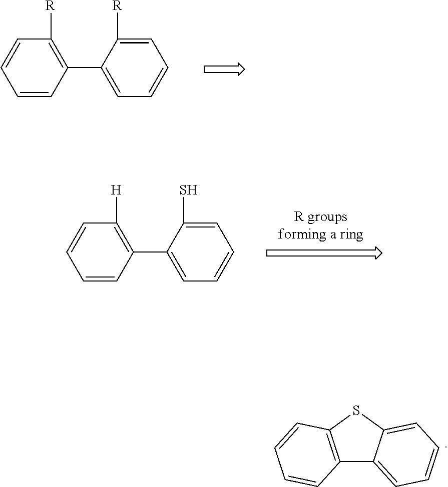

According to an embodiment of the present disclosure, an organic electroluminescent device is disclosed. The organic electroluminescent device comprises:
an anode,
a cathode,
an emissive layer disposed between the anode and the cathode, and
an electron blocking layer disposed between the anode and the emissive layer, wherein the electron blocking layer comprises an electron blocking material with a hole mobility μₕ≤65×10⁻⁵ cm²/(V·s);
capacitance of the organic electroluminescent device satisfies the following condition:
at 500 Hz, a maximum capacitance value of the organic electroluminescent device is Cₘₐₓ, and ΔC=C₀−Cₘₐₓ≥0.4 nF;
wherein C₀ denotes a maximum capacitance value of an organic electroluminescent device A at 500 Hz, and the organic electroluminescent device A is the same as the organic electroluminescent device except that the electron blocking material in the electron blocking layer of the organic electroluminescent device is replaced with Compound HT;
the Compound HT has the following structure:

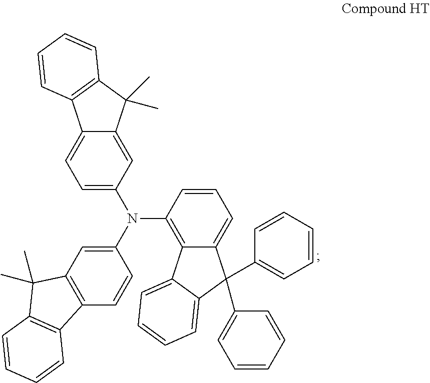 [SMILES: CC1(C)c2ccccc2-c2ccc(N(c3ccc4c(c3)C(C)(C)c3ccccc3-4)c3cccc4c3-c3ccccc3C4(c3ccccc3)c3ccccc3)cc21]

wherein the emissive layer satisfies the following conditions: a hole-only device comprising the emissive layer with a thickness of 400 Å has a drive voltage V_{HOD}@J10≤8.0 V at a current density of 10 mA/cm², and an electron-only device comprising the emissive layer with a thickness of 400 Å has a drive voltage V_{EOD}@J10≤8.0 V at a current density of 10 mA/cm²;
the hole-only device comprising the emissive layer with a thickness of 400 Å has the following structure:
ITO (1200 Å)/HTM:PD (with a weight ratio of 97:3, 100 Å)/HTM (400 Å)/HT-2 (50 Å)/the emissive layer (400 Å)/HTM (400 Å)/HTM:PD (with a weight ratio of 97:3, 100 Å)/Al (1200 Å);
the Compound HTM, the Compound PD, and the Compound HT-2 have the following structures:

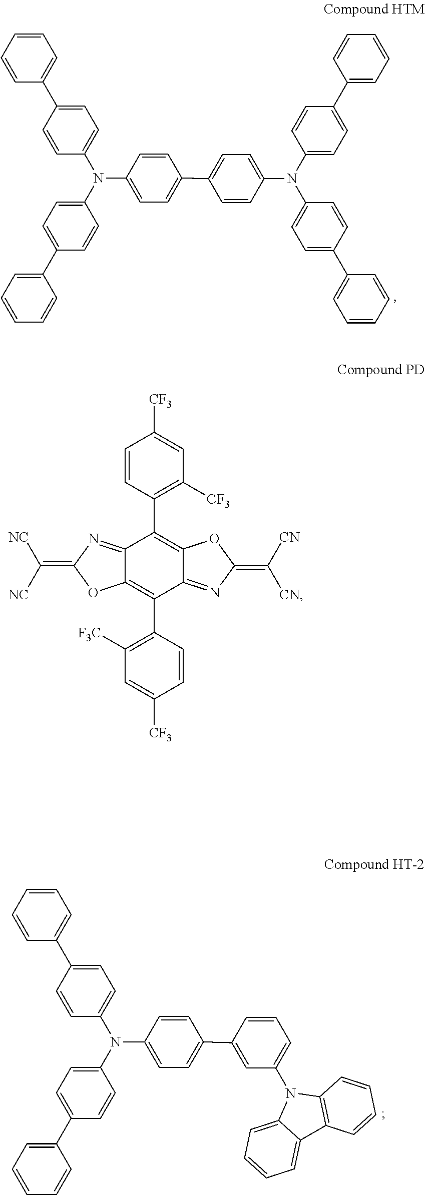 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2ccc(N(c3ccc(-c4ccccc4)cc3)c3ccc(-c4cccc(-n5c6ccccc6c6ccccc65)c4)cc3)cc2)cc1]

the electron-only device comprising the emissive layer with a thickness of 400 Å has the following structure:
ITO (1200 Å)/Liq (10 Å)/the emissive layer (400 Å)/ET:Liq (with a weight ratio of 40:60, 300 Å)/Liq (10 Å)/Al (1200 Å); and
the Compound ET and Liq have the following structures:

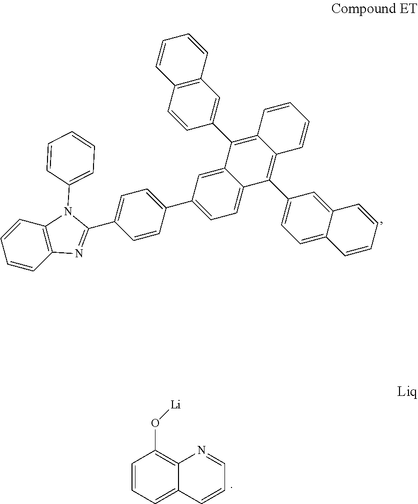

In this embodiment, the emissive layers in the hole-only device comprising the emissive layer and the electron-only device comprising the emissive layer use exactly the same materials and the same doping ratio of materials as the emissive layer in the organic electroluminescent device, but the emissive layers in the hole-only device comprising of the emissive layer and the electron-only device comprising the emissive layer have a thickness of 400 Å, and the thickness of the emissive layer in the organic electroluminescent device is not limited thereto.

In the present disclosure, the expression that “C₀ denotes a maximum capacitance value of an organic electroluminescent device A at 500 Hz, and the organic electroluminescent device A is the same as the organic electroluminescent device except that the electron blocking material in the electron blocking layer of the organic electroluminescent device is replaced with Compound HT” is intended to mean that: in the organic electroluminescent device claimed in the present disclosure (which may be referred to as an organic electroluminescent device Y) which has the electron blocking layer comprising the electron blocking material, the maximum capacitance value of the organic electroluminescent device Y measured at 500 Hz is Cₘₐₓ; in another organic electroluminescent device A which differs from the organic electroluminescent device Y only in that the electron blocking material in the electron blocking layer of the device Y is replaced with Compound HT, the maximum capacitance value of the organic electroluminescent device A measured at 500 Hz is C₀. The difference, Cₘₐₓ−C₀, described herein is a difference between the maximum capacitance of the organic electroluminescent device Y and the maximum capacitance of the organic electroluminescent device A. It is to be noted that the maximum capacitance value Cₘₐₓ of the organic electroluminescent device Y, the maximum capacitance value C₀ of the organic electroluminescent device A, and that ΔC=C₀−Cₘₐₓ≥0.4 nF are all values measured under the following condition: the emissive area of the organic electroluminescent device Y and the emissive area of the organic electroluminescent device A are both 0.04 cm². If the emissive area of the device changes, the corresponding maximum capacitance values C₀ and Cₘₐₓ and ΔC naturally change according to the rule that “a maximum capacitance value per unit of emissive area of the device=the maximum capacitance value/the emissive area”.

According to an embodiment of the present disclosure, the hole-only device comprising the emissive layer with a thickness of 400 Å has a drive voltage V_{HOD}@J10≤7.0 V at a current density of 10 mA/cm².

According to an embodiment of the present disclosure, the hole-only device comprising the emissive layer with a thickness of 400 Å has a drive voltage V_{HOD}@J10≤6.0 V at a current density of 10 mA/cm².

According to an embodiment of the present disclosure, the electron-only device comprising the emissive layer with a thickness of 400 Å has a drive voltage V_{EOD}@J10≤7.0 V at a current density of 10 mA/cm².

According to an embodiment of the present disclosure, the electron-only device comprising the emissive layer with a thickness of 400 Å has a drive voltage V_{EOD}@J10≤6.0 V at a current density of 10 mA/cm².

According to an embodiment of the present disclosure, the electron blocking material has a hole mobility μₕ≤50×10⁵ cm²/(V·s).

According to an embodiment of the present disclosure, the electron blocking material has a hole mobility μₕ≤40×10⁻⁵ cm²/(V·s).

According to an embodiment of the present disclosure, the electron blocking material has a hole mobility μₕ≥1×10⁻⁶ cm²/(V·s).

According to an embodiment of the present disclosure, the electron blocking material has a hole mobility μₕ≥1×10⁻⁵ cm²/(V·s).

According to an embodiment of the present disclosure, ΔC≥0.5 nF.

According to an embodiment of the present disclosure, ΔC≥0.8 nF.

According to an embodiment of the present disclosure, ΔC≥1.0 nF.

According to an embodiment of the present disclosure, at 500 Hz, the maximum capacitance value of the organic electroluminescent device is 0.5 nF≤Cₘₐₓ≤5.5 nF.

According to an embodiment of the present disclosure, the maximum capacitance value of the organic electroluminescent device is 1.0 nF≤Cₘₐₓ≤4.0 nF.

According to an embodiment of the present disclosure, the maximum capacitance value of the organic electroluminescent device is 1.0 nF≤Cₘₐₓ≤3.0 nF.

According to an embodiment of the present disclosure, the maximum capacitance value of the organic electroluminescent device is 1.0 nF≤Cₘₐₓ≤2.5 nF.

According to an embodiment of the present disclosure, the electron blocking layer has a thickness greater than or equal to 350 Å.

According to an embodiment of the present disclosure, the electron blocking layer has a thickness greater than or equal to 500 Å.

According to an embodiment of the present disclosure, the electron blocking layer has a thickness greater than or equal to 650 Å.

According to an embodiment of the present disclosure, the electron blocking layer has a thickness less than or equal to 1200 Å.

According to an embodiment of the present disclosure, the electron blocking layer has a thickness less than or equal to 1000 Å.

According to an embodiment of the present disclosure, the emissive layer satisfies that F≥0.8, wherein F=V_{EOD}@J10/V_{HOD}@J10.

According to an embodiment of the present disclosure, the emissive layer satisfies that F≥0.9, wherein F=V_{EOD}@J10/V_{HOD}@J10.

According to an embodiment of the present disclosure, the emissive layer satisfies that F≥1.0, wherein F=V_{EOD}@J10/V_{HOD}@J10.

According to an embodiment of the present disclosure, the organic electroluminescent device has a peak wavelength greater than or equal to 560 nm.

According to an embodiment of the present disclosure, the organic electroluminescent device has a peak wavelength greater than or equal to 580 nm.

According to an embodiment of the present disclosure, the organic electroluminescent device has a peak wavelength greater than or equal to 600 nm.

According to an embodiment of the present disclosure, the emissive layer comprises a first compound which is a metal complex comprising a metal M and a ligand La coordinated to the metal M, wherein the metal M is selected from a metal with a relative atomic mass greater than 40, and the ligand La has a structure represented by Formula 1:

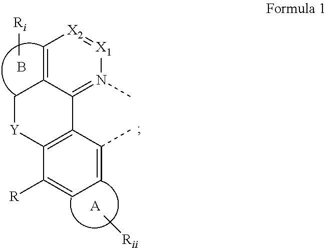

wherein the ring A and the ring B are each independently selected from a five-membered unsaturated carbocyclic ring, an aromatic ring having 6 to 30 carbon atoms, or a heteroaromatic ring having 3 to 30 carbon atoms;
Rᵢ and Rᵢᵢ represent, at each occurrence identically or differently, mono-substitution, multiple substitutions, or non-substitution;
Y is selected from SiR_{y}R_{y}, GeR_{y}R_{y}, NR_{y}, PR_{y}, O, S, or Se; when two R_{y} are present at the same time, the two R_{y} may be the same or different;
X₁ and X₂ are, at each occurrence identically or differently, selected from CRₓ or N;
R, Rᵢ, Rᵢᵢ, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R, Rᵢ, Rᵢᵢ, Rₓ, R_{y} can be optionally joined to form a ring.

In the present disclosure, the expression that “adjacent substituents R, Rᵢ, Rᵢᵢ, Rₓ, R_{y} can be optionally joined to form a ring” is intended to mean that any one or more of groups of adjacent substituents, such as two substituents Rₓ, two substituents R_{y}, two substituents Rᵢᵢ, substituents Rᵢ and Rₓ, substituents Rᵢ and R_{y}, substituents R and R_{y}, and substituents Rᵢ and Rᵢᵢ, can be joined to form a ring. Obviously, it is also possible that none of these substituents are joined to form a ring.

According to an embodiment of the present disclosure, in the ligand La of the first compound, the ring A and the ring B are each independently selected from a five-membered unsaturated carbocyclic ring, an aromatic ring having 6 to 18 carbon atoms, or a heteroaromatic ring having 3 to 18 carbon atoms.

According to an embodiment of the present disclosure, in the ligand La of the first compound, the ring A or the ring B is each independently selected from a five-membered unsaturated carbocyclic ring, an aromatic ring having 6 to 18 carbon atoms, or a heteroaromatic ring having 3 to 18 carbon atoms.

According to an embodiment of the present disclosure, in the ligand La of the first compound, the ring A and the ring B are each independently selected from a five-membered unsaturated carbocyclic ring, an aromatic ring having 6 to 10 carbon atoms, or a heteroaromatic ring having 3 to 10 carbon atoms.

According to an embodiment of the present disclosure, in the ligand La of the first compound, the ring A or the ring B is each independently selected from a five-membered unsaturated carbocyclic ring, an aromatic ring having 6 to 10 carbon atoms, or a heteroaromatic ring having 3 to 10 carbon atoms.

According to an embodiment of the present disclosure, in the first compound, the ligand La has a structure represented by Formula 1-1, Formula 1-2, or Formula 1-3:

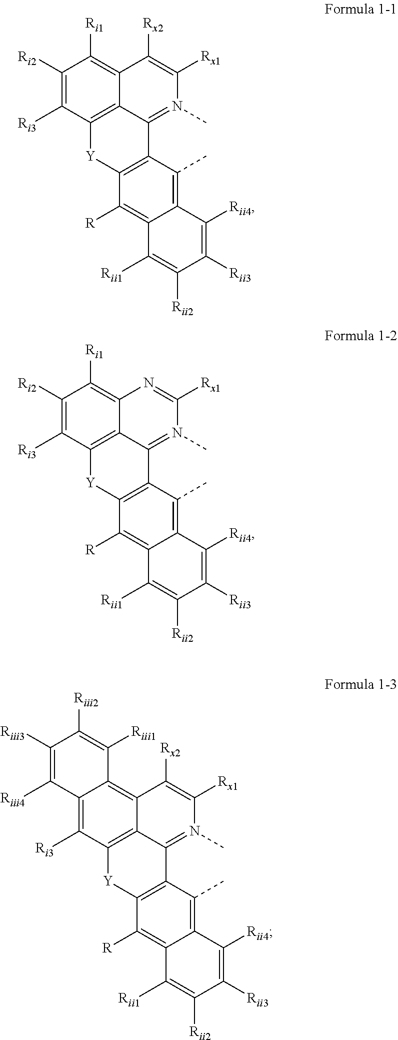

wherein Y is selected from O or S;
Rₓ₁, Rₓ₂, Rᵢ₁, Rᵢ₂, Rᵢ₃, Rᵢᵢ₁, Rᵢᵢ₂, Rᵢᵢ₃, Rᵢᵢ₄, Rᵢᵢᵢ₁, Rᵢᵢᵢ₂, Rᵢᵢᵢ₃, and Rᵢᵢᵢ₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof,
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, and combinations thereof, and
adjacent substituents Rₓ₁, Rₓ₂, Rᵢ₁, Rᵢ₂, Rᵢ₃, Rᵢ₁, Rᵢᵢ₂, Rᵢᵢ₃, Rᵢᵢ₄, Rᵢᵢᵢ₁, Rᵢᵢᵢ₂, Rᵢᵢᵢ₃, Rᵢᵢᵢ₄ can be optionally joined to form a ring.

According to an embodiment of the present disclosure, in the first compound, at least one or two of Rₓ₁, Rₓ₂, Rᵢ₁, Rᵢ₂, Rᵢ₃, Rᵢᵢ₁, Rᵢᵢ₂, Rᵢᵢ₃, Rᵢᵢ₄, Rᵢᵢᵢ₁, Rᵢᵢᵢ₂, Rᵢᵢᵢ₃, and Rᵢᵢᵢ₄ are, at each occurrence identically or differently, selected from deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof; and R is selected from halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof.

According to an embodiment of the present disclosure, in the first compound, at least one or two of Rₓ₁, Rₓ₂, Rᵢ₁, Rᵢ₂, Rᵢᵢ₁, Rᵢᵢ₂, Rᵢᵢ₃, Rᵢᵢ₄, Rᵢᵢᵢ₁, Rᵢᵢᵢ₂, Rᵢᵢᵢ₃, and Rᵢᵢᵢ₄ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof, and R is selected from substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof.

According to an embodiment of the present disclosure, La is, at each occurrence identically or differently, selected from the group consisting of Lₐ₁ to Lₐ₃₁₉, wherein the specific structures of Lₐ₁ to Lₐ₃₁₉ are referred to claim 12.

According to an embodiment of the present disclosure, hydrogens in the structures of Lₐ₁ to Lₐ₃₁₉ can be partially or fully substituted with deuterium.

According to an embodiment of the present disclosure, the first compound has a structure of M(Lₐ)ₘ(L_{b})ₙ(L_{c})_{q};
wherein the metal M is selected from a metal with a relative atomic mass greater than 40;
Lₐ, L_{b}, and L_{c} are a first ligand, a second ligand, and a third ligand of the metal complex, respectively; m is 1, 2, or 3, n is 0, 1, or 2, q is 0, 1, or 2, and m+n+q is equal to an oxidation state of the metal M; when m is greater than 1, multiple Lₐ are the same or different; when n is 2, two L_{b} are the same or different; when q is 2, two L_{c} are the same or different;
Lₐ, L_{b}, and L_{c} can be optionally joined to form a multidentate ligand;
L_{b} and L_{c} are, at each occurrence identically or differently, selected from the group consisting of the following structures:

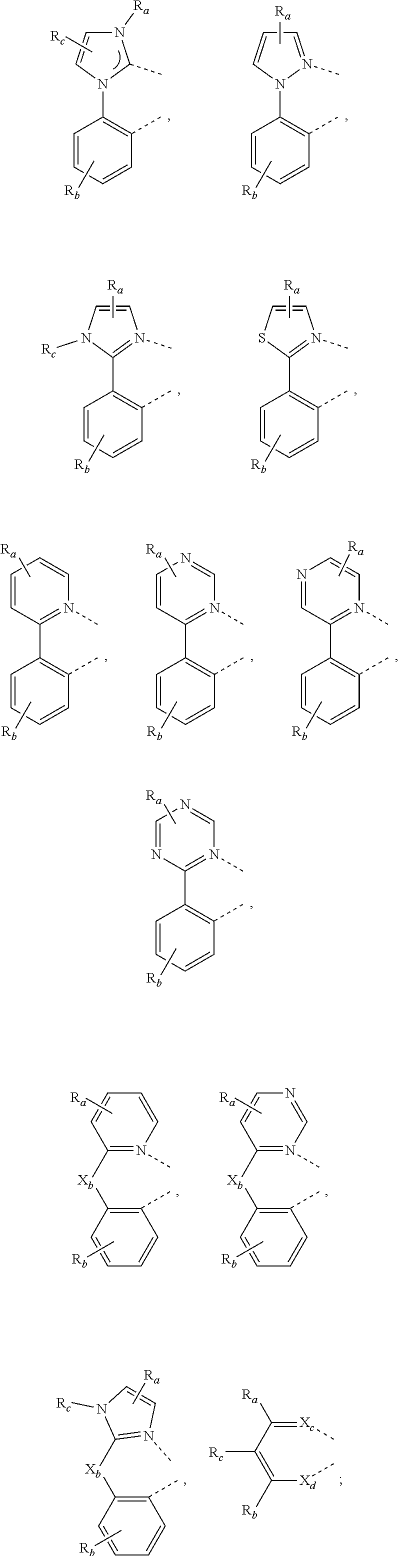

wherein Rₐ, R_{b}, and R_{c} represent, at each occurrence identically or differently, mono-substitution, multiple substitutions, or non-substitution;
X_{b} is, at each occurrence identically or differently, selected from the group consisting of: O, S, Se, NR_{N1}, and CR_{C1}R_{C2};
X_{c} and X_{d} are, at each occurrence identically or differently, selected from the group consisting of: O, S, Se, and NR_{N2};
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents Rₐ, R_{b}, R_{c}, R_{N1}, R_{N2}, R_{C1}, and R_{C2} can be optionally joined to form a ring.

In the present disclosure, the expression that “adjacent substituents it, R_{b}, R_{c}, R_{N1}, R_{N2}, R_{C1}, and R_{C2} can be optionally joined to form a ring” is intended to mean that any one or more of groups of adjacent substituents, such as two substituents Rₐ, two substituents R_{b}, two substituents R_{c}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, substituents Rₐ and R_{N2}, substituents R_{b} and R_{N2}, and substituents R_{C1} and R_{C2}, can be joined to form a ring. For example, adjacent substituents Rₐ and R_{b} in

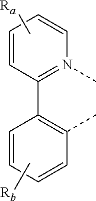

can be optionally joined to form a ring, which can form one or more of the following structures including, but not limited to,

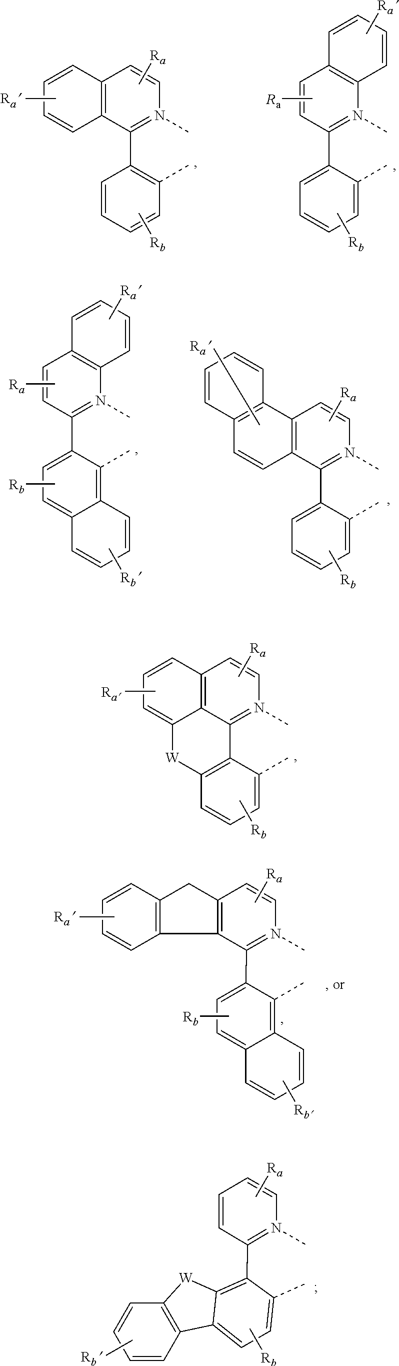

wherein W is selected from O, S, Se, NR_{w}, or CR_{w}R_{w}, and R_{w}, Rₐ′, and R_{b}′ are defined the same as Rₐ. Obviously, it is also possible that none of these substituents are joined to form a ring.

According to an embodiment of the present disclosure, the metal M is, at each occurrence identically or differently, selected from the group consisting of Cu, Ag, Au, Ru, Rh, Pd, Os, Ir, and Pt.

According to an embodiment of the present disclosure, the metal M is, at each occurrence identically or differently, selected from Pt or Ir.

According to an embodiment of the present disclosure, L_{b} is, at each occurrence identically or differently, selected from the following structure:

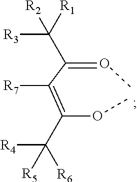

wherein R₁ to R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R₁, R₂, R₃, R₄, R₅, R₆, R₇ can be optionally joined to form a ring.

In the present disclosure, the expression that “adjacent substituents R₁, R₂, R₃, R₄, R₅, R₆, R₇ can be optionally joined to form a ring” is intended to mean that any one or more of groups of adjacent substituents, such as substituents R₁ and R₂, substituents R₁ and R₃, substituents R₂ and R₃, substituents R₄ and R₅, substituents R₄ and R₆, and substituents R₅ and R₆, can be joined to form a ring. Obviously, it is also possible that none of these substituents are joined to form a ring.

According to an embodiment of the present disclosure, at least one or two of R₁ to R₃ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, or a combination thereof; and/or at least one or two of R₄ to R₆ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, or a combination thereof.

According to an embodiment of the present disclosure, at least two of R₁ to R₃ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms, or a combination thereof; and/or at least two of R₄ to R₆ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms, or a combination thereof.

According to an embodiment of the present disclosure, L_{b} is, at each occurrence identically or differently, selected from the group consisting of L_{b1} to L_{b322}, wherein the specific structures of L_{b1} to L_{b322} are referred to claim 15.

According to an embodiment of the present disclosure, L_{c} is, at each occurrence identically or differently, selected from the group consisting of L_{c1} to L_{c231}, wherein the specific structures of L_{c1} to L_{c231} are referred to claim 15.

According to an embodiment of the present disclosure, the first compound has a structure of Ir(Lₐ)₂(L_{b}) or Ir(Lₐ)₂(L_{c}) or Ir(Lₐ)(L_{c})₂;
wherein when the first compound has a structure of Ir(Lₐ)₂(L_{b}), Lₐ is, at each occurrence identically or differently, selected from any one or any two of the group consisting of Lₐ₁ to Lₐ₃₁₉ and L_{b} is selected from any one of the group consisting of L_{b1} to L_{b322}; when the first compound has a structure of Ir(Lₐ)₂(L_{c}), Lₐ is, at each occurrence identically or differently, selected from any one or any two of the group consisting of Lₐ₁ to Lₐ₃₁₉ and L_{c} is selected from any one of the group consisting of L_{c1} to L_{c231}; and when the first compound has a structure of Ir(Lₐ)(L_{c})₂, Lₐ is selected from any one of the group consisting of Lₐ₁ to Lₐ₃₁₉ and L_{c} is, at each occurrence identically or differently, selected from any one or any two of the group consisting of L_{c1} to L_{c231}.

According to an embodiment of the present disclosure, the first compound is selected from the group consisting of Compound C₁ to Compound C₁₃₉ and Compound RD-1 to Compound RD-90, wherein the specific structures of Compound C₁ to Compound C₁₃₉ and Compound RD-1 to Compound RD-90 are referred to claim 16.

According to an embodiment of the present disclosure, the electron blocking material is a second compound having a structure represented by Formula 2-1 or Formula 2-2:

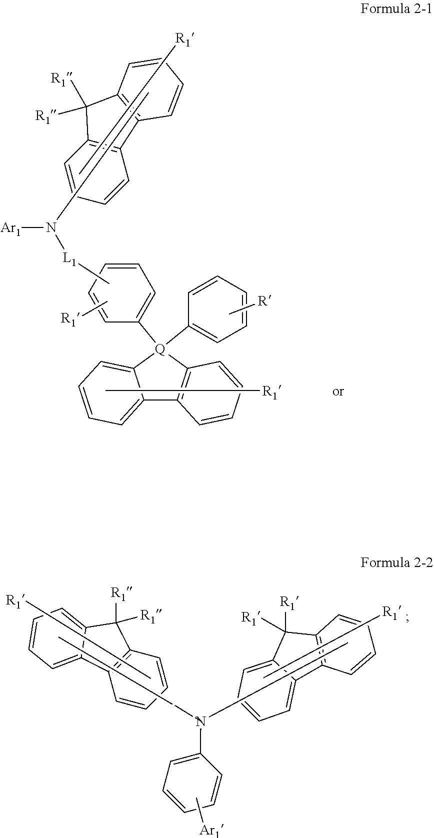

wherein Ar₁ and Ar₁′ are each independently selected from substituted or unsubstituted aryl having 6 to 30 carbon atoms, substituted or unsubstituted heteroaryl having 3 to 30 carbon atoms, or a combination thereof;
Ar₁′ and R₁′ represent, at each occurrence identically or differently, mono-substitution, multiple substitutions, or non-substitution;
L₁ is, at each occurrence identically or differently, selected from a single bond, substituted or unsubstituted arylene having 6 to 30 carbon atoms, substituted or unsubstituted heteroarylene having 3 to 30 carbon atoms, or a combination thereof,
Q is selected from C or Si;
R₁′ and R₁″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and adjacent substituents R₁′ can be optionally joined to form a ring.

In the present disclosure, the expression that “adjacent substituents R₁′ can be optionally joined to form a ring” is intended to mean that a group of adjacent substituents, such as two substituents R₁′, can be joined to form a ring. Obviously, it is also possible that none of these substituents are joined to form a ring.

According to an embodiment of the present disclosure, in Formula 2-1, Q is selected from Si.

According to an embodiment of the present disclosure, in the second compound, R₁′ is, at each occurrence identically or differently, selected from hydrogen, deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, or a combination thereof.

According to an embodiment of the present disclosure, in the second compound, R₁′ is, at each occurrence identically or differently, selected from hydrogen, deuterium, substituted or unsubstituted alkyl having 1 to 20 carbon atoms, or substituted or unsubstituted aryl having 6 to 30 carbon atoms.

According to an embodiment of the present disclosure, in the second compound, R₁″ is, at each occurrence identically or differently, selected from substituted or unsubstituted alkyl having 1 to 20 carbon atoms, substituted or unsubstituted aryl having 6 to 30 carbon atoms, substituted or unsubstituted heteroaryl having 3 to 30 carbon atoms, or a combination thereof.

According to an embodiment of the present disclosure, in the second compound, R₁″ is, at each occurrence identically or differently, selected from substituted or unsubstituted alkyl having 1 to 20 carbon atoms, substituted or unsubstituted aryl having 6 to 30 carbon atoms, or a combination thereof.

According to an embodiment of the present disclosure, in the second compound, Ar₁ and Ar₁′ are, at each occurrence identically or differently, selected from substituted or unsubstituted phenyl, substituted or unsubstituted biphenyl, substituted or unsubstituted terphenyl, substituted or unsubstituted naphthyl, substituted or unsubstituted fluorenyl, substituted or unsubstituted spirofluorenyl, substituted or unsubstituted silafluorenyl, substituted or unsubstituted spirosilafluorenyl, substituted or unsubstituted dibenzofuryl, substituted or unsubstituted dibenzothienyl, substituted or unsubstituted dibenzoselenophenyl, substituted or unsubstituted phenanthryl, substituted or unsubstituted triphenylenyl, substituted or unsubstituted pyridyl, substituted or unsubstituted carbazolyl, substituted or unsubstituted anthryl, substituted or unsubstituted pyrenyl, or a combination thereof.

According to an embodiment of the present disclosure, the second compound is selected from the group consisting of Compound C₁ to Compound C₁₈₄, wherein the specific structures of Compound C₁ to Compound C₁₈₄ are referred to claim 19.

According to an embodiment of the present disclosure, hydrogens in Compound C₁ to Compound C₁₈₄ can be partially or fully substituted with deuterium.

According to an embodiment of the present disclosure, the emissive layer further comprises a host material.

According to an embodiment of the present disclosure, the emissive layer further comprises a host material which is a third compound having a structure of H-L-E, wherein H has a structure represented by Formula 3:

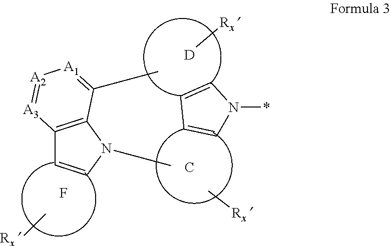

wherein in Formula 3, A₁, A₂, and A₃ are, at each occurrence identically or differently, selected from N or CR′, and the ring C, the ring D, and the ring F are, at each occurrence identically or differently, selected from a carbocyclic ring having 5 to 18 carbon atoms, a heterocyclic ring having 3 to 18 carbon atoms, or a heteroaromatic ring having 3 to 18 carbon atoms;
Rₓ′ represents, at each occurrence identically or differently, mono-substitution, multiple substitutions, or non-substitution;
E is selected from substituted or unsubstituted aryl having 6 to 30 carbon atoms or substituted or unsubstituted heteroaryl having 3 to 30 carbon atoms;
L is selected from a single bond, substituted or unsubstituted arylene having 6 to 30 carbon atoms, substituted or unsubstituted heteroarylene having 3 to 30 carbon atoms, or a combination thereof,
R′ and Rₓ′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R′, Rₓ′ can be optionally joined to form a ring.

In the present disclosure, the expression that “adjacent substituents R′, Rₓ′ can be optionally joined to form a ring” is intended to mean that any one or more of groups of adjacent substituents, such as adjacent substituents R′, adjacent substituents Rₓ′, and adjacent substituents R′ and Rₓ′, can be joined to form a ring. Obviously, for those skilled in the art, it is also possible that none of these groups of adjacent substituents are joined to form a ring.

According to an embodiment of the present disclosure, in the third compound, H has a structure represented by Formula 3-1:

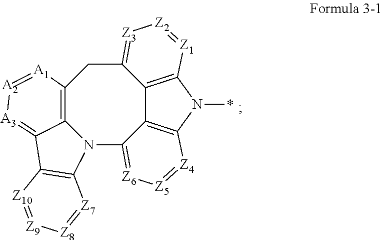

wherein A₁ to A₃ are, at each occurrence identically or differently, selected from N or CR′, and Z₁ to Z₁₀ are, at each occurrence identically or differently, selected from N or CRₓ′;
R′ and Rₓ′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R′, Rₓ′ can be optionally joined to form a ring.

In the present disclosure, the expression that “adjacent substituents R′, Rₓ′ can be optionally joined to form a ring” is intended to mean that adjacent substituents R′ can be optionally joined to form a ring, that adjacent substituents Rₓ′ in Z₁ to Z₃ can be optionally joined to form a ring, that adjacent substituents Rₓ′ in Z₄ to Z₆ can be optionally joined to form a ring, that adjacent substituents Rₓ′ in Z₇ to Z₁₀ can be optionally joined to form a ring, and that adjacent substituents R′ and Rₓ′ can be optionally joined to form a ring, for example, adjacent substituents in A₁ and Z₃, and/or A₃ and Z₁₀, and/or Z₆ and Z₇ can be optionally joined to form a ring. Obviously, for those skilled in the art, it is also possible that adjacent substituents R′, Rₓ′ are not joined to form a ring. In this case, adjacent substituents R′ are not joined to form a ring, and/or adjacent substituents Rₓ′ are not joined to form a ring, and/or adjacent substituents R′ and Rₓ′ are not joined to form a ring.

According to an embodiment of the present disclosure, in the third compound, R′ and Rₓ′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, a cyano group, an isocyano group, a hydroxyl group, a sulfanyl group, and combinations thereof.

According to an embodiment of the present disclosure, in the third compound, at least one of R′ and Rₓ′ is selected from deuterium, halogen, cyano, hydroxyl, sulfanyl, substituted or unsubstituted alkyl having 1 to 20 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, or a combination thereof, and
adjacent substituents R′, Rₓ′ can be optionally joined to form a ring.

According to an embodiment of the present disclosure, in the third compound, at least one of R′ and Rₓ′ is selected from deuterium, fluorine, cyano, hydroxyl, sulfanyl, methyl, trideuteromethyl, vinyl, phenyl, biphenyl, naphthyl, 4-cyanophenyl, dibenzofuryl, dibenzothienyl, triphenylenyl, carbazolyl, 9-phenylcarbazolyl, 9,9-dimethylfluorenyl, pyridyl, phenylpyridyl, or a combination thereof.

According to an embodiment of the present disclosure, in the third compound, H is selected from the group consisting of the following structures:

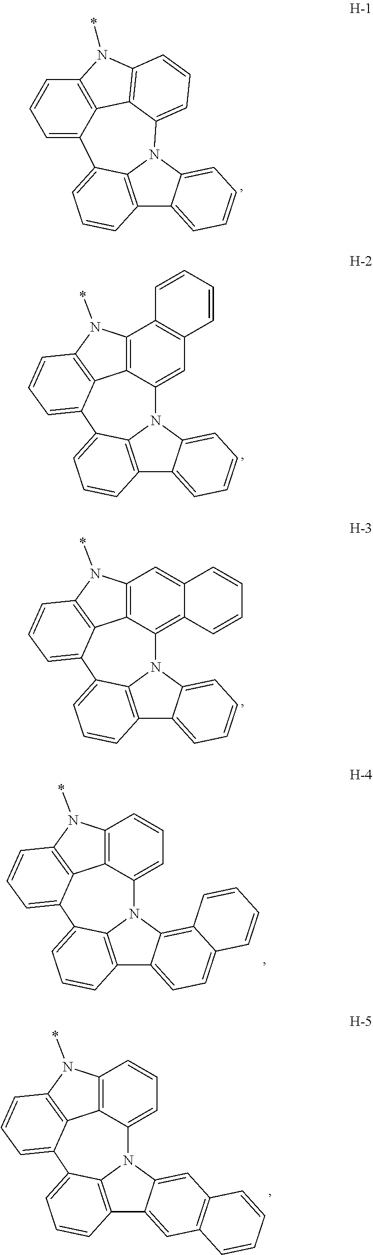

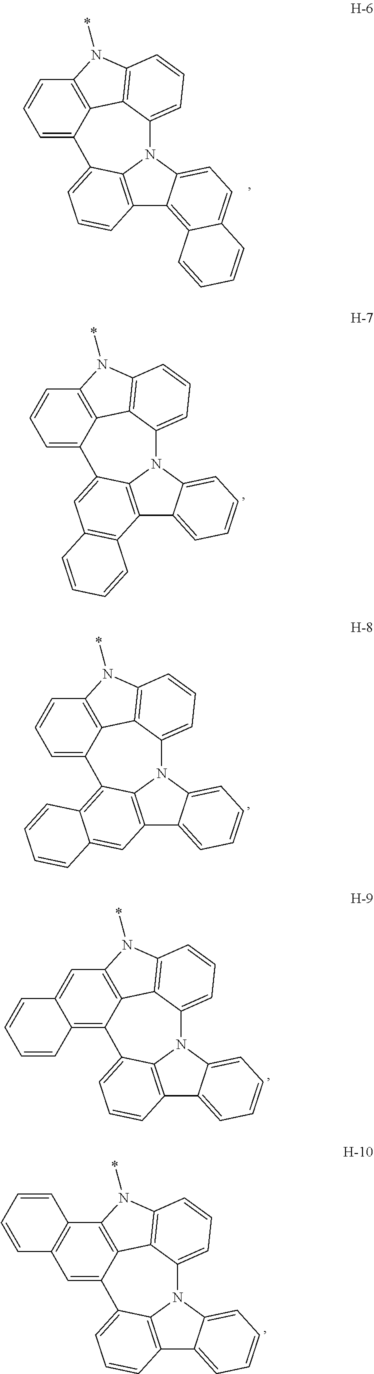

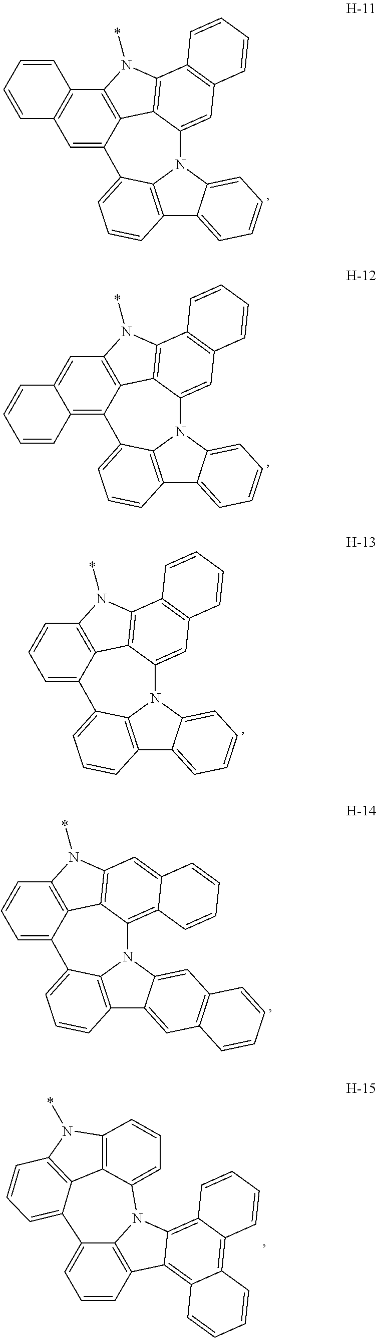

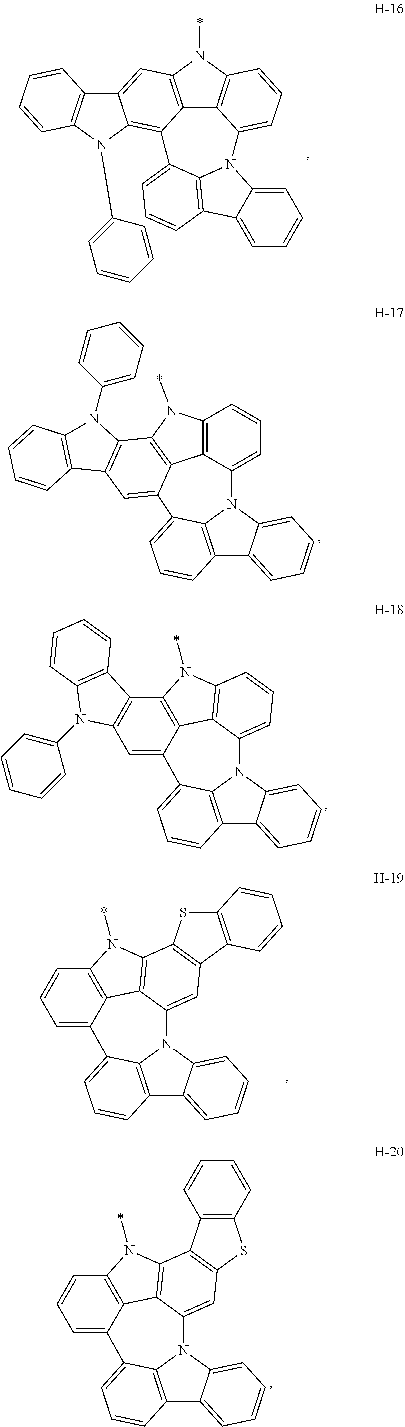

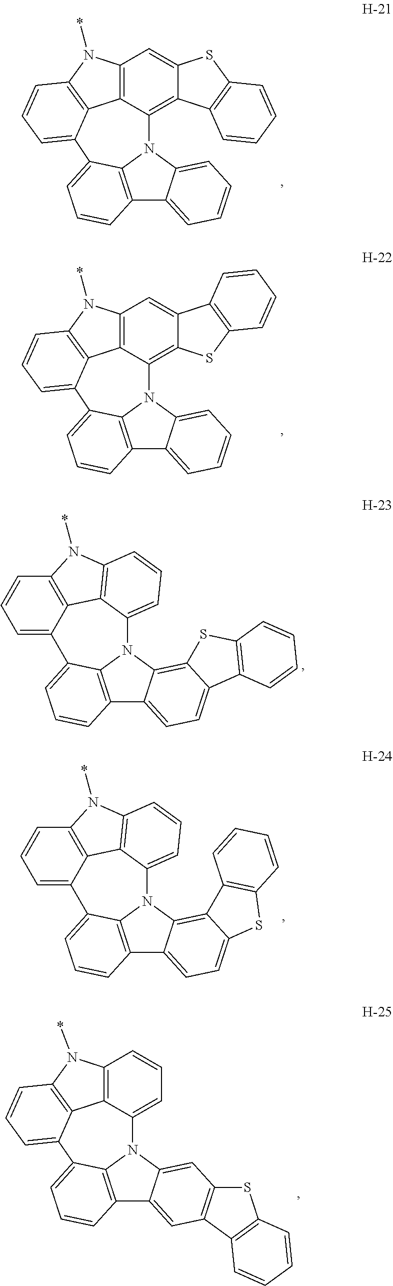

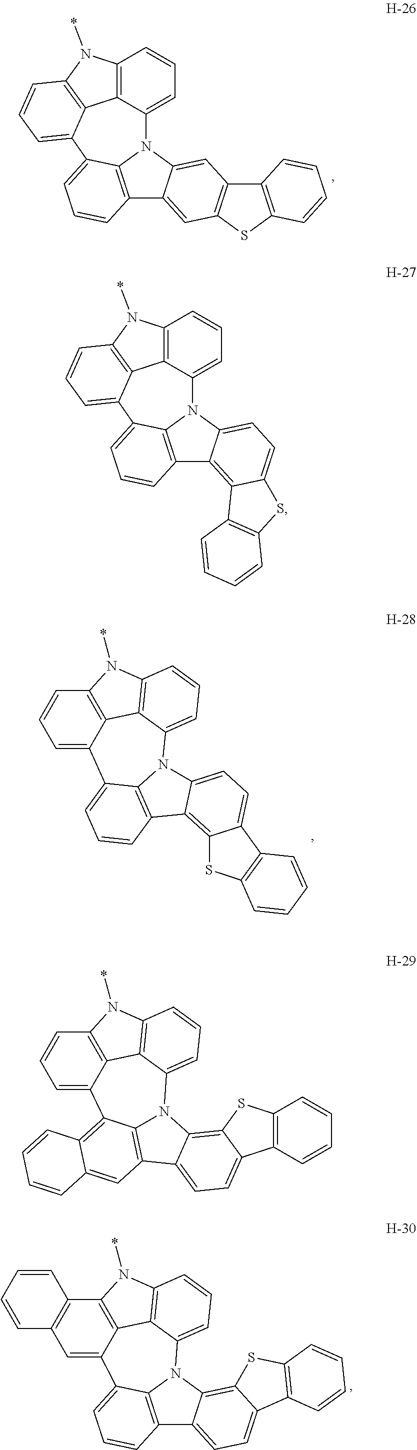 [SMILES: *n1c2cccc3c4cccc5c6cc7sc8ccccc8c7cc6n(c6cccc1c6c32)c45 ; *n1c2cccc3c4cccc5c6c7c(ccc6n(c6cccc1c6c32)c45)sc1ccccc17 ; *n1c2cccc3c4cccc5c6c7sc8ccccc8c7ccc6n(c6cccc1c6c32)c45 ; *n1c2cccc3c2c2c1cccc2n1c2c(ccc4c5ccccc5sc42)c2cc4ccccc4c3c21 ; *n1c2cccc3c2c2c(cc4ccccc4c21)c1cccc2c4ccc5c6ccccc6sc5c4n3c12]

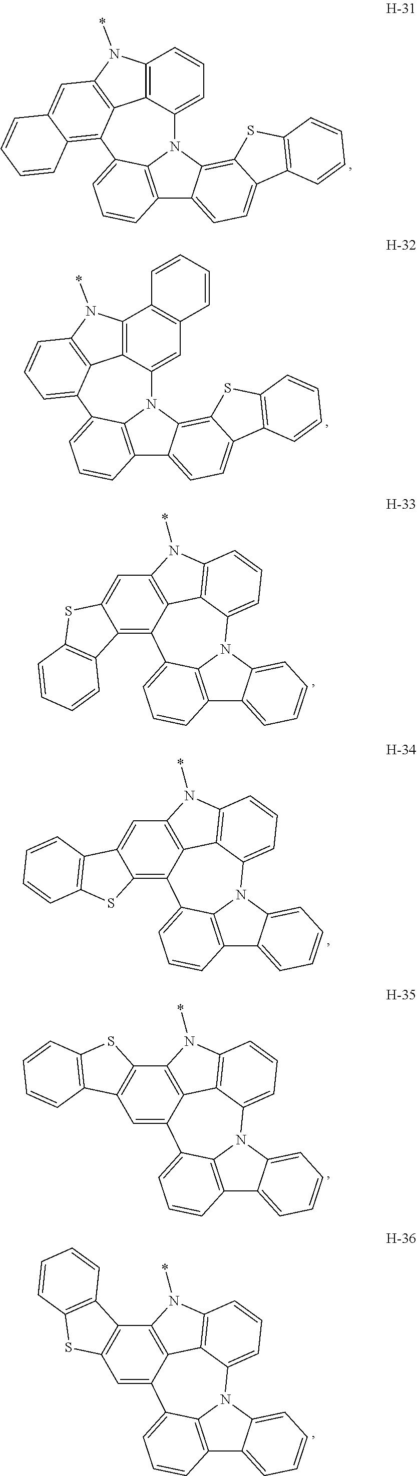

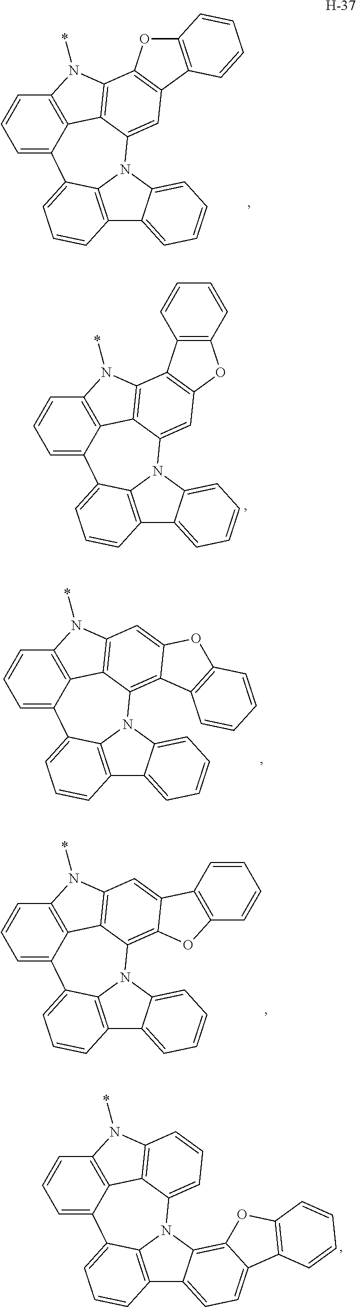

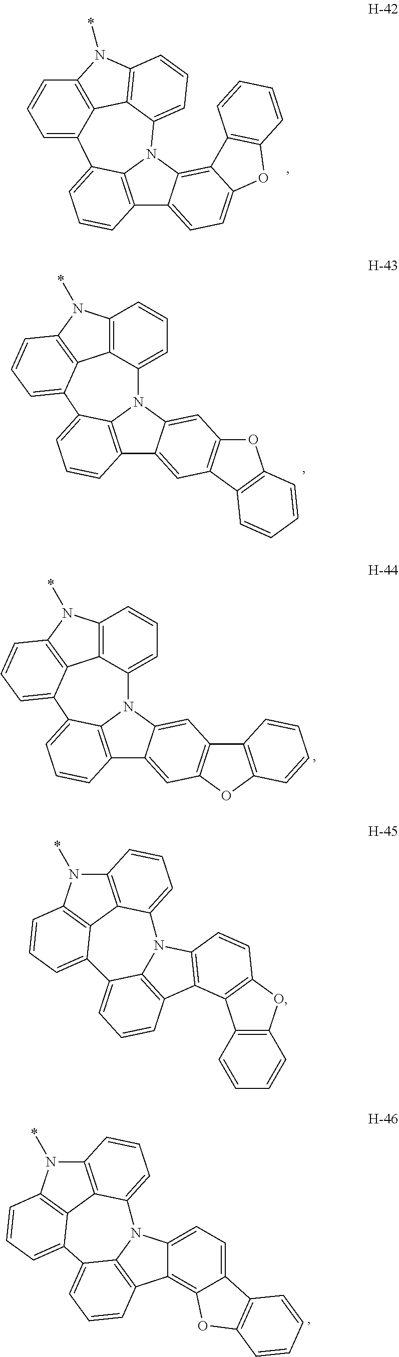 [SMILES: *n1c2cccc3c4cccc5c6ccc7oc8ccccc8c7c6n(c6cccc1c6c32)c45 ; *n1c2cccc3c4cccc5c6cc7c(cc6n(c6cccc1c6c32)c45)oc1ccccc17 ; *n1c2cccc3c4cccc5c6cc7oc8ccccc8c7cc6n(c6cccc1c6c32)c45 ; *n1c2cccc3c4cccc5c6c7c(ccc6n(c6cccc1c6c32)c45)oc1ccccc17 ; *n1c2cccc3c4cccc5c6c7oc8ccccc8c7ccc6n(c6cccc1c6c32)c45]

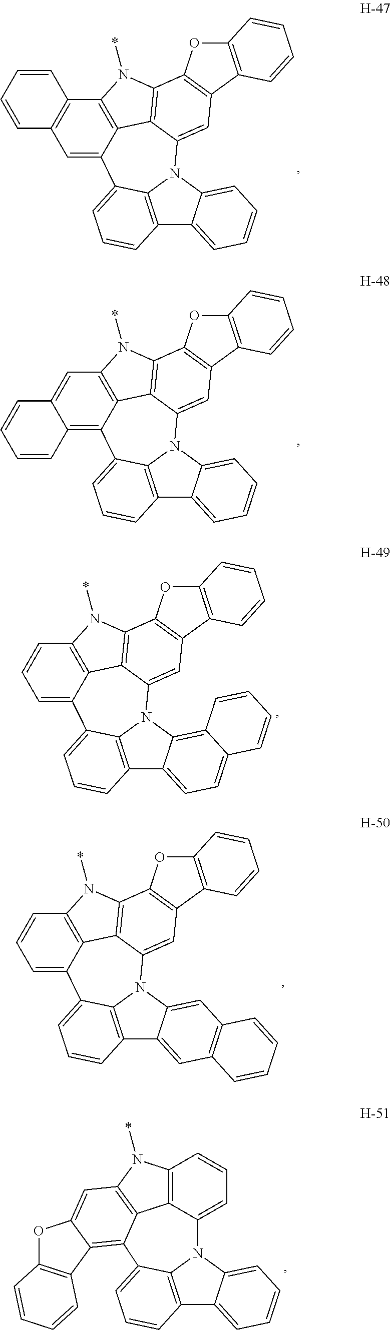

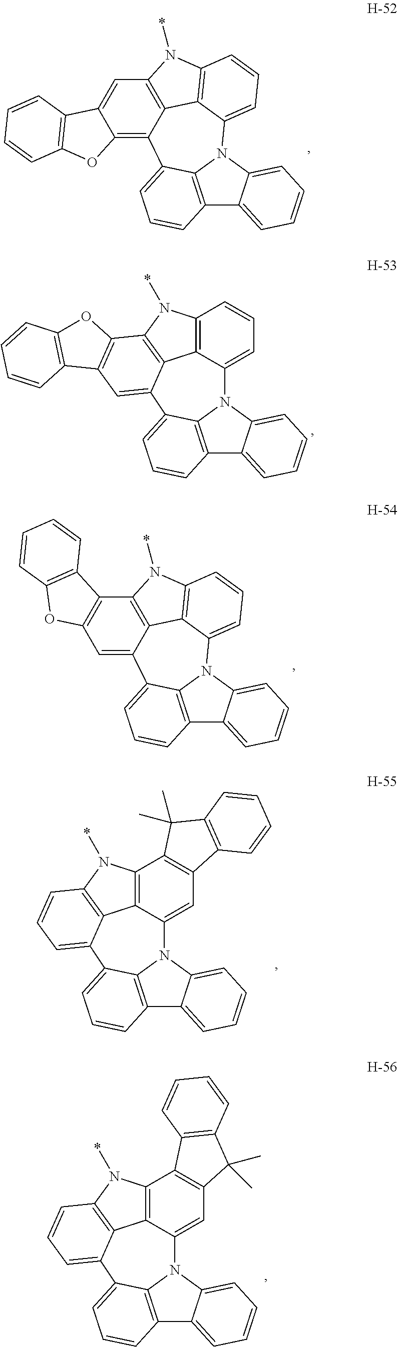

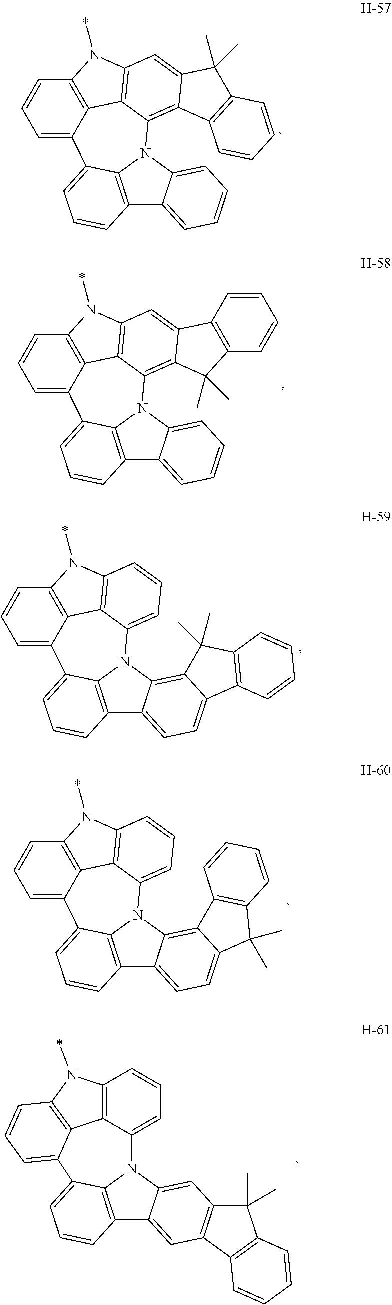 [SMILES: *n1c2cccc3c4cccc5c6ccccc6n(c6c7c(cc1c6c32)C(C)(C)c1ccccc1-7)c45 ; *n1c2cccc3c4cccc5c6ccccc6n(c6c7c(cc1c6c32)-c1ccccc1C7(C)C)c45 ; *n1c2cccc3c4cccc5c6ccc7c(c6n(c6cccc1c6c32)c45)C(C)(C)c1ccccc1-7 ; *n1c2cccc3c4cccc5c6ccc7c(c6n(c6cccc1c6c32)c45)-c1ccccc1C7(C)C ; *n1c2cccc3c4cccc5c6cc7c(cc6n(c6cccc1c6c32)c45)C(C)(C)c1ccccc1-7]

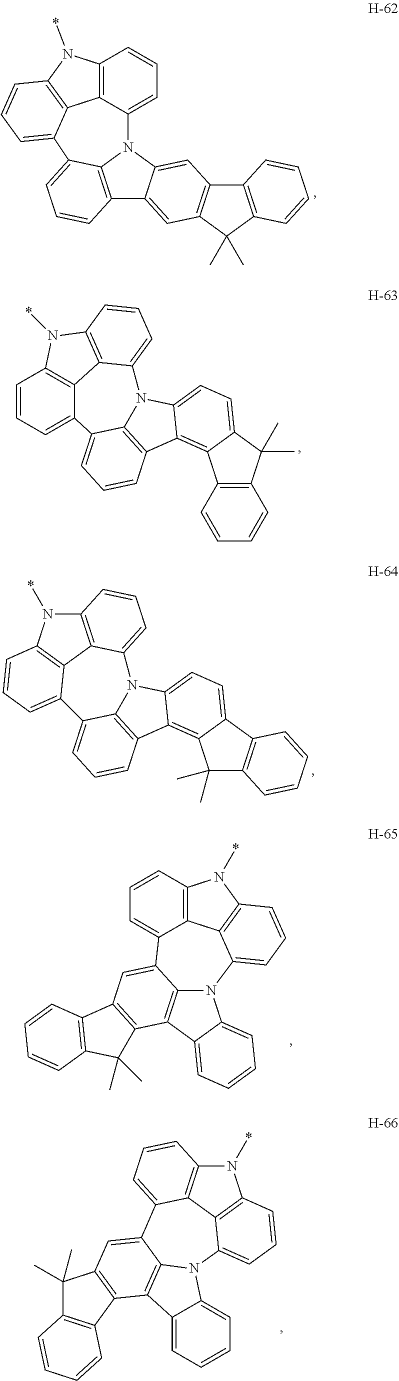

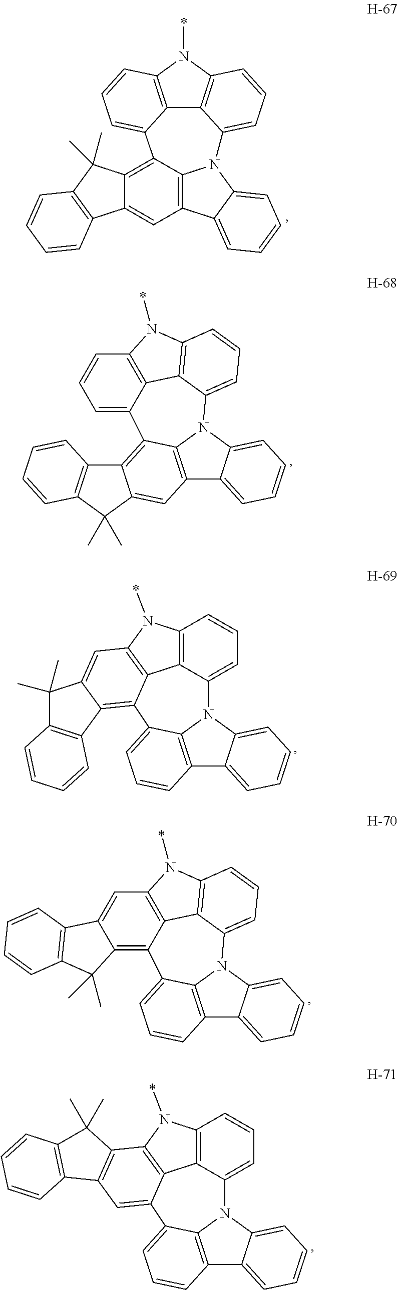

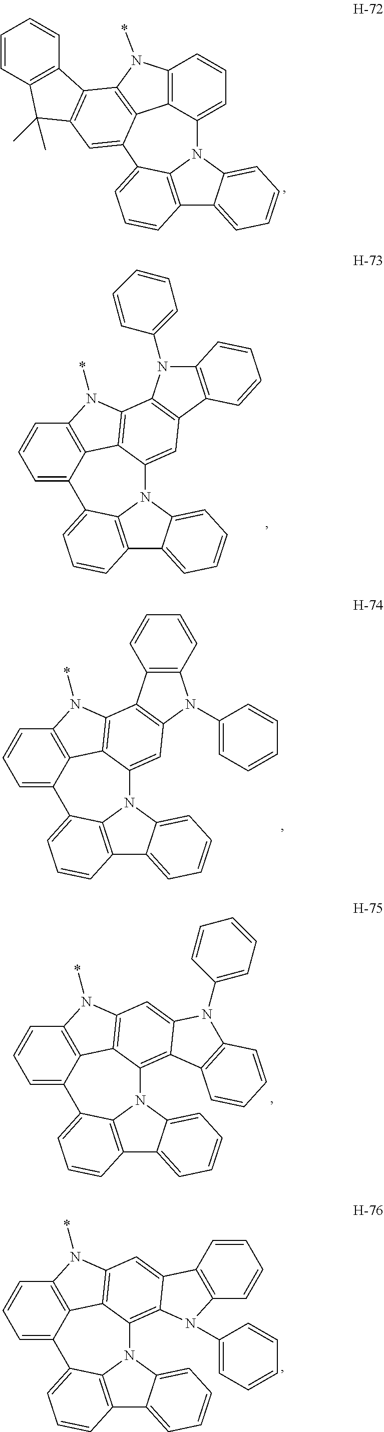

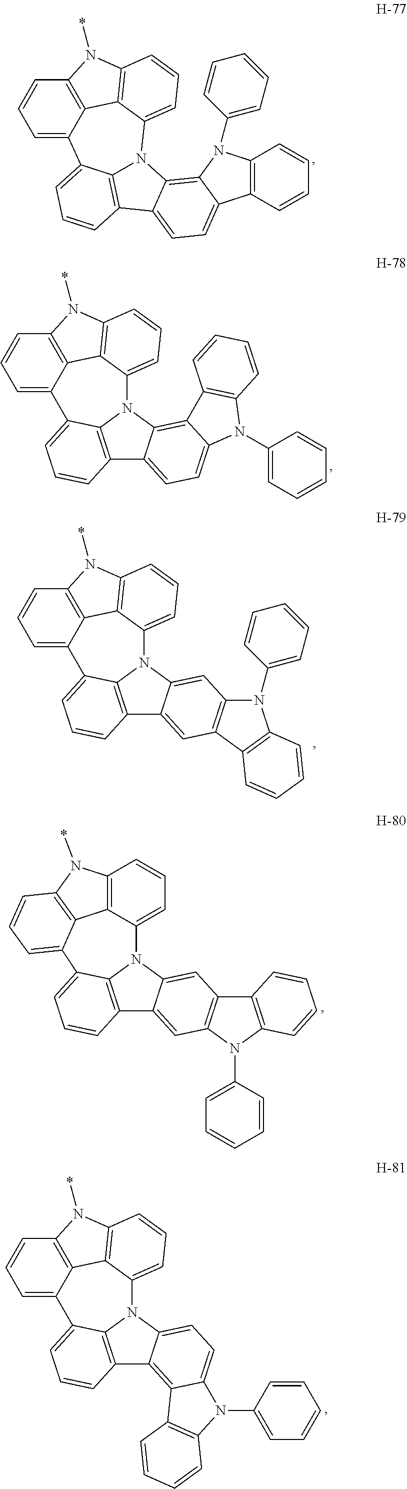 [SMILES: *n1c2cccc3c4cccc5c6ccc7c8ccccc8n(-c8ccccc8)c7c6n(c6cccc1c6c32)c45 ; *n1c2cccc3c4cccc5c6ccc7c(c8ccccc8n7-c7ccccc7)c6n(c6cccc1c6c32)c45 ; *n1c2cccc3c4cccc5c6cc7c8ccccc8n(-c8ccccc8)c7cc6n(c6cccc1c6c32)c45 ; *n1c2cccc3c4cccc5c6cc7c(cc6n(c6cccc1c6c32)c45)c1ccccc1n7-c1ccccc1 ; *n1c2cccc3c4cccc5c6c7c8ccccc8n(-c8ccccc8)c7ccc6n(c6cccc1c6c32)c45]

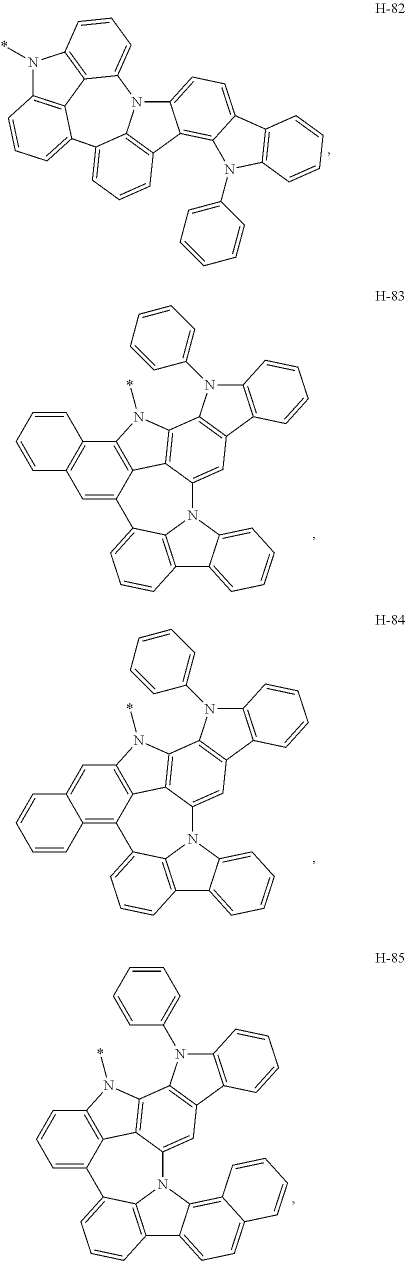

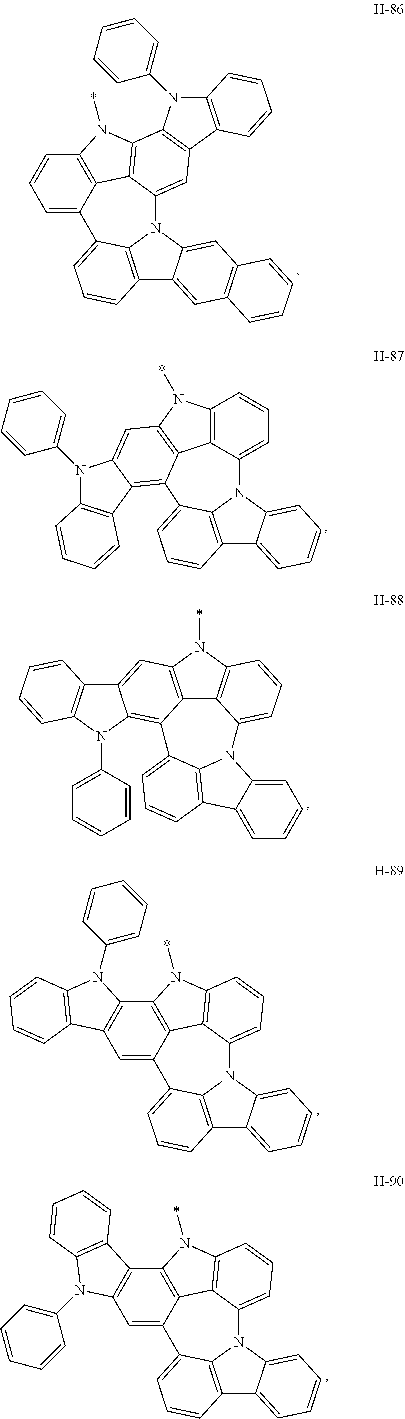

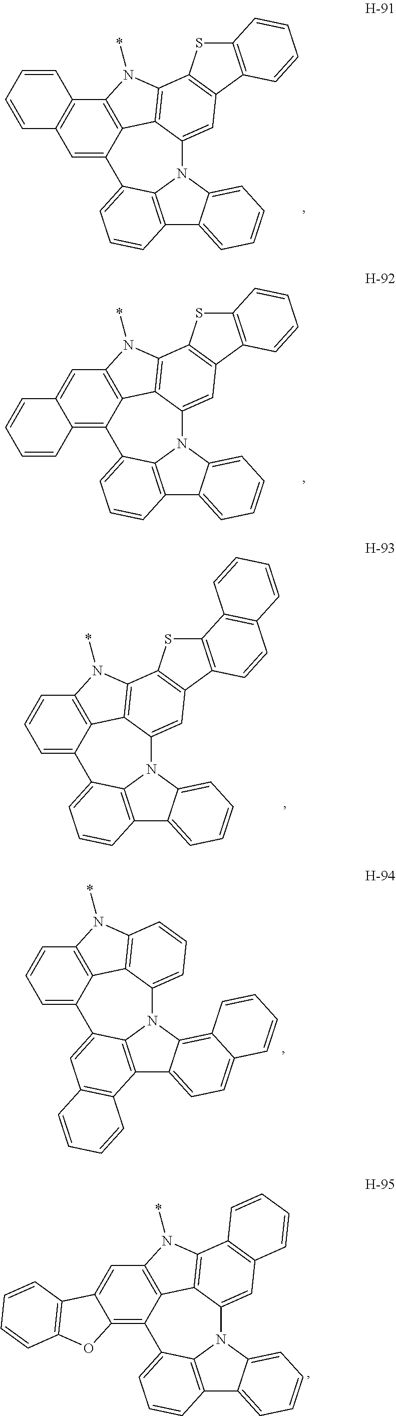

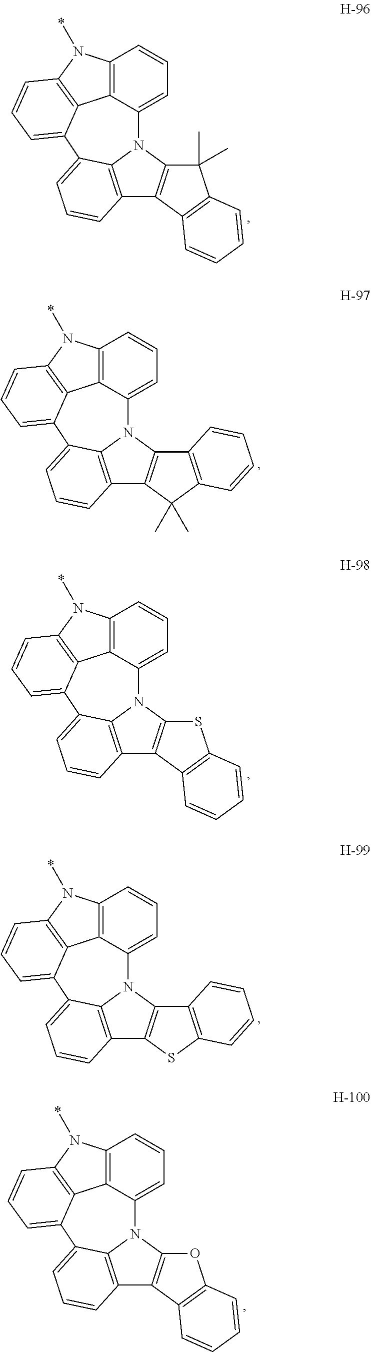 [SMILES: *n1c2cccc3c4cccc5c6c(n(c7cccc1c7c32)c54)C(C)(C)c1ccccc1-6 ; *n1c2cccc3c4cccc5c6c(n(c7cccc1c7c32)c54)-c1ccccc1C6(C)C ; *n1c2cccc3c4cccc5c6c7ccccc7sc6n(c6cccc1c6c32)c45 ; *n1c2cccc3c4cccc5c6sc7ccccc7c6n(c6cccc1c6c32)c45 ; *n1c2cccc3c4cccc5c6c7ccccc7oc6n(c6cccc1c6c32)c45]

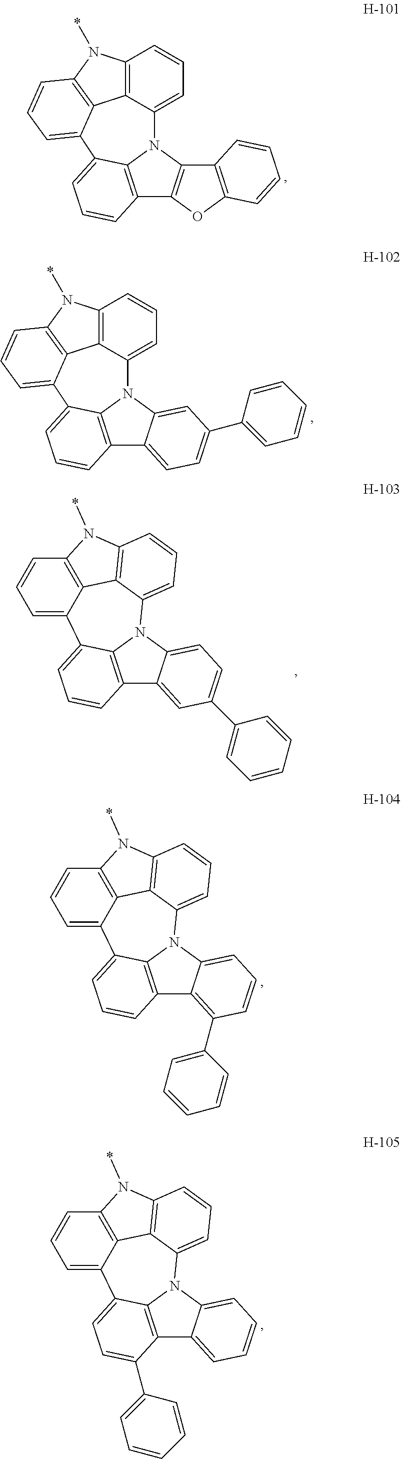

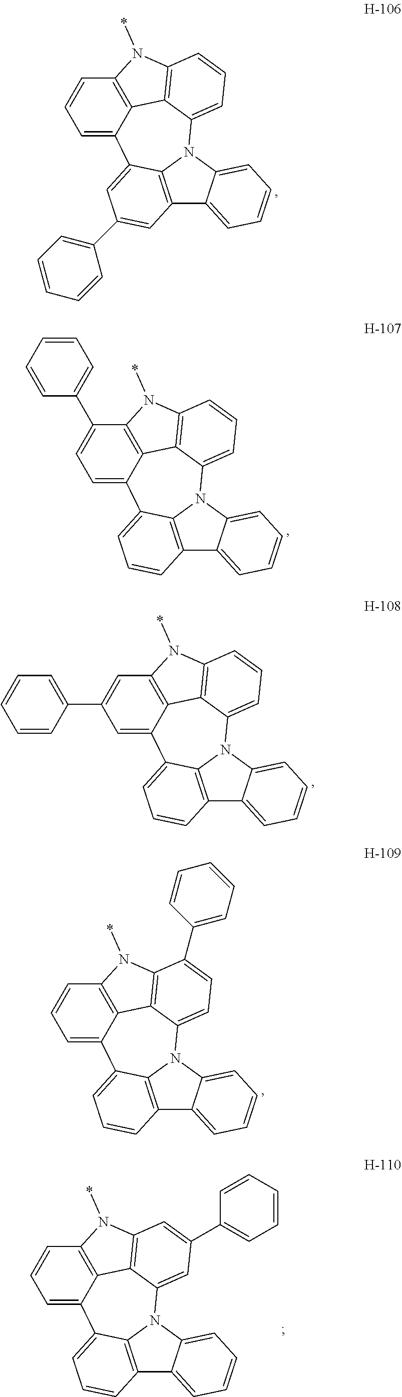

wherein “*” represents a position where L is joined in the structures of H-1 to H-110.

According to an embodiment of the present disclosure, hydrogens in the structures of H-1 to H-110 can be partially or fully substituted with deuterium.

According to an embodiment of the present disclosure, in the third compound, E has a structure represented by Formula E-a or Formula E-b:

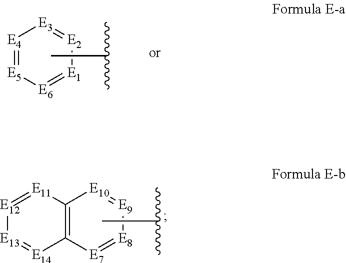

wherein E₁ to E₁₄ are, at each occurrence identically or differently, selected from C, CRₑ, or N;
Rₑ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents Rₑ can be optionally joined to form a ring.

In this embodiment, “ [symbol] ” represents a position where L is joined in the structure of E.

In this embodiment, in Formula E-a, one of E₁ to E₆ is C and joined to L; in Formula E-b, one of E₇ to E₁₄ is C and joined to L.

In this embodiment, the expression that “adjacent substituents Rₑ can be optionally joined to form a ring” is intended to mean that any adjacent substituents Rₑ can be joined to form a ring. Obviously, it is also possible that any adjacent substituents Rₑ are not joined to form a ring.

According to an embodiment of the present disclosure, in Formula E-a, three of E₁ to E₆ are N; in Formula E-b, two of E₇ to E₁₀ are N.

According to an embodiment of the present disclosure, in the third compound, E has a structure represented by any one of Formula E-1 to Formula E-11:

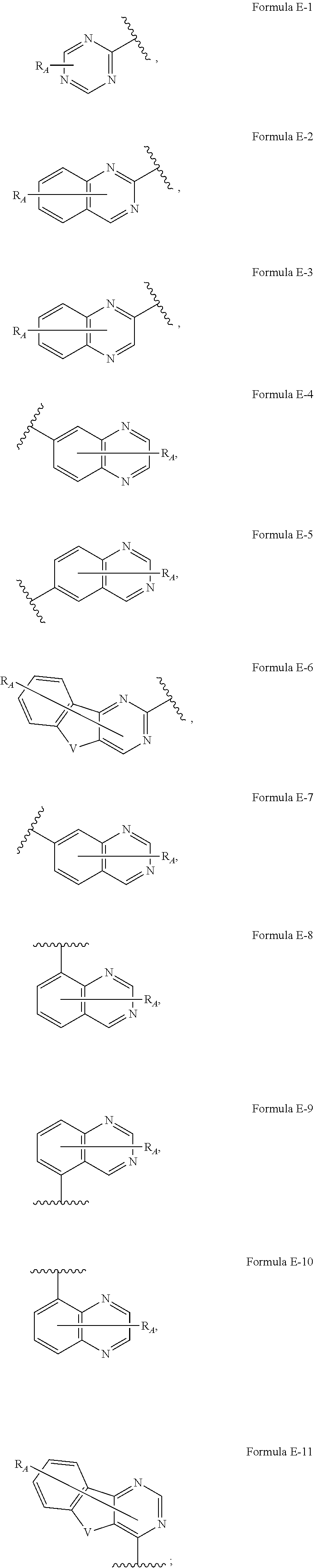

wherein R_{A} represents, at each occurrence identically or differently, mono-substitution, multiple substitutions, or non-substitution;
V is selected from O, S, or Se;
R_{A} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof, and
adjacent substituents R_{A} can be optionally joined to form a ring.

In this embodiment, “ [symbol] ” represents a position where L is joined in the structure of E.

According to an embodiment of the present disclosure, in Formula E-1 to Formula E-11, R_{A} is, at each occurrence identically or differently, selected from the group consisting of: hydrogen, deuterium, halogen, cyano, hydroxyl, sulfanyl, substituted or unsubstituted alkyl having 1 to 20 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, and combinations thereof, and
adjacent substituents R_{A} can be optionally joined to form a ring.

According to an embodiment of the present disclosure, in Formula E-1 to Formula E-11, R_{A} is, at each occurrence identically or differently, selected from the group consisting of: hydrogen, deuterium, fluorine, cyano, hydroxyl, sulfanyl, methyl, trideuteromethyl, vinyl, phenyl, biphenyl, naphthyl, 4-cyanophenyl, dibenzofuryl, dibenzothienyl, triphenylenyl, carbazolyl, 9-phenylcarbazolyl, 9,9-dimethylfluorenyl, pyridyl, phenylpyridyl, and combinations thereof.

According to an embodiment of the present disclosure, in Formula E-1 to Formula E-11, at least one R_{A} exists, and R_{A} is, at each occurrence identically or differently, selected from the group consisting of: deuterium, halogen, cyano, hydroxyl, sulfanyl, substituted or unsubstituted alkyl having 1 to 20 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, and combinations thereof, and
adjacent substituents R_{A} can be optionally joined to form a ring.

According to an embodiment of the present disclosure, in Formula E-1 to Formula E-11, at least one R_{A} exists, and R_{A} is, at each occurrence identically or differently, selected from the group consisting of: deuterium, fluorine, cyano, methyl, trideuteromethyl, phenyl, biphenyl, naphthyl, 4-cyanophenyl, dibenzofuryl, dibenzothienyl, triphenylenyl, carbazolyl, 9-phenylcarbazolyl, 9,9-dimethylfluorenyl, pyridyl, phenylpyridyl, and combinations thereof.

According to an embodiment of the present disclosure, in the third compound, E is selected from the group consisting of the following structures:

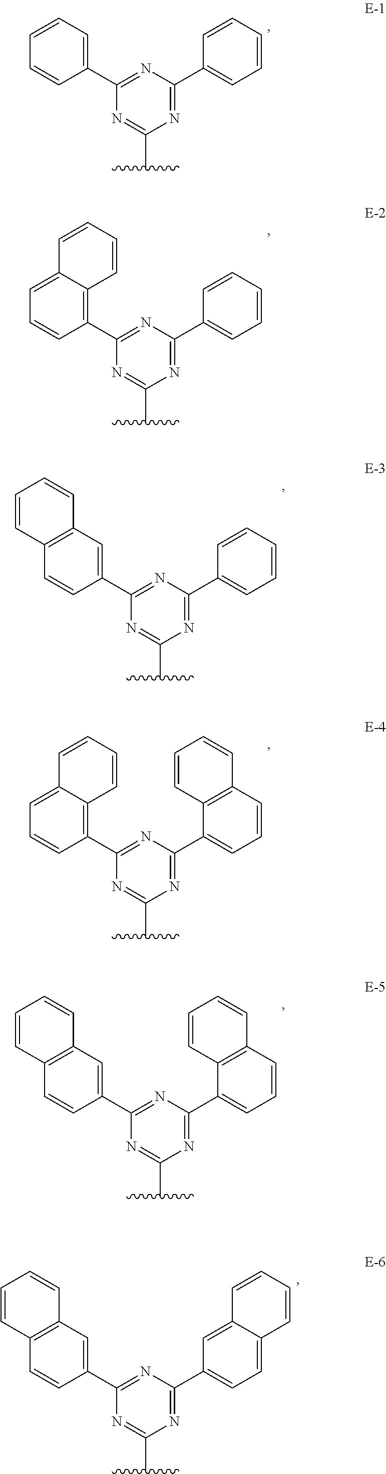 [SMILES: *c1nc(-c2ccccc2)nc(-c2ccccc2)n1 ; *c1nc(-c2ccccc2)nc(-c2cccc3ccccc23)n1 ; *c1nc(-c2ccccc2)nc(-c2ccc3ccccc3c2)n1 ; *c1nc(-c2cccc3ccccc23)nc(-c2cccc3ccccc23)n1 ; *c1nc(-c2ccc3ccccc3c2)nc(-c2cccc3ccccc23)n1 ; *c1nc(-c2ccc3ccccc3c2)nc(-c2ccc3ccccc3c2)n1]

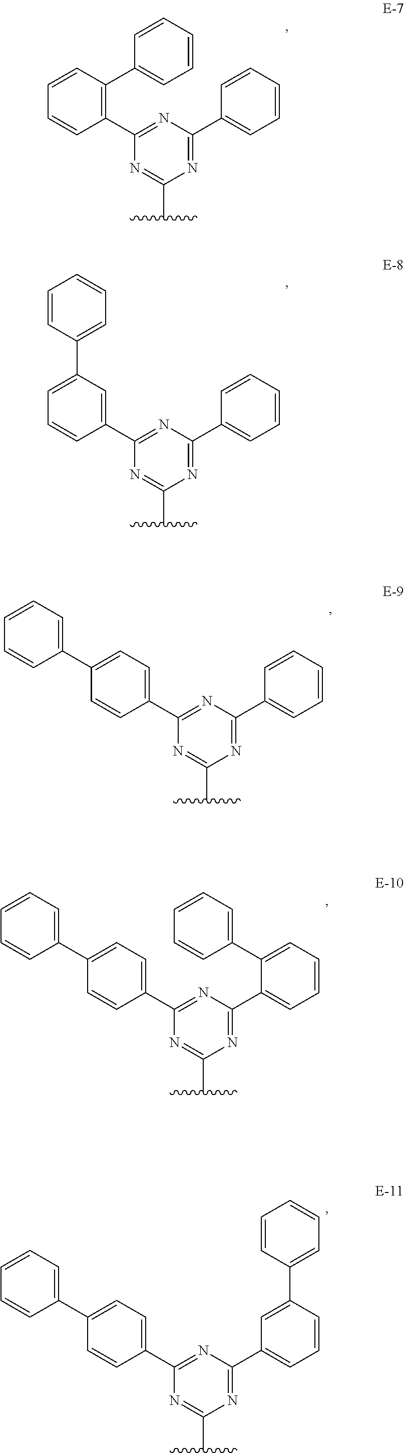 [SMILES: *c1nc(-c2ccccc2)nc(-c2ccccc2-c2ccccc2)n1 ; *c1nc(-c2ccccc2)nc(-c2cccc(-c3ccccc3)c2)n1 ; *c1nc(-c2ccccc2)nc(-c2ccc(-c3ccccc3)cc2)n1 ; *c1nc(-c2ccc(-c3ccccc3)cc2)nc(-c2ccccc2-c2ccccc2)n1 ; *c1nc(-c2ccc(-c3ccccc3)cc2)nc(-c2cccc(-c3ccccc3)c2)n1]

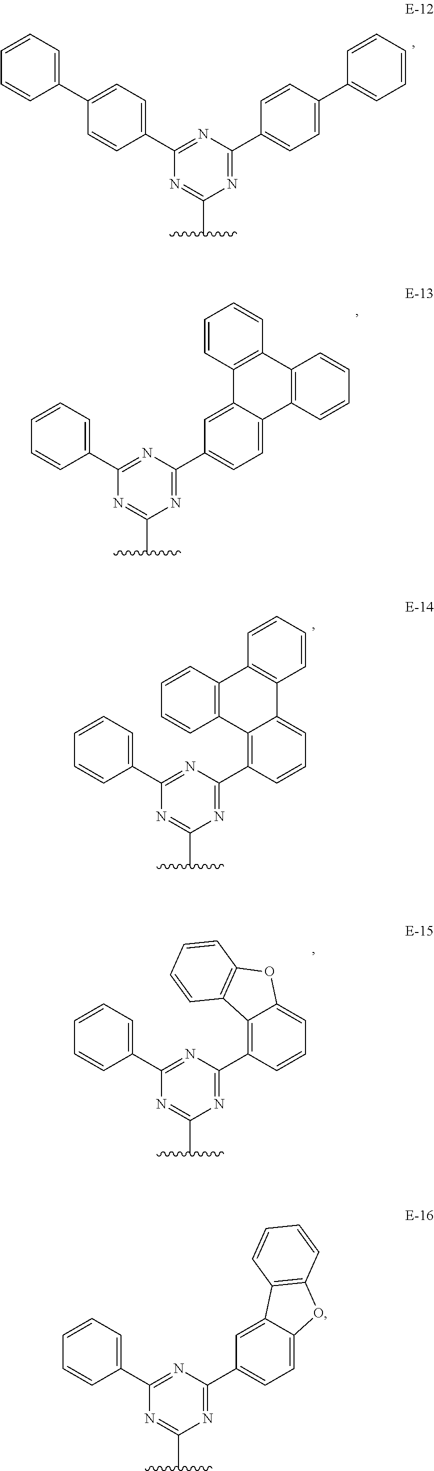 [SMILES: *c1nc(-c2ccc(-c3ccccc3)cc2)nc(-c2ccc(-c3ccccc3)cc2)n1 ; *c1nc(-c2ccccc2)nc(-c2ccc3c4ccccc4c4ccccc4c3c2)n1 ; *c1nc(-c2ccccc2)nc(-c2cccc3c4ccccc4c4ccccc4c23)n1 ; *c1nc(-c2ccccc2)nc(-c2cccc3oc4ccccc4c23)n1 ; *c1nc(-c2ccccc2)nc(-c2ccc3oc4ccccc4c3c2)n1]

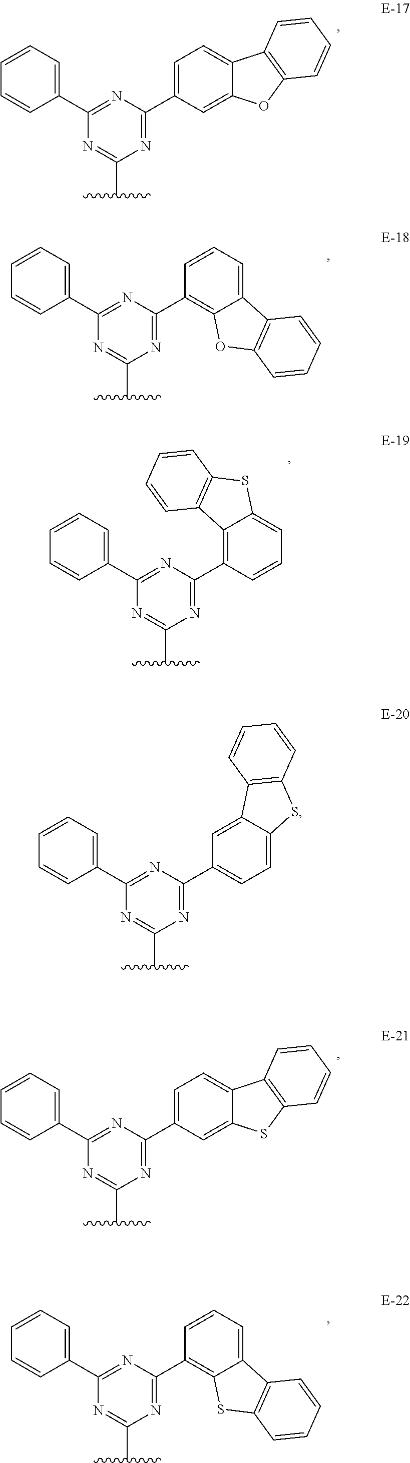 [SMILES: *c1nc(-c2ccccc2)nc(-c2ccc3c(c2)oc2ccccc23)n1 ; *c1nc(-c2ccccc2)nc(-c2cccc3c2oc2ccccc23)n1 ; *c1nc(-c2ccccc2)nc(-c2cccc3sc4ccccc4c23)n1 ; *c1nc(-c2ccccc2)nc(-c2ccc3sc4ccccc4c3c2)n1 ; *c1nc(-c2ccccc2)nc(-c2ccc3c(c2)sc2ccccc23)n1 ; *c1nc(-c2ccccc2)nc(-c2cccc3c2sc2ccccc23)n1]

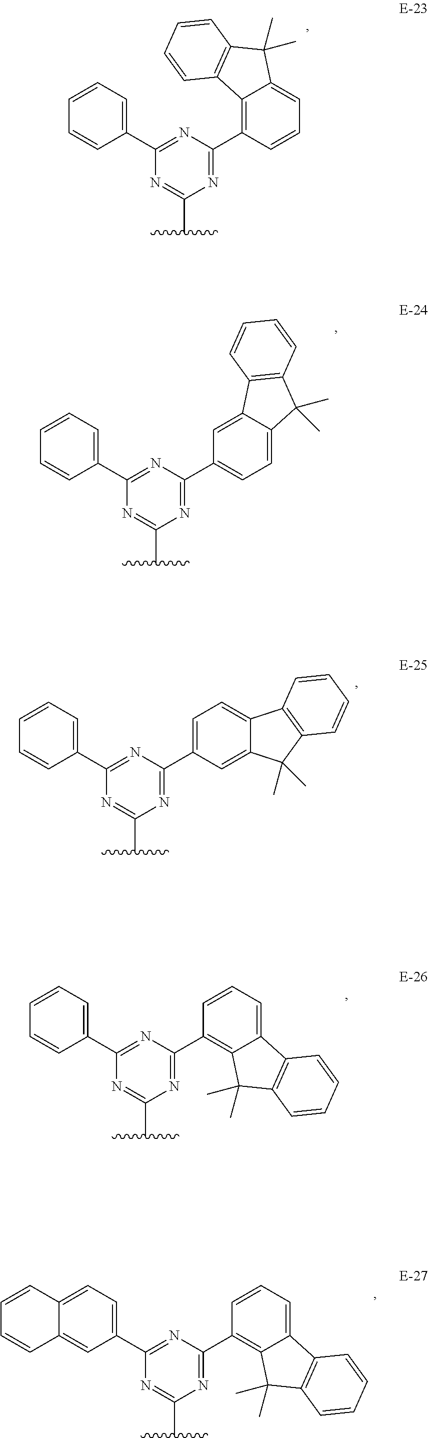 [SMILES: *c1nc(-c2ccccc2)nc(-c2cccc3c2-c2ccccc2C3(C)C)n1 ; *c1nc(-c2ccccc2)nc(-c2ccc3c(c2)-c2ccccc2C3(C)C)n1 ; *c1nc(-c2ccccc2)nc(-c2ccc3c(c2)C(C)(C)c2ccccc2-3)n1 ; *c1nc(-c2ccccc2)nc(-c2cccc3c2C(C)(C)c2ccccc2-3)n1 ; *c1nc(-c2ccc3ccccc3c2)nc(-c2cccc3c2C(C)(C)c2ccccc2-3)n1]

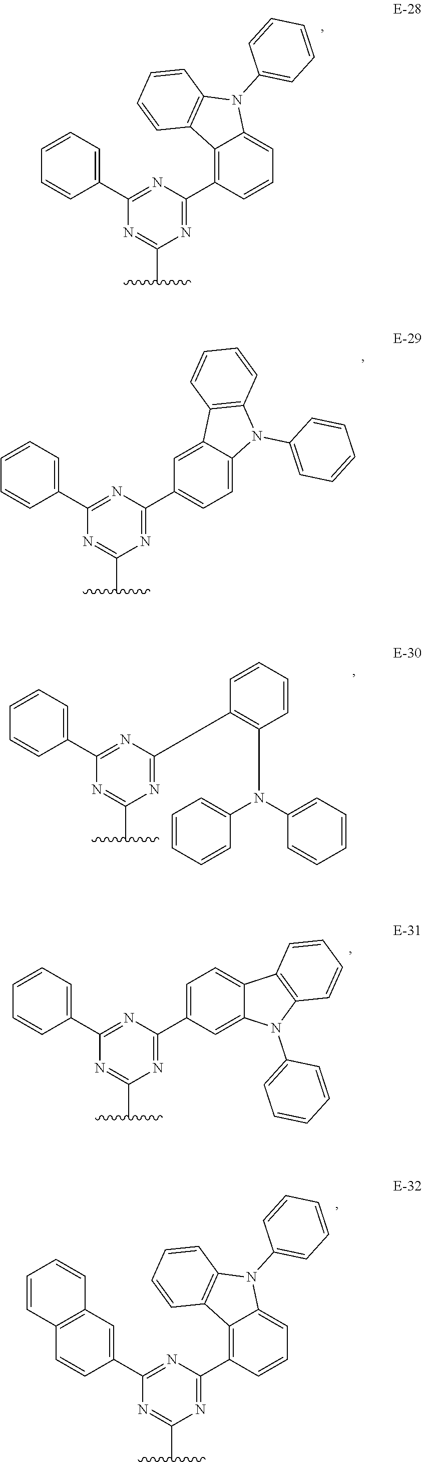 [SMILES: *c1nc(-c2ccccc2)nc(-c2cccc3c2c2ccccc2n3-c2ccccc2)n1 ; *c1nc(-c2ccccc2)nc(-c2ccc3c(c2)c2ccccc2n3-c2ccccc2)n1 ; *c1nc(-c2ccccc2)nc(-c2ccccc2N(c2ccccc2)c2ccccc2)n1 ; *c1nc(-c2ccccc2)nc(-c2ccc3c4ccccc4n(-c4ccccc4)c3c2)n1 ; *c1nc(-c2ccc3ccccc3c2)nc(-c2cccc3c2c2ccccc2n3-c2ccccc2)n1]

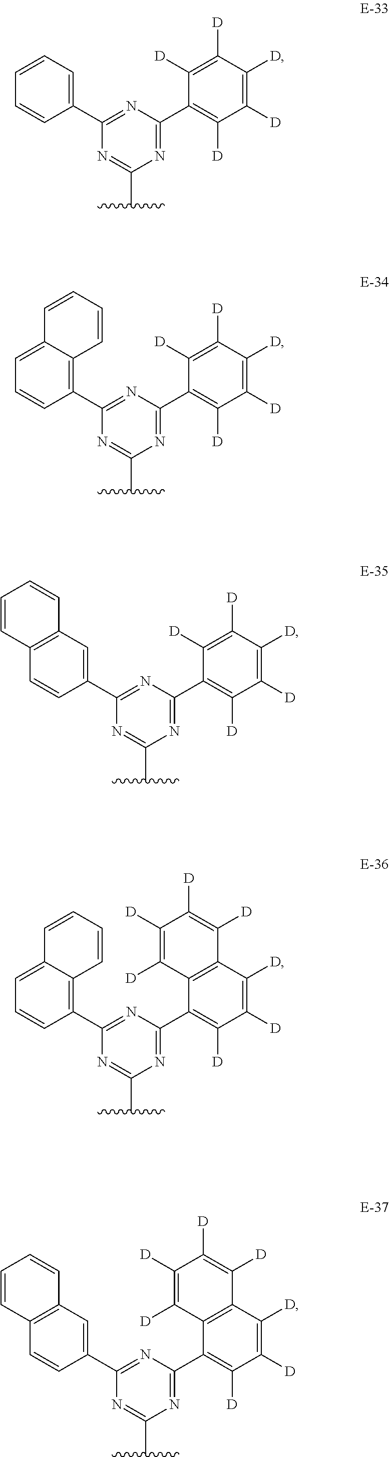

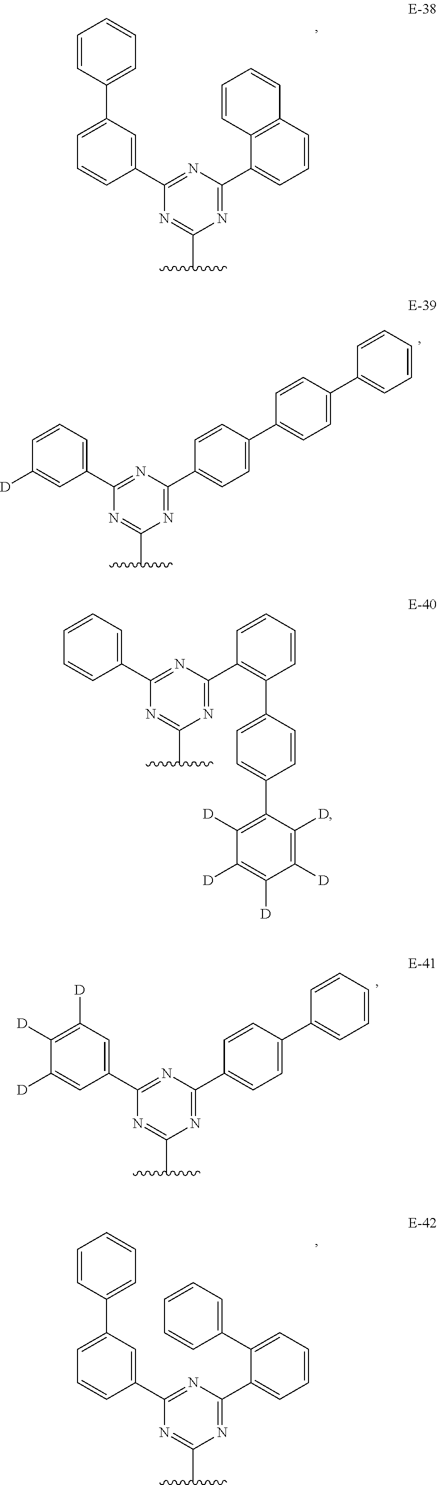

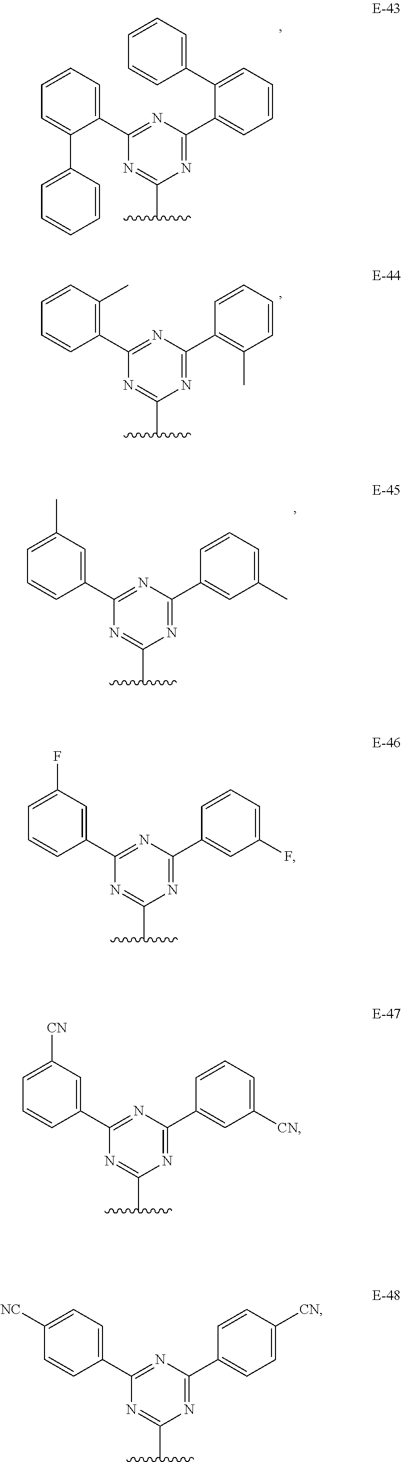 [SMILES: *c1nc(-c2ccccc2-c2ccccc2)nc(-c2ccccc2-c2ccccc2)n1 ; *c1nc(-c2ccccc2C)nc(-c2ccccc2C)n1 ; *c1nc(-c2cccc(C)c2)nc(-c2cccc(C)c2)n1 ; *c1nc(-c2cccc(F)c2)nc(-c2cccc(F)c2)n1 ; *c1nc(-c2cccc(C#N)c2)nc(-c2cccc(C#N)c2)n1 ; *c1nc(-c2ccc(C#N)cc2)nc(-c2ccc(C#N)cc2)n1]

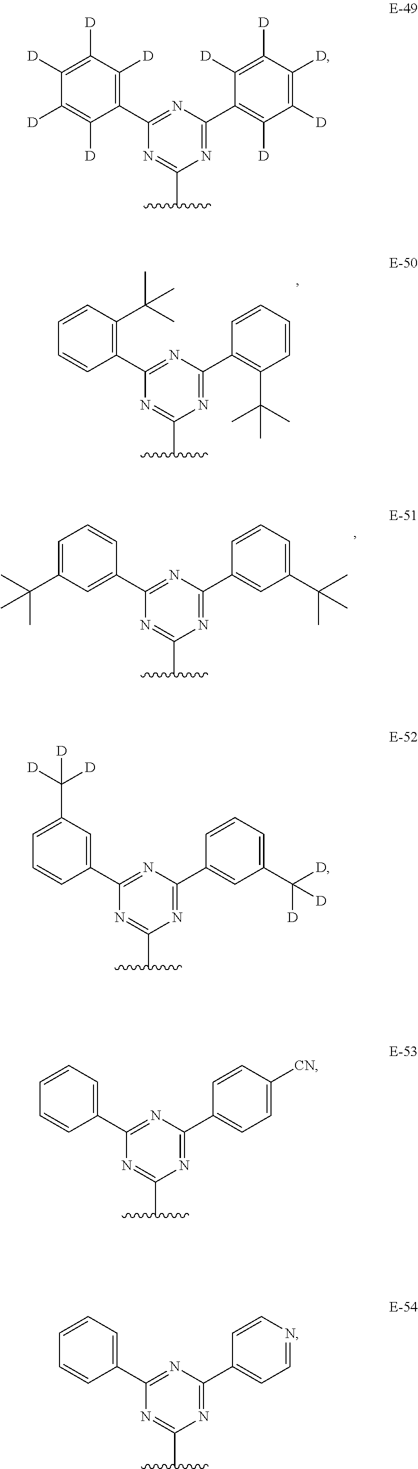

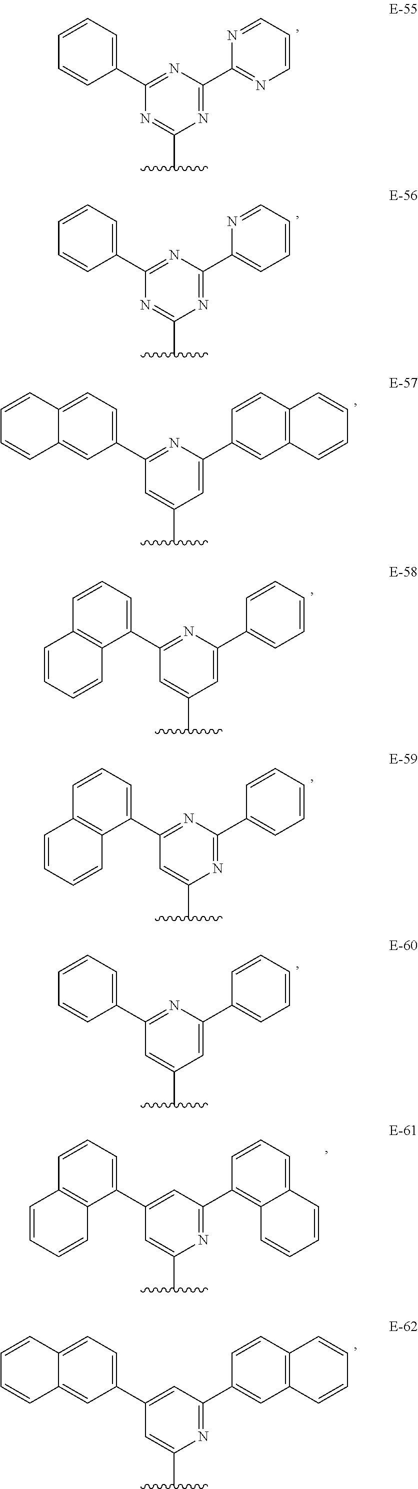

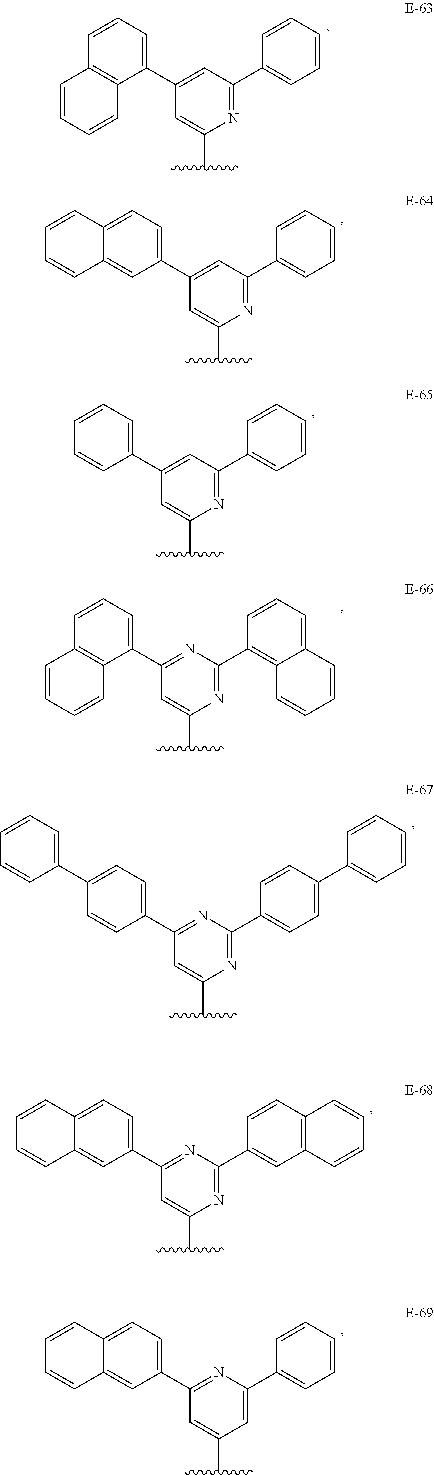

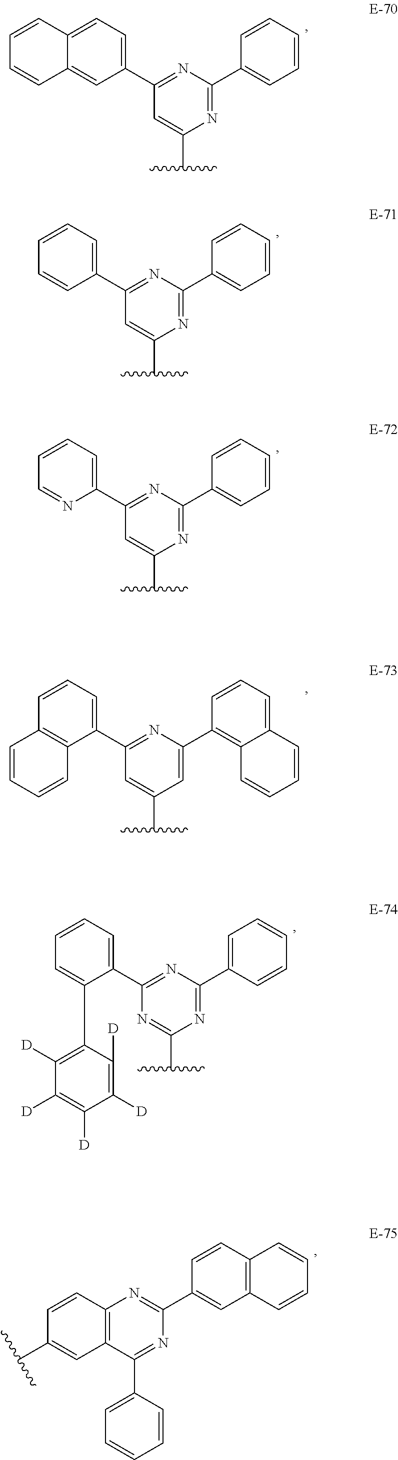 [SMILES: *c1cc(-c2ccc3ccccc3c2)nc(-c2ccccc2)n1 ; *c1cc(-c2ccccc2)nc(-c2ccccc2)n1 ; *c1cc(-c2ccccn2)nc(-c2ccccc2)n1 ; *c1cc(-c2cccc3ccccc23)nc(-c2cccc3ccccc23)c1 ; *c1nc(-c2ccccc2)nc(-c2ccccc2-c2c([2H])c([2H])c([2H])c([2H])c2[2H])n1 ; *c1ccc2nc(-c3ccc4ccccc4c3)nc(-c3ccccc3)c2c1]

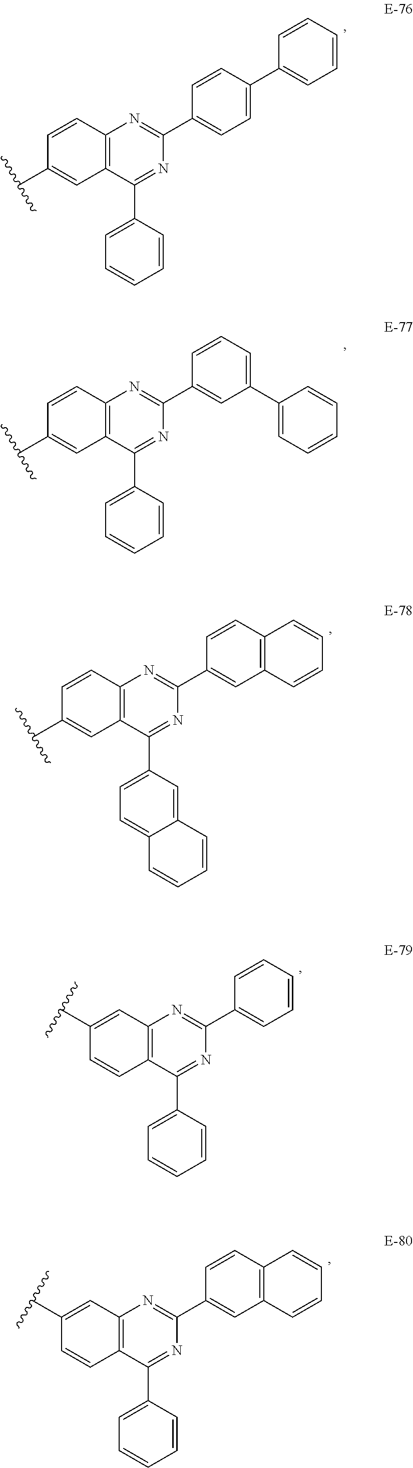 [SMILES: *c1ccc2nc(-c3ccc(-c4ccccc4)cc3)nc(-c3ccccc3)c2c1 ; *c1ccc2nc(-c3cccc(-c4ccccc4)c3)nc(-c3ccccc3)c2c1 ; *c1ccc2nc(-c3ccc4ccccc4c3)nc(-c3ccc4ccccc4c3)c2c1 ; *c1ccc2c(-c3ccccc3)nc(-c3ccccc3)nc2c1 ; *c1ccc2c(-c3ccccc3)nc(-c3ccc4ccccc4c3)nc2c1]

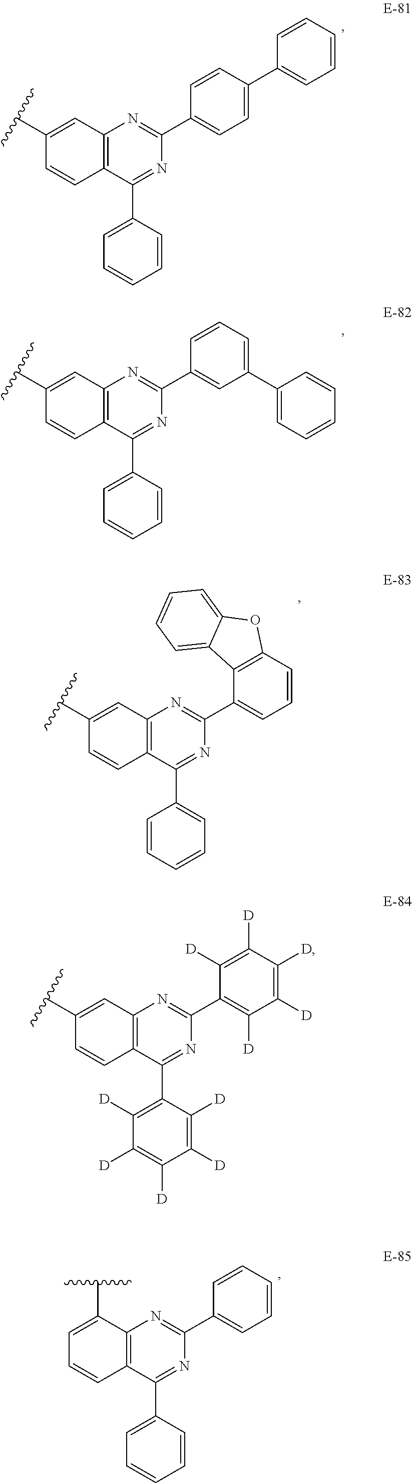

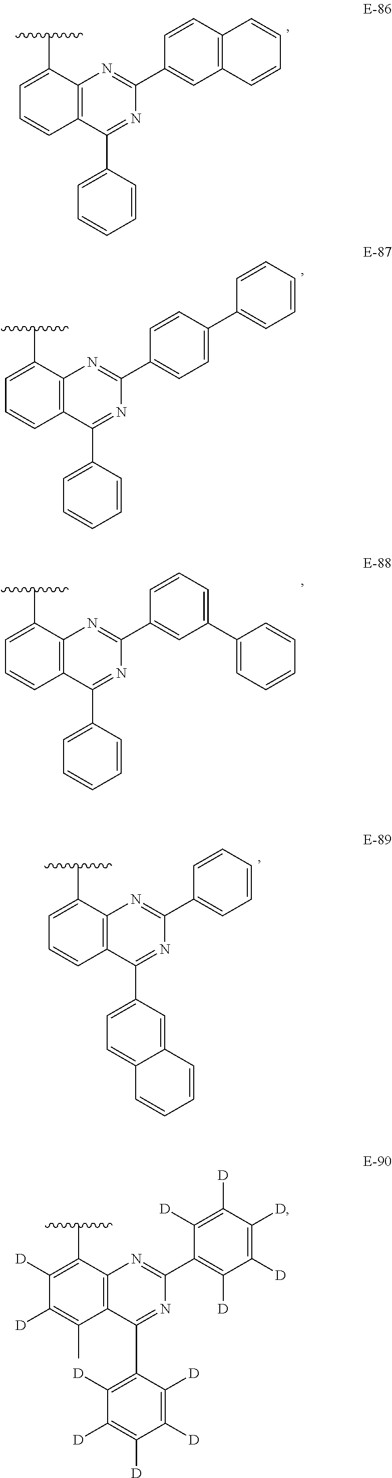

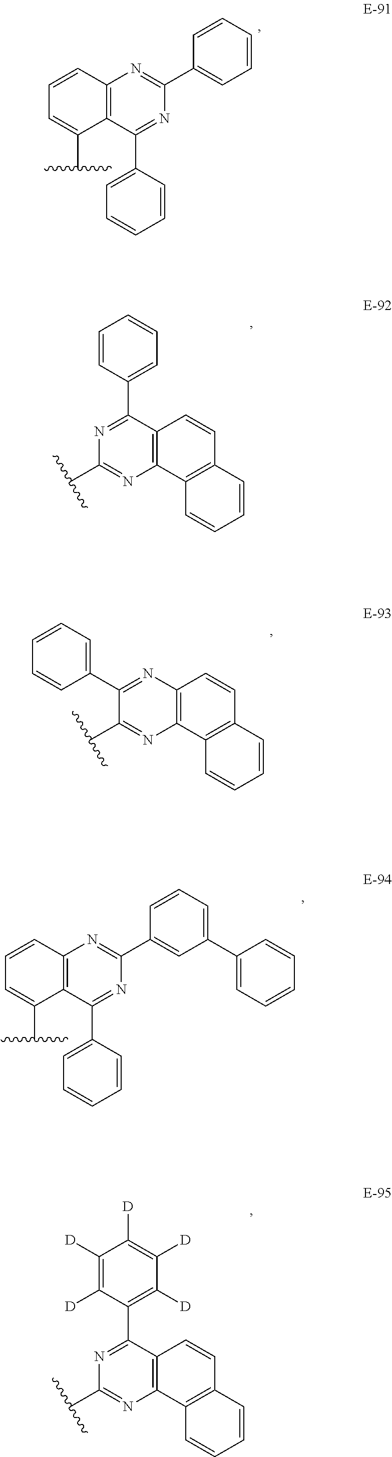 [SMILES: *c1cccc2nc(-c3ccccc3)nc(-c3ccccc3)c12 ; *c1nc(-c2ccccc2)c2ccc3ccccc3c2n1 ; *c1nc2c(ccc3ccccc32)nc1-c1ccccc1 ; *c1cccc2nc(-c3cccc(-c4ccccc4)c3)nc(-c3ccccc3)c12 ; *c1nc(-c2c([2H])c([2H])c([2H])c([2H])c2[2H])c2ccc3ccccc3c2n1]

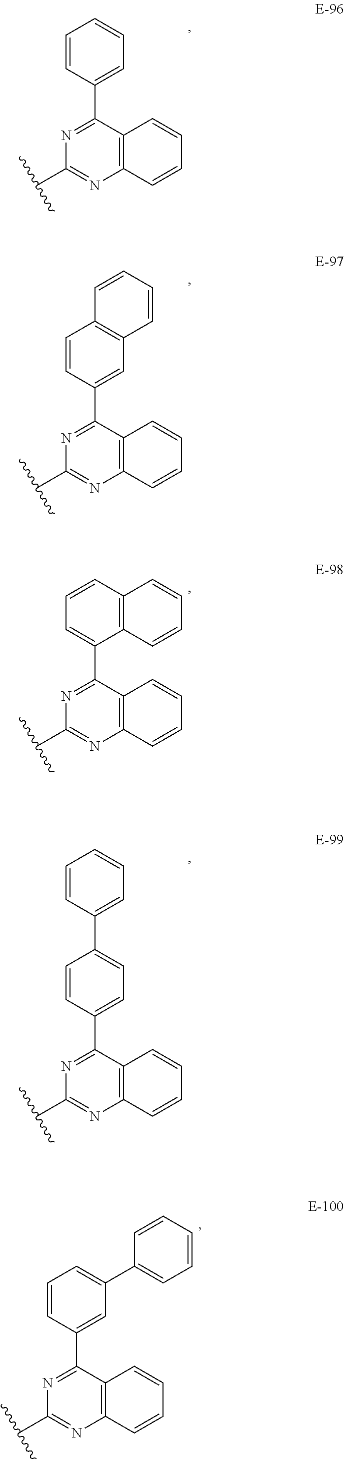 [SMILES: *c1nc(-c2ccccc2)c2ccccc2n1 ; *c1nc(-c2ccc3ccccc3c2)c2ccccc2n1 ; *c1nc(-c2cccc3ccccc23)c2ccccc2n1 ; *c1nc(-c2ccc(-c3ccccc3)cc2)c2ccccc2n1 ; *c1nc(-c2cccc(-c3ccccc3)c2)c2ccccc2n1]

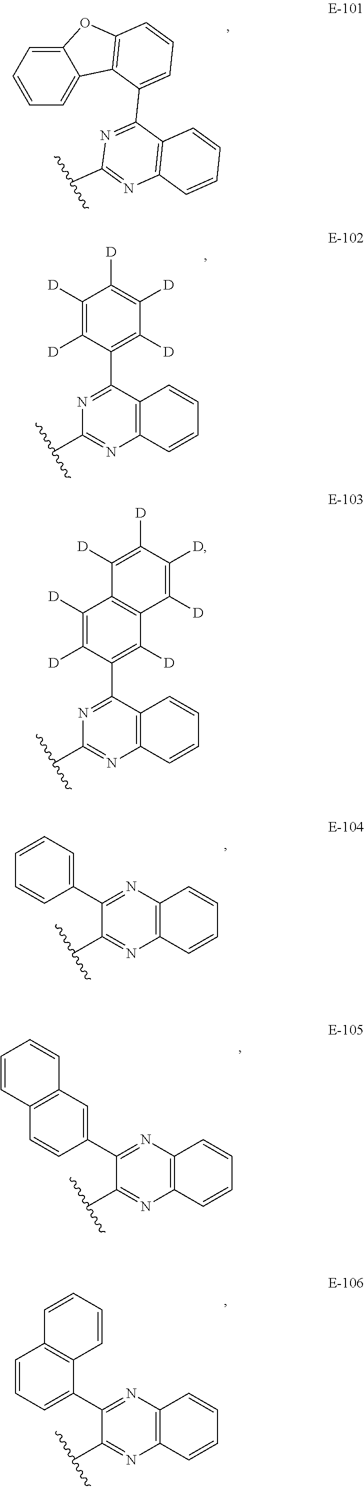

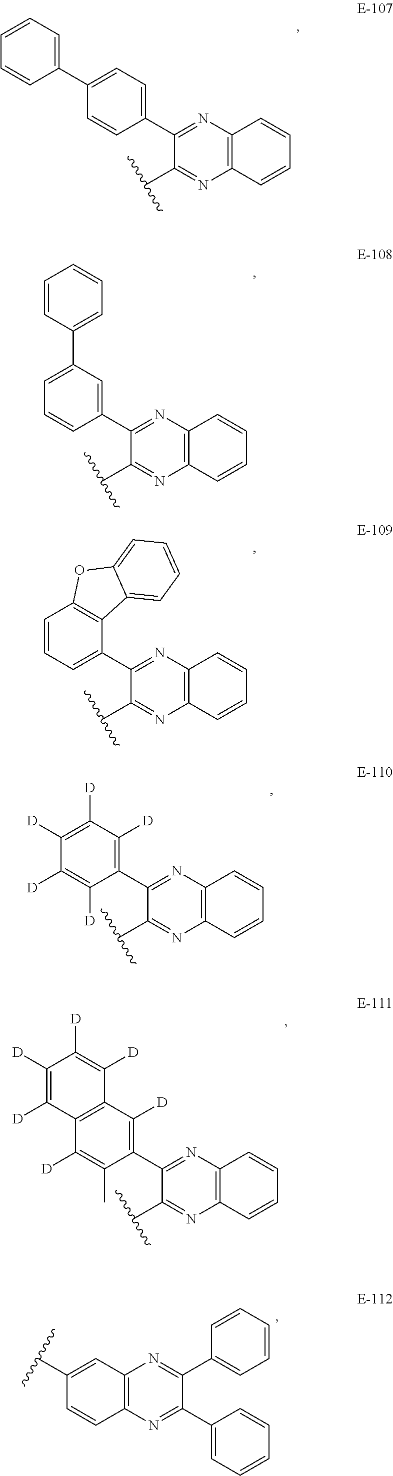 [SMILES: *c1nc2ccccc2nc1-c1ccc(-c2ccccc2)cc1 ; *c1nc2ccccc2nc1-c1cccc(-c2ccccc2)c1 ; *c1nc2ccccc2nc1-c1cccc2oc3ccccc3c12 ; *c1nc2ccccc2nc1-c1c([2H])c([2H])c([2H])c([2H])c1[2H] ; *c1nc2ccccc2nc1-c1c(C)c([2H])c2c([2H])c([2H])c([2H])c([2H])c2c1[2H] ; *c1ccc2nc(-c3ccccc3)c(-c3ccccc3)nc2c1]

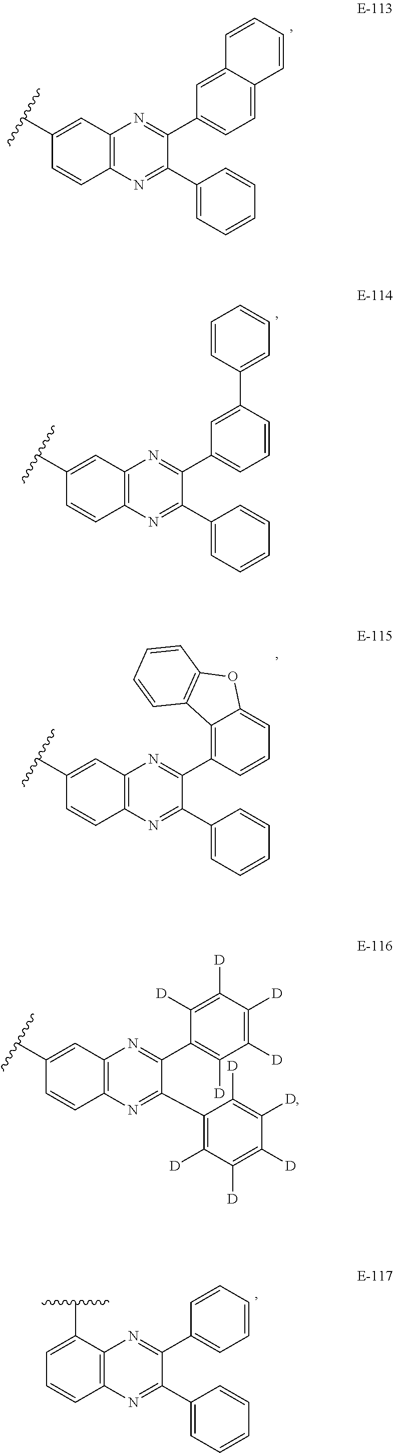

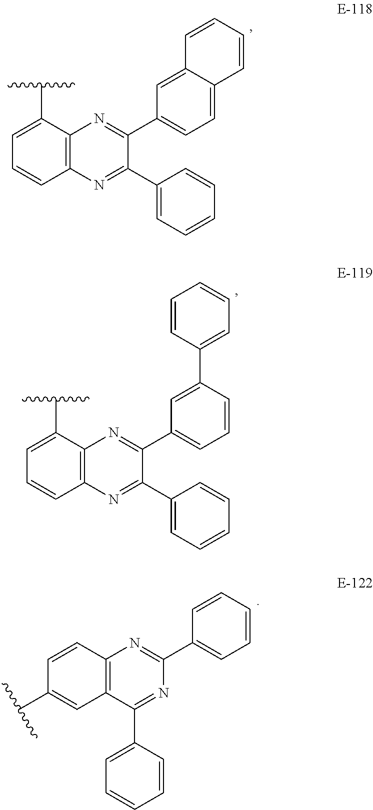 [SMILES: *c1cccc2nc(-c3ccccc3)c(-c3ccc4ccccc4c3)nc12 ; *c1cccc2nc(-c3ccccc3)c(-c3cccc(-c4ccccc4)c3)nc12 ; *c1ccc2nc(-c3ccccc3)nc(-c3ccccc3)c2c1]

According to an embodiment of the present disclosure, in the third compound, L is selected from a single bond, substituted or unsubstituted arylene having 6 to 20 carbon atoms, substituted or unsubstituted heteroarylene having 3 to 20 carbon atoms, or a combination thereof.

According to an embodiment of the present disclosure, in the third compound, L is selected from the group consisting of the following structures:

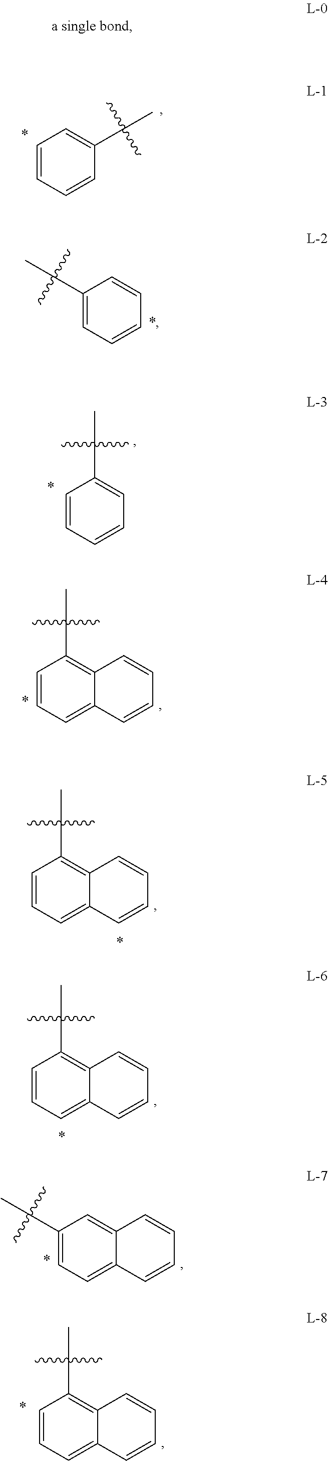

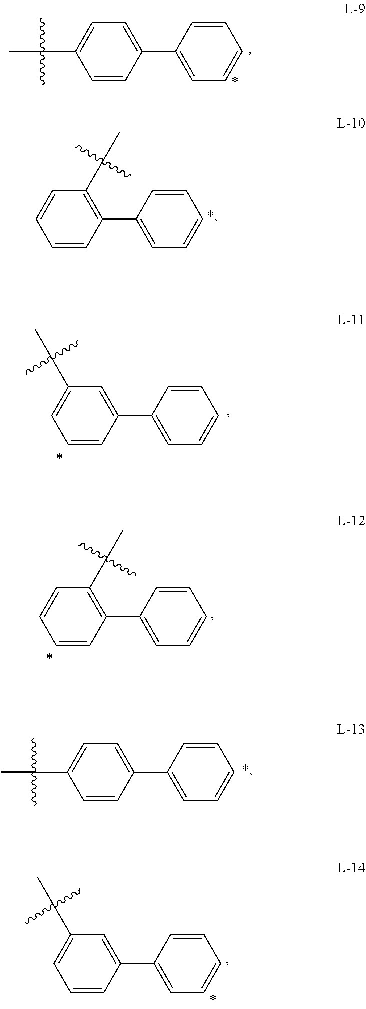 [SMILES: *c1ccc(-c2ccccc2)cc1 ; *c1ccccc1-c1ccccc1 ; *c1cccc(-c2ccccc2)c1 ; *c1ccccc1-c1ccccc1 ; *c1ccc(-c2ccccc2)cc1 ; *c1cccc(-c2ccccc2)c1]

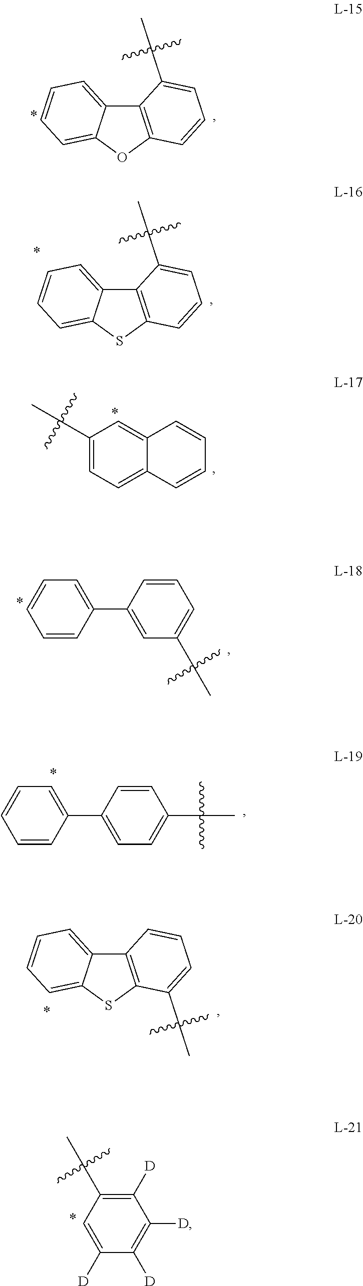

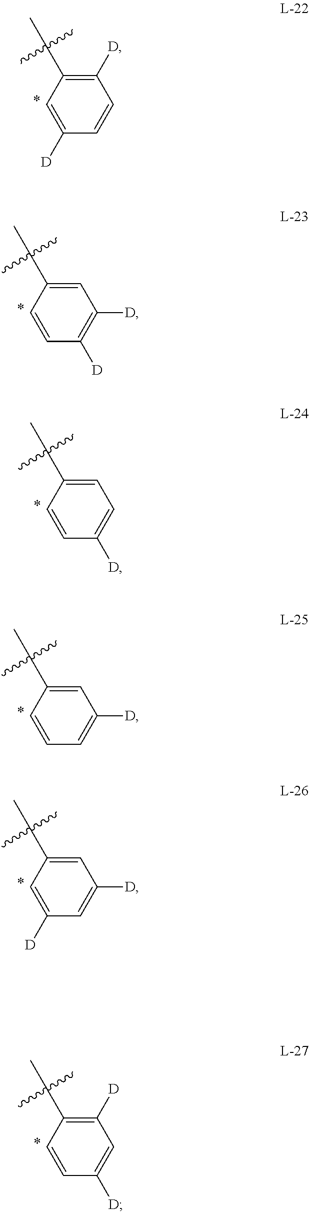

wherein

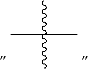

represents a position where E is joined in the structures of L-1 to L-27, and “*” represents a position where H is joined in the structures of L-1 to L-27.

According to an embodiment of the present disclosure, hydrogens in the structures of L-1 to L-27 can be partially or fully substituted with deuterium.

According to an embodiment of the present disclosure, the third compound has a structure of H-L-E, wherein H is selected from any one of the group consisting of H-1 to H-110, L is selected from any one of the group consisting of L-0 to L-27, and E is selected from any one of the group consisting of E-1 to E-122.

According to an embodiment of the present disclosure, the third compound is selected from the group consisting of Compound 1-1 to Compound 1-99:

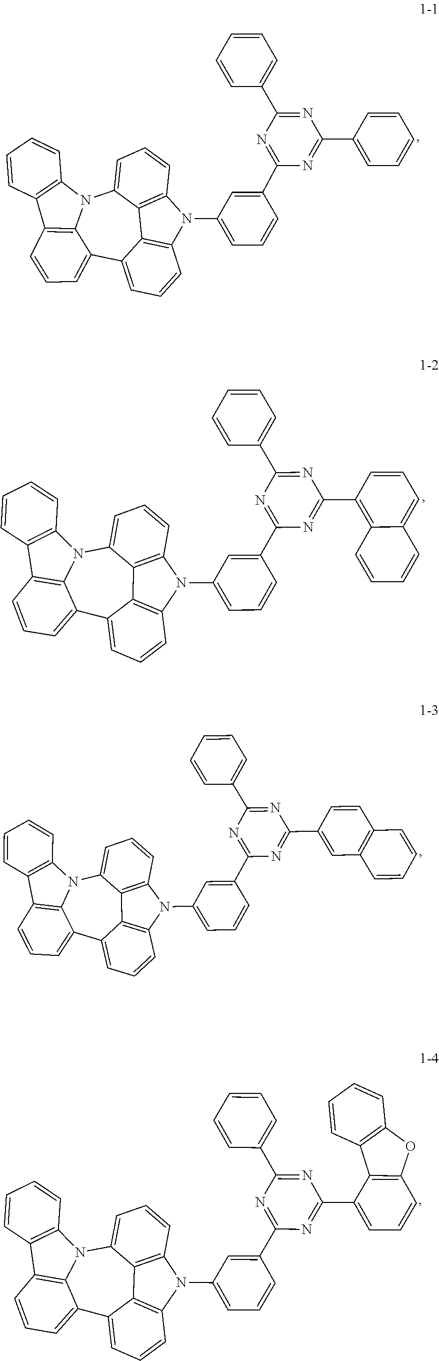 [SMILES: c1ccc(-c2nc(-c3ccccc3)nc(-c3cccc(-n4c5cccc6c7cccc8c9ccccc9n(c9cccc4c9c65)c78)c3)n2)cc1 ; c1ccc(-c2nc(-c3cccc(-n4c5cccc6c7cccc8c9ccccc9n(c9cccc4c9c65)c78)c3)nc(-c3cccc4ccccc34)n2)cc1 ; c1ccc(-c2nc(-c3cccc(-n4c5cccc6c7cccc8c9ccccc9n(c9cccc4c9c65)c78)c3)nc(-c3ccc4ccccc4c3)n2)cc1 ; c1ccc(-c2nc(-c3cccc(-n4c5cccc6c7cccc8c9ccccc9n(c9cccc4c9c65)c78)c3)nc(-c3cccc4oc5ccccc5c34)n2)cc1]

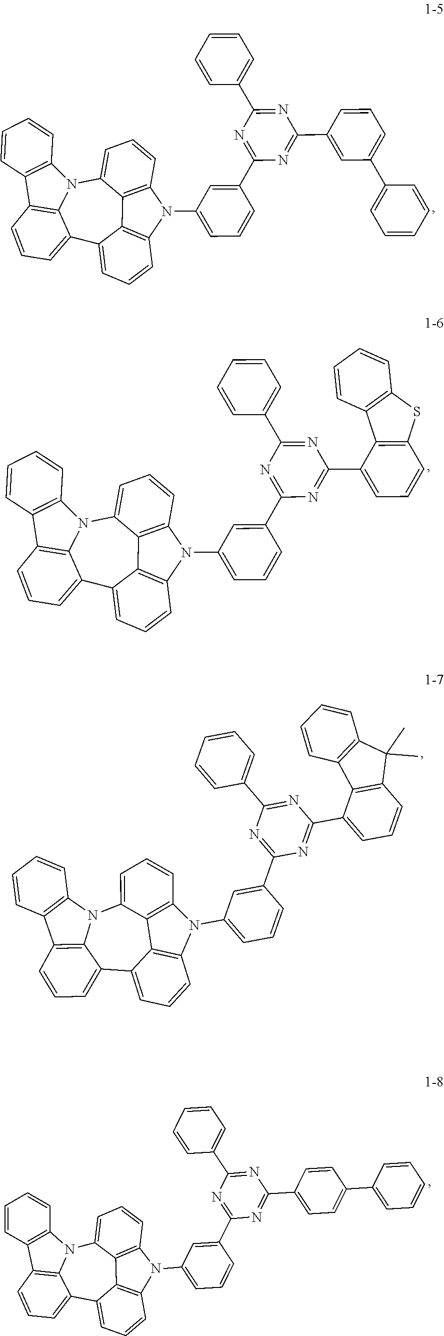 [SMILES: c1ccc(-c2cccc(-c3nc(-c4ccccc4)nc(-c4cccc(-n5c6cccc7c8cccc9c%10ccccc%10n(c%10cccc5c%10c76)c89)c4)n3)c2)cc1 ; c1ccc(-c2nc(-c3cccc(-n4c5cccc6c7cccc8c9ccccc9n(c9cccc4c9c65)c78)c3)nc(-c3cccc4sc5ccccc5c34)n2)cc1 ; CC1(C)c2ccccc2-c2c(-c3nc(-c4ccccc4)nc(-c4cccc(-n5c6cccc7c8cccc9c%10ccccc%10n(c%10cccc5c%10c76)c89)c4)n3)cccc21 ; c1ccc(-c2ccc(-c3nc(-c4ccccc4)nc(-c4cccc(-n5c6cccc7c8cccc9c%10ccccc%10n(c%10cccc5c%10c76)c89)c4)n3)cc2)cc1]

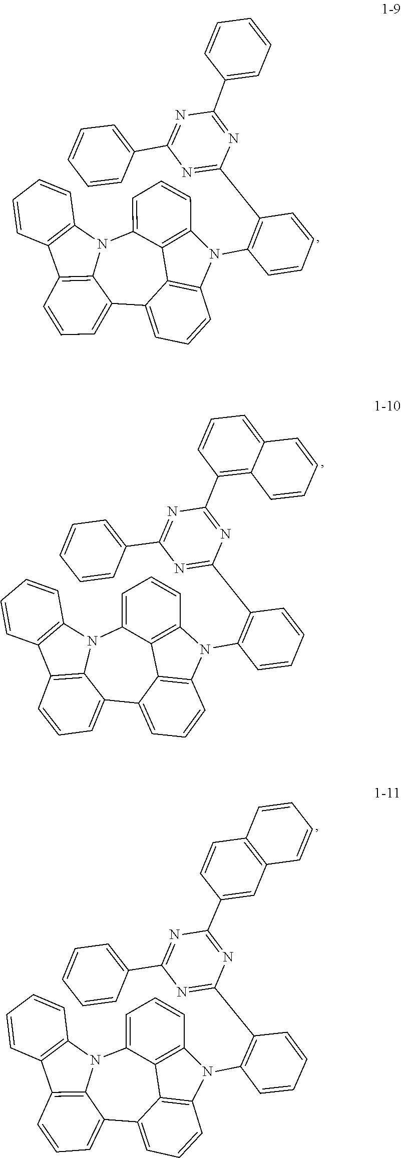 [SMILES: c1ccc(-c2nc(-c3ccccc3)nc(-c3ccccc3-n3c4cccc5c6cccc7c8ccccc8n(c8cccc3c8c54)c67)n2)cc1 ; c1ccc(-c2nc(-c3ccccc3-n3c4cccc5c6cccc7c8ccccc8n(c8cccc3c8c54)c67)nc(-c3cccc4ccccc34)n2)cc1 ; c1ccc(-c2nc(-c3ccc4ccccc4c3)nc(-c3ccccc3-n3c4cccc5c6cccc7c8ccccc8n(c8cccc3c8c54)c67)n2)cc1]

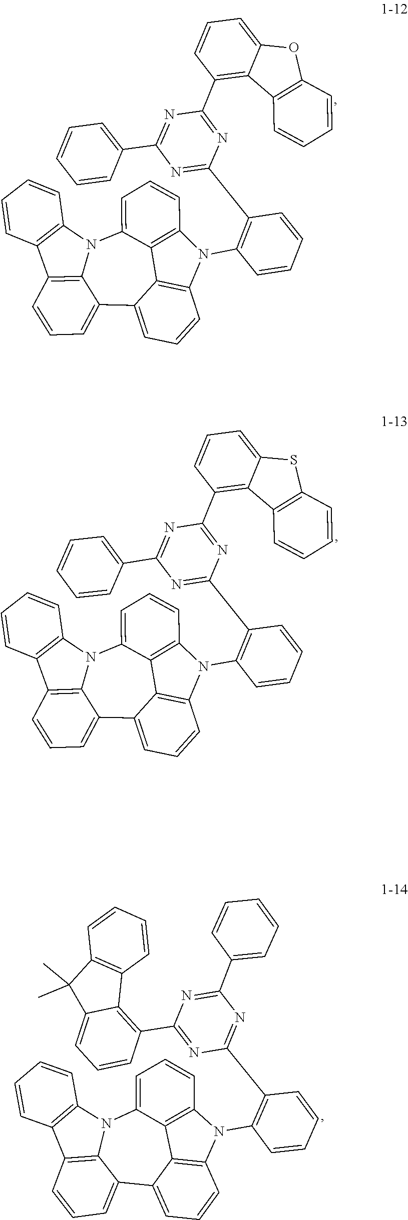 [SMILES: c1ccc(-c2nc(-c3ccccc3-n3c4cccc5c6cccc7c8ccccc8n(c8cccc3c8c54)c67)nc(-c3cccc4oc5ccccc5c34)n2)cc1 ; c1ccc(-c2nc(-c3ccccc3-n3c4cccc5c6cccc7c8ccccc8n(c8cccc3c8c54)c67)nc(-c3cccc4sc5ccccc5c34)n2)cc1 ; CC1(C)c2ccccc2-c2c(-c3nc(-c4ccccc4)nc(-c4ccccc4-n4c5cccc6c7cccc8c9ccccc9n(c9cccc4c9c65)c78)n3)cccc21]

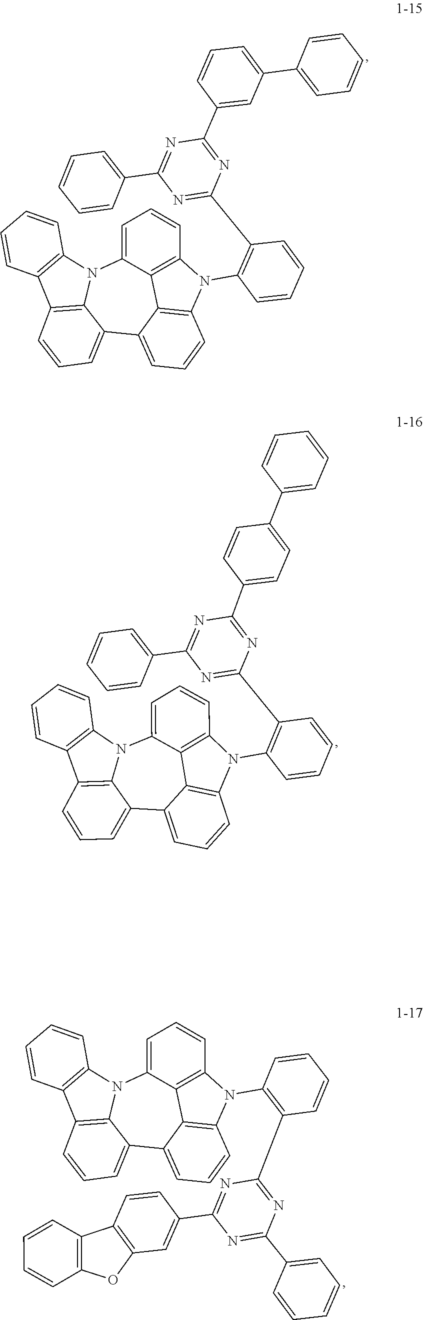 [SMILES: c1ccc(-c2cccc(-c3nc(-c4ccccc4)nc(-c4ccccc4-n4c5cccc6c7cccc8c9ccccc9n(c9cccc4c9c65)c78)n3)c2)cc1 ; c1ccc(-c2ccc(-c3nc(-c4ccccc4)nc(-c4ccccc4-n4c5cccc6c7cccc8c9ccccc9n(c9cccc4c9c65)c78)n3)cc2)cc1 ; c1ccc(-c2nc(-c3ccc4c(c3)oc3ccccc34)nc(-c3ccccc3-n3c4cccc5c6cccc7c8ccccc8n(c8cccc3c8c54)c67)n2)cc1]

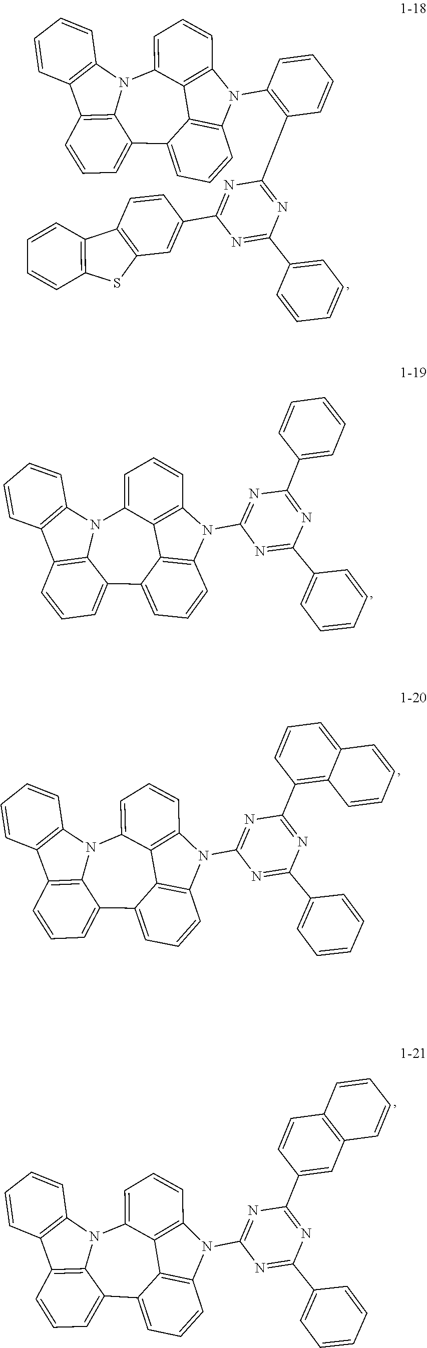 [SMILES: c1ccc(-c2nc(-c3ccc4c(c3)sc3ccccc34)nc(-c3ccccc3-n3c4cccc5c6cccc7c8ccccc8n(c8cccc3c8c54)c67)n2)cc1 ; c1ccc(-c2nc(-c3ccccc3)nc(-n3c4cccc5c6cccc7c8ccccc8n(c8cccc3c8c54)c67)n2)cc1 ; c1ccc(-c2nc(-c3cccc4ccccc34)nc(-n3c4cccc5c6cccc7c8ccccc8n(c8cccc3c8c54)c67)n2)cc1 ; c1ccc(-c2nc(-c3ccc4ccccc4c3)nc(-n3c4cccc5c6cccc7c8ccccc8n(c8cccc3c8c54)c67)n2)cc1]

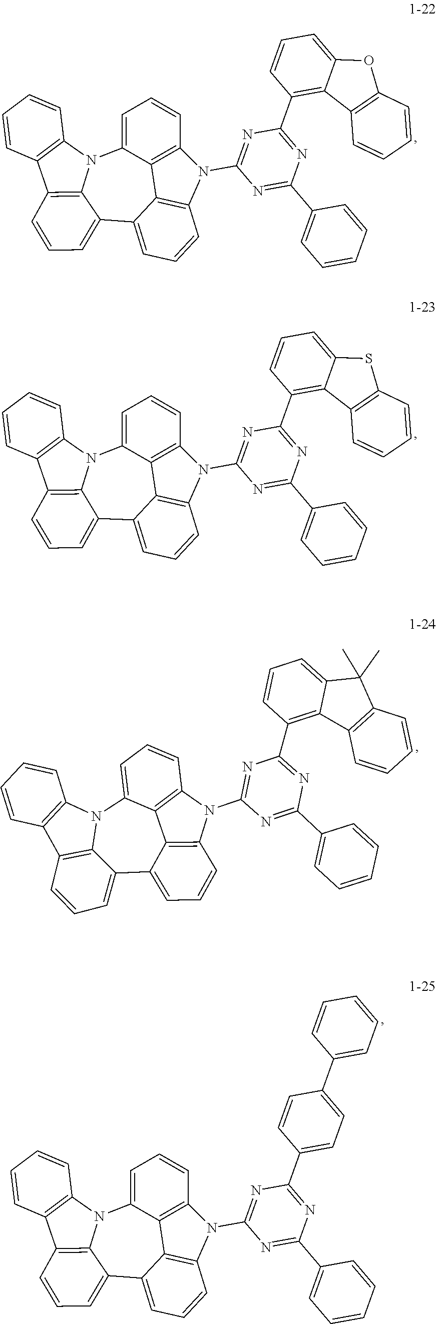 [SMILES: c1ccc(-c2nc(-c3cccc4oc5ccccc5c34)nc(-n3c4cccc5c6cccc7c8ccccc8n(c8cccc3c8c54)c67)n2)cc1 ; c1ccc(-c2nc(-c3cccc4sc5ccccc5c34)nc(-n3c4cccc5c6cccc7c8ccccc8n(c8cccc3c8c54)c67)n2)cc1 ; CC1(C)c2ccccc2-c2c(-c3nc(-c4ccccc4)nc(-n4c5cccc6c7cccc8c9ccccc9n(c9cccc4c9c65)c78)n3)cccc21 ; c1ccc(-c2ccc(-c3nc(-c4ccccc4)nc(-n4c5cccc6c7cccc8c9ccccc9n(c9cccc4c9c65)c78)n3)cc2)cc1]

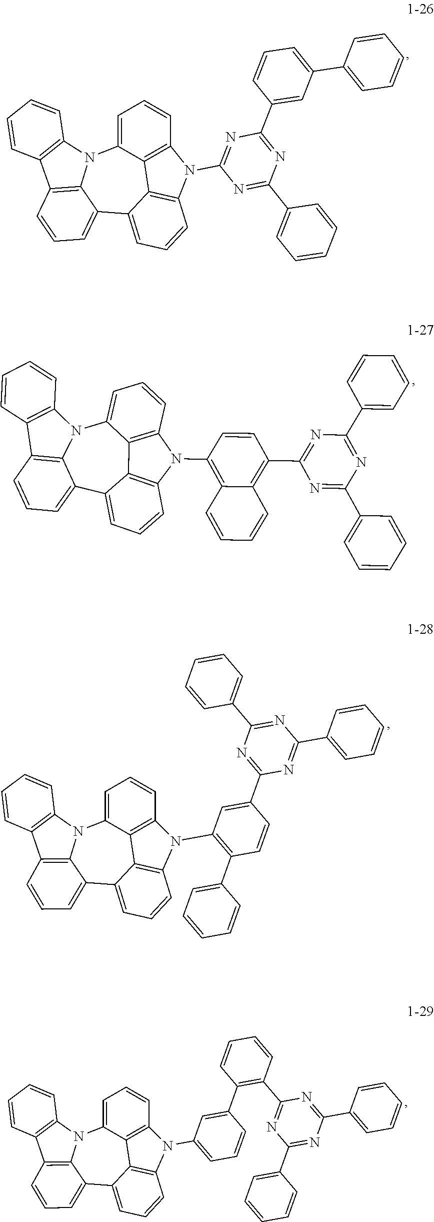 [SMILES: c1ccc(-c2cccc(-c3nc(-c4ccccc4)nc(-n4c5cccc6c7cccc8c9ccccc9n(c9cccc4c9c65)c78)n3)c2)cc1 ; c1ccc(-c2nc(-c3ccccc3)nc(-c3ccc(-n4c5cccc6c7cccc8c9ccccc9n(c9cccc4c9c65)c78)c4ccccc34)n2)cc1 ; c1ccc(-c2nc(-c3ccccc3)nc(-c3ccc(-c4ccccc4)c(-n4c5cccc6c7cccc8c9ccccc9n(c9cccc4c9c65)c78)c3)n2)cc1 ; c1ccc(-c2nc(-c3ccccc3)nc(-c3ccccc3-c3cccc(-n4c5cccc6c7cccc8c9ccccc9n(c9cccc4c9c65)c78)c3)n2)cc1]

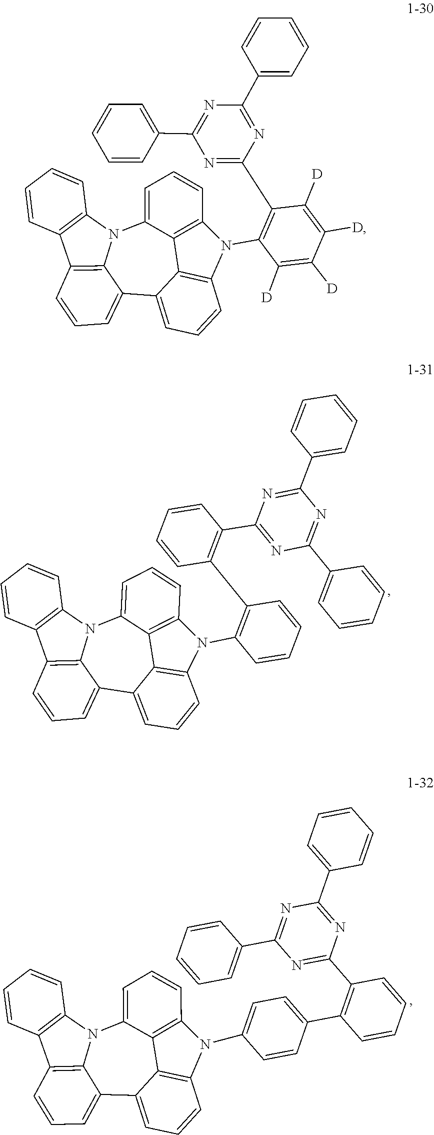

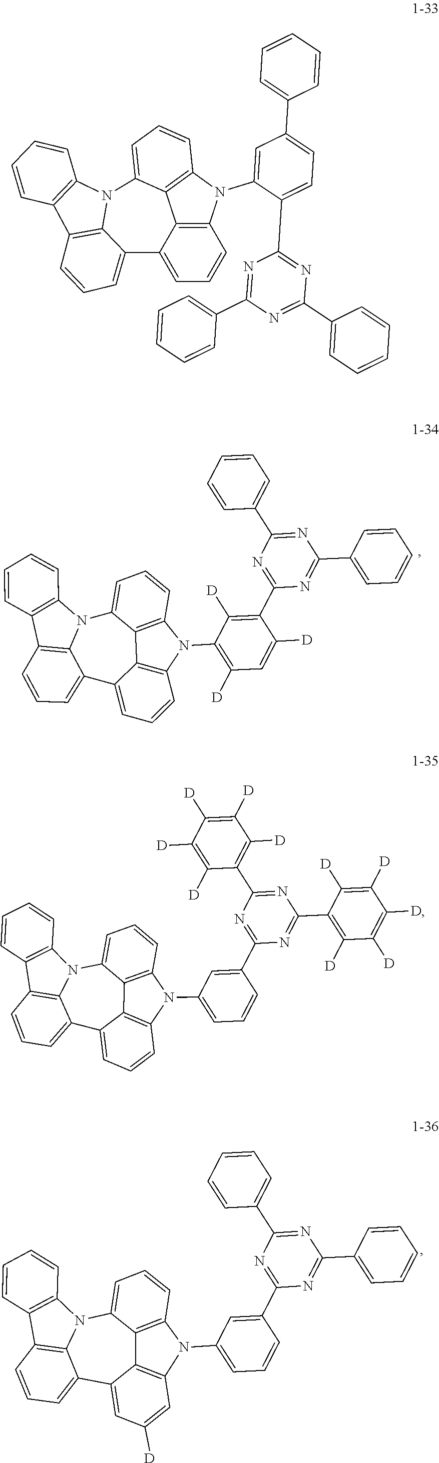

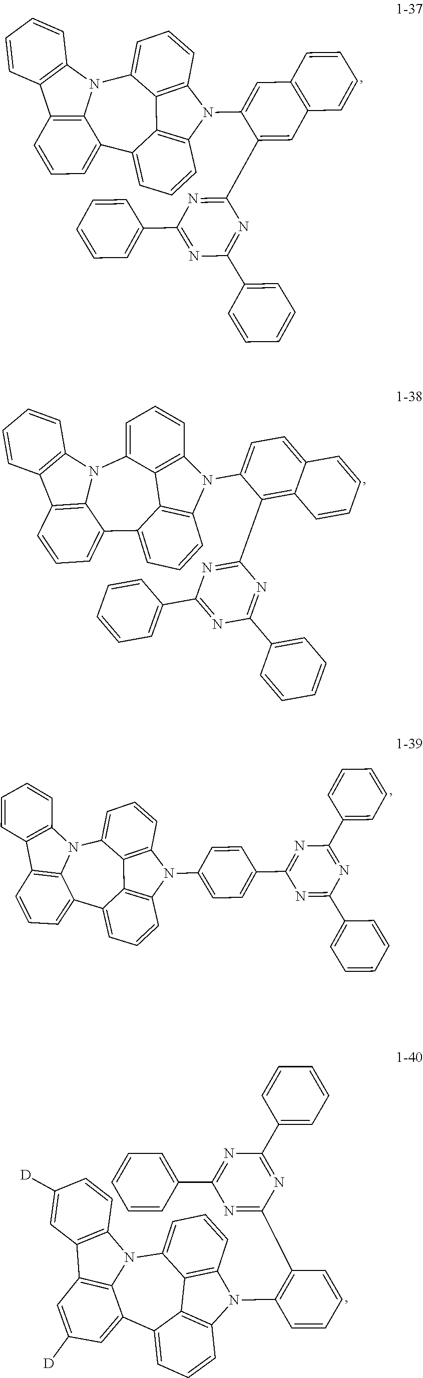 [SMILES: c1ccc(-c2nc(-c3ccccc3)nc(-c3cc4ccccc4cc3-n3c4cccc5c6cccc7c8ccccc8n(c8cccc3c8c54)c67)n2)cc1 ; c1ccc(-c2nc(-c3ccccc3)nc(-c3c(-n4c5cccc6c7cccc8c9ccccc9n(c9cccc4c9c65)c78)ccc4ccccc34)n2)cc1 ; c1ccc(-c2nc(-c3ccccc3)nc(-c3ccc(-n4c5cccc6c7cccc8c9ccccc9n(c9cccc4c9c65)c78)cc3)n2)cc1 ; [2H]c1ccc2c(c1)c1cc([2H])cc3c4cccc5c4c4c(cccc4n2c31)n5-c1ccccc1-c1nc(-c2ccccc2)nc(-c2ccccc2)n1]

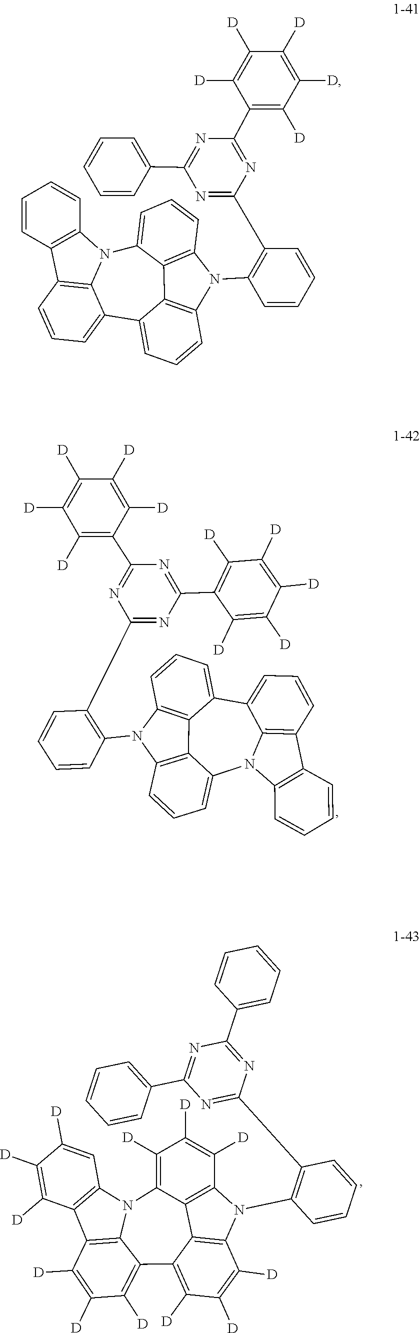

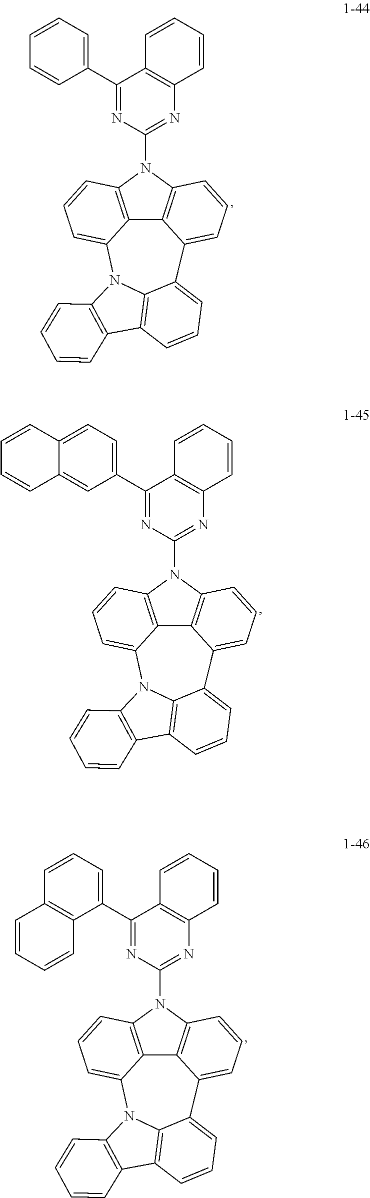 [SMILES: c1ccc(-c2nc(-n3c4cccc5c6cccc7c8ccccc8n(c8cccc3c8c54)c67)nc3ccccc23)cc1 ; c1ccc2cc(-c3nc(-n4c5cccc6c7cccc8c9ccccc9n(c9cccc4c9c65)c78)nc4ccccc34)ccc2c1 ; c1ccc2c(-c3nc(-n4c5cccc6c7cccc8c9ccccc9n(c9cccc4c9c65)c78)nc4ccccc34)cccc2c1]

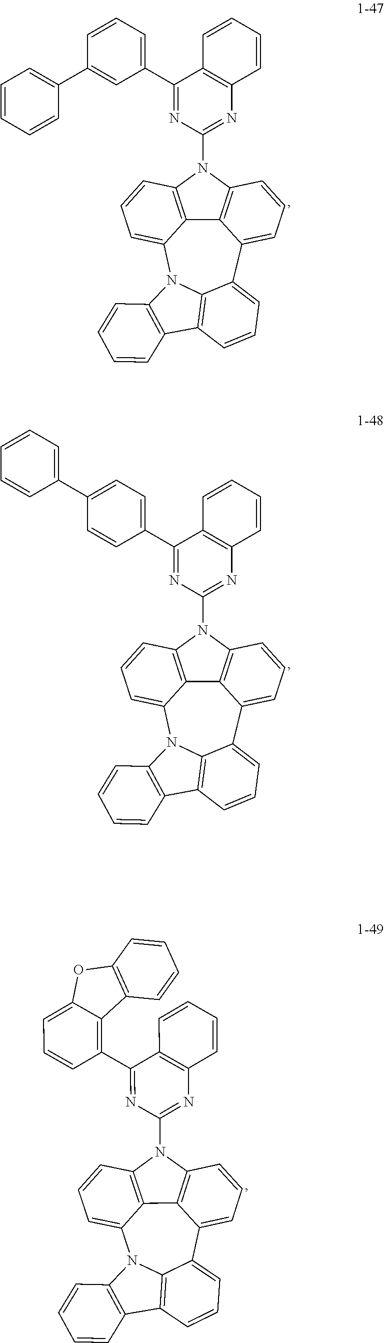 [SMILES: c1ccc(-c2cccc(-c3nc(-n4c5cccc6c7cccc8c9ccccc9n(c9cccc4c9c65)c78)nc4ccccc34)c2)cc1 ; c1ccc(-c2ccc(-c3nc(-n4c5cccc6c7cccc8c9ccccc9n(c9cccc4c9c65)c78)nc4ccccc34)cc2)cc1 ; c1ccc2c(-c3cccc4oc5ccccc5c34)nc(-n3c4cccc5c6cccc7c8ccccc8n(c8cccc3c8c54)c67)nc2c1]

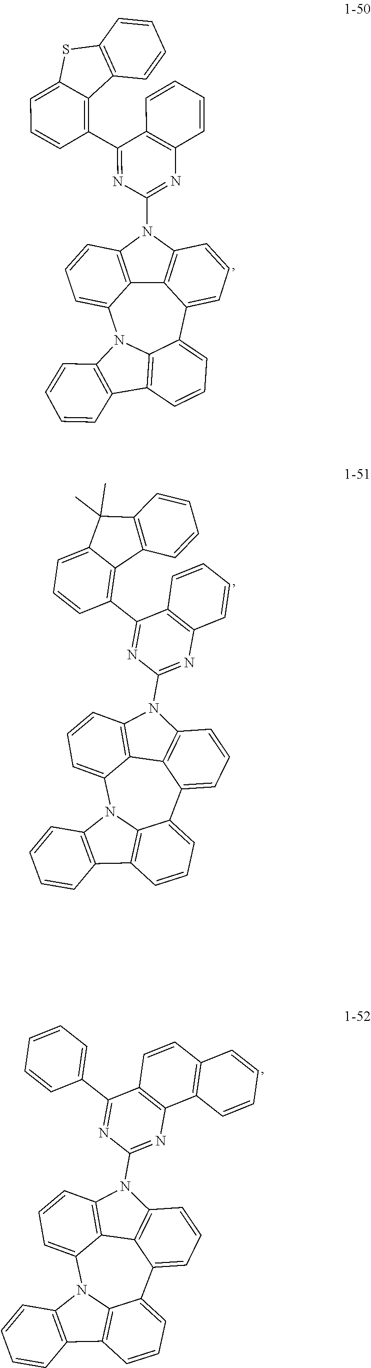 [SMILES: c1ccc2c(-c3cccc4sc5ccccc5c34)nc(-n3c4cccc5c6cccc7c8ccccc8n(c8cccc3c8c54)c67)nc2c1 ; CC1(C)c2ccccc2-c2c(-c3nc(-n4c5cccc6c7cccc8c9ccccc9n(c9cccc4c9c65)c78)nc4ccccc34)cccc21 ; c1ccc(-c2nc(-n3c4cccc5c6cccc7c8ccccc8n(c8cccc3c8c54)c67)nc3c2ccc2ccccc23)cc1]

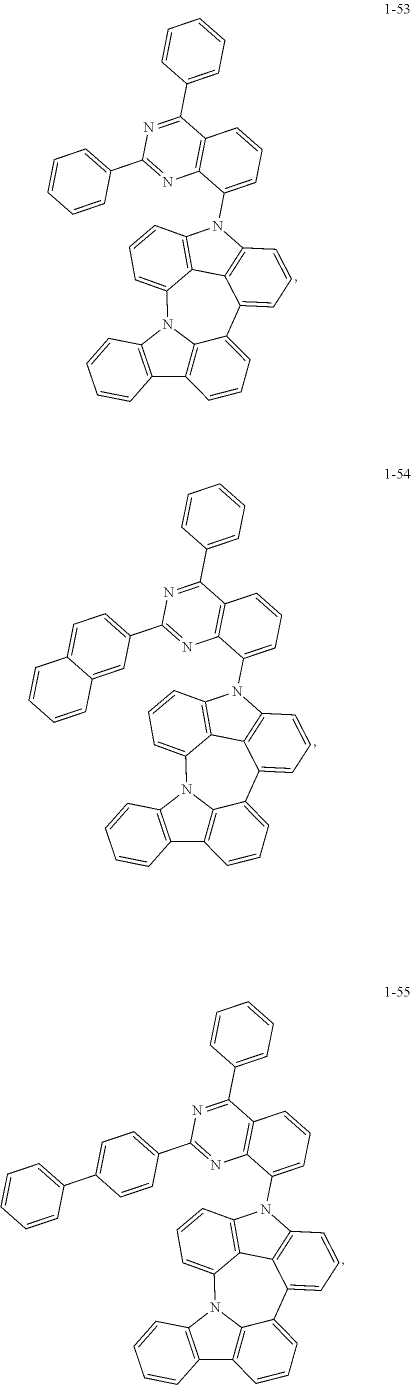 [SMILES: c1ccc(-c2nc(-c3ccccc3)c3cccc(-n4c5cccc6c7cccc8c9ccccc9n(c9cccc4c9c65)c78)c3n2)cc1 ; c1ccc(-c2nc(-c3ccc4ccccc4c3)nc3c(-n4c5cccc6c7cccc8c9ccccc9n(c9cccc4c9c65)c78)cccc23)cc1 ; c1ccc(-c2ccc(-c3nc(-c4ccccc4)c4cccc(-n5c6cccc7c8cccc9c%10ccccc%10n(c%10cccc5c%10c76)c89)c4n3)cc2)cc1]

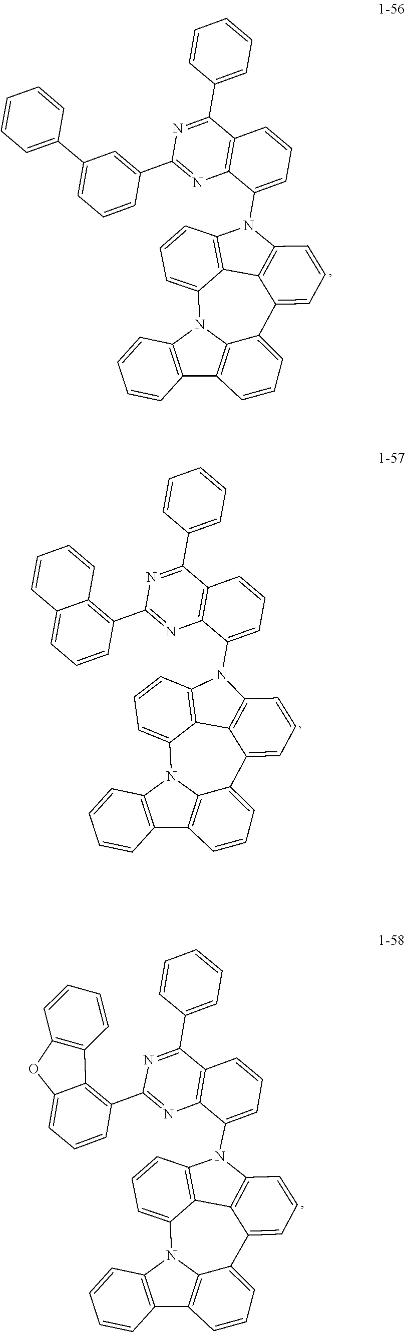 [SMILES: c1ccc(-c2cccc(-c3nc(-c4ccccc4)c4cccc(-n5c6cccc7c8cccc9c%10ccccc%10n(c%10cccc5c%10c76)c89)c4n3)c2)cc1 ; c1ccc(-c2nc(-c3cccc4ccccc34)nc3c(-n4c5cccc6c7cccc8c9ccccc9n(c9cccc4c9c65)c78)cccc23)cc1 ; c1ccc(-c2nc(-c3cccc4oc5ccccc5c34)nc3c(-n4c5cccc6c7cccc8c9ccccc9n(c9cccc4c9c65)c78)cccc23)cc1]

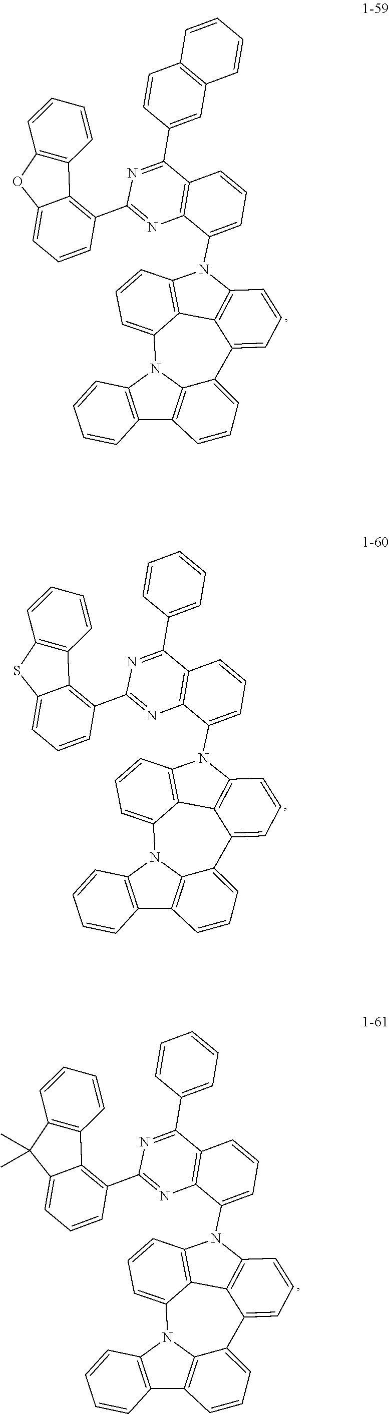 [SMILES: c1ccc2cc(-c3nc(-c4cccc5oc6ccccc6c45)nc4c(-n5c6cccc7c8cccc9c%10ccccc%10n(c%10cccc5c%10c76)c89)cccc34)ccc2c1 ; c1ccc(-c2nc(-c3cccc4sc5ccccc5c34)nc3c(-n4c5cccc6c7cccc8c9ccccc9n(c9cccc4c9c65)c78)cccc23)cc1 ; CC1(C)c2ccccc2-c2c(-c3nc(-c4ccccc4)c4cccc(-n5c6cccc7c8cccc9c%10ccccc%10n(c%10cccc5c%10c76)c89)c4n3)cccc21]

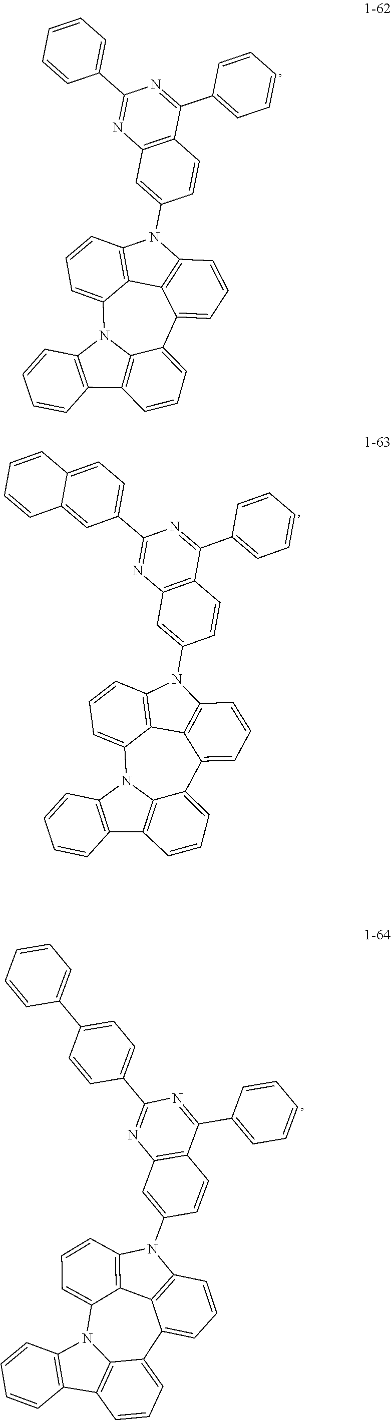

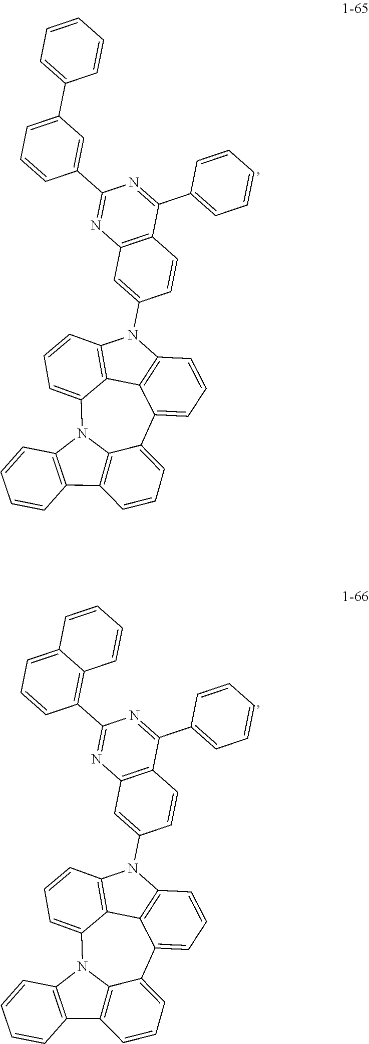 [SMILES: c1ccc(-c2cccc(-c3nc(-c4ccccc4)c4ccc(-n5c6cccc7c8cccc9c%10ccccc%10n(c%10cccc5c%10c76)c89)cc4n3)c2)cc1 ; c1ccc(-c2nc(-c3cccc4ccccc34)nc3cc(-n4c5cccc6c7cccc8c9ccccc9n(c9cccc4c9c65)c78)ccc23)cc1]

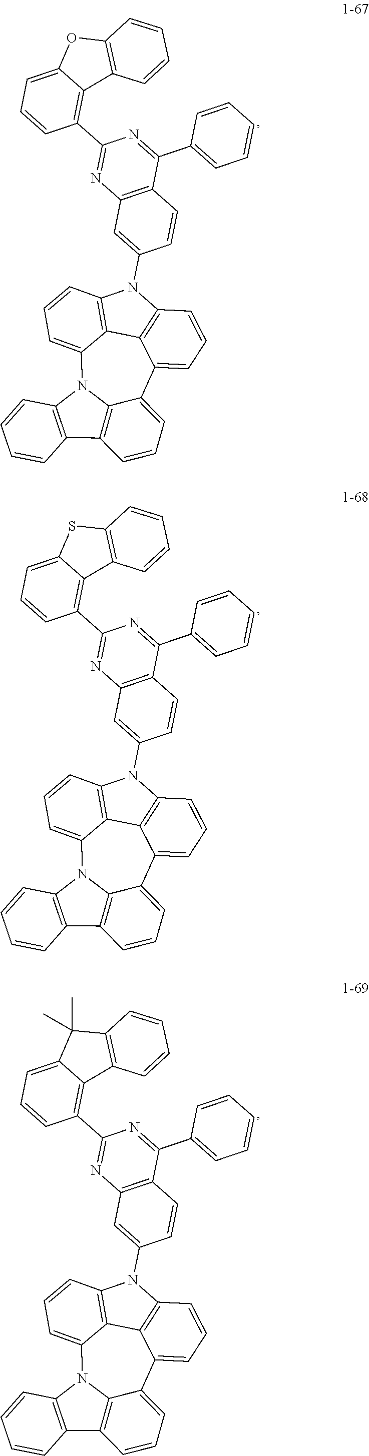

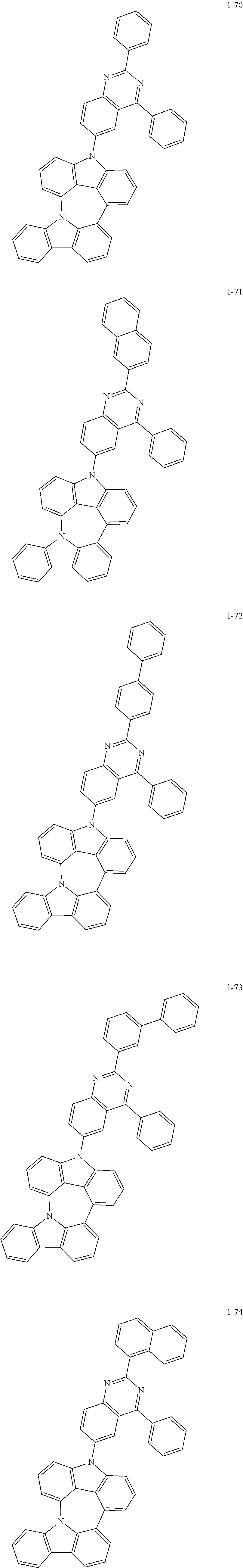 [SMILES: c1ccc(-c2nc(-c3ccccc3)c3cc(-n4c5cccc6c7cccc8c9ccccc9n(c9cccc4c9c65)c78)ccc3n2)cc1 ; c1ccc(-c2nc(-c3ccc4ccccc4c3)nc3ccc(-n4c5cccc6c7cccc8c9ccccc9n(c9cccc4c9c65)c78)cc23)cc1 ; c1ccc(-c2ccc(-c3nc(-c4ccccc4)c4cc(-n5c6cccc7c8cccc9c%10ccccc%10n(c%10cccc5c%10c76)c89)ccc4n3)cc2)cc1 ; c1ccc(-c2cccc(-c3nc(-c4ccccc4)c4cc(-n5c6cccc7c8cccc9c%10ccccc%10n(c%10cccc5c%10c76)c89)ccc4n3)c2)cc1 ; c1ccc(-c2nc(-c3cccc4ccccc34)nc3ccc(-n4c5cccc6c7cccc8c9ccccc9n(c9cccc4c9c65)c78)cc23)cc1]

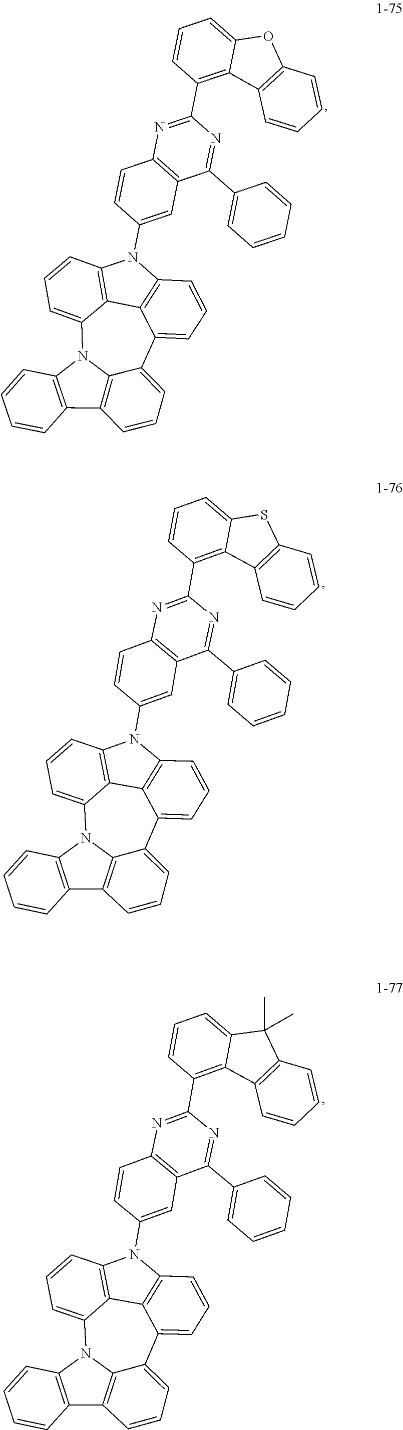 [SMILES: c1ccc(-c2nc(-c3cccc4oc5ccccc5c34)nc3ccc(-n4c5cccc6c7cccc8c9ccccc9n(c9cccc4c9c65)c78)cc23)cc1 ; c1ccc(-c2nc(-c3cccc4sc5ccccc5c34)nc3ccc(-n4c5cccc6c7cccc8c9ccccc9n(c9cccc4c9c65)c78)cc23)cc1 ; CC1(C)c2ccccc2-c2c(-c3nc(-c4ccccc4)c4cc(-n5c6cccc7c8cccc9c%10ccccc%10n(c%10cccc5c%10c76)c89)ccc4n3)cccc21]

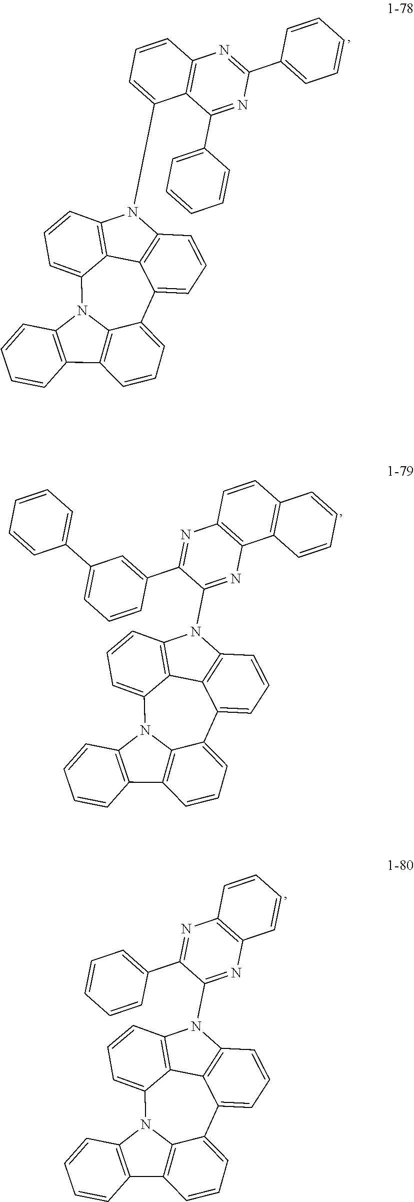 [SMILES: c1ccc(-c2nc(-c3ccccc3)c3c(-n4c5cccc6c7cccc8c9ccccc9n(c9cccc4c9c65)c78)cccc3n2)cc1 ; c1ccc(-c2cccc(-c3nc4ccc5ccccc5c4nc3-n3c4cccc5c6cccc7c8ccccc8n(c8cccc3c8c54)c67)c2)cc1 ; c1ccc(-c2nc3ccccc3nc2-n2c3cccc4c5cccc6c7ccccc7n(c7cccc2c7c43)c56)cc1]

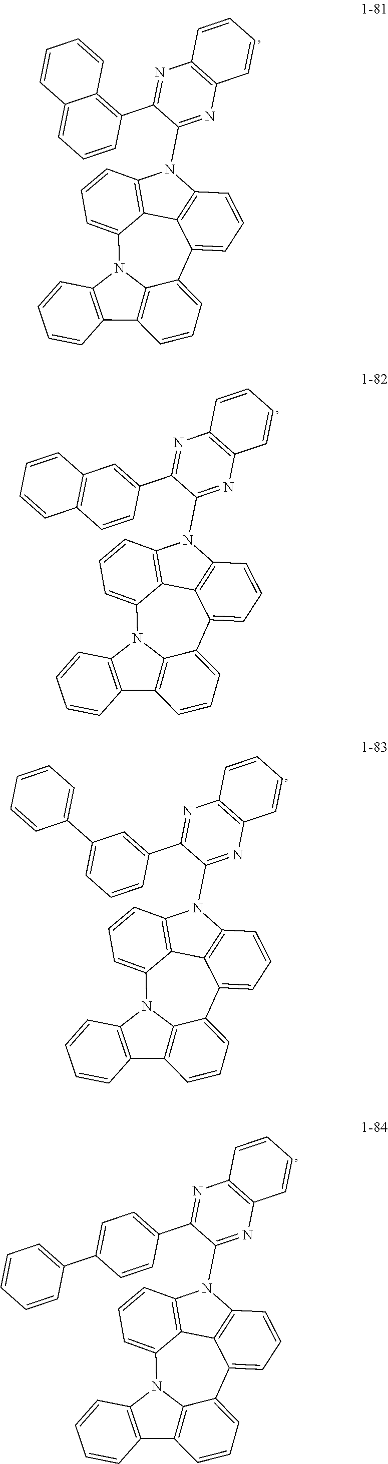 [SMILES: c1ccc2c(-c3nc4ccccc4nc3-n3c4cccc5c6cccc7c8ccccc8n(c8cccc3c8c54)c67)cccc2c1 ; c1ccc2cc(-c3nc4ccccc4nc3-n3c4cccc5c6cccc7c8ccccc8n(c8cccc3c8c54)c67)ccc2c1 ; c1ccc(-c2cccc(-c3nc4ccccc4nc3-n3c4cccc5c6cccc7c8ccccc8n(c8cccc3c8c54)c67)c2)cc1 ; c1ccc(-c2ccc(-c3nc4ccccc4nc3-n3c4cccc5c6cccc7c8ccccc8n(c8cccc3c8c54)c67)cc2)cc1]

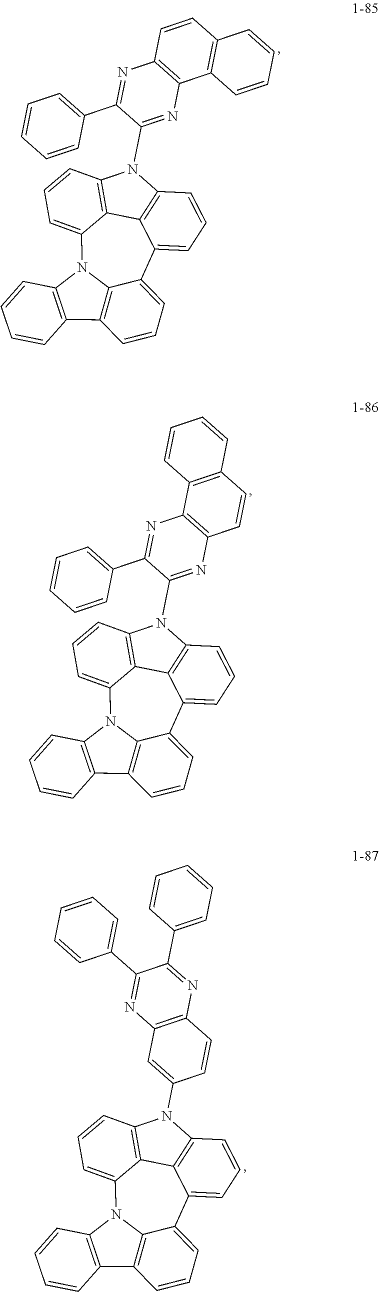 [SMILES: c1ccc(-c2nc3ccc4ccccc4c3nc2-n2c3cccc4c5cccc6c7ccccc7n(c7cccc2c7c43)c56)cc1 ; c1ccc(-c2nc3c(ccc4ccccc43)nc2-n2c3cccc4c5cccc6c7ccccc7n(c7cccc2c7c43)c56)cc1 ; c1ccc(-c2nc3ccc(-n4c5cccc6c7cccc8c9ccccc9n(c9cccc4c9c65)c78)cc3nc2-c2ccccc2)cc1]

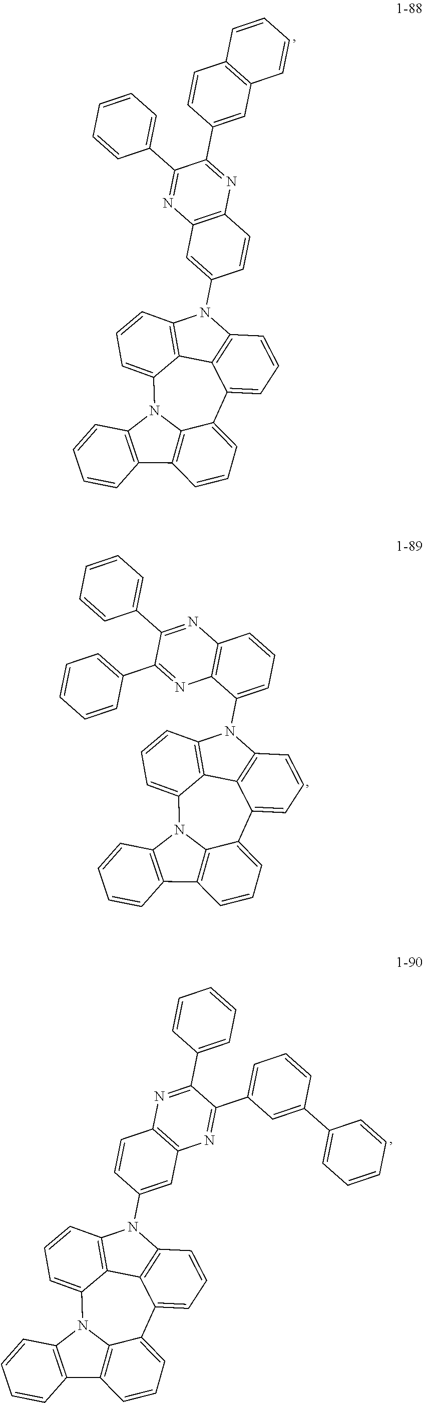 [SMILES: c1ccc(-c2nc3cc(-n4c5cccc6c7cccc8c9ccccc9n(c9cccc4c9c65)c78)ccc3nc2-c2ccc3ccccc3c2)cc1 ; c1ccc(-c2nc3cccc(-n4c5cccc6c7cccc8c9ccccc9n(c9cccc4c9c65)c78)c3nc2-c2ccccc2)cc1 ; c1ccc(-c2cccc(-c3nc4cc(-n5c6cccc7c8cccc9c%10ccccc%10n(c%10cccc5c%10c76)c89)ccc4nc3-c3ccccc3)c2)cc1]

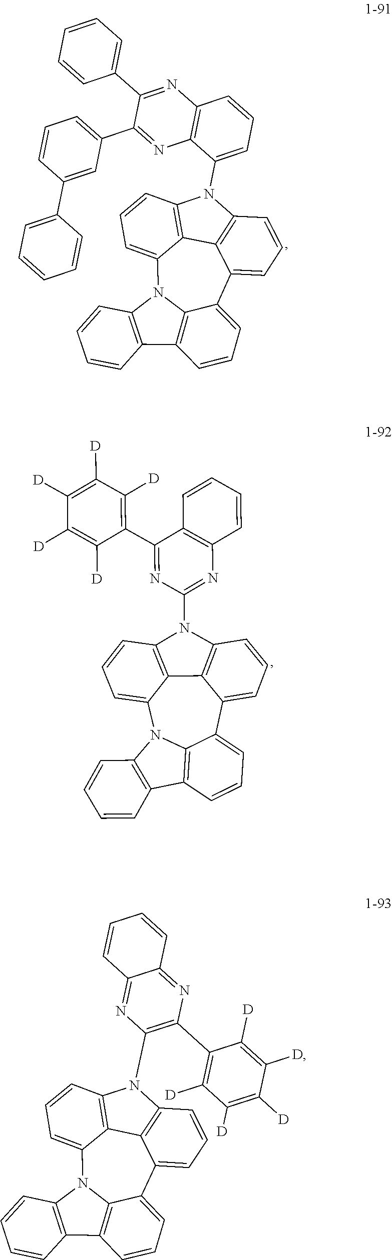

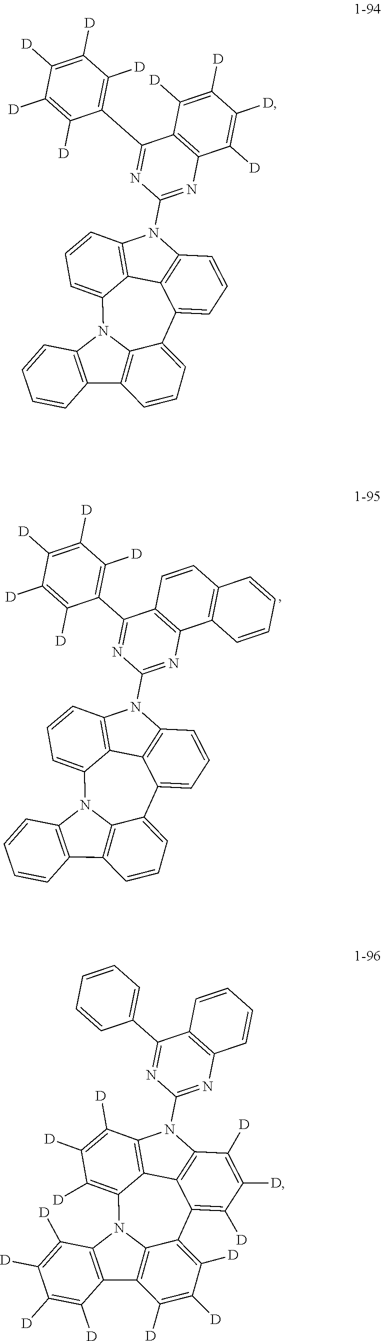

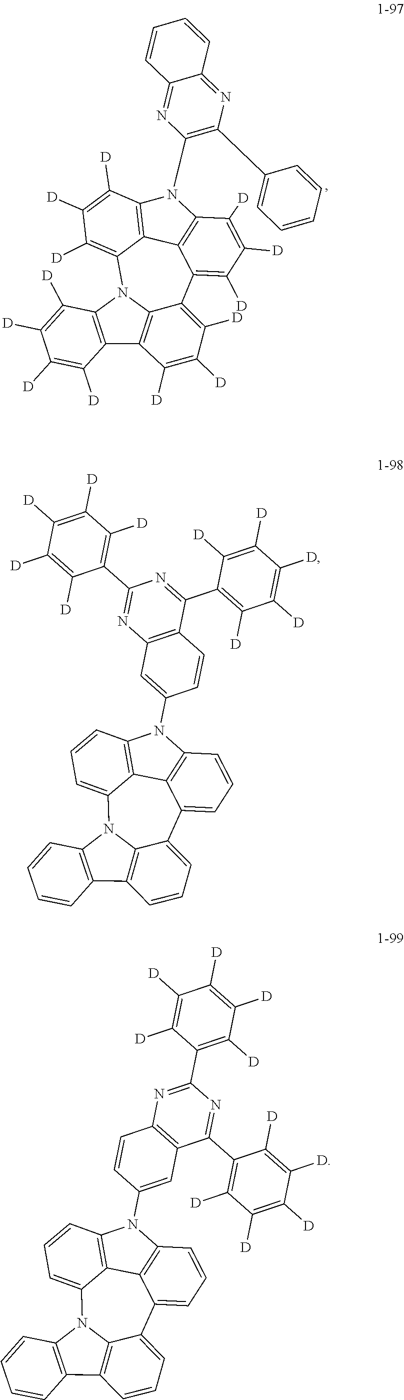

According to an embodiment of the present disclosure, hydrogens in Compound 1-1 to Compound 1-99 can be partially or fully substituted with deuterium.

According to an embodiment of the present disclosure, in the organic electroluminescent device, the emissive layer is in direct contact with the electron blocking layer.

According to an embodiment of the present disclosure, an organic electroluminescent device is disclosed. The organic electroluminescent device comprises:
an anode,
a cathode,
an emissive layer disposed between the anode and the cathode, and
an electron blocking layer disposed between the anode and the emissive layer, wherein the electron blocking layer comprises an electron blocking material with a hole mobility μₕ≤65×10⁻⁵ cm²/(V·s);
capacitance of the organic electroluminescent device satisfies the following condition: at 500 Hz, a maximum capacitance value per unit of emissive area of the organic electroluminescent device is Cₘₐₓ₋ₛ, and ΔCₛ=C₀₋ₛ−Cₘₐₓ₋ₛ≥10 nF/cm²;
wherein C₀₋ₛ denotes a maximum capacitance value per unit of emissive area of an organic electroluminescent device A at 500 Hz, and the organic electroluminescent device A is the same as the organic electroluminescent device except that the electron blocking material in the electron blocking layer of the organic electroluminescent device is replaced with Compound HT;
Compound HT has the following structure:

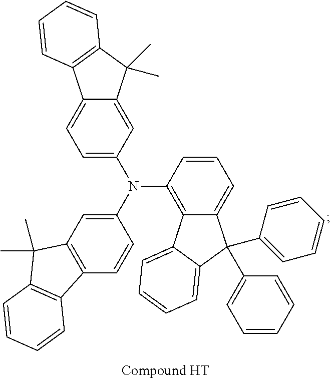 [SMILES: CC1(C)c2ccccc2-c2ccc(N(c3ccc4c(c3)C(C)(C)c3ccccc3-4)c3cccc4c3-c3ccccc3C4(c3ccccc3)c3ccccc3)cc21]

wherein the emissive layer satisfies the following conditions: a hole-only device comprising the emissive layer with a thickness of 400 Å has a drive voltage V_{HOD}@J10≤8.0 V at a current density of 10 mA/cm², and an electron-only device comprising the emissive layer with a thickness of 400 Å has a drive voltage V_{EOD}@J10≤8.0 V at a current density of 10 mA/cm²;
the hole-only device comprising the emissive layer with a thickness of 400 Å has the following structure:
ITO (1200 Å)/HTM:PD (with a weight ratio of 97:3, 100 Å)/HTM (400 Å)/HT-2 (50 Å)/the emissive layer (400 Å)/HTM (400 Å)/HTM:PD (with a weight ratio of 97:3, 100 Å)/A₁ (1200 Å);
Compound HTM, Compound PD, and Compound HT-2 have the following structures:

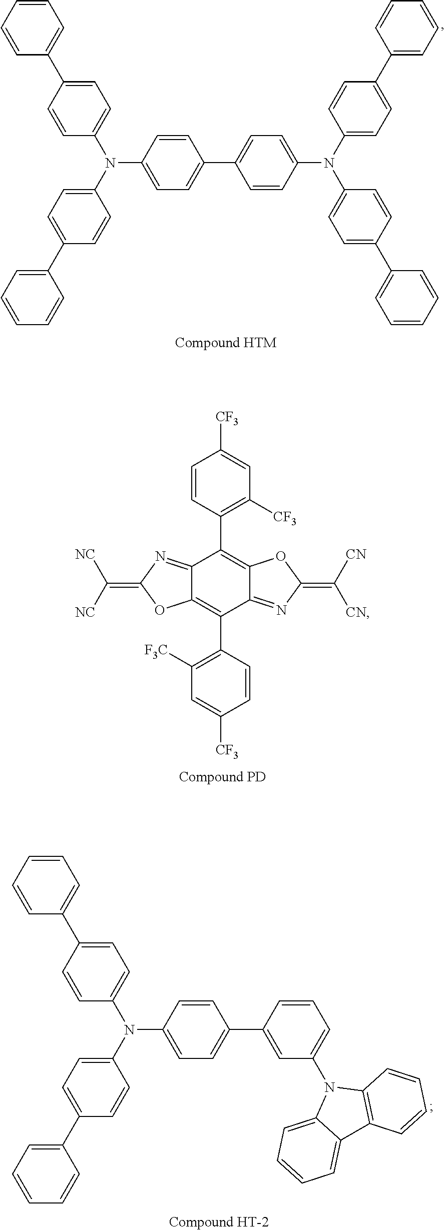 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2ccc(N(c3ccc(-c4ccccc4)cc3)c3ccc(-c4cccc(-n5c6ccccc6c6ccccc65)c4)cc3)cc2)cc1]

the electron-only device comprising the emissive layer with a thickness of 400 Å has the following structure:
ITO (1200 Å)/Liq (10 Å)/the emissive layer (400 Å)/ET:Liq (with a weight ratio of 40:60, 300 Å)/Liq (10 Å)/Al (1200 Å); and
Compound ET and Liq have the following structures:

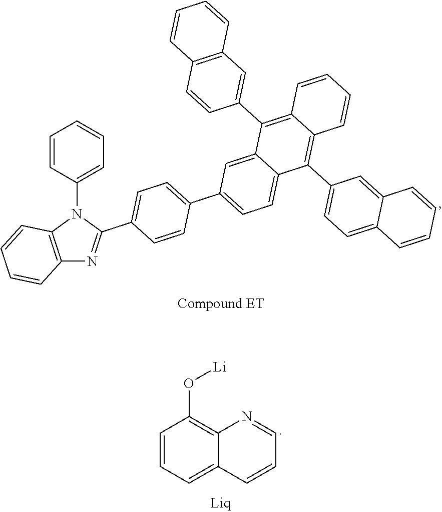

In this embodiment, “the maximum capacitance value per unit of emissive area of the organic electroluminescent device” refers to that if a maximum capacitance value of an organic electroluminescent device Y with an emissive area S (unit: cm²) at 500 Hz is Cₘₐₓ (unit: nF), the maximum capacitance value per unit of emissive area is Cₘₐₓ₋ₛ=Cₘₐₓ/S (unit: nF/cm²). Similarly, “the maximum capacitance value C₀₋ₛ per unit of emissive area of the organic electroluminescent device A at 500 Hz” refers to that if a maximum capacitance value of the organic electroluminescent device A with the emissive area S (unit: cm²) is C₀ (unit: nF), then the maximum capacitance value per unit of emissive area is C₀₋ₛ=C₀/S (unit: nF/cm²). For example, if the maximum capacitance value of the organic electroluminescent device Y with an emissive area S of 0.04 cm² and the maximum capacitance value of the organic electroluminescent device A with an emissive area S of 0.04 cm² at 500 Hz are Cₘₐₓ and C₀, respectively, then the maximum capacitance value per unit of emissive area of the organic electroluminescent device Y is Cₘₐₓ₋ₛ=Cₘₐₓ/0.04 (unit: nF/cm²), the maximum capacitance value per unit of emissive area of the organic electroluminescent device A is C₀₋ₛ=C₀/0.04 (unit: nF/cm²), and a difference between the maximum capacitance values per unit of emissive area of the organic electroluminescent device A and the organic electroluminescent device Y is ΔCₛ=C₀₋ₛ−Cₘₐₓ₋ₛ=C₀/0.04−Cₘₐₓ/0.04 (unit: nF/cm²). In another example, when the emissive area of 8 cm², the maximum capacitance value of the organic electroluminescent device Y is 8Cₘₐₓ₋ₛ (unit: nF), the maximum capacitance value of the organic electroluminescent device A is 8C₀₋ₛ (unit: nF), and the difference between the maximum capacitance values of the organic electroluminescent device A and the organic electroluminescent device Y is ΔCₛ=8C₀₋ₛ₋₈Cₘₐₓ₋ₛ=200C₀−200Cₘₐₓ (unit: nF/cm²).

According to an embodiment of the present disclosure, ΔCₛ≥12.5 nF/cm².

According to an embodiment of the present disclosure, ΔCₛ≥20 nF/cm².

According to an embodiment of the present disclosure, ΔCₛ≥25 nF/cm².

According to an embodiment of the present disclosure, the maximum capacitance value per unit of emissive area of the organic electroluminescent device is 12.5 nF/cm²≤Cₘₐₓ₋ₛ≤137.5 nF/cm².

According to an embodiment of the present disclosure, the maximum capacitance value per unit of emissive area of the organic electroluminescent device is 25 nF/cm²≤Cₘₐₓ₋ₛ≤100 nF/cm².

According to an embodiment of the present disclosure, the maximum capacitance value per unit of emissive area of the organic electroluminescent device is 25 nF/cm²≤Cₘₐₓ₋ₛ≤75 nF/cm².

According to an embodiment of the present disclosure, the maximum capacitance value per unit of emissive area of the organic electroluminescent device is 25 nF/cm²≤Cₘₐₓ₋ₛ≤62.5 nF/cm².

According to an embodiment of the present disclosure, a display assembly is disclosed. The display assembly comprises an organic electroluminescent device, wherein the specific structure of the organic electroluminescent device is shown in any one of the preceding embodiments.

Combination with Other Materials

The materials described in the present disclosure for a particular layer in an organic light emitting device can be used in combination with various other materials present in the device. The combinations of these materials are described in more detail in U.S. Pat. Pub. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, compounds disclosed herein may be used in combination with a wide variety of light-emitting dopants, hosts, transporting layers, blocking layers, injection layers, electrodes, and other layers that may be present. The combination of these materials is described in detail in paragraphs 0080-0101 of U.S. Pat. Pub. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

The present disclosure has found through researches that the matching of materials in a device, such as the selection, combination, and matching of an emissive layer material with certain hole and electron transporting characteristics and an electron blocking material with a particular hole mobility, can greatly reduce device capacitance and reduce a device voltage to obtain higher display quality, which is analyzed and described below in conjunction with specific data.

In the present disclosure, a hole-only device (HOD) comprising an emissive layer to be tested was prepared by the following method: a glass substrate having a thickness of 0.7 mm, patterned with an indium tin oxide (ITO) anode with a thickness of 1200 Å, and having a sheet resistance of 14 to 20 Ω/sq and an effective emissive area of 4 mm² was washed with deionized water and a detergent, and then the ITO surface was treated with oxygen plasma and UV ozone. The substrate was dried in a glovebox to remove moisture, mounted on a support, and transferred into a vacuum chamber. The organic layers specified below were sequentially deposited on the anode layer through vacuum thermal evaporation at a rate of 0.01-10 Å/s and at a vacuum degree of about 106 Torr. Compound HTM and Compound PD were co-deposited at a weight ratio of 97:3 for use as a hole injection layer (HIL, 100 Å). Compound HTM was deposited for use as a hole transporting layer (HTL, 400 Å). Compound HT-2 was used as an electron blocking layer (EBL, 50 Å). The emissive layer (EML, 400 Å) to be tested was deposited. On the EML, Compound HTM was deposited for use as an electron transporting layer (ETL, 400 Å). Compound HTM and Compound PD were co-deposited at a weight ratio of 97:3 for use as an electron injection layer (EIL, 100 Å). Finally, the metal aluminum was deposited for use as a cathode (1200 Å). The device was transferred back to the glovebox and encapsulated with a glass lid to complete the device. The device was the hole-only device having the following structure: ITO (1200 Å)/HTM:PD (with a weight ratio of 97:3, 100 Å)/HTM (400 Å)/HT-2 (50 Å)/the emissive layer (400 Å)/HTM (400 Å)/HTM:PD (with a weight ratio of 97:3, 100 Å)/Al (1200 Å).

Compound HTM, Compound PD, and Compound HT-2 have the following structures:

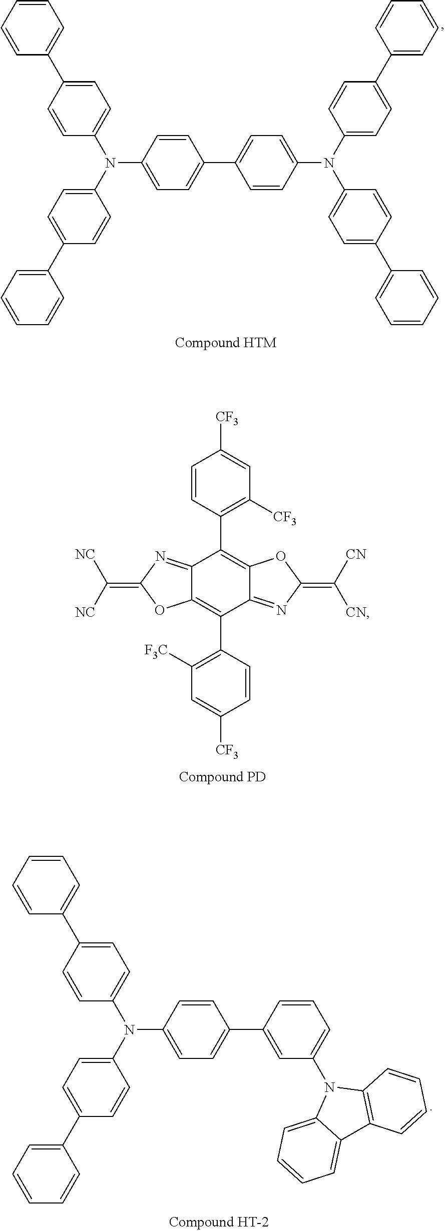 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2ccc(N(c3ccc(-c4ccccc4)cc3)c3ccc(-c4cccc(-n5c6ccccc6c6ccccc65)c4)cc3)cc2)cc1]

In the present disclosure, an electron-only device (EOD) comprising the emissive layer to be tested was prepared by the following method: a glass substrate having a thickness of 0.7 mm, patterned with an indium tin oxide (ITO) anode with a thickness of 1200 Å, and having a sheet resistance of 14 to 20 Ω/sq and an effective emissive area of 4 mm² was washed with deionized water and a detergent, and then the ITO surface was treated with oxygen plasma and UV ozone. The substrate was dried in a glovebox to remove moisture, mounted on a support, and transferred into a vacuum chamber. The organic layers specified below were sequentially deposited on the anode layer through vacuum thermal evaporation at a rate of 0.01-10 Å/s and at a vacuum degree of about 10⁻⁶ Torr. A compound Liq was deposited for use as an electron injection layer (EIL, 10 Å). The emissive layer (EML, 400 Å) to be tested was deposited. On the EML, Compound ET and the compound Liq were co-deposited at a weight ratio of 40:60 (300 Å). The compound Liq was deposited (10 Å). Finally, the metal aluminum was deposited for use as a cathode (1200 Å). The device was transferred back to the glovebox and encapsulated with a glass lid to complete the device. The device was the electron-only device having the following structure: ITO (1200 Å)/Liq (10 Å)/the emissive layer (400 Å)/ET:Liq (with a weight ratio of 40:60, 300 Å)/Liq (10 Å)/Al (1200 Å).

Compound ET and Liq have the following structures:

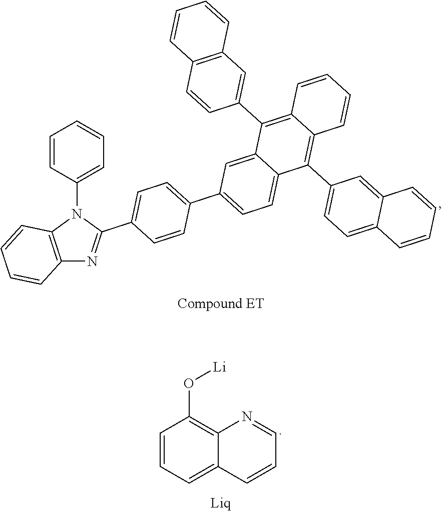

J-V curves of the hole-only device and the electron-only device were tested separately by a current-voltage-luminance (IVL) photoelectric testing system S-1000GA4 of Suzhou Fstar Scientific Instrument Co., Ltd., and drive voltages (V) at a current density of 10 mA/cm², that is, V_{HOD}@J10 and V_{EOD}@J10, were obtained. The data are shown in Table 1. The structures of Compound 1-9, Compound RD-4, Compound RD, and Compound P-RH are given after Table 3.

TABLE 1
V_{EOD}@J10, V_{HOD}@J10, and F of some emissive layers

| | | | | F = |
|---|---|---|---|---|
| Emissive | Structure of the | V_{HOD}@J10 | V_{EOD}@J10 | V_{EOD}/ |
| Layer No. | Emissive Layer | [V] | [V] | V_{HOD} |
| Emissive | Compound | 4.78 | 5.67 | 1.19 |
| layer 1 | 1-9:Compound RD-4 | | | |
| | (98:2, 400 Å) | | | |
| Emissive | Compound | 8.14 | 5.75 | 0.71 |
| layer 2 | 1-9:Compound RD | | | |
| | (98:2, 400 Å) | | | |
| Emissive | Compound | 4.80 | 8.20 | 1.71 |
| layer 3 | 1-9:Compound | | | |
| | P-RH:Compound | | | |
| | RD-4 (30:68:2, 400 Å) | | | |

V_{HOD}@J10 represents the hole transporting performance of the emissive layer, and V_{EOD}@J10 represents the electron transporting performance of the emissive layer. V_{HOD}@J10 or V_{EOD}@J10 less than or equal to 8.00 V indicates good hole or electron transporting performance of the emissive layer, and V_{HOD}@J10 or V_{EOD}@J10 greater than 8.00 V indicates poor hole or electron transporting performance of the emissive layer.

V_{HOD}@J10 and V_{EOD}@J10 of the emissive layer 1 were 4.78 V and 5.67 V, respectively. Therefore, the emissive layer 1 had relatively good hole and electron transporting performance. V_{HOD}@J10 and V_{EOD}@J10 of the emissive layer 2 were 8.14 V and 5.75 V, respectively. Therefore, the emissive layer 2 had relatively poor hole transporting performance and relatively good electron transporting performance. When a certain amount of a p-type host material P-RH was doped into the emissive layer 1, the emissive layer 3 was obtained, V_{HOD}@J10 of the emissive layer 3 was 4.80 V and differed not much from V_{HOD}@J10 of the emissive layer 1, and the emissive layer 3 also had relatively good hole transporting performance, but V_{EOD}@J10 of the emissive layer 3 was 8.20 V. Compared with the emissive layer 1, the emissive layer doped with the p-type host material P-RH had a greatly reduced electron transporting capability. Thus the emissive layer 3 had relatively good hole transporting performance and relatively poor electron transporting performance. Additionally, V_{HOD}@J10≤8.00 V, V_{EOD}@J10≤8.00 V, and F=V_{EOD}/V_{HOD}≥0.8 of the emissive layer indicate that the emissive layer not only has relatively good hole and electron transporting performance but also has a hole transporting capacity stronger than its electron transporting capacity.

In the present disclosure, highest occupied molecular orbital (HOMO) energy levels of compounds were measured through cyclic voltammetry. The specific method adopted an electrochemical workstation CorrTest CS120 produced by Wuhan Corrtest Instruments Corp., Ltd and a three-electrode working system where a platinum disk electrode served as a working electrode, a Ag/AgNO₃ electrode served as a reference electrode, and a platinum wire electrode served as an auxiliary electrode. With anhydrous DCM as a solvent and 0.1 mol/L tetrabutylammonium hexafluorophosphate as a supporting electrolyte, a compound to be tested was prepared into a solution of 10⁻³ mol/L, and nitrogen was introduced into the solution for 10 min for oxygen removal before the test. The parameters of the instrument were set as follows: a scan rate of 100 mV/s, a potential interval of 0.5 mV, and a test window of 1 V to −0.5 V HOMO energy levels of some compounds are listed in Table 2.

In the present disclosure, a hole mobility test device (HMTD) was prepared by the following method: a glass substrate having a thickness of 0.7 mm, patterned with an indium tin oxide (ITO) anode with a thickness of 1200 Å, and having a sheet resistance of 14 to 20 Ω/sq and an effective emissive area of 4 mm² was washed with deionized water and a detergent, and then the ITO surface was treated with oxygen plasma and UV ozone. The substrate was dried in a glovebox to remove moisture, mounted on a support, and transferred into a vacuum chamber. The organic layers specified below were sequentially deposited on the anode layer through vacuum thermal evaporation at a rate of 0.01-10 Å/s and at a vacuum degree of about 10⁻⁶ Torr. Compound HTM2 and Compound PD were co-deposited at a weight ratio of 80:20 for use as a hole injection layer (HIL, 100 Å). The compound to be tested was deposited at a thickness of 1000 Å. Compound HTM2 and Compound PD were co-deposited at a weight ratio of 80:20 for use as an electron injection layer (EIL, 100 Å). Finally, the metal silver was deposited for use as a cathode (200 Å). The device was transferred back to the glovebox and encapsulated with a glass lid to complete the device. The device was the hole mobility test device having the following structure: ITO (1200 Å)/HTM2:PD (with a weight ratio of 80:20, 100 Å)/the compound to be tested (1000 Å)/HTM2:PD (with a weight ratio of 80:20, 100 Å)/Ag (200 Å).

Compound HTM2 and Compound PD have the following structures:

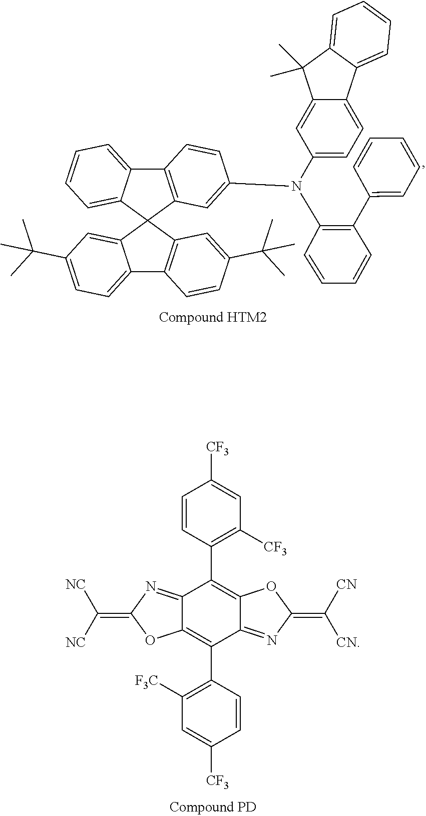 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1]

In the present disclosure, for the hole mobility of the compound, the J-V curve of the above hole mobility test device was tested by the IVL photoelectric testing system S-1000GA4 of Suzhou Fstar Scientific Instrument Co., Ltd., a J^{1/2}-V curve of the device was fitted, and the hole mobility was calculated according to Mott-Gurney equation.

The Mott-Gurney equation is as follows:

$$μ = \frac{8 {d}^{3}}{9 {ε}_{o} {ε}_{r}} {( \frac{\sqrt{J}}{V} )}^{2} .$$

In the Mott-Gurney equation, εᵣ denotes a relative dielectric constant of the compound to be tested and εᵣ=3 for an organic compound, εₒ denotes a vacuum dielectric constant and εₒ=8.85×10⁻¹² F/m, d denotes a sample thickness (unit: m), J denotes a current density (unit: A/m²), V denotes a voltage (unit: V), and μ denotes the hole mobility of the compound to be tested. The compound to be tested was tested to 80 mA/cm² by scanning the voltage (with a step size of 0.3 V), the J^{1/2}-V curve of the device comprising the compound to be tested was plotted, and test points (generally no less than 4 data points) close to 80 mA/cm² were selected. Here, the data under appropriate voltage conditions were selected for fitting to obtain a fitting straight line whose formula was y=ax−b, wherein the slope a represents J^{1/2}/V, the abscissa x represents the voltage V, the ordinate y represents a square root of the current density J, and b represents an intercept. The hole mobility of the compound may be calculated through the above formulas.

The HOMO energy levels and hole mobility of some compounds obtained by the preceding method are shown in Table 2.

TABLE 2
HOMO energy levels and hole mobility of some compounds

| | | Hole Mobility |
|---|---|---|
| Compound No. | HOMO [eV] | [×10⁻⁵ cm²/(V · s)] |
| HT | −5.182 | 68 |
| C176 | −5.113 | 28 |
| C64 | −5.131 | 27 |
| C4 | −5.125 | 30 |

In commercial applications, the thickness of an electron blocking layer is generally greater than 350 Å or even reaches about 1000 Å. Therefore, to avoid or reduce the problems of a high voltage and the like due to too large a thickness of the electron blocking layer, a material with a relatively high hole mobility is widely applied. As shown in Table 2, different electron blocking materials have different hole mobility, where Compound HT had a hole mobility of 68×10−5 cm²/(V·s), which has a relatively high hole mobility and is a relatively good electron blocking material. However, the hole mobility of each electron blocking material, Compound C₁₇₆, Compound C₆₄, or Compound C₄, was lower than that of Compound HT and was 28×10⁻⁵ cm²/(V·s), 27×10⁻⁵ cm²/(V·s), and 30×10⁻⁵ cm²/(V·s), respectively. These electron blocking materials are not preferred in commercial applications. Additionally, the HOMO energy level of a material used in the electron blocking layer generally needs to be between HOMO energy levels of a material used in the hole transporting layer and a host material in the emissive layer to avoid a relatively high potential barrier due to a relatively large energy level difference.

Generally speaking, in commercial devices, those emissive layers having relatively good hole transporting performance (V_{HOD}@J10≤8.0 V) and relatively good electron transporting performance (V_{EOD}@J10≤8.0 V) are generally matched with the electron blocking material with a high hole mobility to ensure a relatively low device voltage. However, the matching of such emissive layers with the electron blocking material with a high hole mobility accelerates the transport and accumulation of holes in the device, and thus an amount of holes accumulated gradually increases, resulting in an increase in capacitance, which affects the reaction rate and display quality of the device at a high refresh rate. The inventors have found that the matching of such emissive layers with an electron blocking material with a relatively low hole mobility can effectively reduce the transport and accumulation of holes. Meanwhile, since the emissive layers have relatively good hole transporting performance and electron transporting performance, the recombination of holes and electrons in the emissive layer is facilitated, and the accumulation of holes can be further reduced so that the device capacitance can be greatly reduced. The following description is provided through specific device examples.

### Device Example

### Example 1: Preparation of an Organic Electroluminescent Device Emitting Red Light

A glass substrate having a thickness of 0.7 mm, patterned with an ITO/silver (Ag)/ITO anode with a thickness of 75 Å/1500 Å/150 Å, and having a sheet resistance of 0.1 to 0.3 Ω/sq and an emissive area of 0.04 cm² was washed with deionized water and a detergent, and then the ITO surface was treated with oxygen plasma and UV ozone. The substrate was dried in a glovebox to remove moisture, mounted on a support, and transferred into a vacuum chamber. The organic layers specified below were sequentially deposited on the anode layer through vacuum thermal evaporation at a rate of 0.01-10 Å/s and at a vacuum degree of about 10⁻⁶ Torr. Compound HTM and Compound PD were co-deposited at a weight ratio of 97:3 for use as a hole injection layer (HIL, 100 Å). Compound HTM was deposited for use as a hole transporting layer (HTL, 1300 Å). Compound C₁₇₆ was deposited for use as an electron blocking layer (EBL, 750 Å), which is a microcavity adjustment layer reaching an optimal microcavity length at a thickness of 750 Å. Compound 1-9 and Compound RD-4 were co-deposited at a weight ratio of 98:2 for use as an emissive layer (EML, 400 Å). Compound HB was deposited for use as a hole blocking layer (HBL, 50 Å). Compound ET and Liq were co-deposited at a weight ratio of 40:60 for use as an electron transporting layer (ETL, 350 Å). On the ETL, the metal Yb was deposited for use as an electron injection layer (EIL, 10 Å). The metal magnesium and the metal silver were co-deposited at a weight ratio of 10:90 for use as a cathode (140 Å). Finally, a CPL material was deposited for use as a capping layer (CPL, 650 Å), where the CPL material is a selected material with a refractive index of about 1.68 at 620 nm, and a 30 nm thick CPL material deposited on a silicon wafer was tested by an ellipsometer ES01 from BEIJING ELLITOP to obtain the refractive index). The device was transferred back to the glovebox and encapsulated with a glass lid to complete the device.

Example 2: This example was prepared by the same method as Example 1 except that Compound C₆₄ was deposited for use as an electron blocking layer (EBL, 750 Å).

Example 3: This example was prepared by the same method as Example 1 except that Compound C₄ was deposited for use as an electron blocking layer (EBL, 750 Å).

Comparative Example 1: This comparative example was prepared by the same method as Example 1 except that Compound HT was deposited for use as an electron blocking layer (EBL, 750 Å).

Comparative Example 2: This comparative example was prepared by the same method as Comparative Example 1 except that Compound 1-9 and Compound RD were co-deposited at a weight ratio of 98:2 for use as an emissive layer (EML, 400 Å).

Comparative Example 3: This comparative example was prepared by the same method as Example 1 except that Compound 1-9 and Compound RD were co-deposited at a weight ratio of 98:2 for use as an emissive layer (EML, 400 Å).

Comparative Example 4: This comparative example was prepared by the same method as Comparative Example 1 except that Compound 1-9, Compound P-RH, and Compound RD-4 were co-deposited at a weight ratio of 30:68:2 for use as an emissive layer (EML, 400 Å).

Comparative Example 5: This comparative example was prepared by the same method as Example 1 except that Compound 1-9, Compound P-RH, and Compound RD-4 were co-deposited at a weight ratio of 30:68:2 for use as an emissive layer (EML, 400 Å).

The structures and thicknesses of part of layers of the devices are shown in Table 3. A layer using more than one material is obtained by doping different compounds at their weight ratio as recorded.

TABLE 3
Device structures of some organic layers in Examples
1 to 3 and Comparative Examples 1 to 5

| Device | | | |
|---|---|---|---|
| No. | HTL | EBL | EML |
| Example 1 | HTM | Compound C176 | Compound 1-9:Compound |
| | (1300 Å) | (750 Å) | RD-4 (98:2, 400 Å) |
| Example 2 | HTM | Compound C64 | Compound 1-9:Compound |
| | (1300 Å) | (750 Å) | RD-4 (98:2, 400 Å) |
| Example 3 | HTM | Compound C4 | Compound 1-9:Compound |
| | (1300 Å) | (750 Å) | RD-4 (98:2, 400 Å) |
| Comparative | HTM | Compound HT | Compound 1-9:Compound |
| Example 1 | (1300 Å) | (750 Å) | RD-4 (98:2, 400 Å) |
| Comparative | HTM | Compound HT | Compound 1-9:Compound |
| Example 2 | (1300 Å) | (750 Å) | RD (98:2, 400 Å) |
| Comparative | HTM | Compound C176 | Compound 1-9:Compound |
| Example 3 | (1300 Å) | (750 Å) | RD (98:2, 400 Å) |
| Comparative | HTM | Compound HT | Compound 1-9:Compound |
| Example 4 | (1300 Å) | (750 Å) | P-RH:Compound RD-4 |
| | | | (30:68:2, 400 Å) |
| Comparative | HTM | Compound C176 | Compound 1-9:Compound |
| Example 5 | (1300 Å) | (750 Å) | P-RH:Compound RD-4 |
| | | | (30:68:2, 400 Å) |

The materials used in the devices have the following structures:

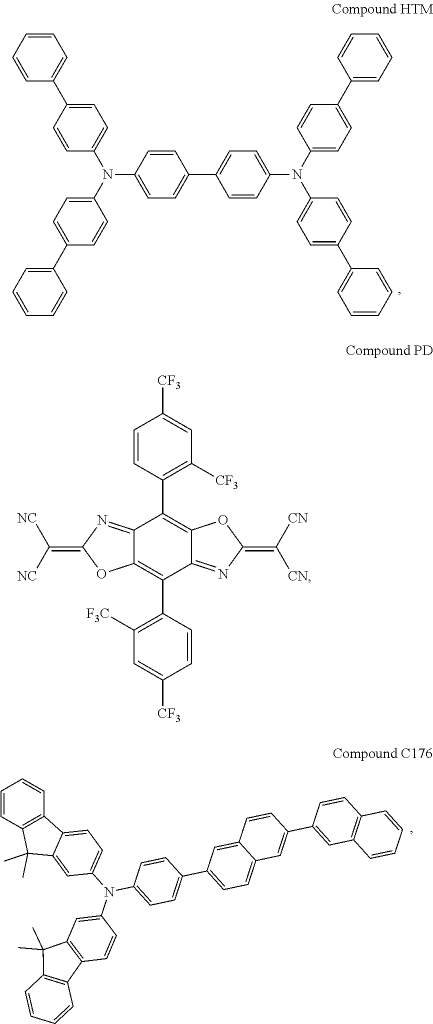 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; CC1(C)c2ccccc2-c2ccc(N(c3ccc(-c4ccc5cc(-c6ccc7ccccc7c6)ccc5c4)cc3)c3ccc4c(c3)C(C)(C)c3ccccc3-4)cc21]

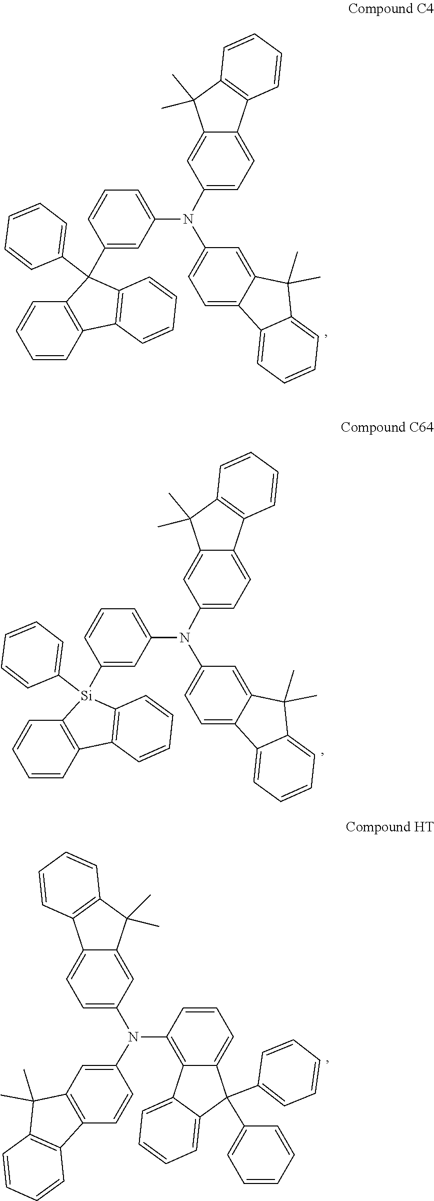

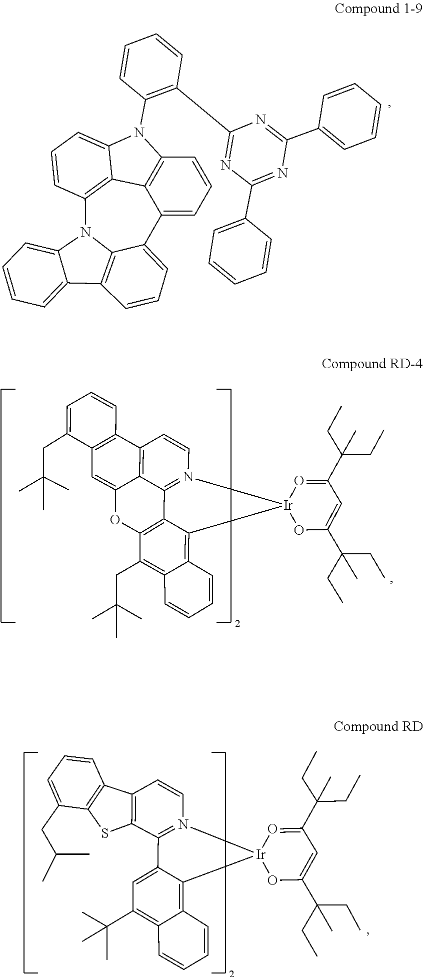

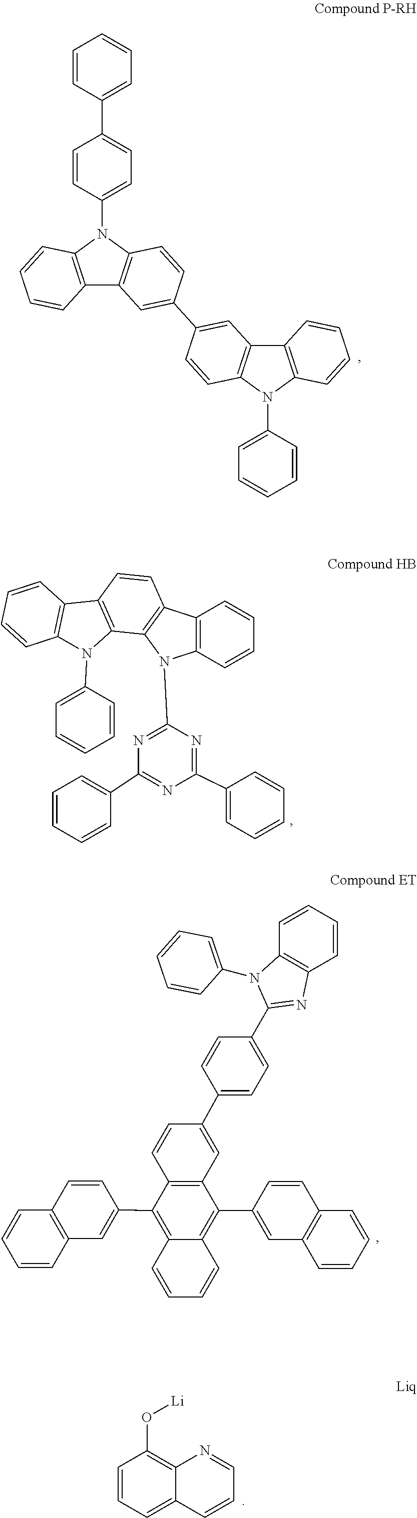

Device data of Examples 1 to 3 and Comparative Examples 1 to 5 are listed in Table 4. Color coordinates, a luminescence wavelength (λₘₐₓ), a voltage (V), and current efficiency (CE) were measured at a current density of 10 mA/cm². A direct current bias voltage of −4 V to 5 V was applied to the electrodes at two ends of the device, and an alternating current voltage of 100 mV with a frequency of 500 Hz was superimposed at the same time. The maximum capacitance (Cₘₐₓ, C₀) of Examples 1 to 3 and Comparative Examples 1 to 5 was tested, and ΔC was calculated, wherein ΔC corresponding to Examples 1 to 3 was a difference between the maximum capacitance of Examples 1 to 3 and the maximum capacitance of Comparative Example 1; ΔC corresponding to Comparative Example 3 was a difference between the maximum capacitance of Comparative Example 3 and the maximum capacitance of Comparative Example 2; and ΔC corresponding to Comparative Example was a difference between the maximum capacitance of Comparative Example and the maximum capacitance of Comparative Example 4.

TABLE 4
Device data of Examples 1 to 3 and Comparative Examples 1 to 5

| | | | | | | Maximum | |
|---|---|---|---|---|---|---|---|
| | | | | | | Capac- | |
| | | | λₘₐₓ | Volt- | CE | itance | ΔC |
| No. | CIEₓ | CIE_{y} | [nm] | age[V] | [cd/A] | [nF] | [nF] |
| Example 1 | 0.684 | 0.316 | 620 | 3.5 | 76 | 1.63 | 1.26 |
| Example 2 | 0.683 | 0.317 | 620 | 3.5 | 74 | 2.34 | 0.55 |
| Example 3 | 0.682 | 0.317 | 620 | 3.5 | 75 | 2.46 | 0.43 |
| Comparative | 0.684 | 0.316 | 620 | 3.7 | 73 | 2.89 | / |
| Example 1 | | | | | | | |
| Comparative | 0.687 | 0.313 | 622 | 3.8 | 71 | 2.11 | / |
| Example 2 | | | | | | | |
| Comparative | 0.687 | 0.313 | 622 | 3.6 | 73 | 1.79 | 0.32 |
| Example 3 | | | | | | | |
| Comparative | 0.686 | 0.312 | 620 | 4.21 | 33 | 2.72 | / |
| Example 4 | | | | | | | |
| Comparative | 0.686 | 0.312 | 620 | 3.91 | 32 | 2.93 | −0.21 |
| Example 5 | | | | | | | |

Table 4 shows the voltages, efficiency, and maximum capacitance of electroluminescent devices matching electron blocking materials having different hole mobility with emissive layers having different hole/electron transporting performance; among the device data selected here, the colors were basically the same, and the luminescence wavelengths were all about 620 nm.

For Examples 1 to 3 and Comparative Example 1, as shown in Table 1, V_{HOD}@J10 and V_{EOD}@J10 of the emissive layer (emissive layer 1) were 4.78 V and 5.67 V respectively, which were both less than 8.00 V, and the emissive layer had relatively good hole and electron transporting performance. In Example 1, after the particular emissive layer was matched with the electron blocking material, Compound C₁₇₆, with a relatively small hole mobility (μₕ=28×10⁻⁵ cm²/(V·s)), the maximum capacitance of the device was only 1.63 nF (that is, the maximum capacitance per unit of emissive area of the device was 40.75 nF/cm²). In Comparative Example 1, the emissive layer was matched with the commonly used electron blocking material, Compound HT, with a relatively large hole mobility (μₕ=68×10⁻⁵ cm²/(V·s)), and the maximum capacitance was as high as 2.89 nF (that is, the maximum capacitance per unit of emissive area of the device was 72.25 nF/cm²). Compared with Comparative Example 1, Example 1 had the maximum capacitance reduced by 1.26 nF (that is, the maximum capacitance per unit of emissive area of the device was reduced by 31.5 nF/cm²) for the main reason that the electron blocking material with a relatively small hole mobility was matched with the emissive layer with relatively good hole and electron transporting performance, and a hole migration rate in the device was reduced so that a carrier balance in the device can be effectively adjusted, thereby reducing the accumulation of holes in the device and reducing the maximum capacitance of the device. Meanwhile, although Example 1 used the electron blocking material with a relatively small hole mobility, the voltage of Example 1 was still reduced by 0.2 V compared with that of Comparative Example 1 for the reason that the HOMO energy level of the electron blocking material, Compound C₁₇₆, was −5.113 eV and more approximated to the HOMO energy level (−5.088 eV) of the hole transporting material, Compound HTM so that an energy barrier in the device was relatively small and the voltage was reduced. It is worth noting that in addition to the improvements in capacitance and voltage, the current efficiency of Example 1 was further improved by 4.1% based on the already high efficiency level of Comparative Example 1, which is very rare.

Similarly, in Examples 2 and 3, the emissive layer (emissive layer 1) was separately matched with the electron blocking materials, Compound C₆₄ (μₕ=27×10⁻⁵ cm²/(V·s)) and Compound C₄ (μₕ=30×10⁻⁵ cm²/(V·s)), with a relatively small hole mobility. Compared with Comparative Example 1, Examples 2 and 3 had the capacitance greatly reduced by 0.55 nF (that is, the maximum capacitance per unit of emissive area of the device was reduced by 13.75 nF/cm²) and 0.43 nF (that is, the maximum capacitance per unit of emissive area of the device was reduced by 10.75 nF/cm²) respectively, indicating that when the emissive layer with relatively good hole transporting performance and electron transporting performance is matched with the electron blocking material with a relatively small hole mobility, the device capacitance can be greatly reduced. Meanwhile, since the HOMO energy level (−5.131 eV) of Compound C₆₄ and the HOMO energy level (−5.125 eV) of Compound C₄ relatively approximated to the HOMO energy level (−5.088 eV) of Compound HTM, compared with Comparative Example 1, 5 Examples 2 and 3 both had the voltage reduced by 0.2 V. Additionally, the current efficiency was further improved based on the already high efficiency level of Comparative Example 1.

For Comparative Examples 2 and 3, as shown in Table 1, V_{HOD}@J10 and V_{EOD}@J10 of the emissive layer (emissive layer 2) were 8.14 V and 5.75 V, respectively, and the emissive layer had relatively poor hole transporting performance and relatively good electron transporting performance. When the emissive layer was matched with the electron blocking material, Compound HT, with a relatively high hole mobility, the maximum capacitance of Comparative Example 2 was 2.11 nF (that is, the maximum capacitance per unit of emissive area of the device was 52.75 nF/cm²). In Comparative Example 3, the emissive layer was matched with the electron blocking material, Compound C₁₇₆, with a relatively low hole mobility, the maximum capacitance of Comparative Example 3 was reduced by only 0.32 nF (that is, the maximum capacitance per unit of emissive area of the device was reduced by 8 nF/cm²) compared with that of Comparative Example 2, which was far smaller than the capacitance decrease of Example 1 relative to Comparative Example 1 (1.26 nF, that is, the maximum capacitance per unit of emissive area of the device was reduced by 31.5 nF/cm²).

Additionally, Comparative Example 3 differed from Example 1 only in that the emissive layers were different. However, the maximum capacitance of Comparative Example 3 was 1.79 nF (that is, the maximum capacitance per unit of emissive area of the device was 44.75 nF/cm²), which was significantly higher than the maximum capacitance of Example 1, indicating that only when the electron blocking material with a relatively low hole mobility disclosed in the present disclosure is matched with the emissive layer with relatively good hole transporting performance and electron transporting performance, can the capacitance be greatly reduced. Additionally, Example 1 was significantly superior to Comparative Example 3 in terms of device voltage and efficiency.

The preceding data indicated that the emissive layer of the present disclosure having relatively good hole transporting performance and relatively good electron transporting performance, when matched with the electron blocking material of the present disclosure having a relatively low hole mobility, can greatly reduce the device capacitance and further reduce the device voltage and improve device efficiency so that the device has better performance.

For Comparative Examples 4 and 5, as shown in Table 1, V_{HOD}@J10 and V_{EOD}@J10 of the emissive layer (emissive layer 3) were 4.80 V and 8.20 V, respectively, and the emissive layer had relatively good hole transporting performance and relatively poor electron transporting performance. The emissive layer was matched with Compound HT with a relatively high hole mobility in Comparative Example 4, and the emissive layer was matched with Compound C₁₇₆ with a relatively low hole mobility in Comparative Example 5. Compared with Comparative Example 4, Comparative Example 5 had the capacitance increased by 0.21 nF instead of being reduced (that is, the maximum capacitance per unit of emissive area of the device was increased by 5.25 nF/cm²), which was contrary to the great capacitance decrease of Example 1 relative to Comparative Example 1. This indicated again that only when the electron blocking material with a relatively low hole mobility disclosed in the present disclosure is matched with the emissive layer with relatively good hole transporting performance and electron transporting performance, can the capacitance be greatly reduced. Additionally, Comparative Example 5 differed from Example 1 only in that the emissive layers were different. However, the maximum capacitance of Comparative Example 5 was 2.93 nF (that is, the maximum capacitance per unit of emissive area of the device was 73.25 nF/cm²), which was far higher than the maximum capacitance of Example 1. Additionally, Example 1 was significantly superior to Comparative Example 5 in terms of device voltage and efficiency.

To conclude, the organic electroluminescent device disclosed in the present disclosure, where the emissive layer has relatively good hole transporting performance (for example, V_{HOD}@J10≤8.00 V) and relatively good electron transporting performance (for example, V_{EOD}@J10≤8.00 V) and is matched with the electron blocking material with a relatively low hole mobility selected in the present disclosure, can greatly reduce the device capacitance, which is conducive to improving the rapid charging and discharging of the entire panel and improving the response speed and power consumption of the device, and also has good performance such as the further reduced device voltage and improved device efficiency so that the organic electroluminescent device has significant advantages in the industry.

It should be understood that various embodiments described herein are merely examples and not intended to limit the scope of the present disclosure. Therefore, it is apparent to those skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. An organic electroluminescent device, comprising:
an anode,
a cathode,
an emissive layer disposed between the anode and the cathode, and
an electron blocking layer disposed between the anode and the emissive layer, wherein the electron blocking layer comprises an electron blocking material with a hole mobility μₕ≤65×10⁻⁵ cm²/(V·s);
capacitance of the organic electroluminescent device satisfies the following condition:
at 500 Hz, a maximum capacitance value of the organic electroluminescent device is Cₘₐₓ, and ΔC=C₀−Cₘₐₓ≥0.4 nF;
wherein C₀ denotes a maximum capacitance value of an organic electroluminescent device A at 500 Hz, and the organic electroluminescent device A is the same as the organic electroluminescent device except that the electron blocking material in the electron blocking layer of the organic electroluminescent device is replaced with Compound HT; and
the Compound HT has the following structure: 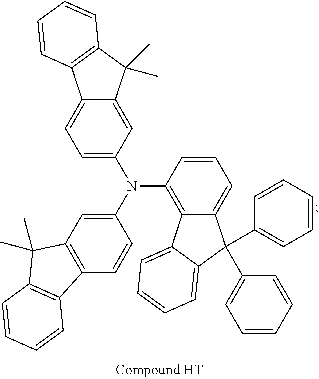 [SMILES: CC1(C)c2ccccc2-c2ccc(N(c3ccc4c(c3)C(C)(C)c3ccccc3-4)c3cccc4c3-c3ccccc3C4(c3ccccc3)c3ccccc3)cc21]
wherein the emissive layer satisfies the following conditions: a hole-only device comprising the emissive layer with a thickness of 400 Å has a drive voltage V_{HOD}@J10≤8.0 V at a current density of 10 mA/cm², and an electron-only device comprising the emissive layer with a thickness of 400 Å has a drive voltage V_{EOD}@J10≤8.0 V at a current density of 10 mA/cm²;
the hole-only device comprising the emissive layer with a thickness of 400 Δ has the following structure:
ITO (1200 Å)/HTM:PD (with a weight ratio of 97:3, 100 Å)/HTM (400 Å)/HT-2 (50 Å)/the emissive layer (400 Å)/HTM (400 Å)/HTM:PD (with a weight ratio of 97:3, 100 Å)/A₁ (1200 Å);
the Compound HTM, the Compound PD, and the Compound HT-2 have the following structures: 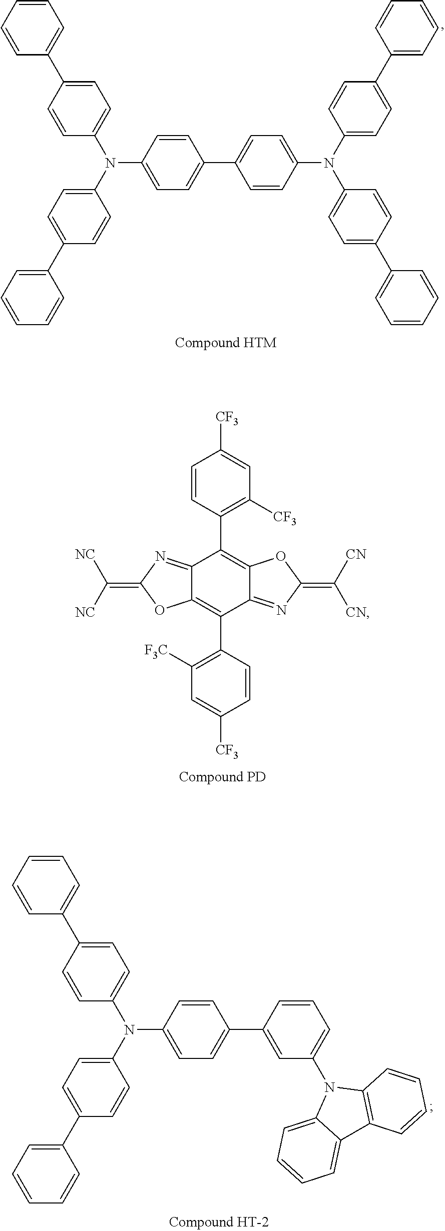 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2ccc(N(c3ccc(-c4ccccc4)cc3)c3ccc(-c4cccc(-n5c6ccccc6c6ccccc65)c4)cc3)cc2)cc1]
the electron-only device comprising the emissive layer with a thickness of 400 Δ has the following structure:
ITO (1200 Å)/Liq (10 Å)/the emissive layer (400 Å)/ET:Liq (with a weight ratio of 40:60, 300 Å)/Liq (10 Å)/Al (1200 Å); and
the Compound ET and Liq have the following structures:

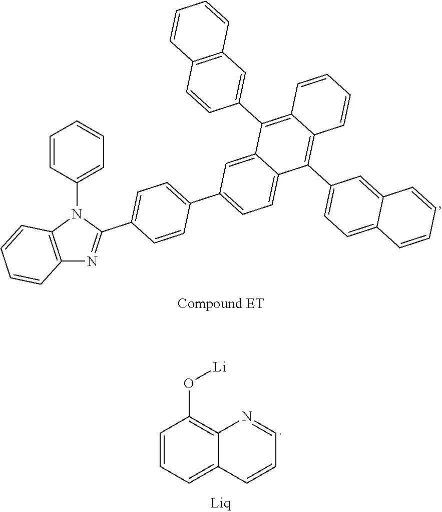

2. The organic electroluminescent device according to claim 1, wherein the hole-only device comprising the emissive layer with a thickness of 400 Δ has a drive voltage V_{HOD}@J10≤7.0 V at a current density of 10 mA/cm²;
preferably, the hole-only device comprising the emissive layer with a thickness of 400 Δ has a drive voltage V_{HOD}@J10≤6.0 V at a current density of 10 mA/cm².

3. The organic electroluminescent device according to claim 1, wherein the electron-only device comprising the emissive layer with a thickness of 400 Δ has a drive voltage V_{EOD}@J10≤7.0 V at a current density of 10 mA/cm²;
preferably, the electron-only device comprising the emissive layer with a thickness of 400 Å has a drive voltage V_{EOD}@J10≤6.0 V at a current density of 10 mA/cm².

4. The organic electroluminescent device according to claim 1, wherein the electron blocking material has a hole mobility μₕ≤50×10⁻⁵ cm²/(V·s);
preferably, the electron blocking material has a hole mobility μₕ≤40×10⁻⁵ cm²/(V·s).

5. The organic electroluminescent device according to claim 1, wherein the electron blocking material has a hole mobility μₕ≥1×10⁻⁶ cm²/(V·s);
preferably, the electron blocking material has a hole mobility μₕ≥1×10⁻⁵ cm²/(V·s).

6. The organic electroluminescent device according to claim 1, wherein ΔC≥0.5 nF;
preferably, ΔC≥0.8 nF;
more preferably, ΔC≥1.0 nF.

7. The organic electroluminescent device according to claim 1, wherein the electron blocking layer has a thickness greater than or equal to 350 Å;
preferably, the electron blocking layer has a thickness greater than or equal to 500 Å;
more preferably, the electron blocking layer has a thickness greater than or equal to 650 Å.

8. The organic electroluminescent device according to claim 1, wherein the emissive layer satisfies that F≥0.8, wherein F=V_{EOD}@J10/V_{HOD}@J10;
preferably, the emissive layer satisfies that F≥0.9, wherein F=V_{EOD}@J10/V_{HOD}@J10;
more preferably, the emissive layer satisfies that F≥1.0, wherein F=V_{EOD}@J10/V_{HOD}@J10.

9. The organic electroluminescent device according to claim 1, wherein the organic electroluminescent device has a peak wavelength greater than or equal to 560 nm;
preferably, the organic electroluminescent device has a peak wavelength greater than or equal to 580 nm;
more preferably, the organic electroluminescent device has a peak wavelength greater than or equal to 600 nm.

10. The organic electroluminescent device according to claim 1, wherein the emissive layer comprises a first compound which is a metal complex comprising a metal M and a ligand Lₐ coordinated to the metal M, wherein the metal M is selected from a metal with a relative atomic mass greater than 40, and the ligand Lₐ has a structure represented by Formula 1: 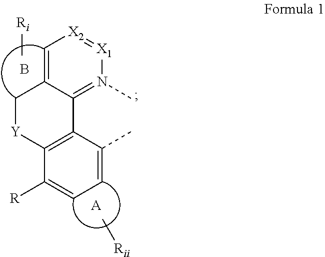
wherein the ring A and the ring B are each independently selected from a five-membered unsaturated carbocyclic ring, an aromatic ring having 6 to 30 carbon atoms, or a heteroaromatic ring having 3 to 30 carbon atoms;
Rᵢ and Rᵢᵢ represent, at each occurrence identically or differently, mono-substitution, multiple substitutions, or non-substitution;
Y is selected from SiR_{y}R_{y}, GeR_{y}R_{y}, NR_{y}, PR_{y}, O, S, or Se; when two R_{y} are present at the same time, the two R_{y} may be the same or different;
X₁ and X₂ are, at each occurrence identically or differently, selected from CRₓ or N;
R, Rᵢ, Rᵢᵢ, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R, Rᵢ, Rᵢᵢ, Rₓ, R_{y} can be optionally joined to form a ring.

11. The organic electroluminescent device according to claim 10, wherein in the first compound, the ligand Lₐ has a structure represented by Formula 1-1, Formula 1-2, or Formula 1-3: 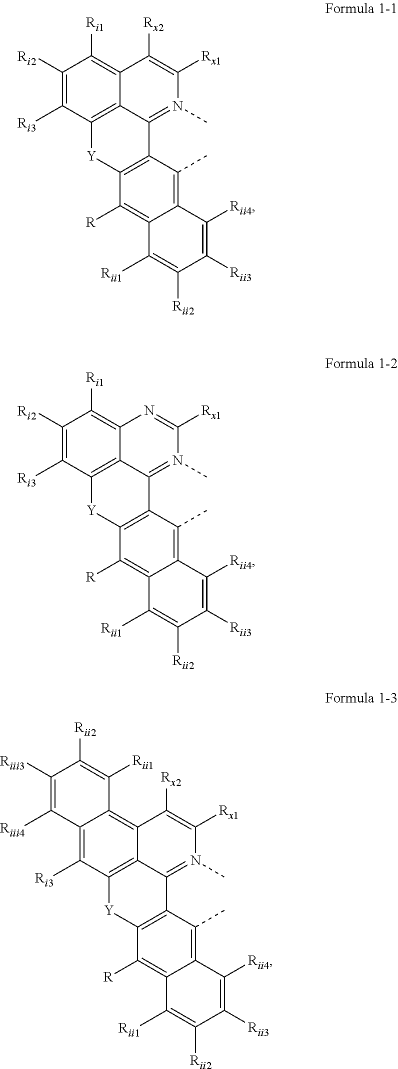
wherein Y is selected from O or S;
Rₓ₁, Rₓ₂, Rᵢ₁, Rᵢ₂, Rᵢ₃, Rᵢᵢ₁, Rᵢᵢ₂, Rᵢᵢ₃, Rᵢᵢ₄, Rᵢᵢᵢ₁, Rᵢᵢᵢ₂, Rᵢᵢᵢ₃, and Rᵢᵢᵢ₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof,
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, and combinations thereof, and
adjacent substituents R, Rₓ₁, Rₓ₂, Rᵢ₁, Rᵢ₂, Rᵢ₃, Rᵢ, Rᵢᵢ₂, Rᵢᵢ₃, Rᵢᵢ₄, Rᵢᵢᵢ₁, Rᵢᵢᵢ₂, Rᵢᵢᵢ₃, Rᵢᵢᵢ₄ can be optionally joined to form a ring;
preferably, at least one or two of Rₓ₁, Rₓ₂, Rᵢ₁, Rᵢ₂, Rᵢ₃, Rᵢᵢ₁, Rᵢᵢ₂, Rᵢᵢ₃, Rᵢᵢ₄, Rᵢᵢᵢ₁, Rᵢᵢᵢ₂, Rᵢᵢᵢ₃, and Rᵢᵢᵢ₄ are, at each occurrence identically or differently, selected from deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof, and R is selected from halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof,
more preferably, at least one or two of Rₓ₁, Rₓ₂, Rᵢ₁, Rᵢ₂, Rᵢ₃, Rᵢᵢ₁, Rᵢᵢ₂, Rᵢᵢ₃, Rᵢᵢ₄, Rᵢᵢᵢ₁, Rᵢᵢᵢ₂, Rᵢᵢᵢ₃, and Rᵢᵢᵢ₄ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof; and R is selected from substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof.

12. The organic electroluminescent device according to claim 10, wherein Lₐ is, at each occurrence identically or differently, selected from the group consisting of the following structures: 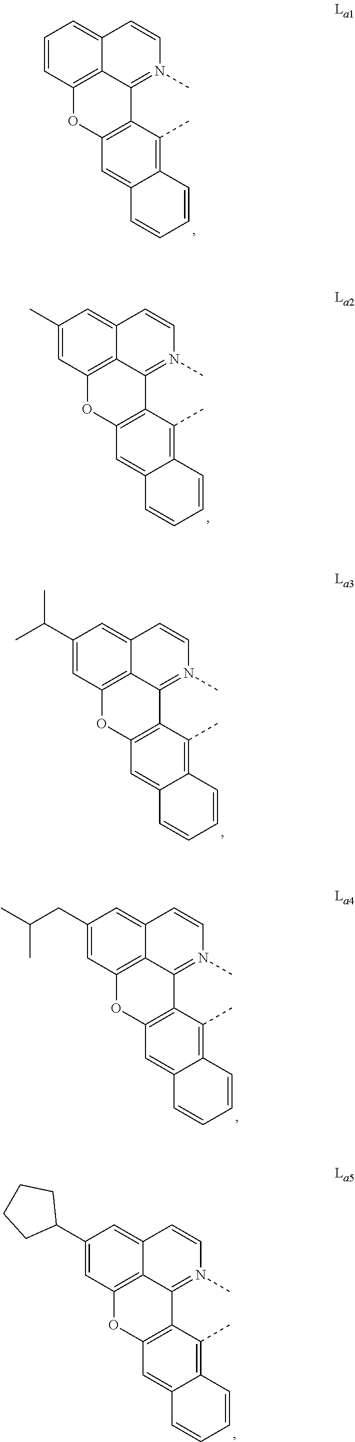 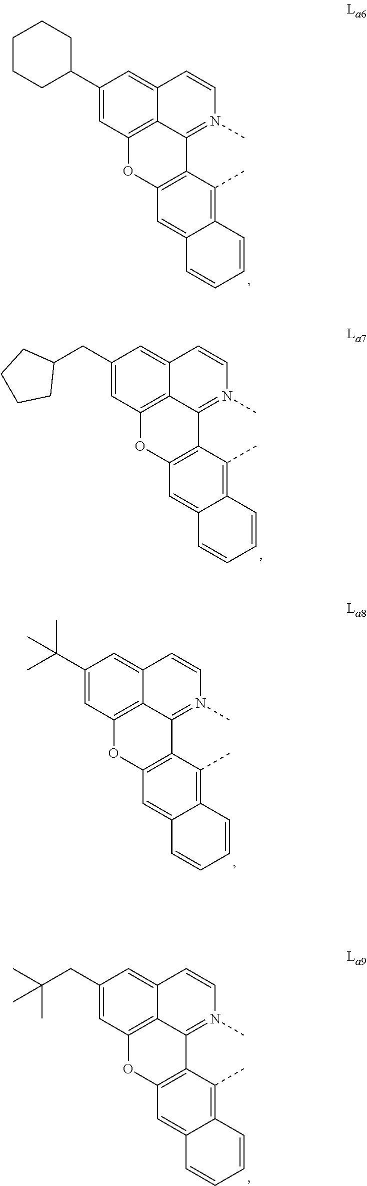 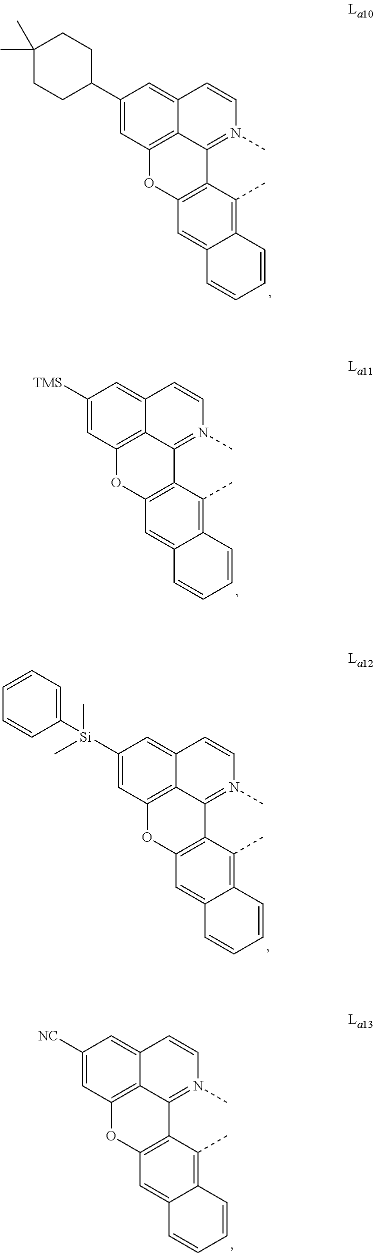 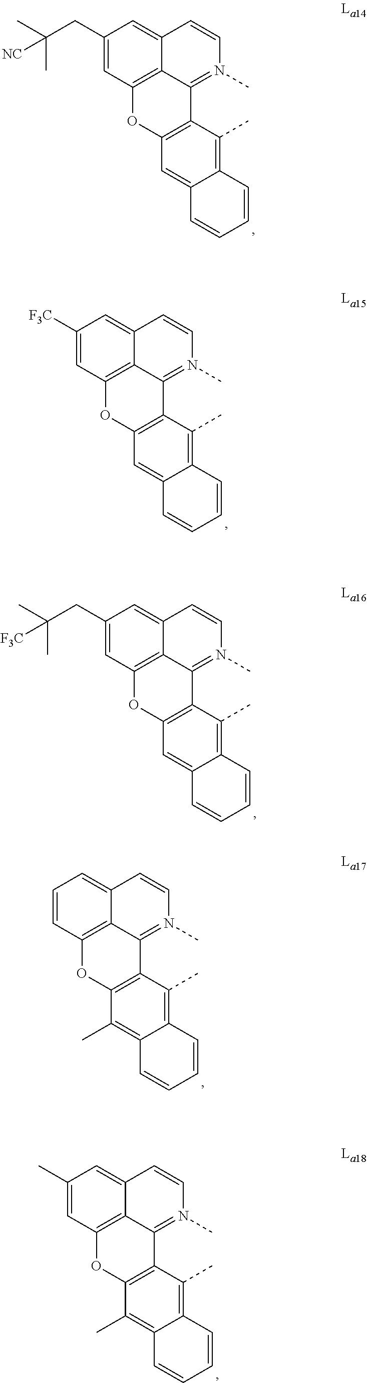 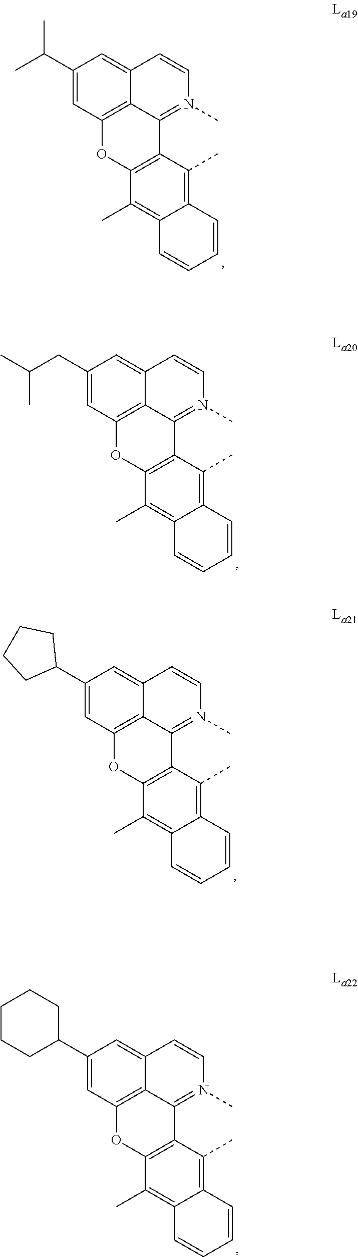 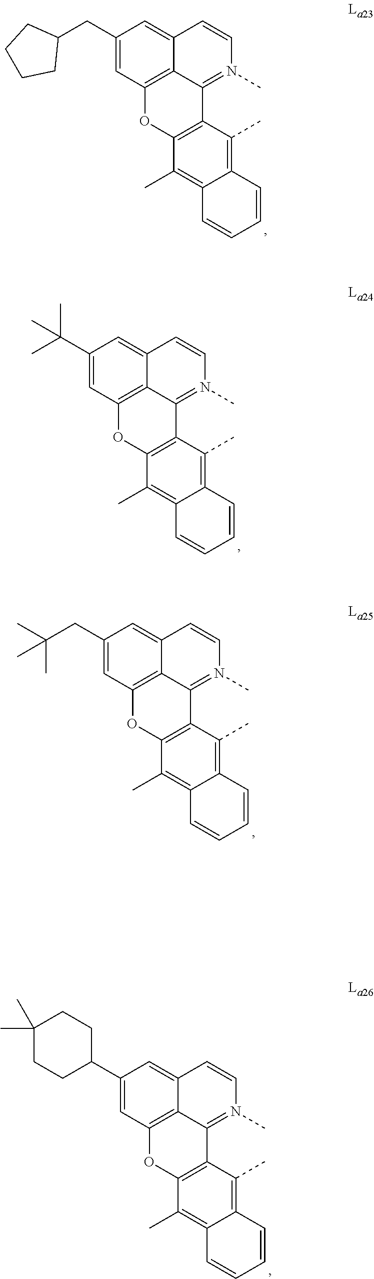 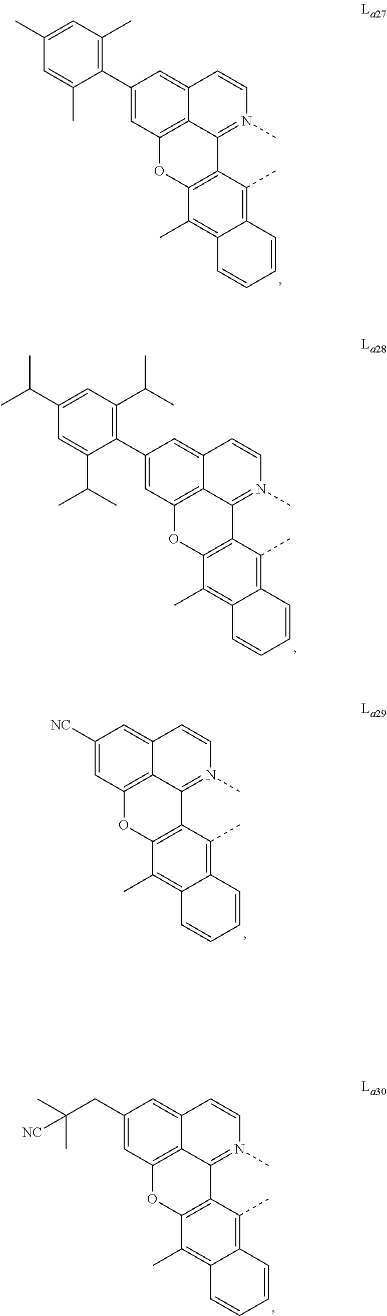 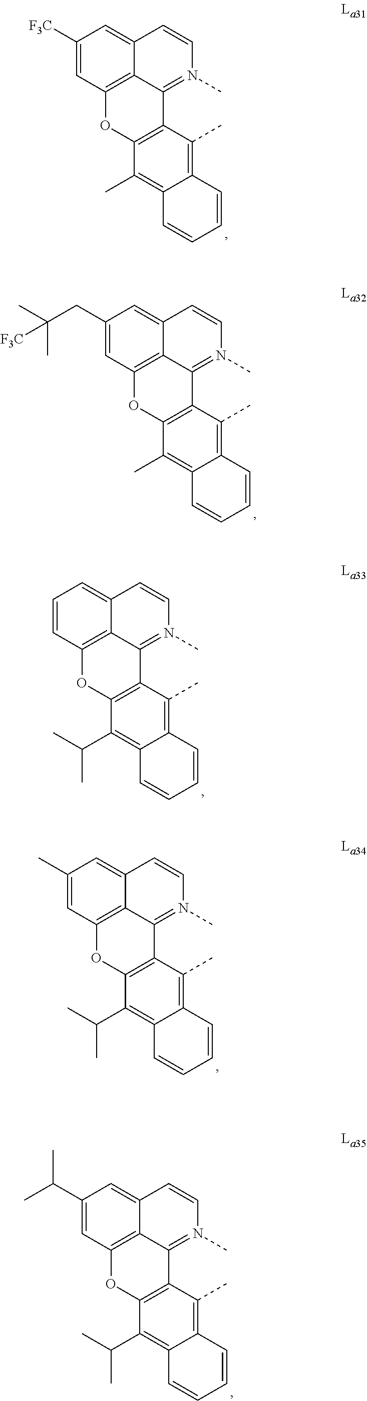 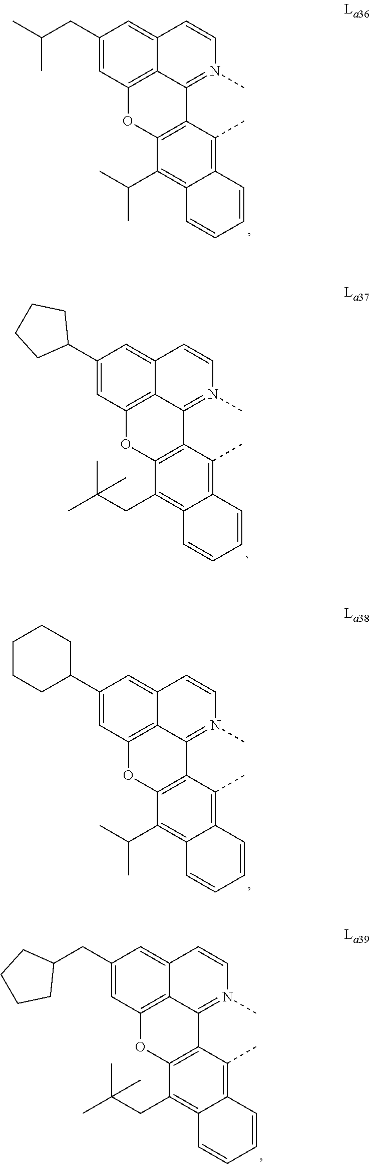 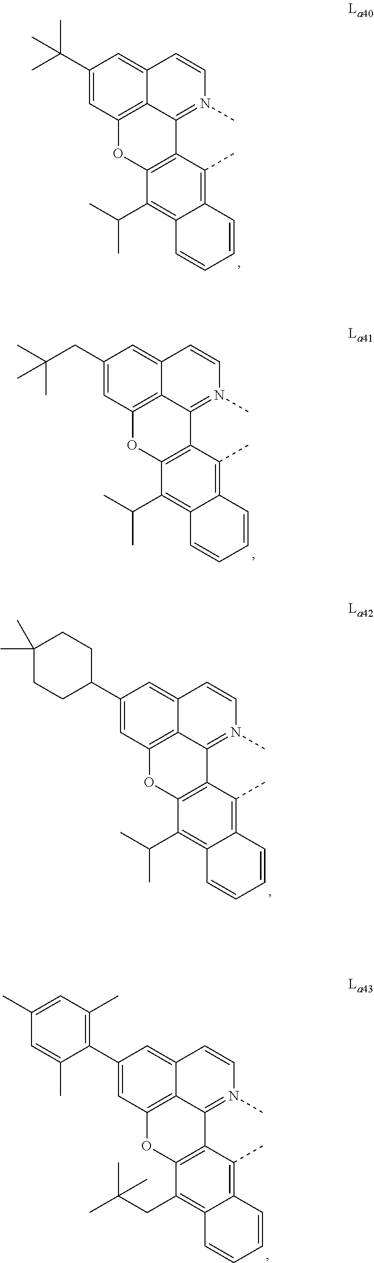 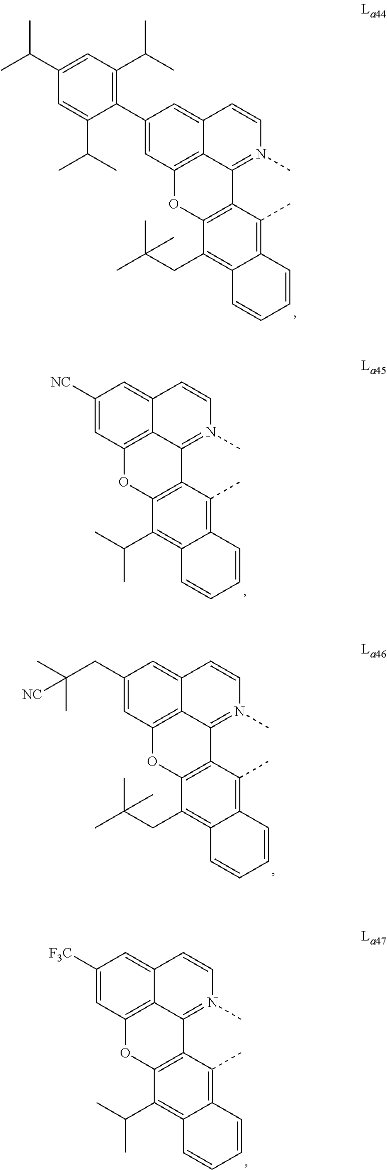 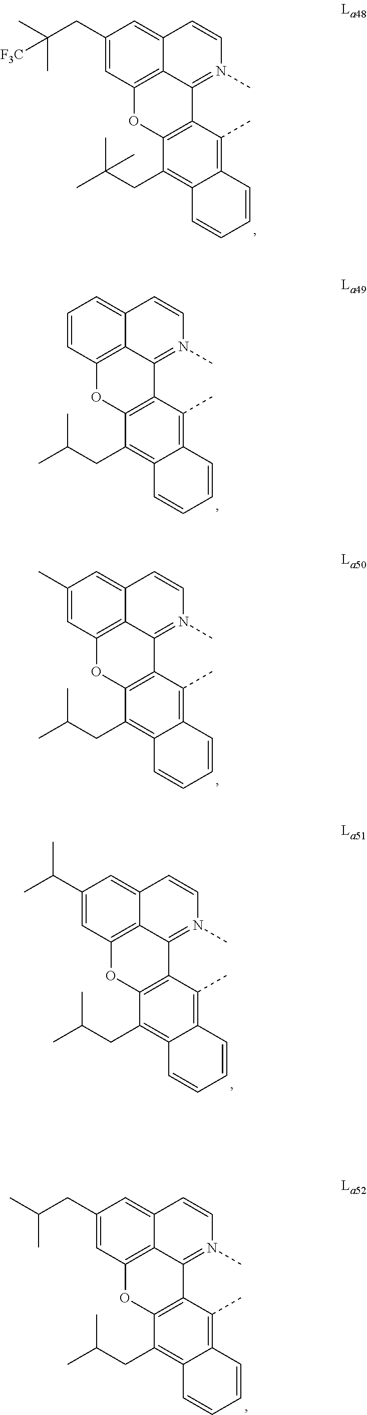 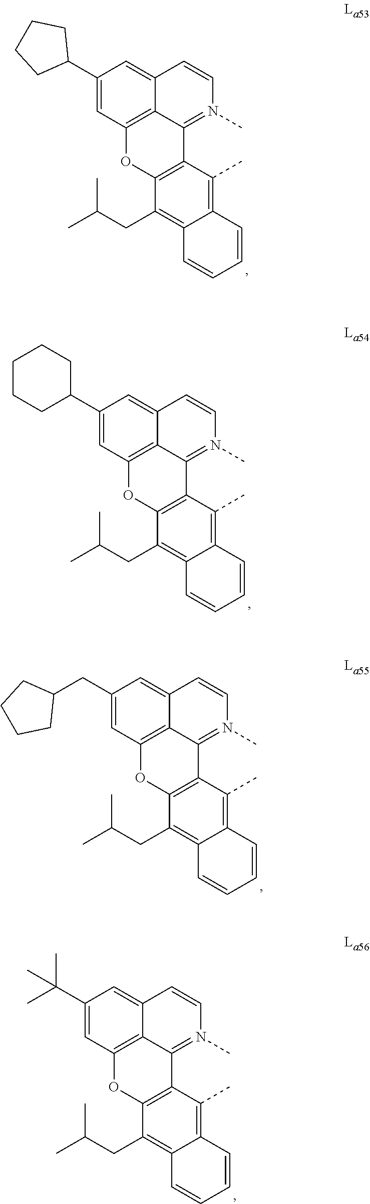 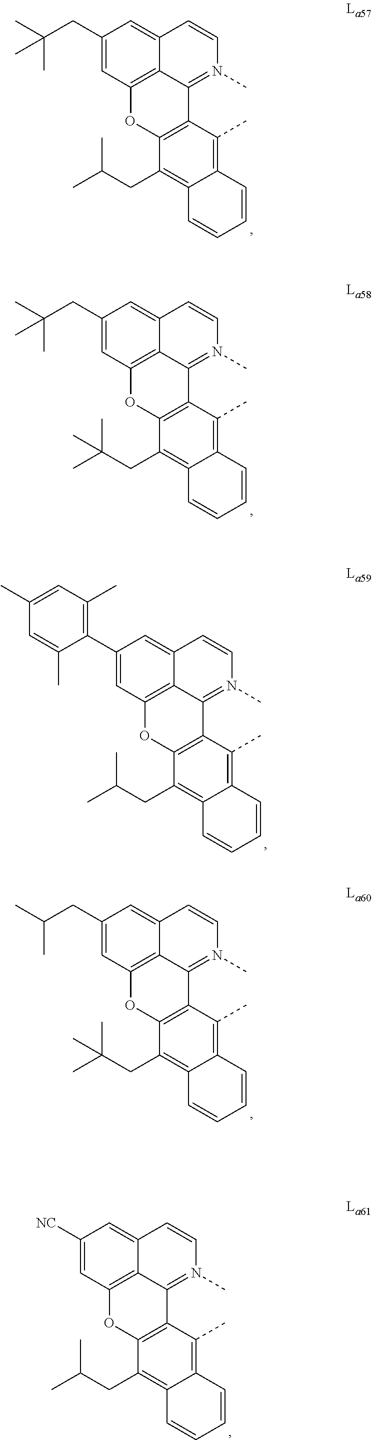 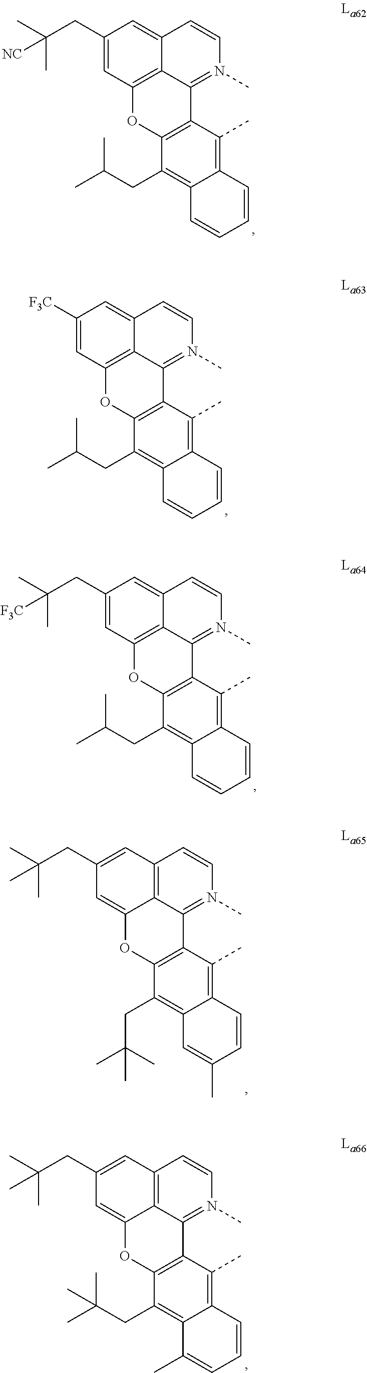 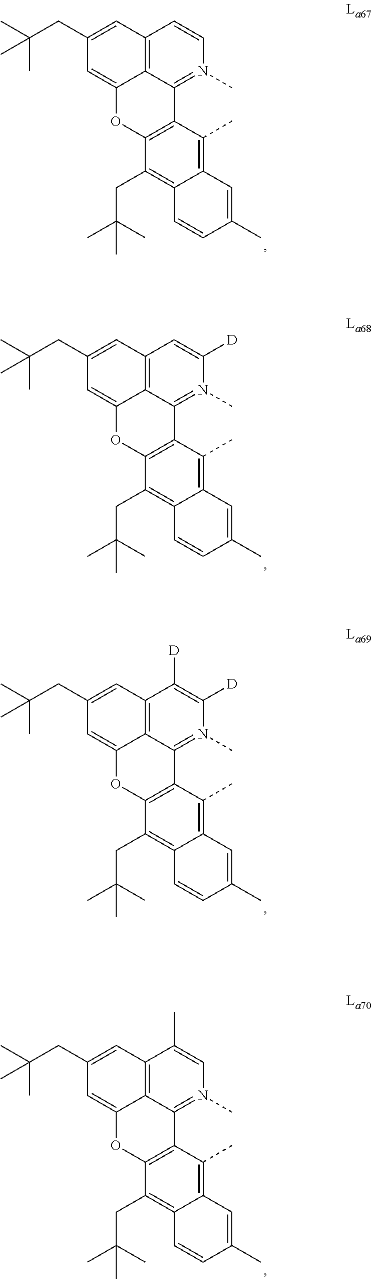 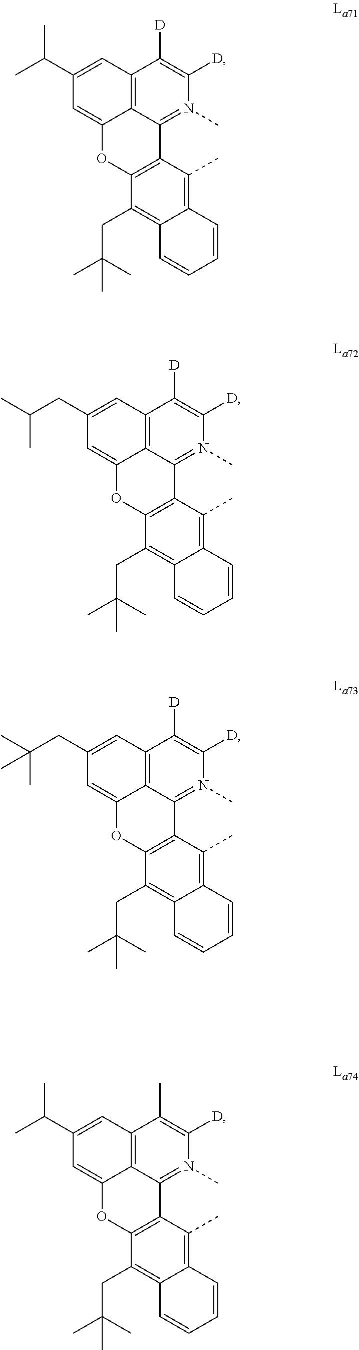 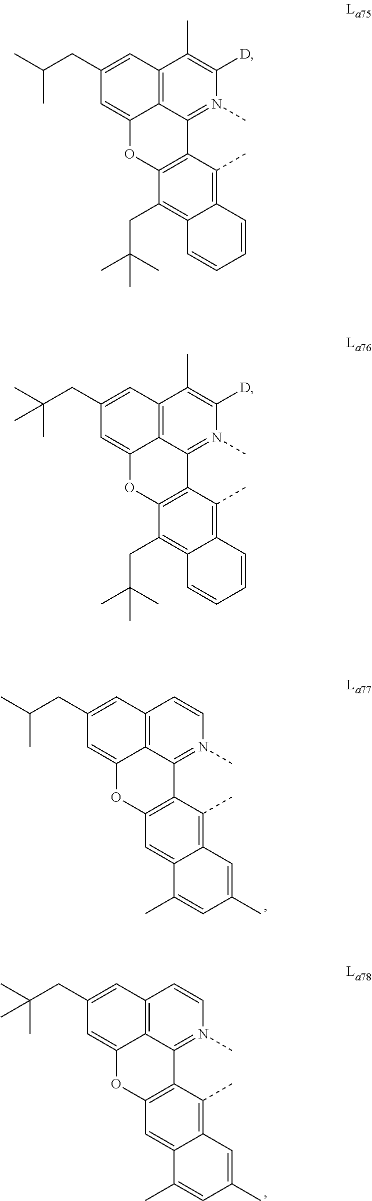 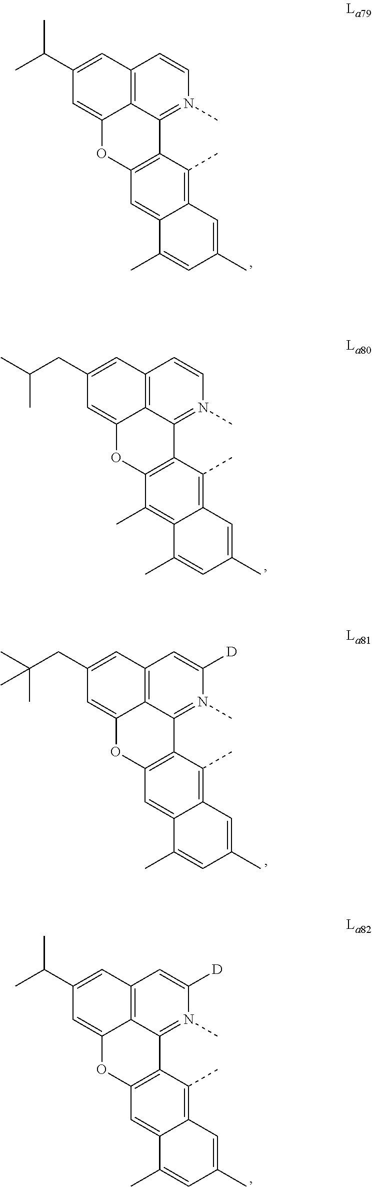 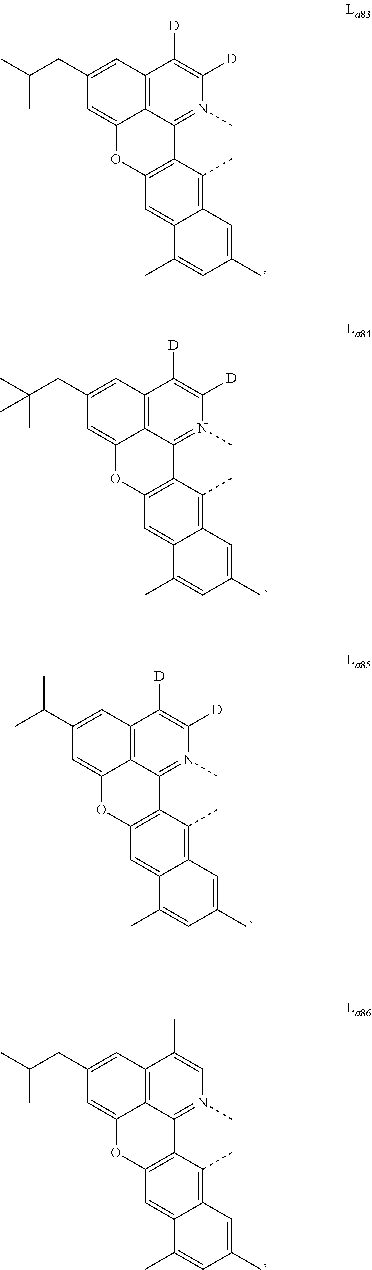 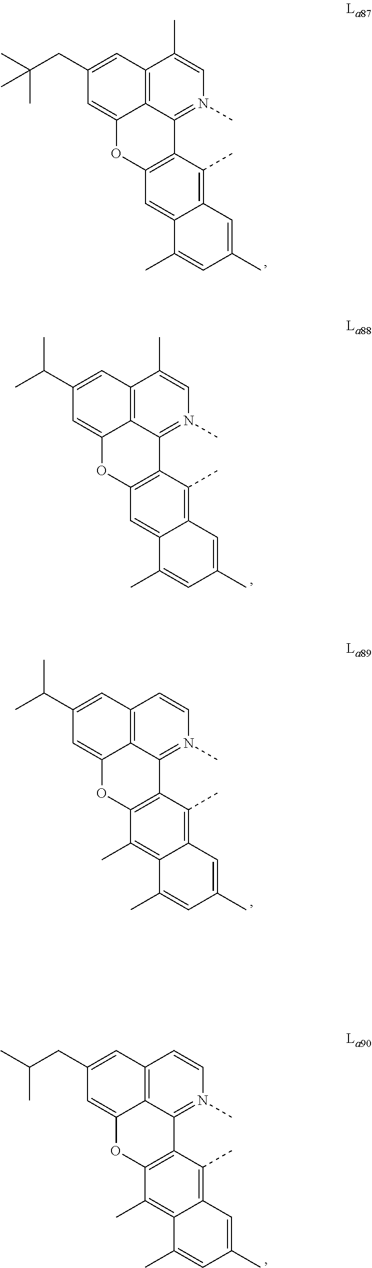 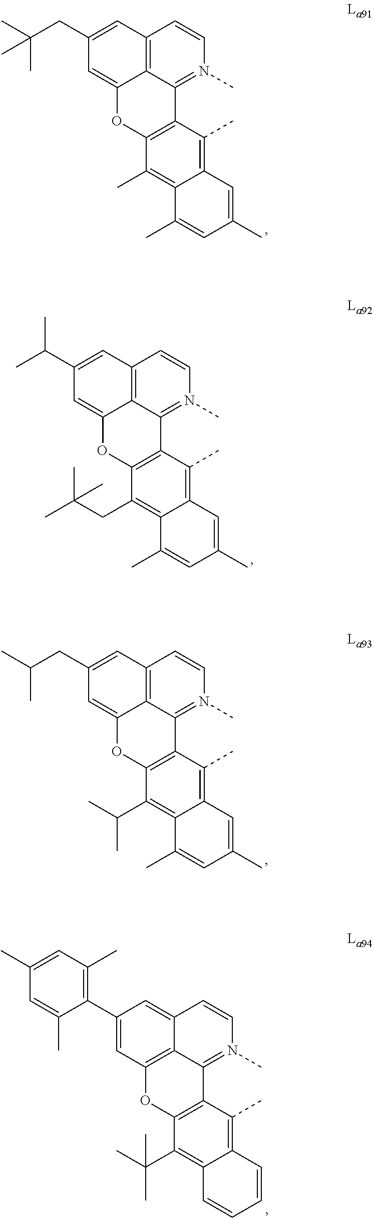 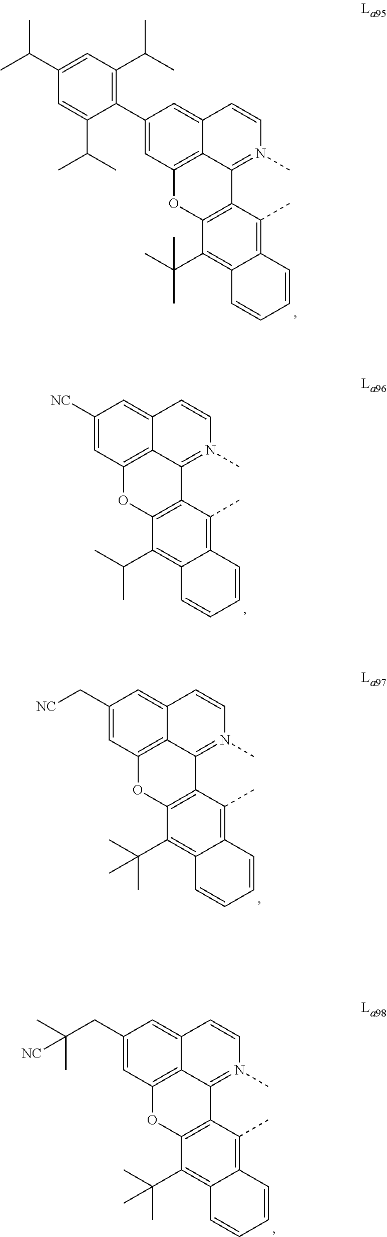 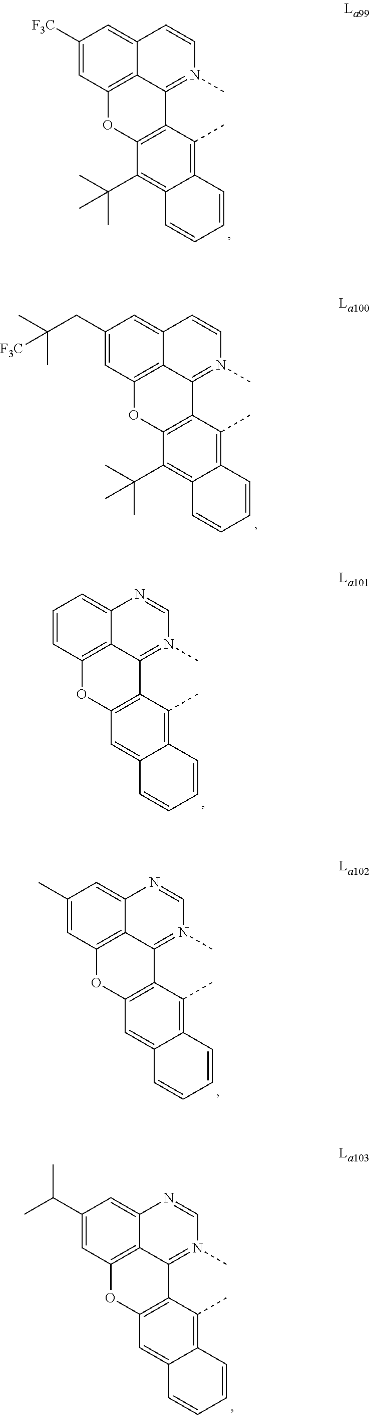 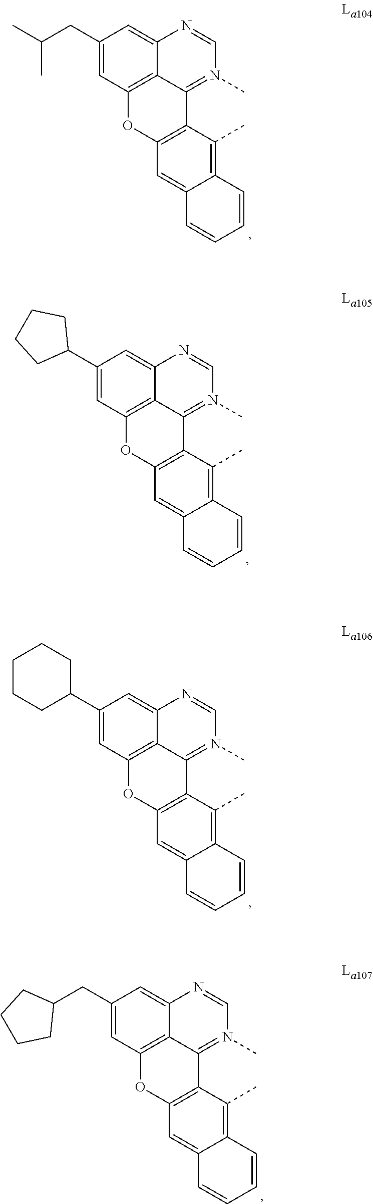 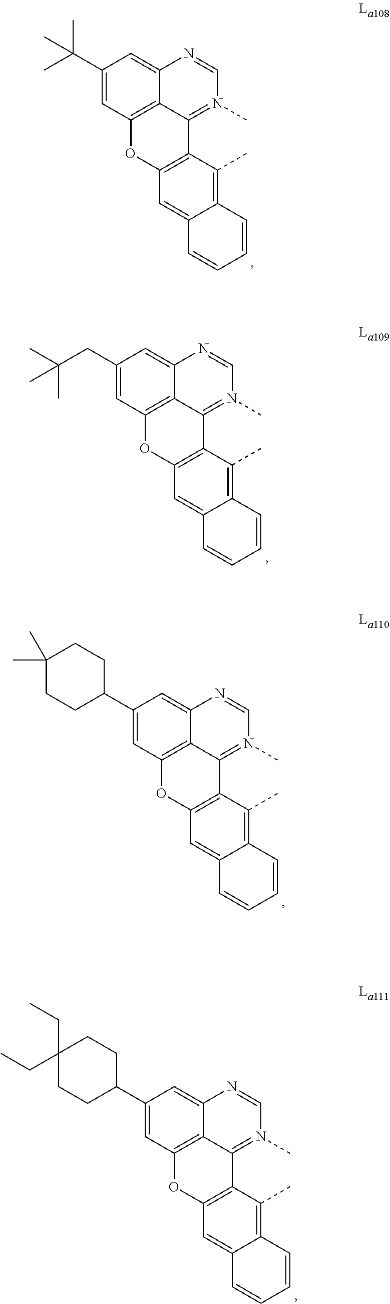 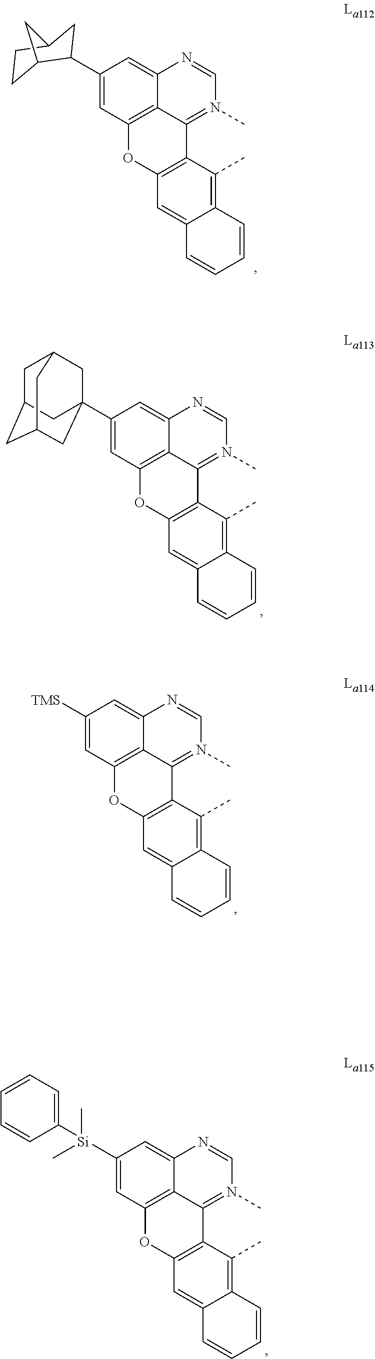 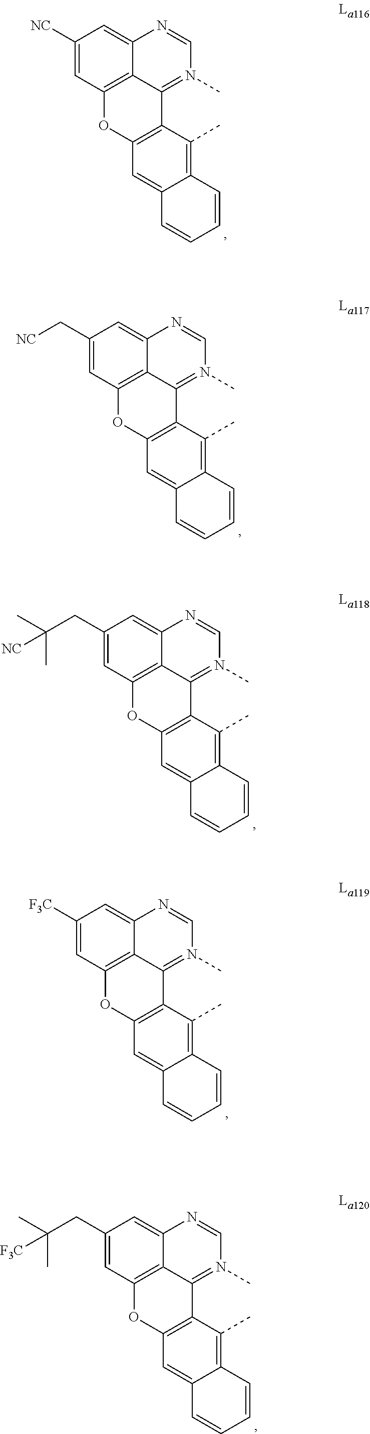 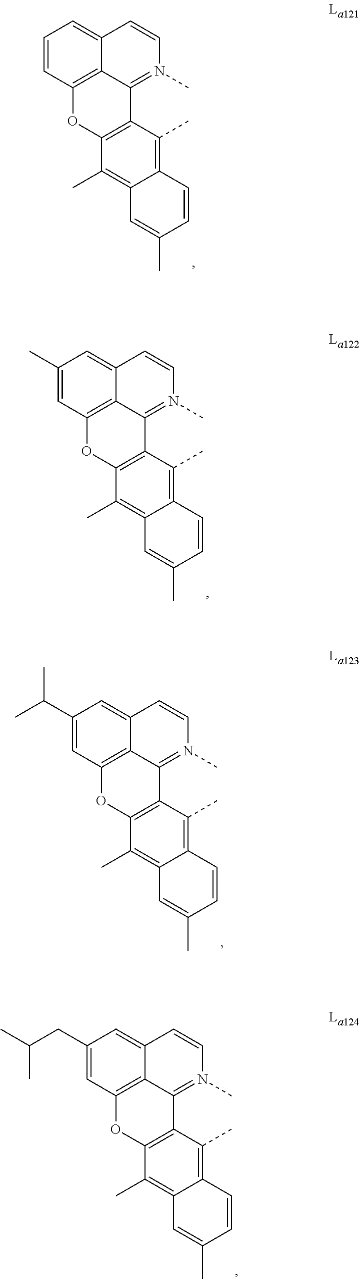 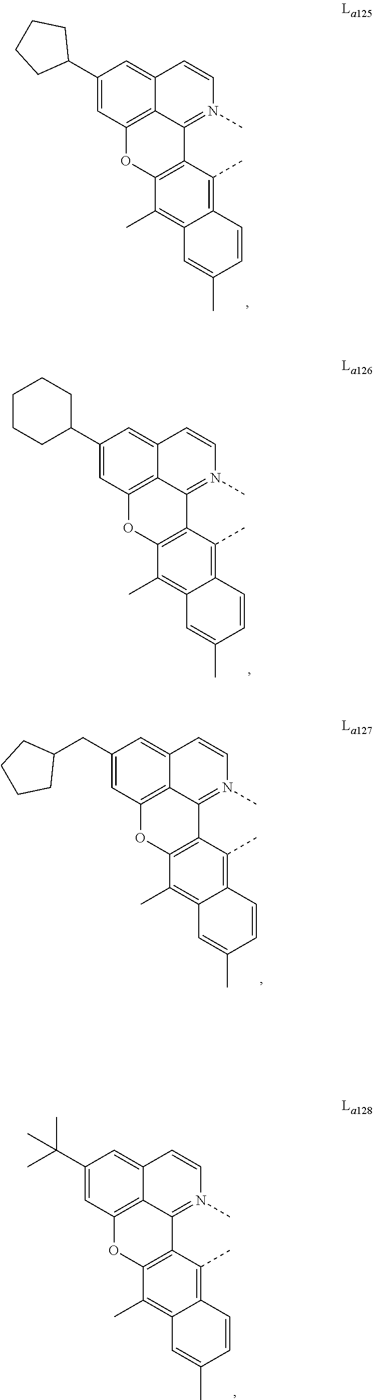 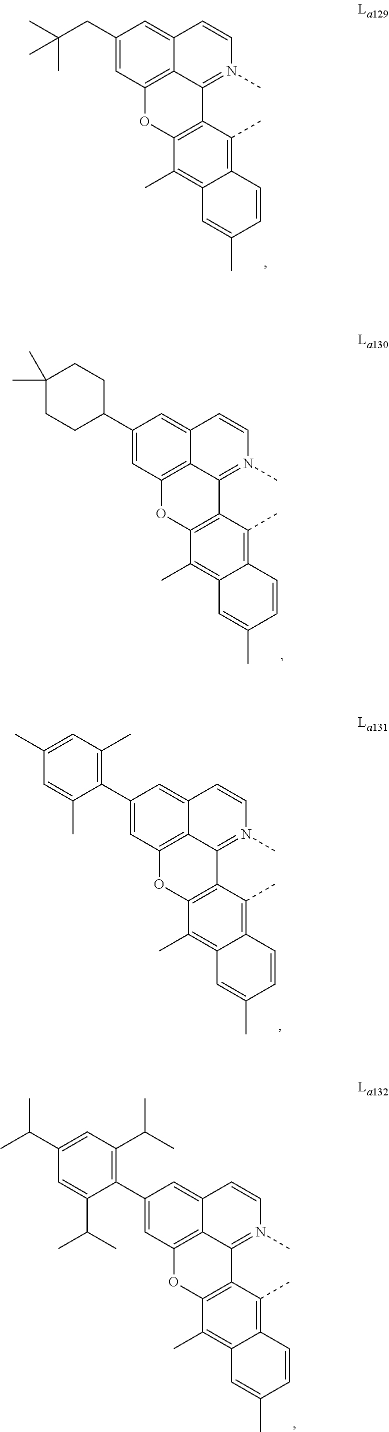 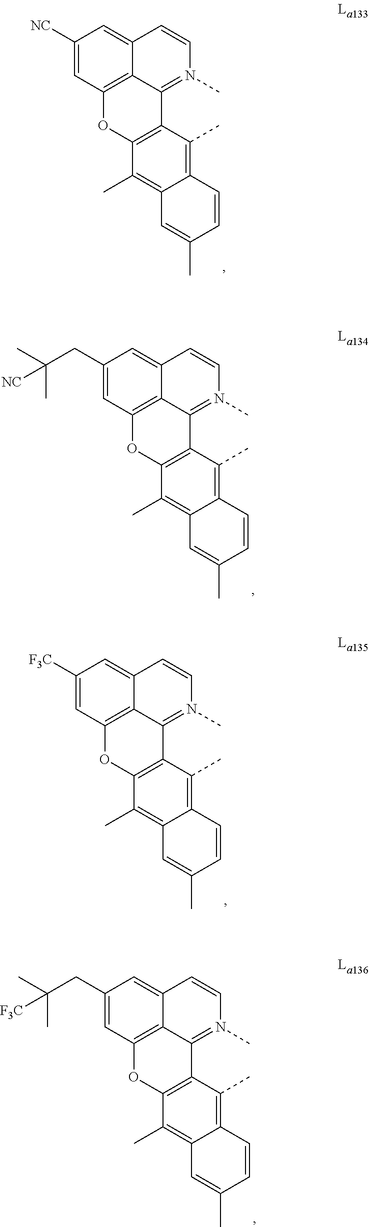 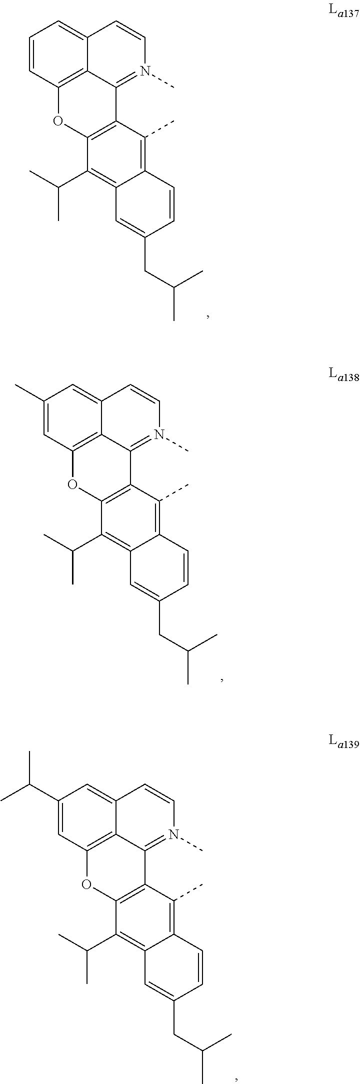 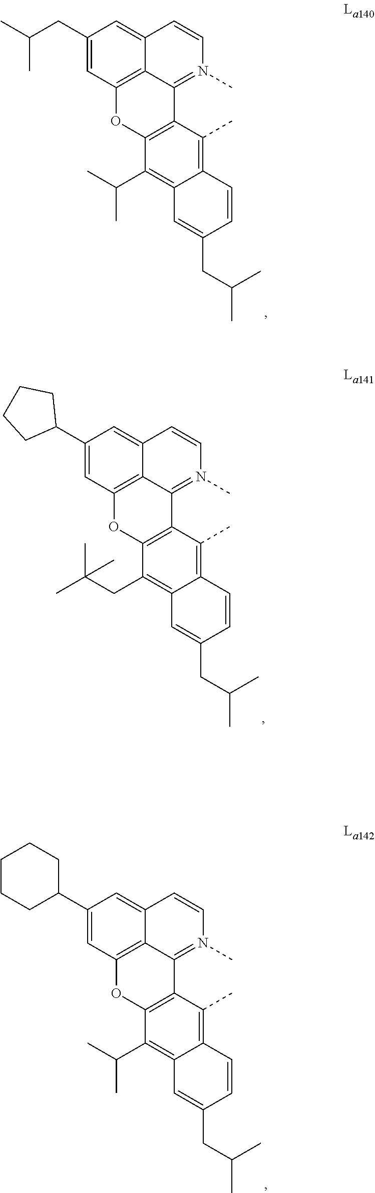 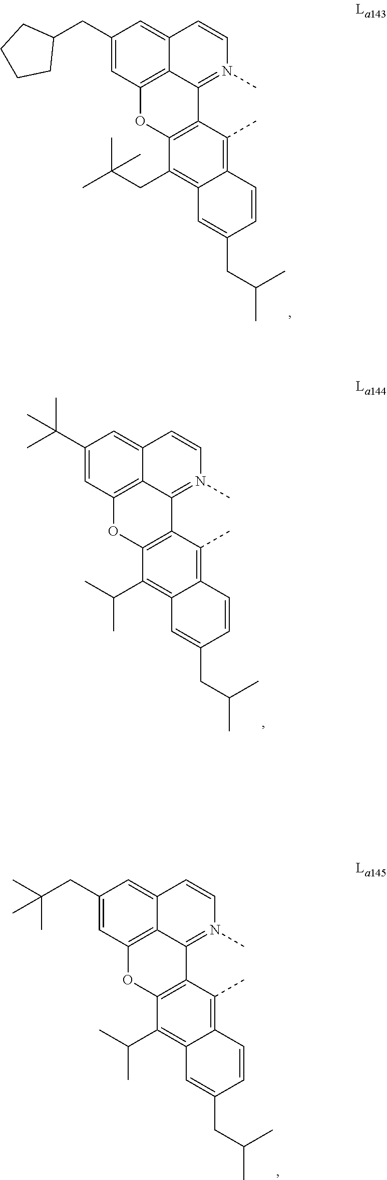 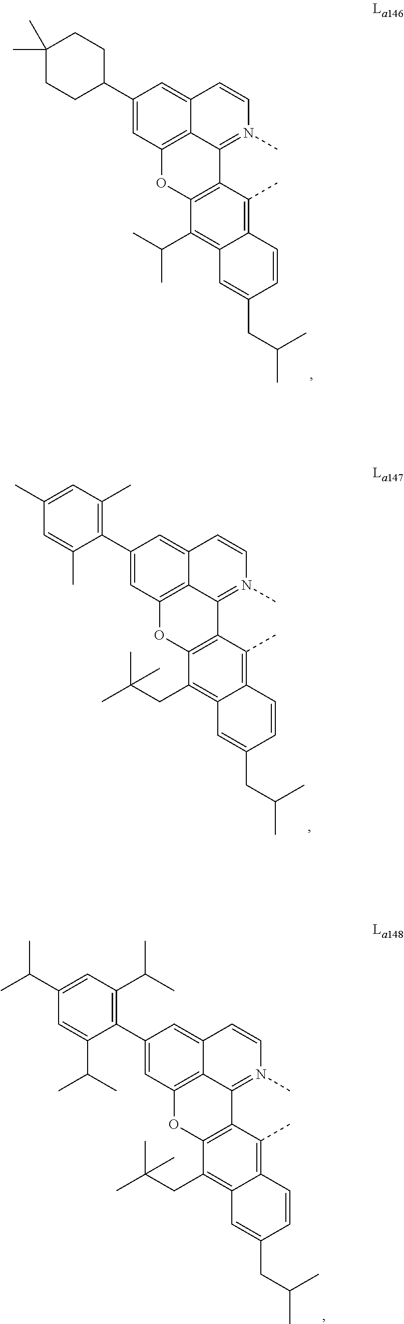 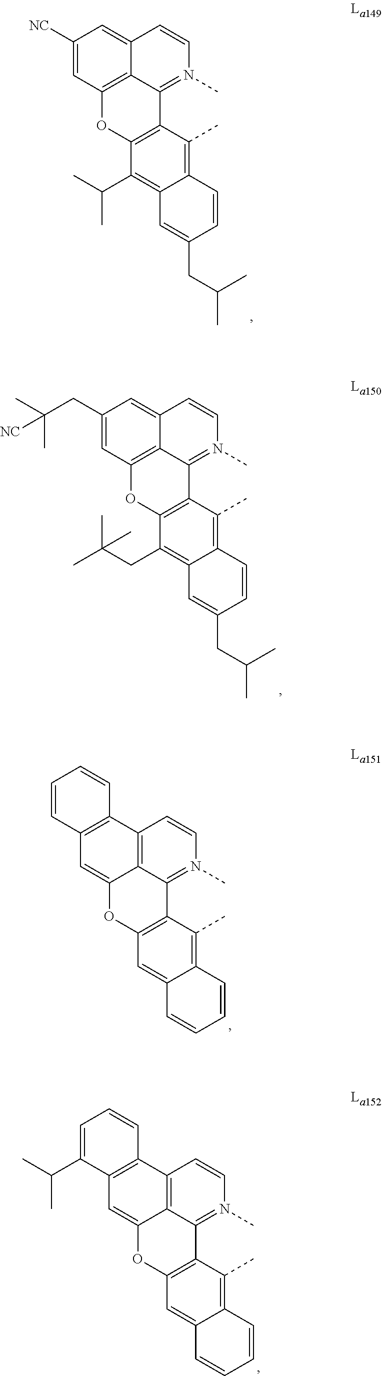 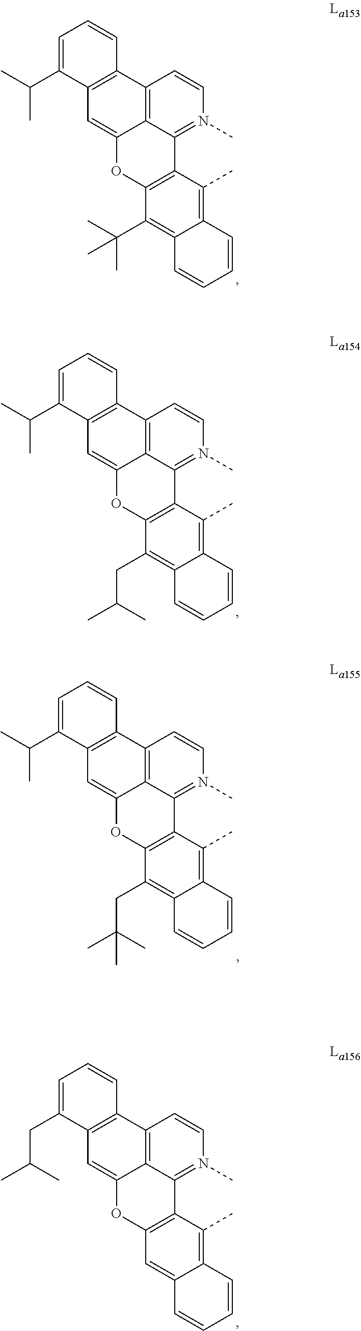 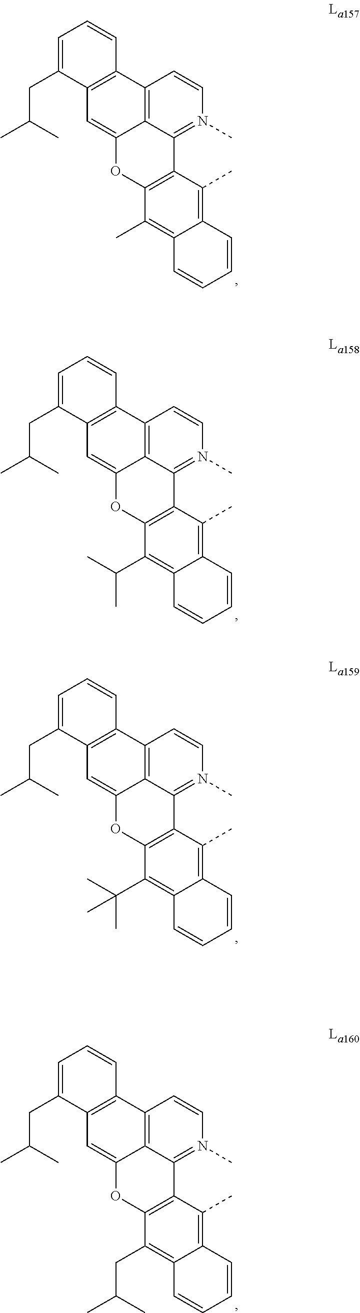 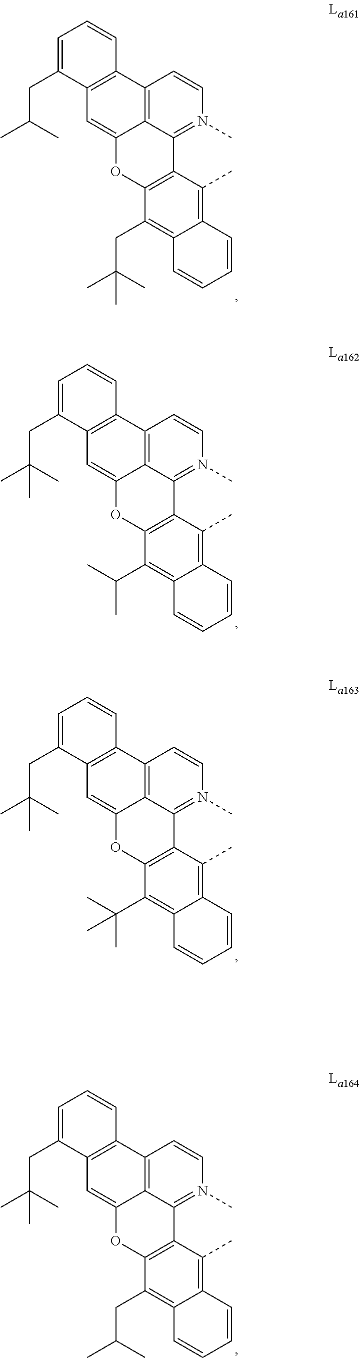 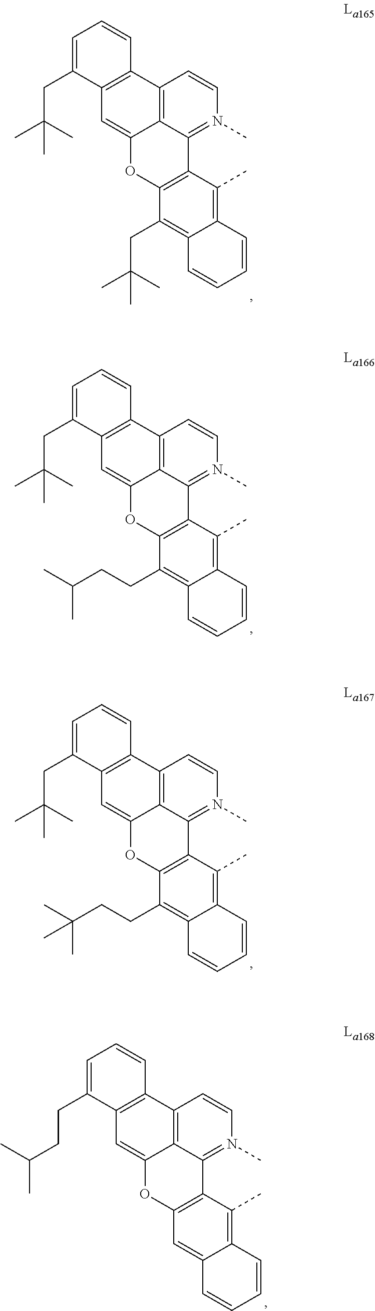 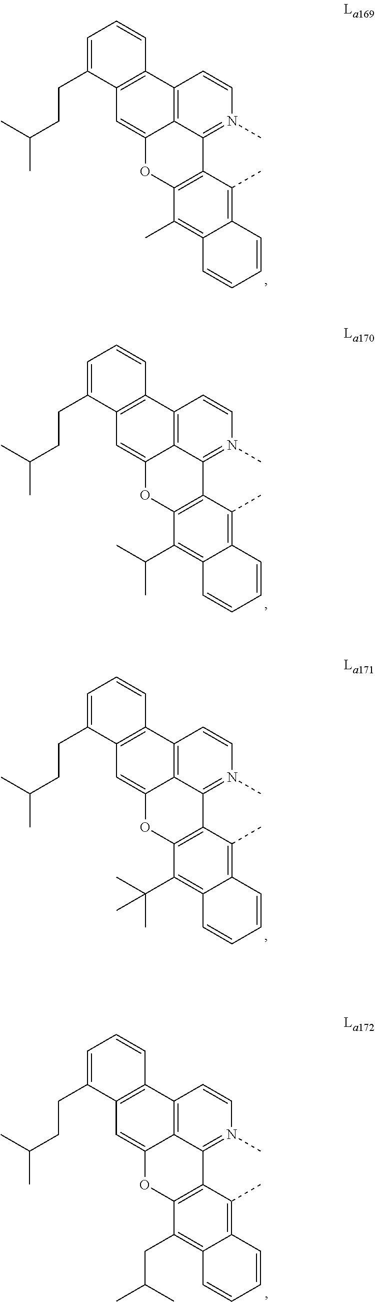 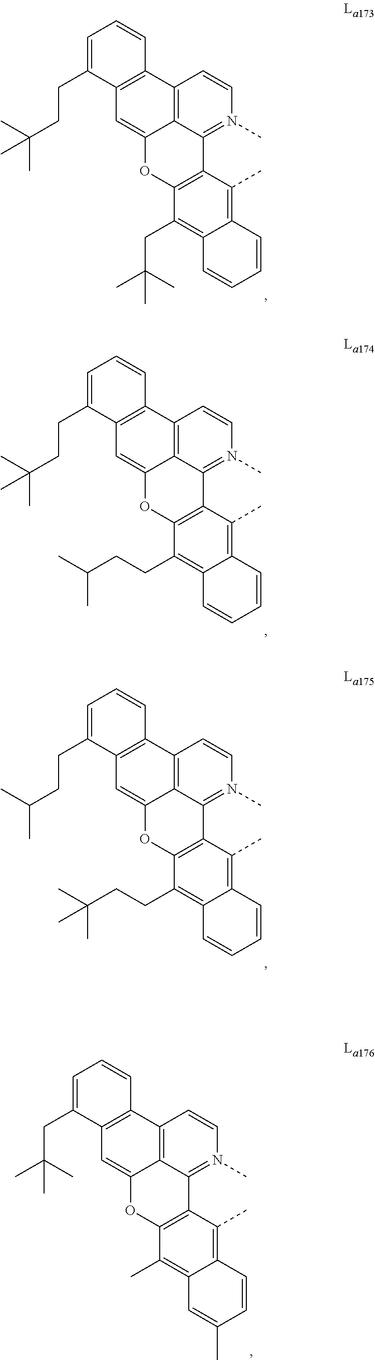 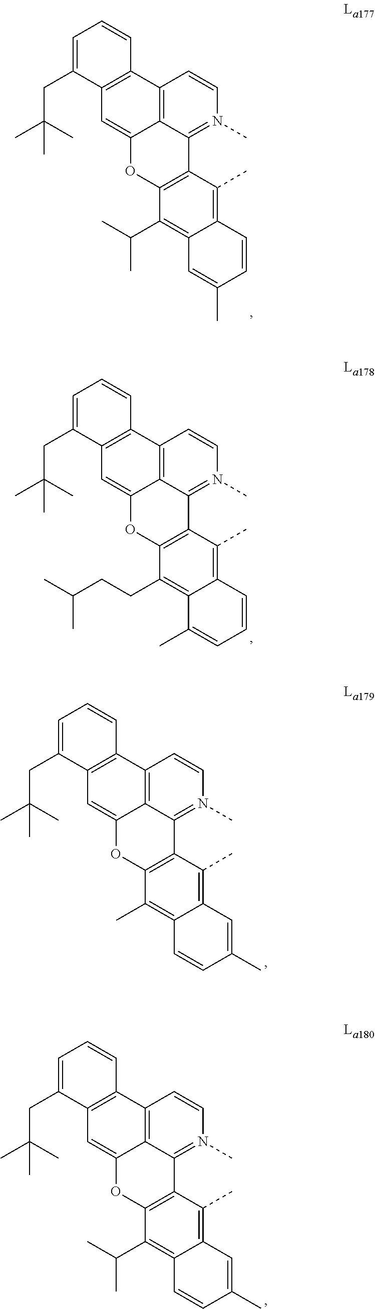 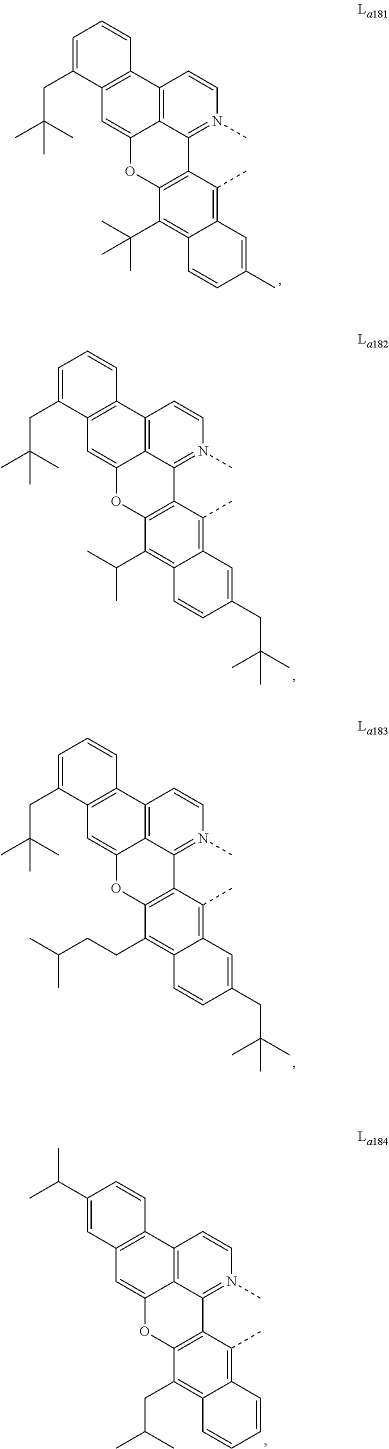 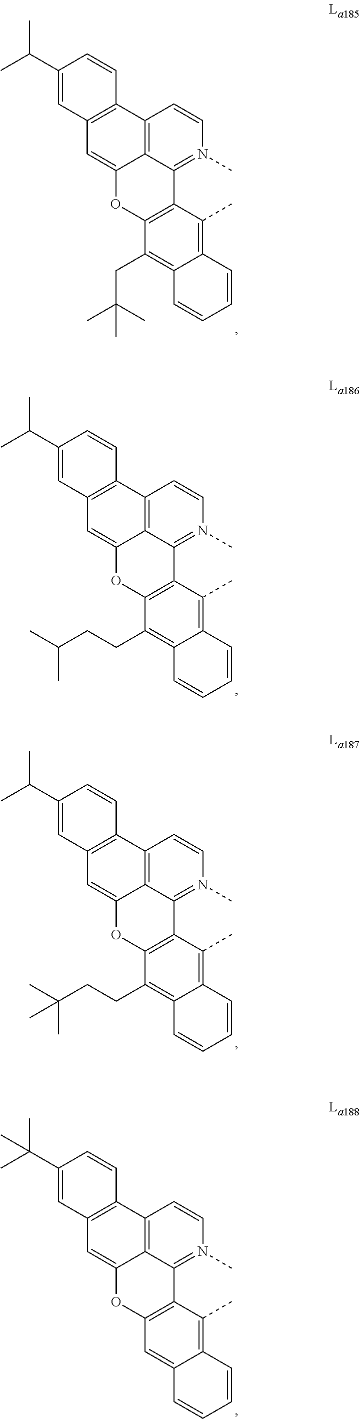 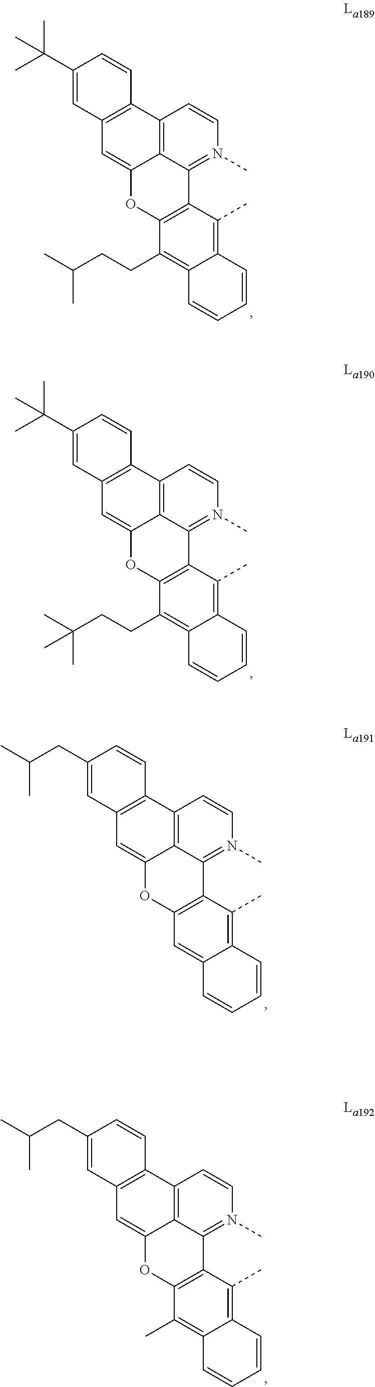 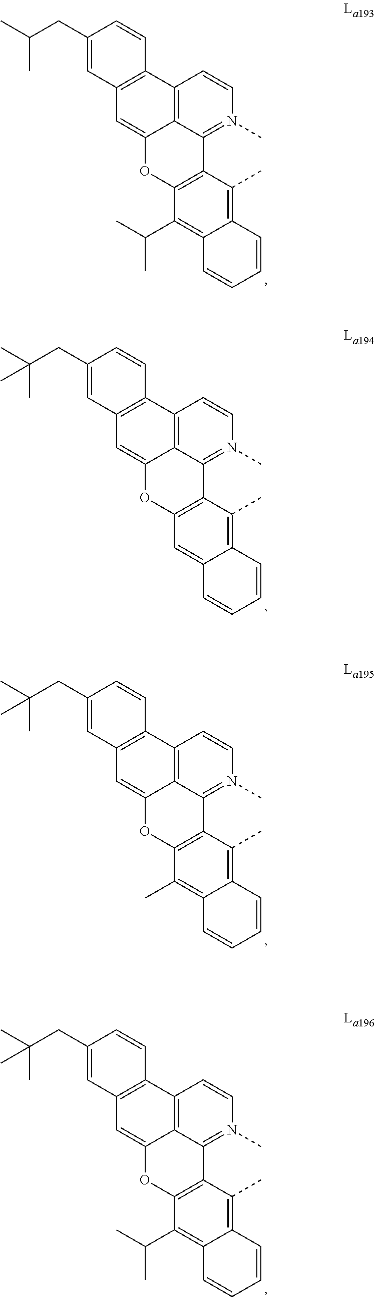 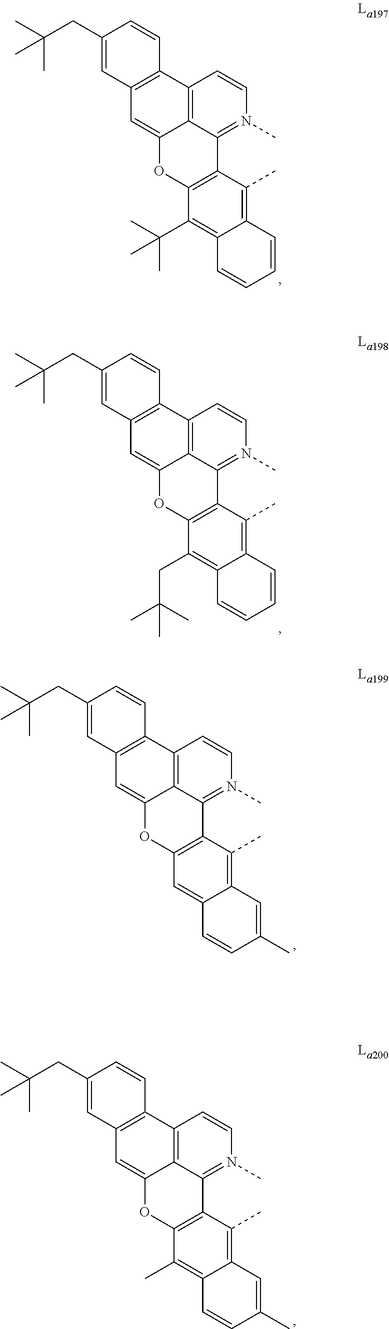 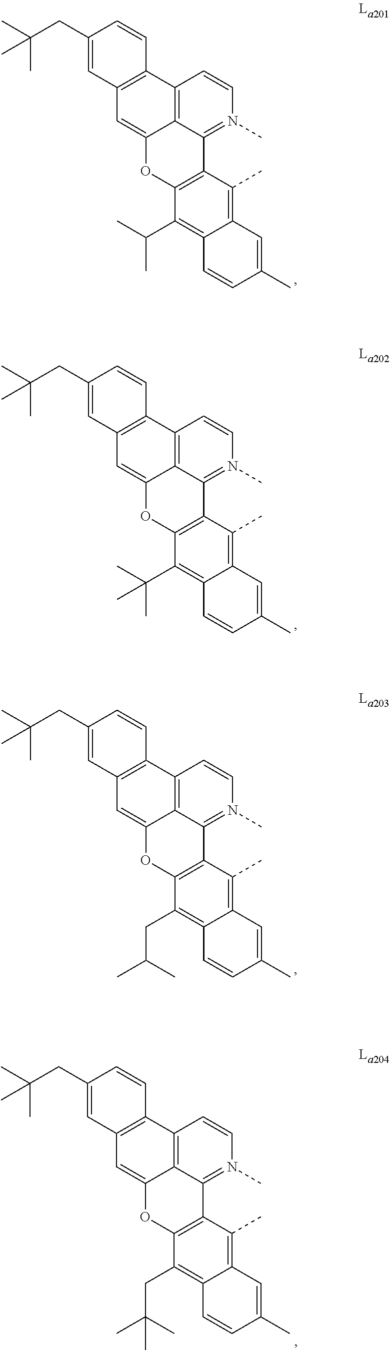 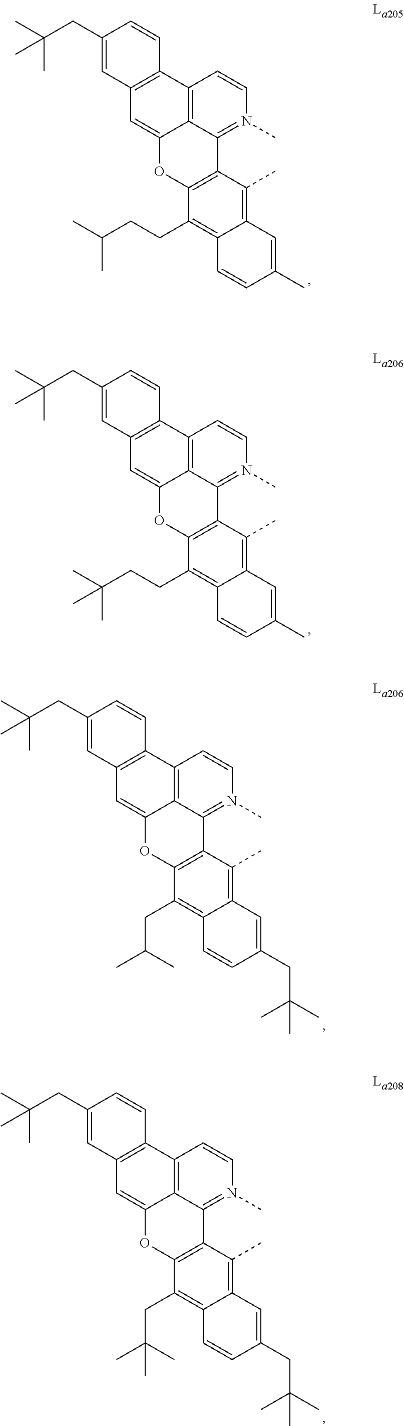 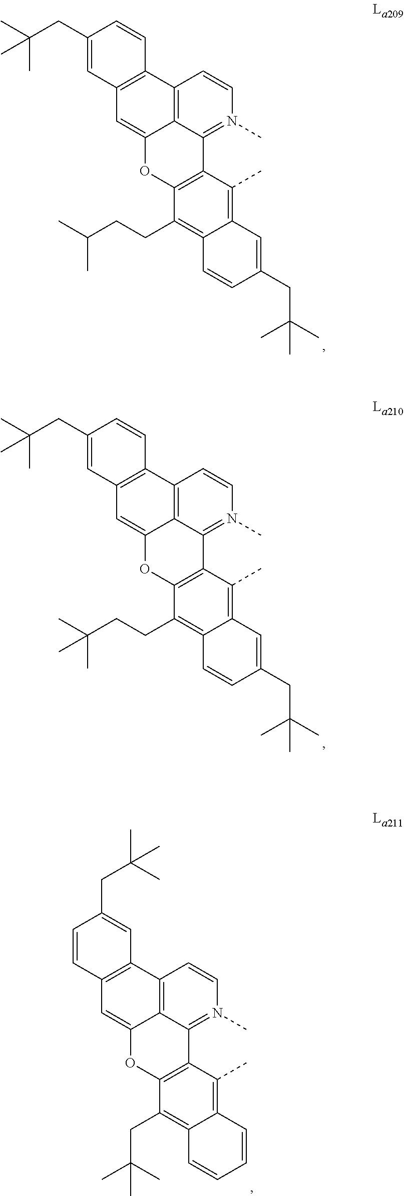 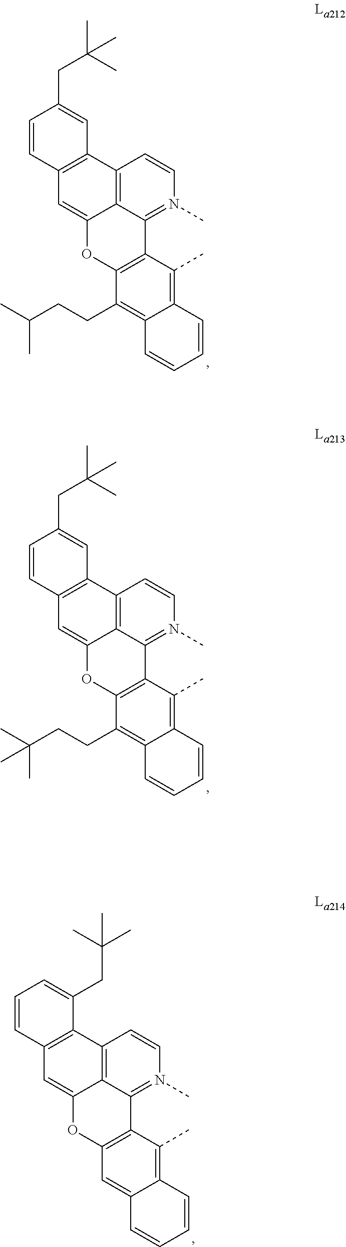 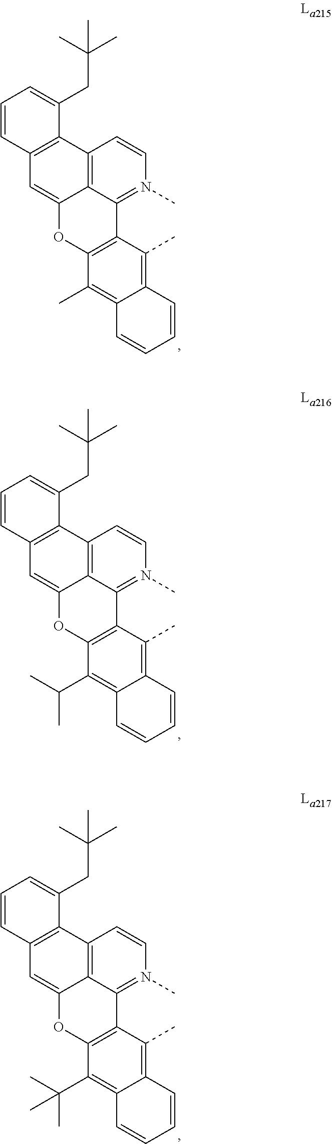 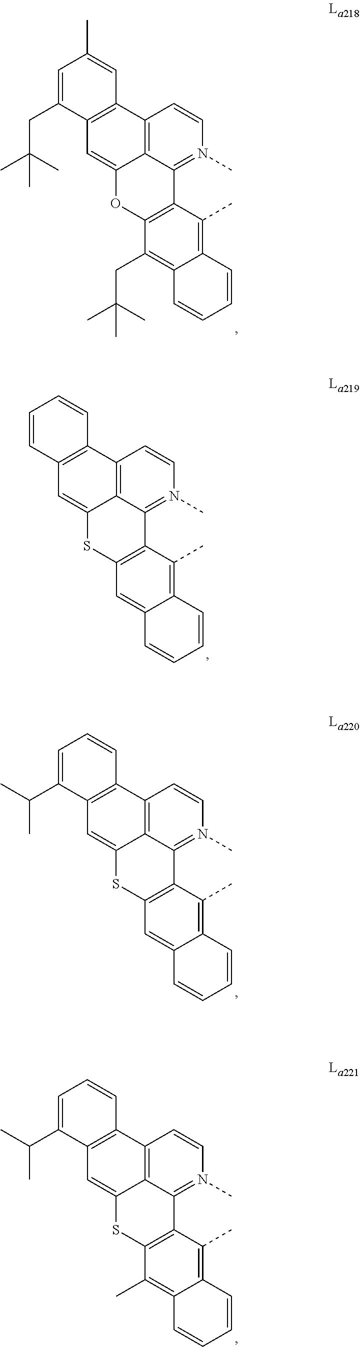 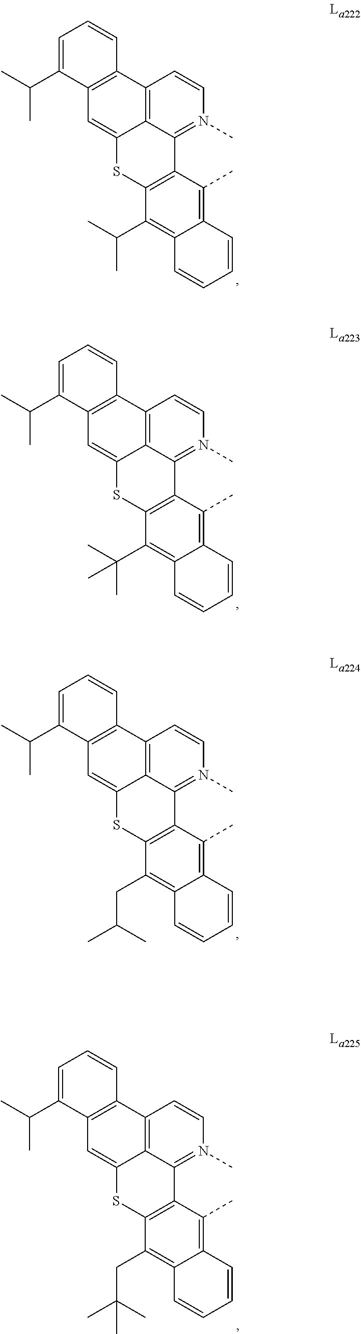 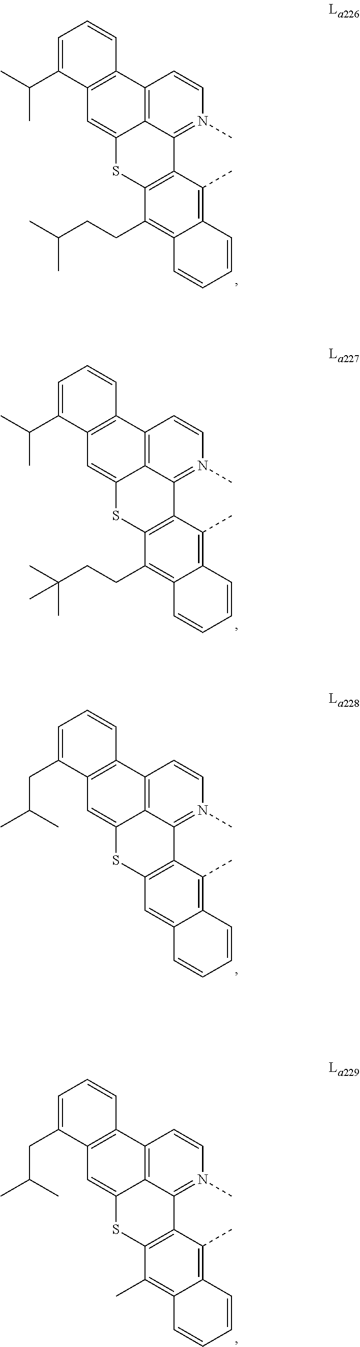 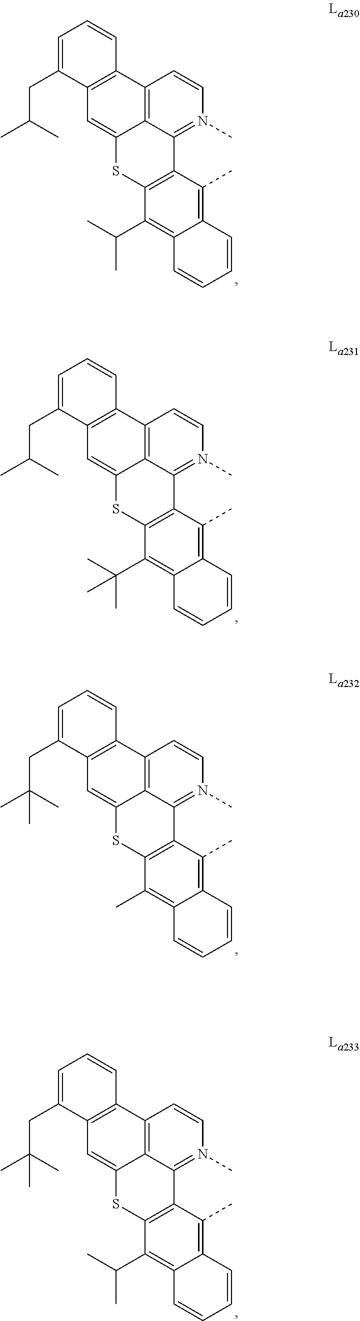 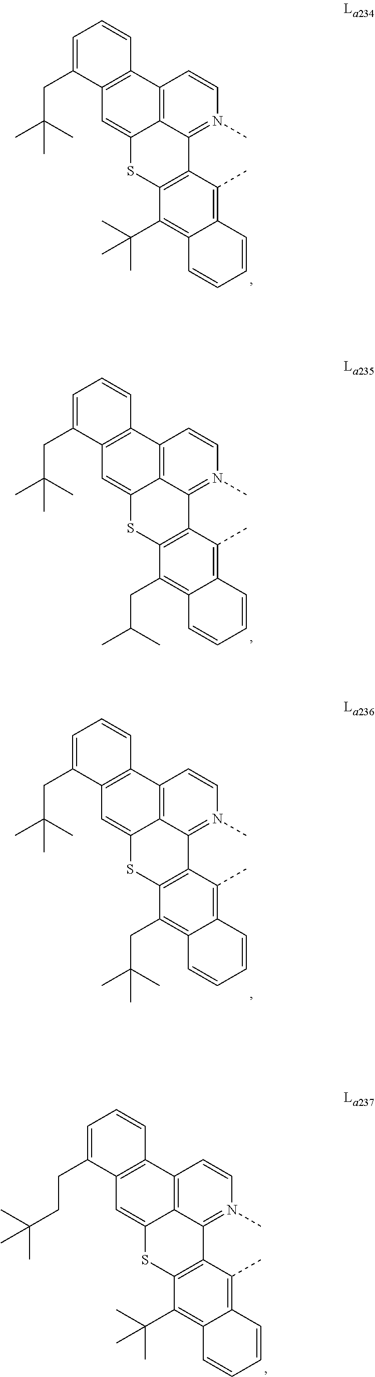 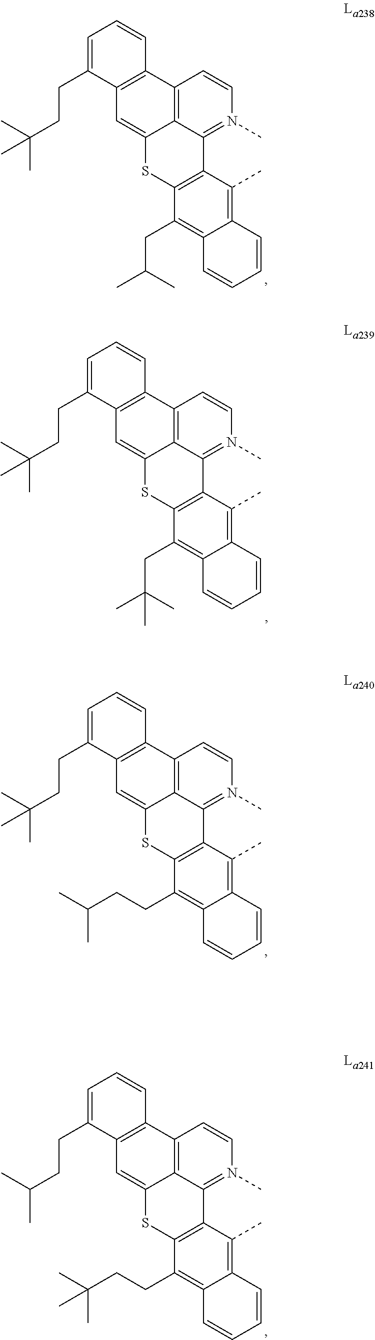 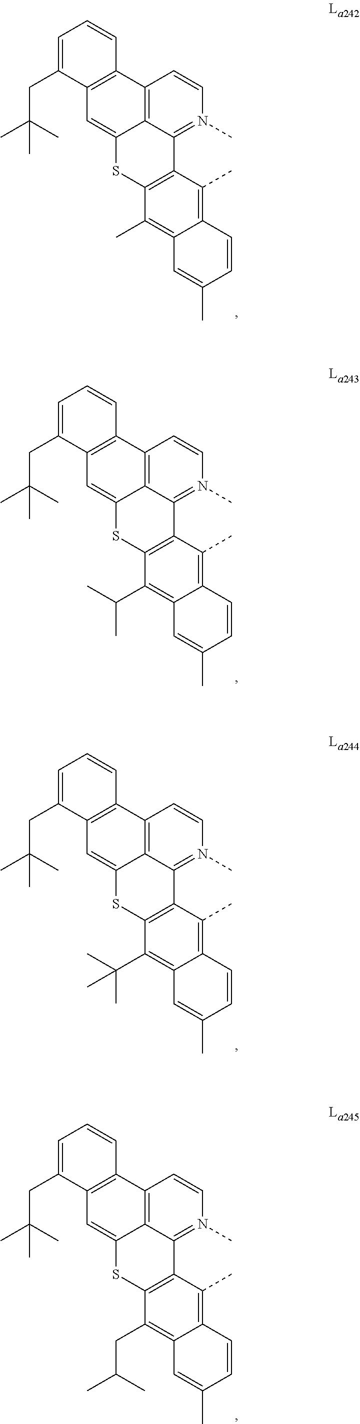 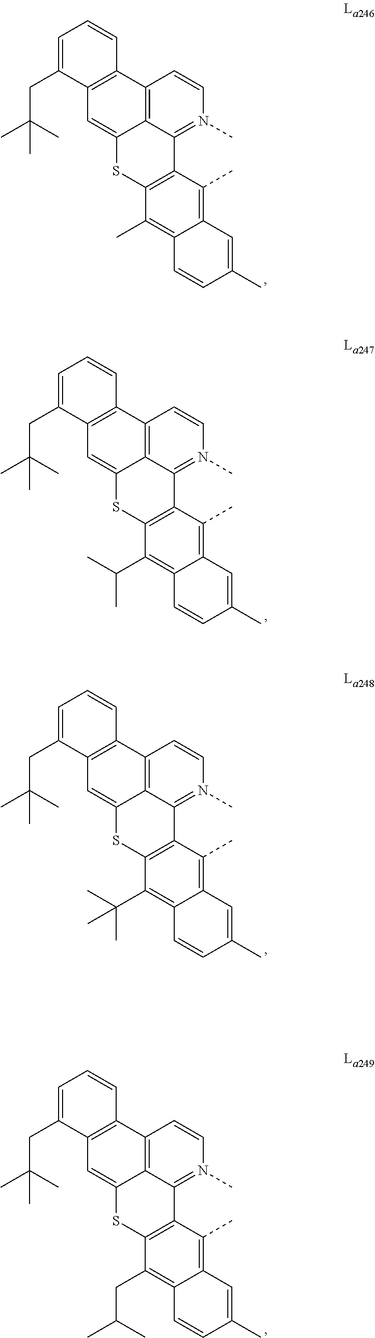 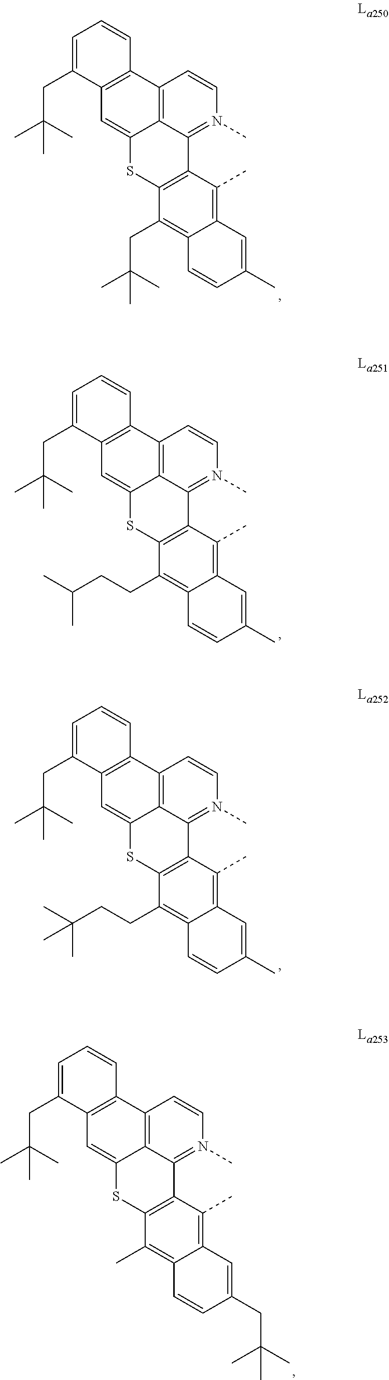 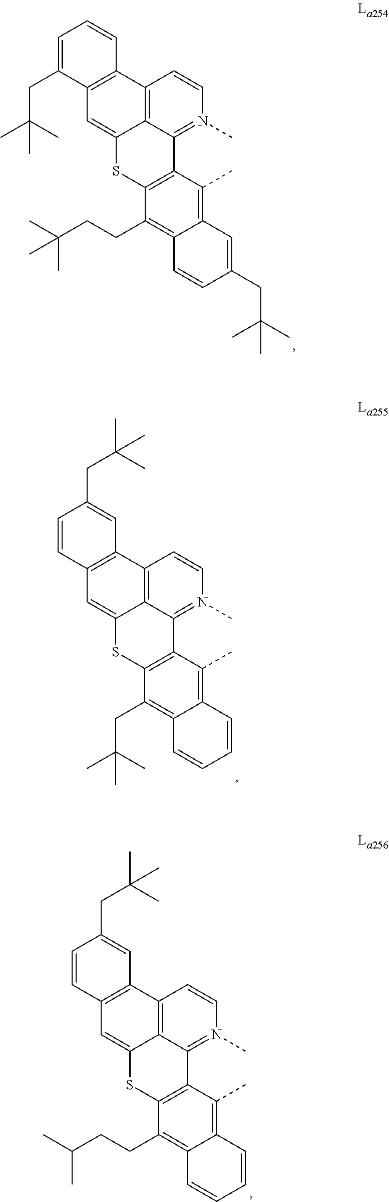 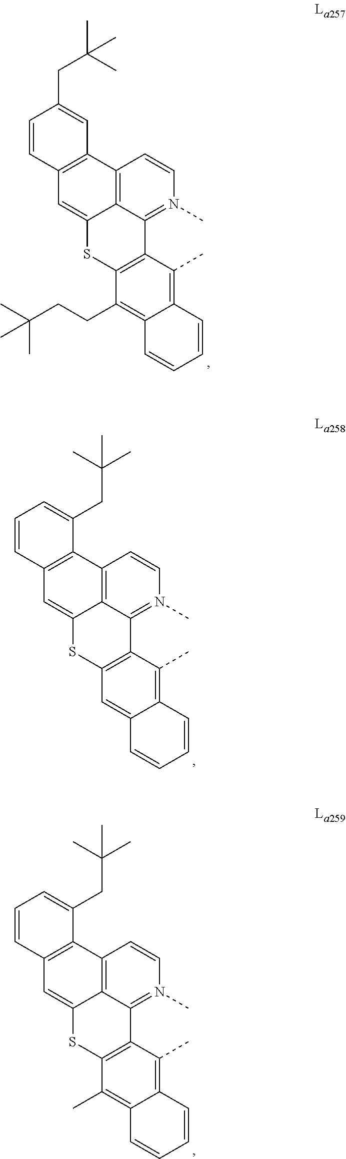 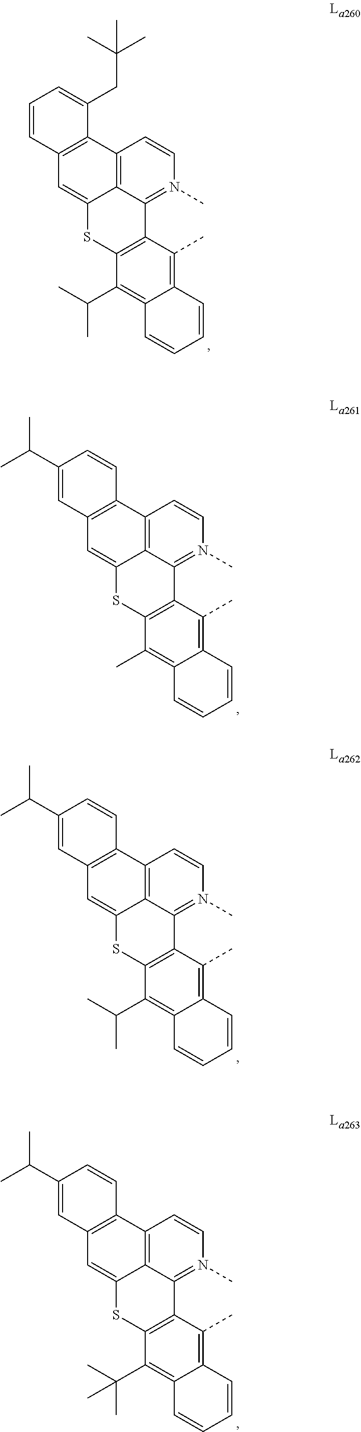 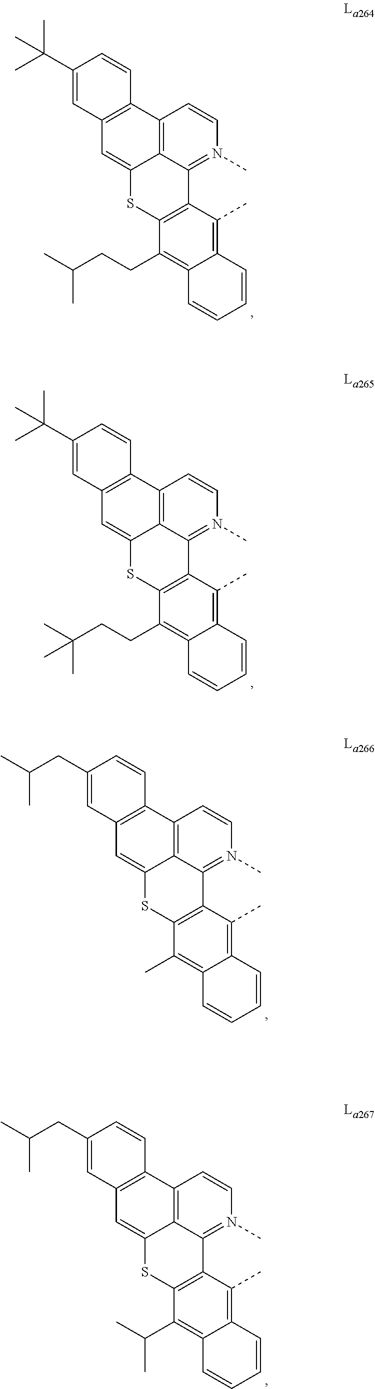 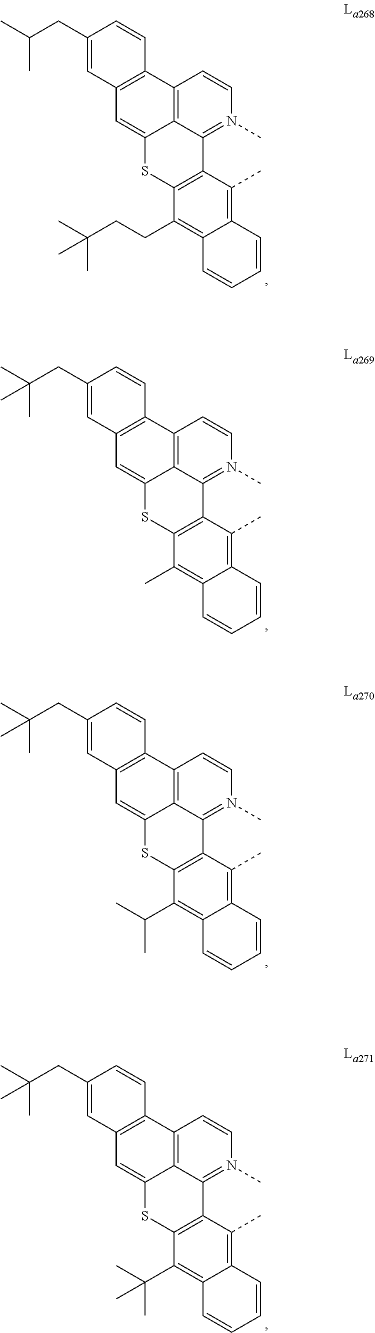 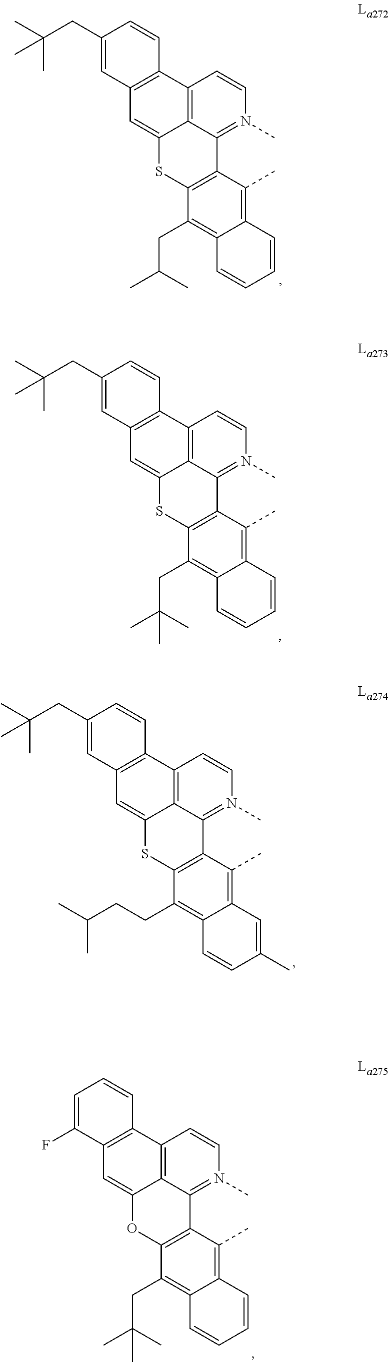 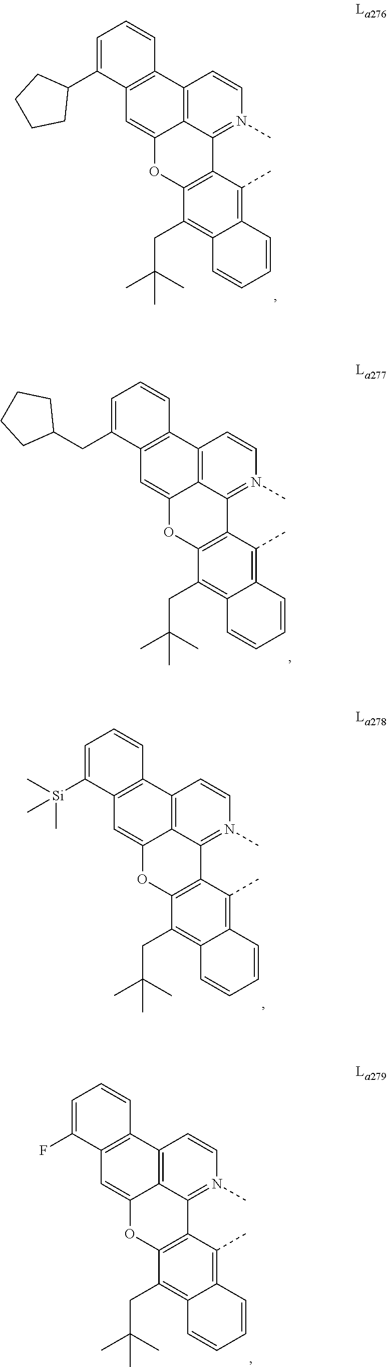 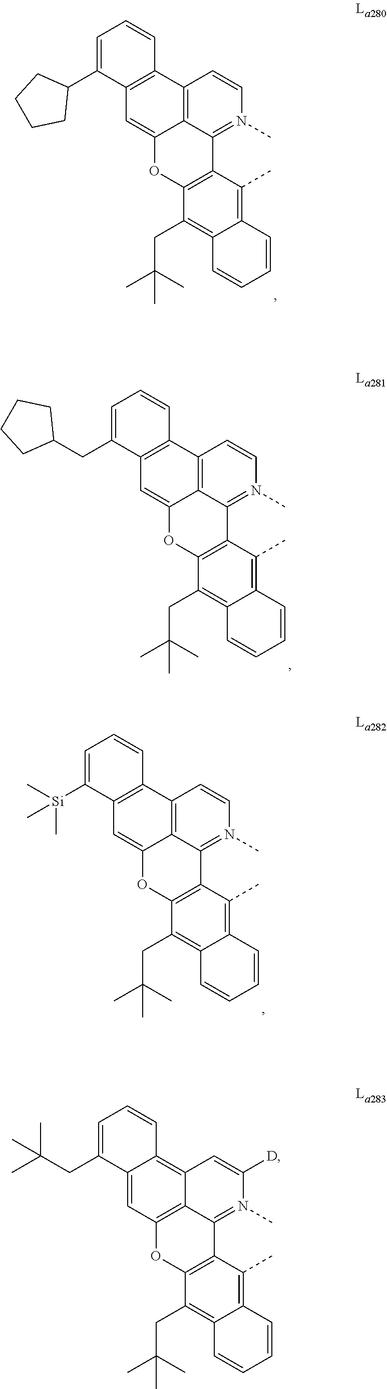 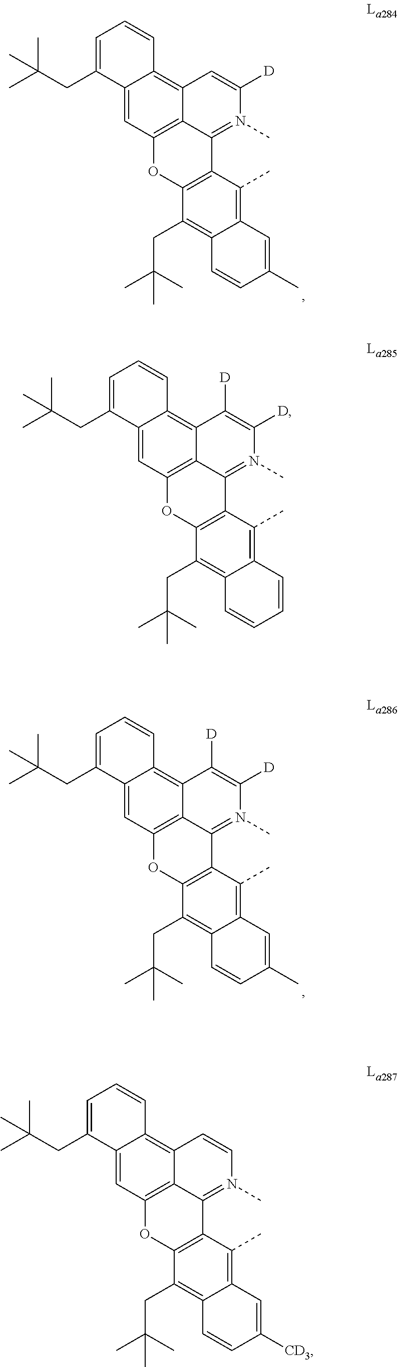 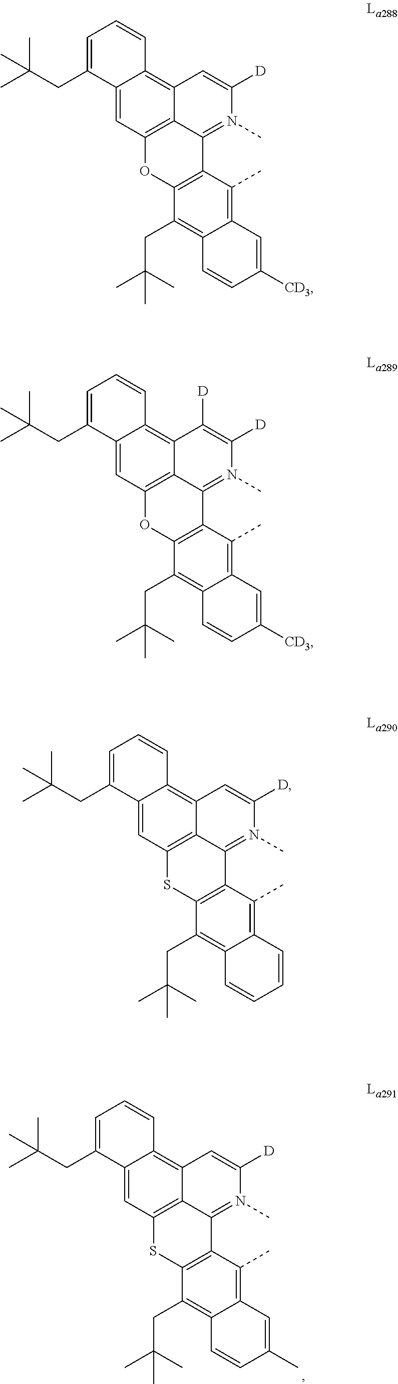 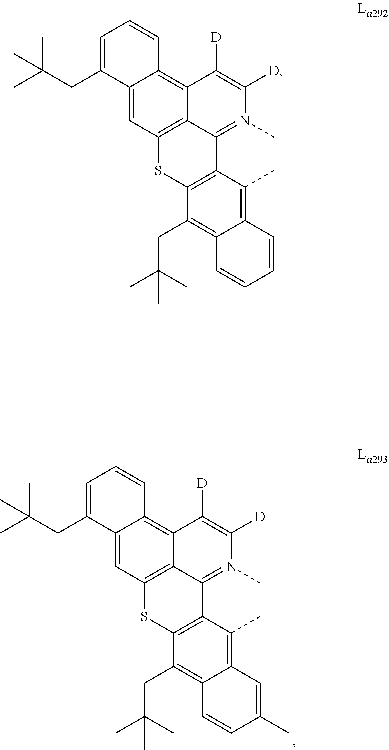 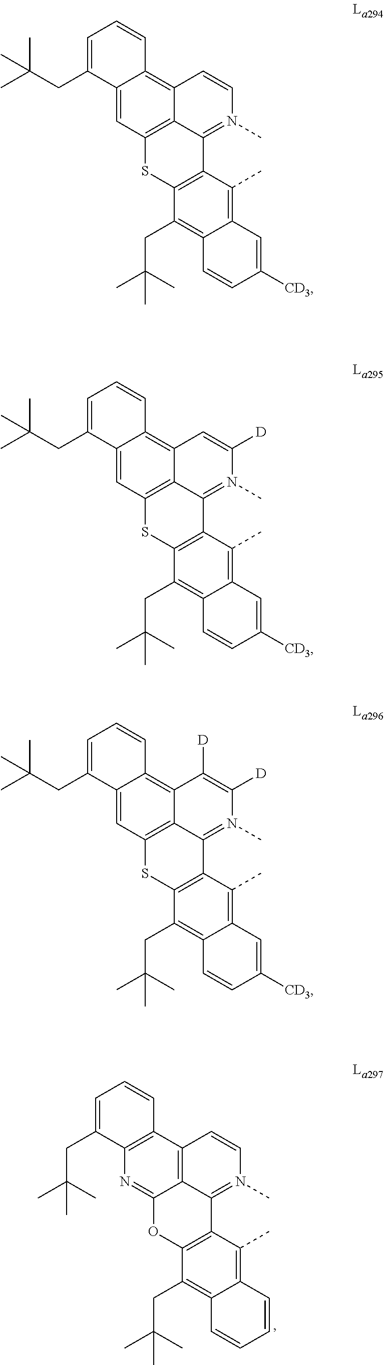 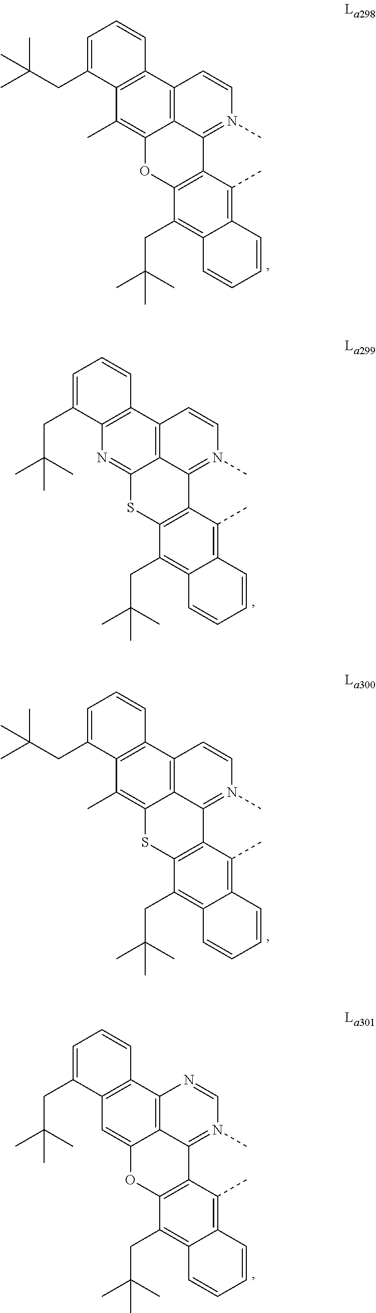 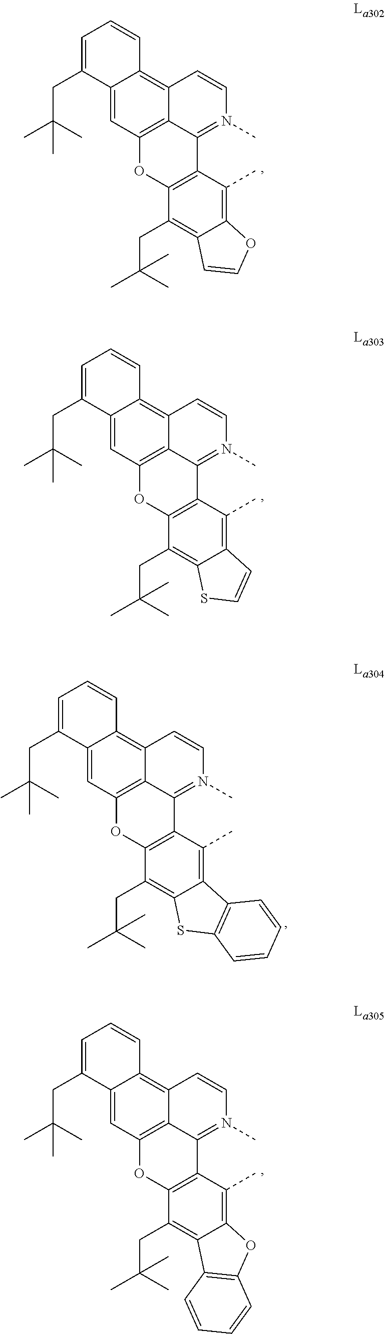 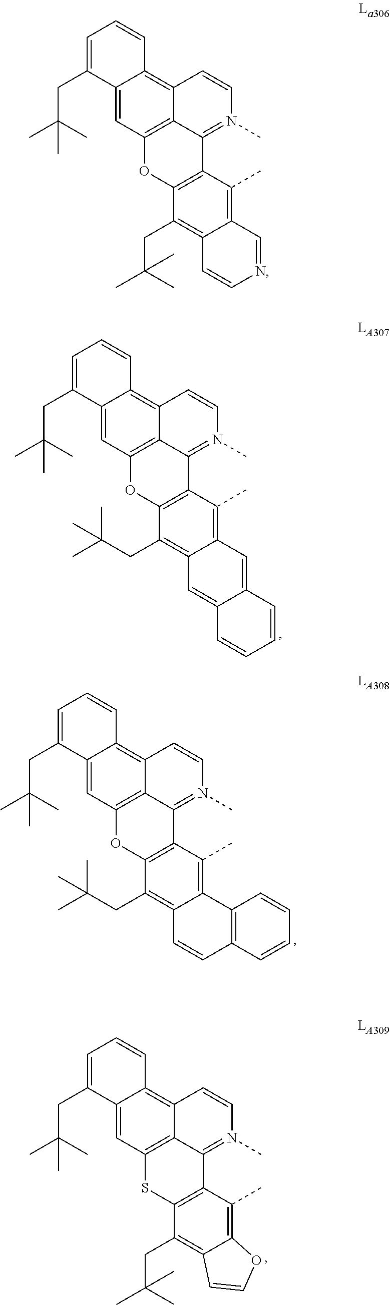 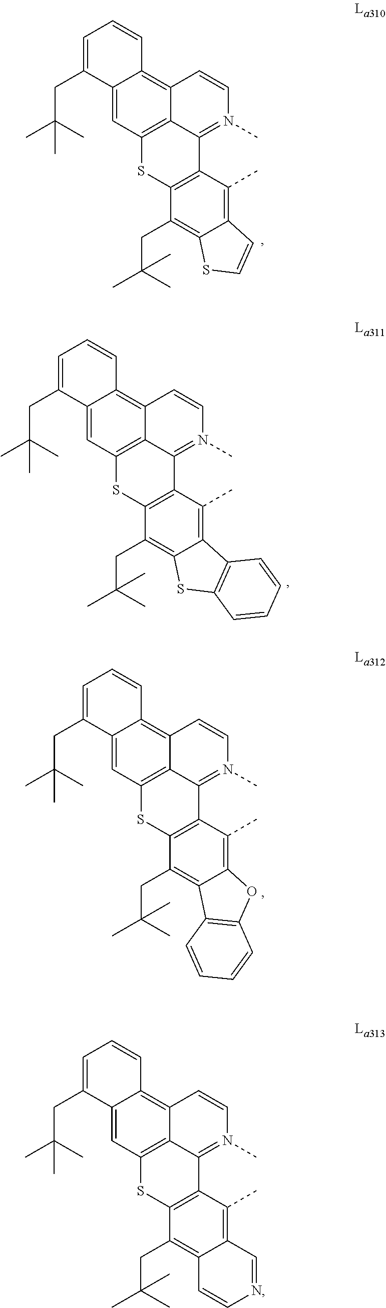 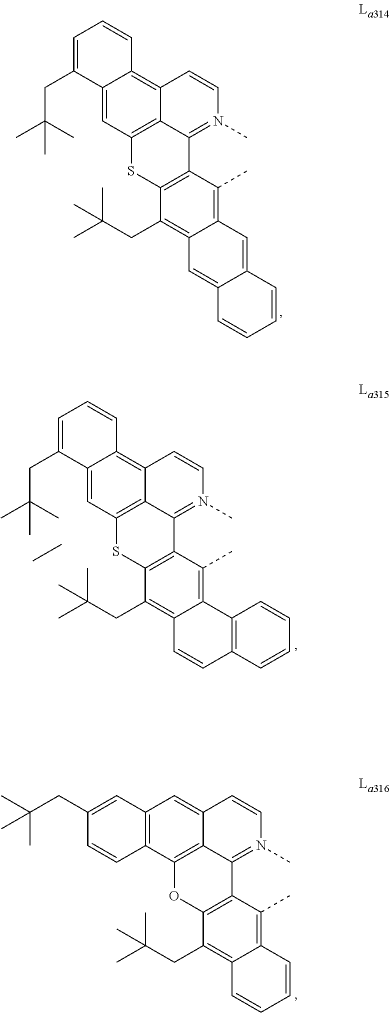 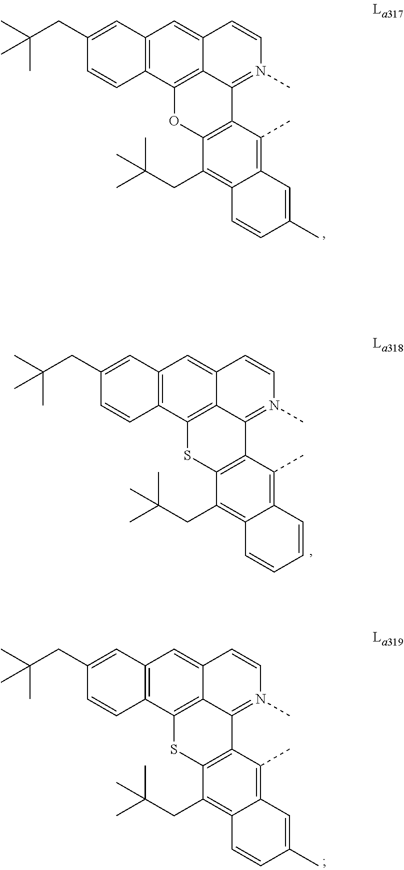
wherein in the above structures, TMS represents trimethylsilyl; and
optionally, hydrogens in the structures of Lₐ₁ to Lₐ₃₁₉ can be partially or fully substituted with deuterium.

13. The organic electroluminescent device according to claim 12, wherein the first compound has a structure of M(Lₐ)ₘ(L_{b})ₙ(L_{c})_{q};
wherein the metal M is selected from a metal with a relative atomic mass greater than 40;
preferably, the metal M is, at each occurrence identically or differently, selected from the group consisting of Cu, Ag, Au, Ru, Rh, Pd, Os, Ir, and Pt; more preferably, the metal M is, at each occurrence identically or differently, selected from Pt or Ir;
Lₐ, L_{b}, and L_{c} are a first ligand, a second ligand, and a third ligand of the metal complex, respectively; m is 1, 2, or 3, n is 0, 1, or 2, q is 0, 1, or 2, and m+n+q is equal to an oxidation state of the metal M; when m is greater than 1, multiple Lₐ are the same or different; when n is 2, two L_{b} are the same or different; when q is 2, two L_{c} are the same or different;
Lₐ, L_{b}, and L_{c} can be optionally joined to form a multidentate ligand;
L_{b} and L_{c} are, at each occurrence identically or differently, selected from the group consisting of the following structures: 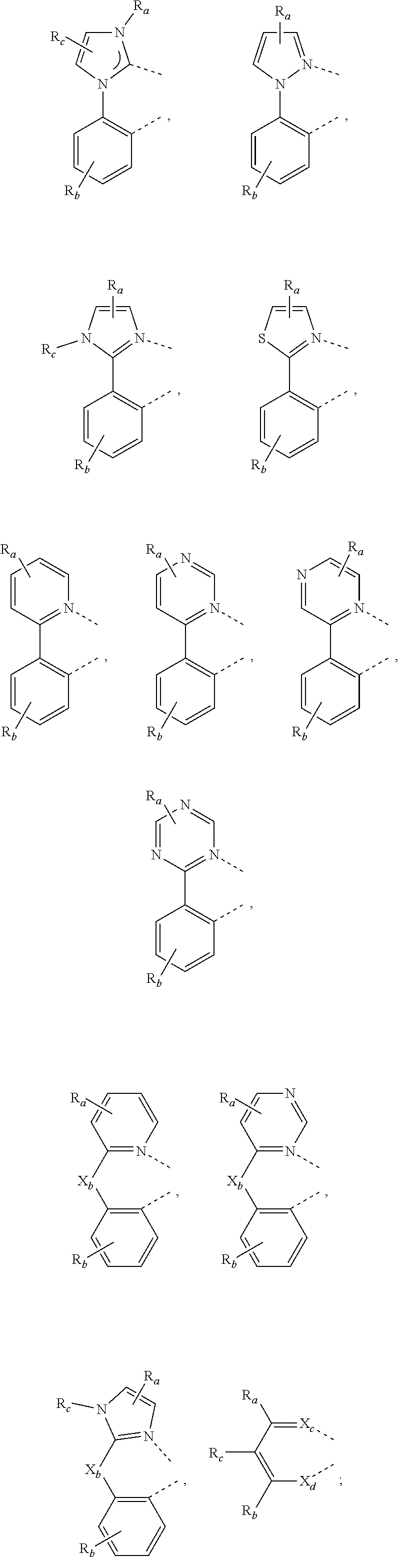
wherein Rₐ, R_{b}, and R_{c} represent, at each occurrence identically or differently, mono-substitution, multiple substitutions, or non-substitution;
X_{b} is, at each occurrence identically or differently, selected from the group consisting of: O, S, Se, NR_{N1}, and CR_{C1}R_{C2};
X_{c} and X_{d} are, at each occurrence identically or differently, selected from the group consisting of: O, S, Se, and NR_{N2};
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents Rₐ, R_{b}, R_{c}, R_{N1}, R_{N2}, R_{C1}, and R_{C2} can be optionally joined to form a ring.

14. The organic electroluminescent device according to claim 13, wherein L_{b} is, at each occurrence identically or differently, selected from the following structure: 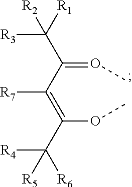
wherein R₁ to R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
preferably, at least one or two of R₁ to R₃ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, or a combination thereof, and/or at least one or two of R₄ to R₆ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, or a combination thereof,
more preferably, at least two of R₁ to R₃ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms, or a combination thereof, and/or at least two of R₄ to R₆ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms, or a combination thereof.

15. The organic electroluminescent device according to claim 13, wherein L_{b} is, at each occurrence identically or differently, selected from the group consisting of the following structures: 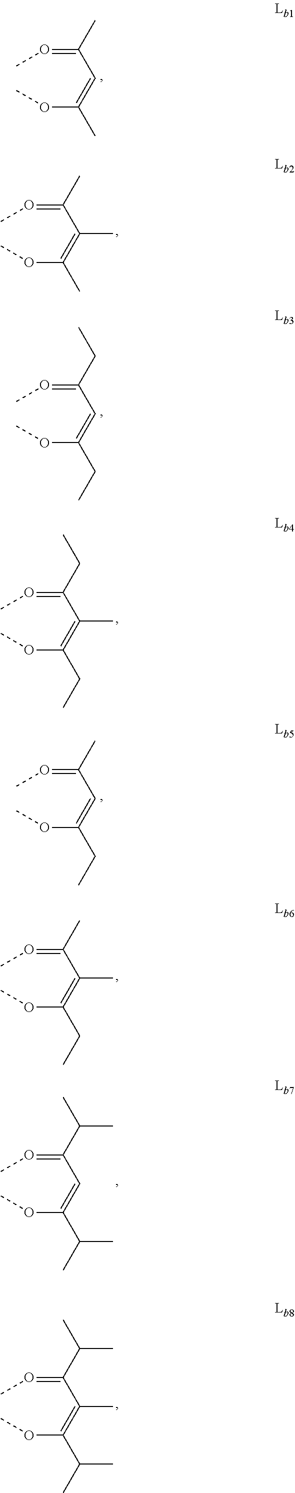 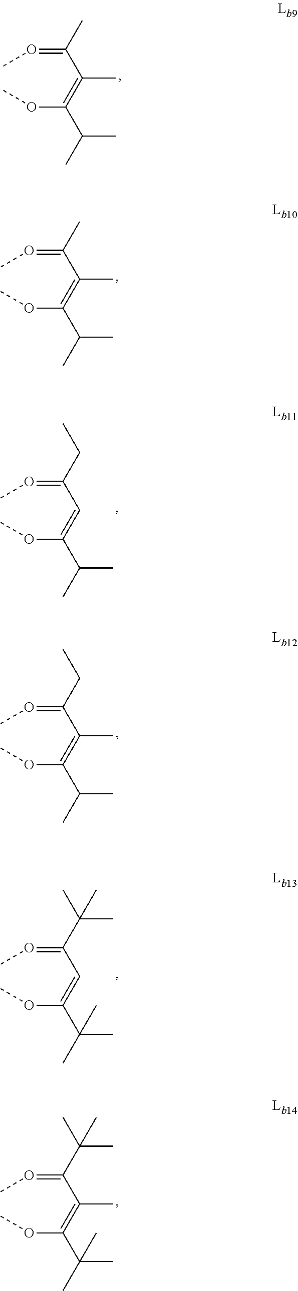 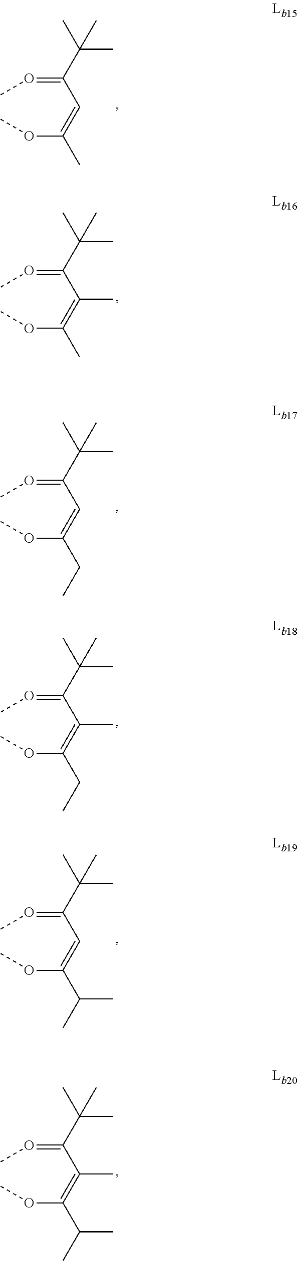 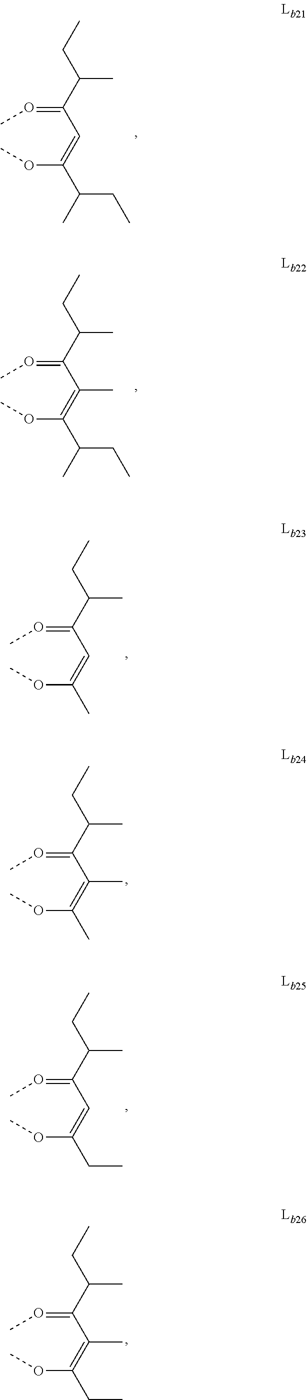 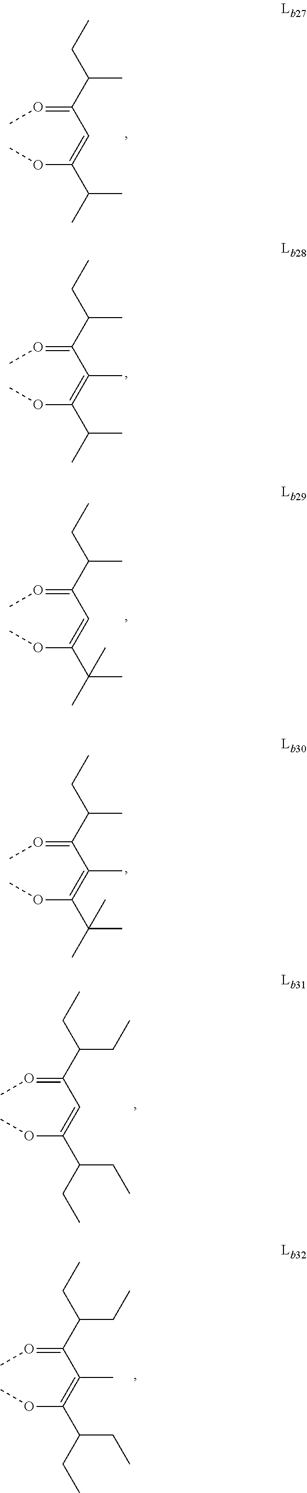 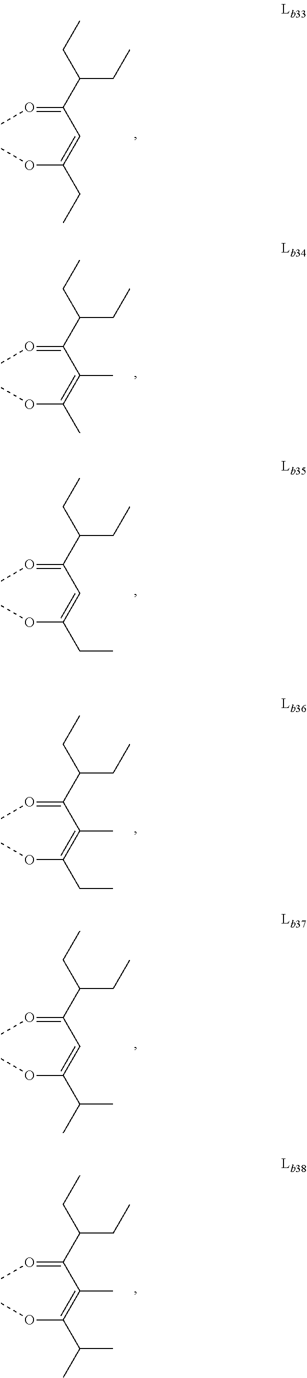 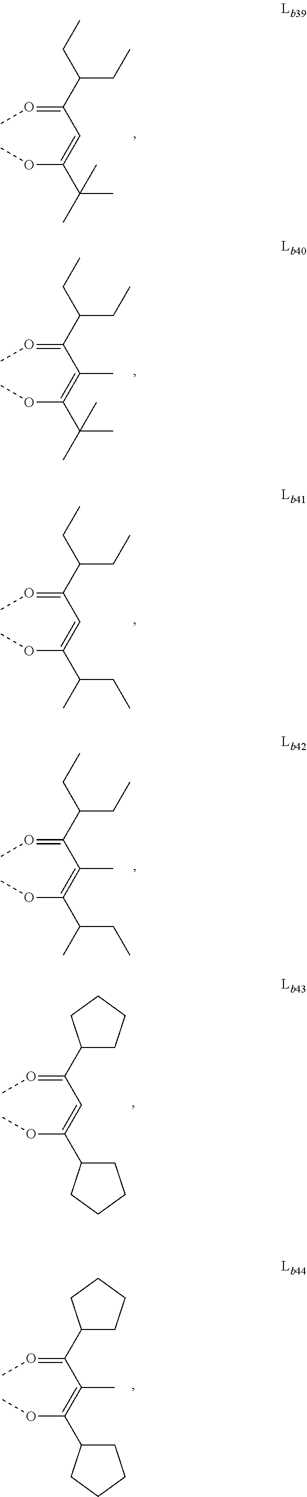 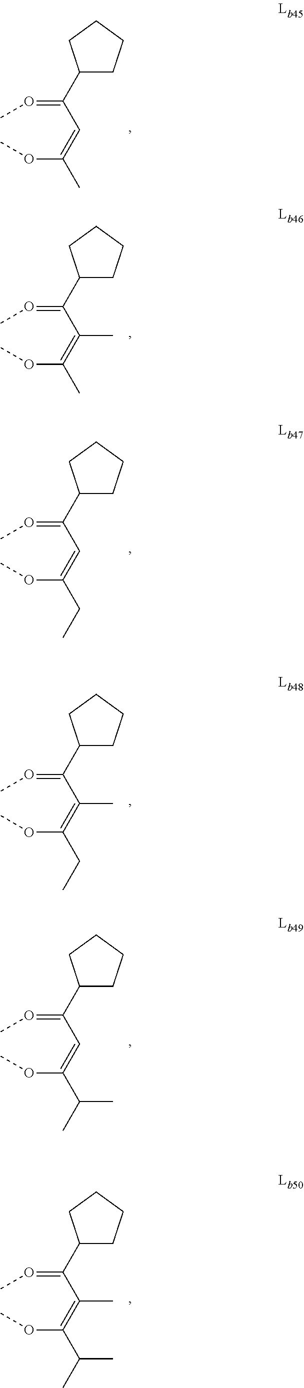 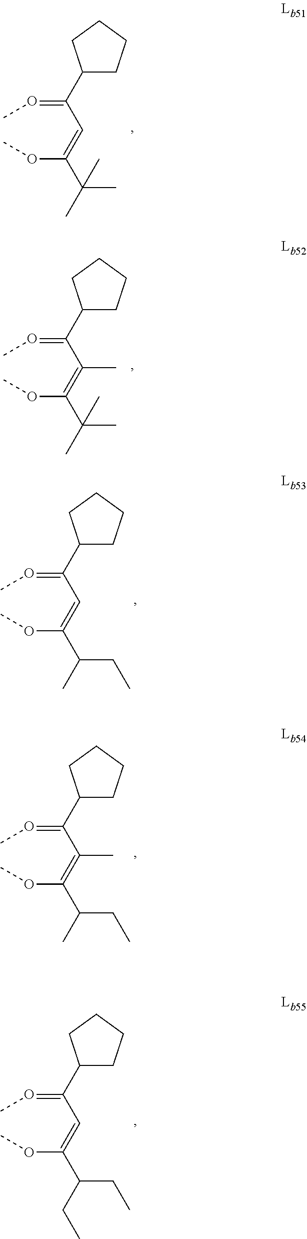 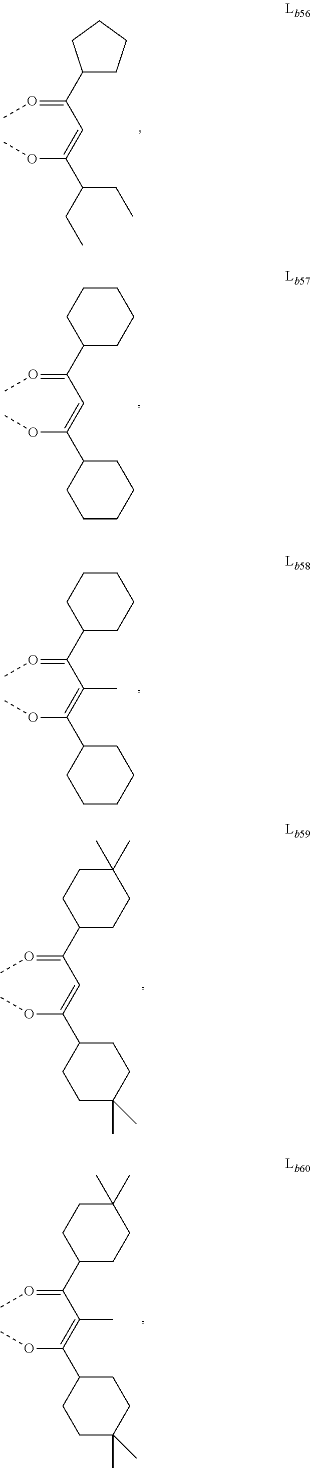 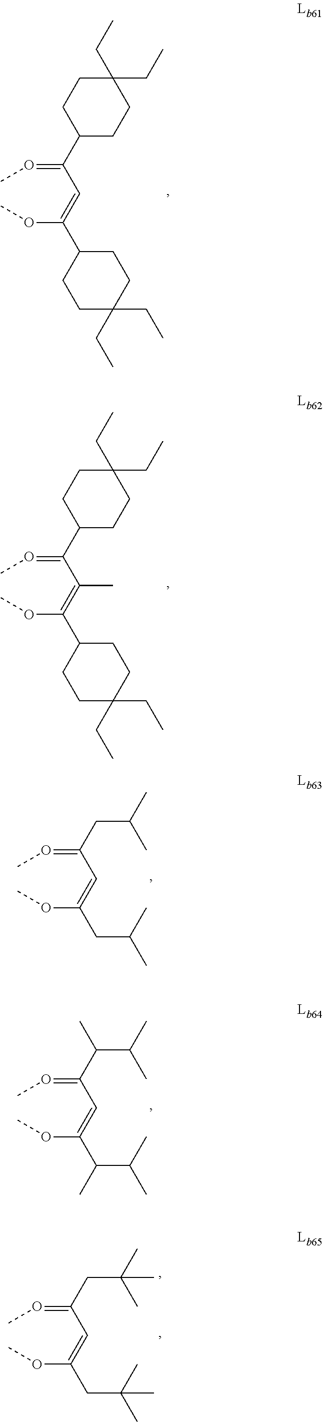 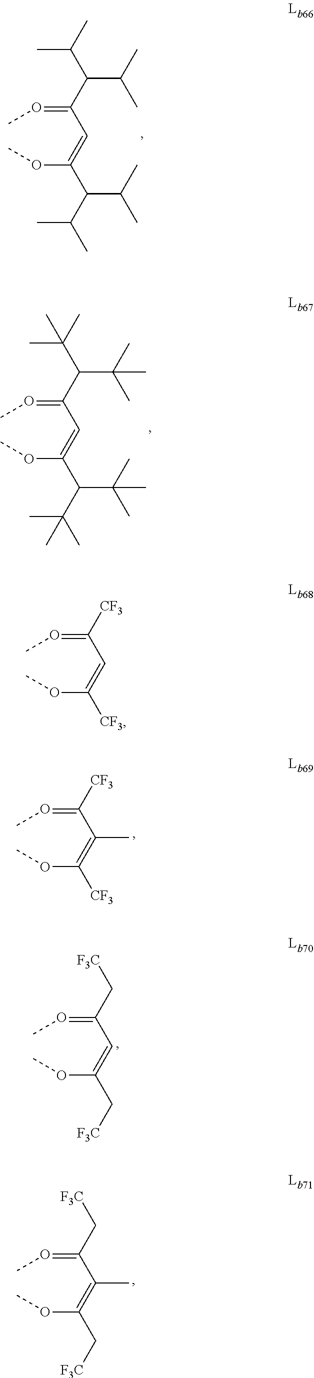 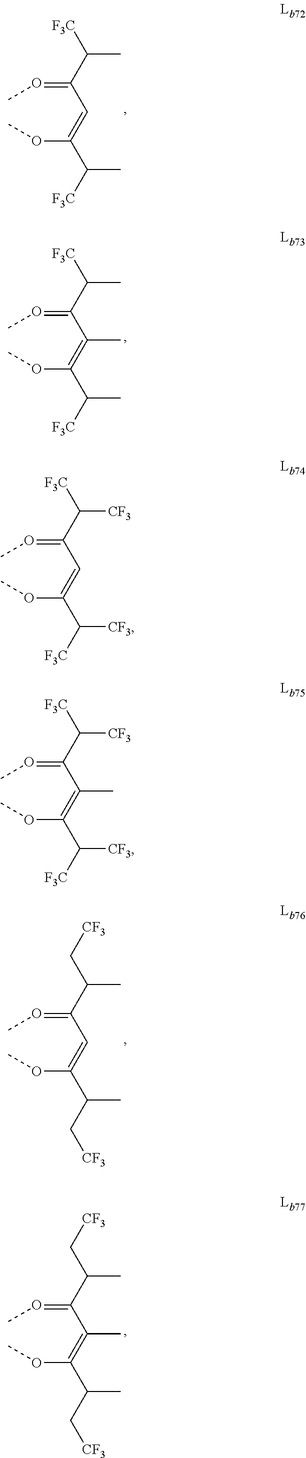 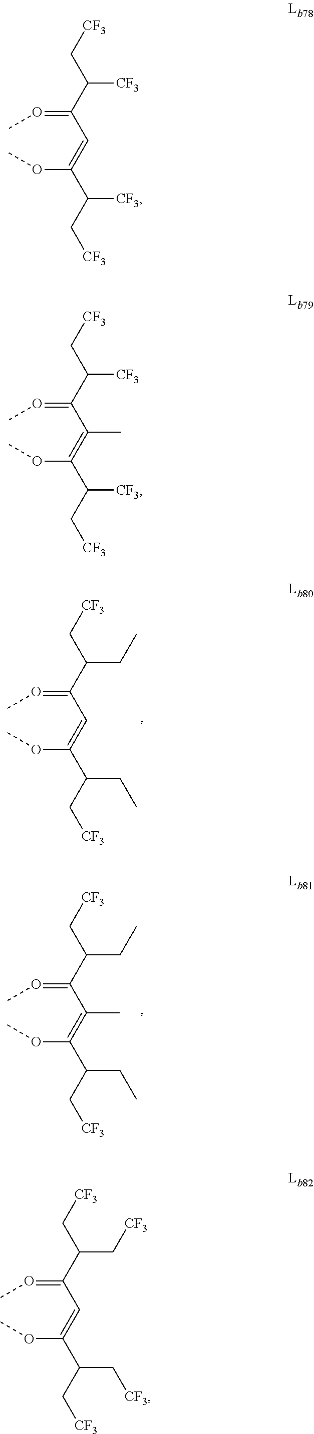 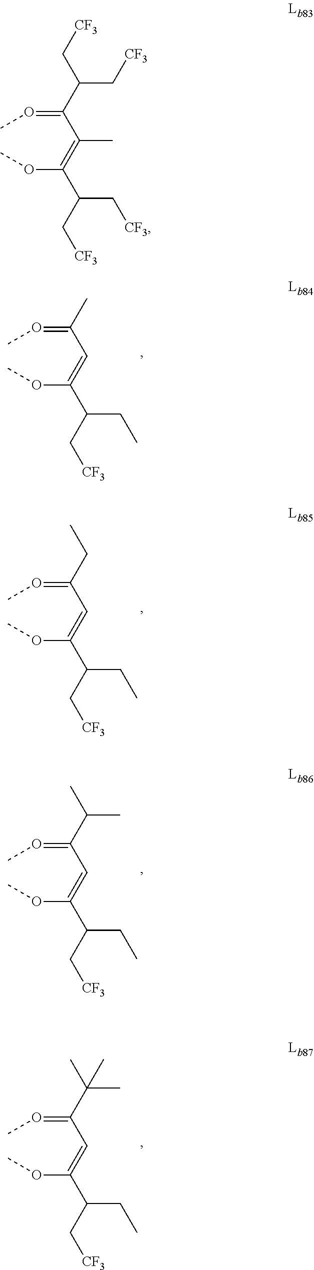 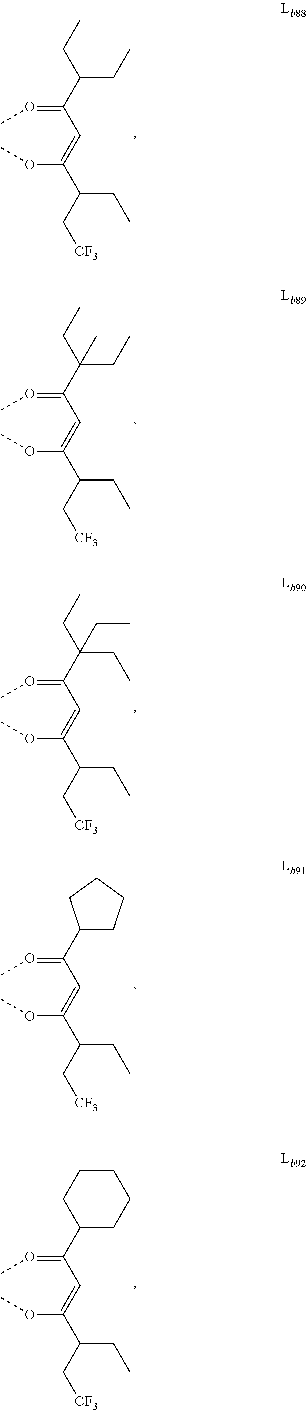 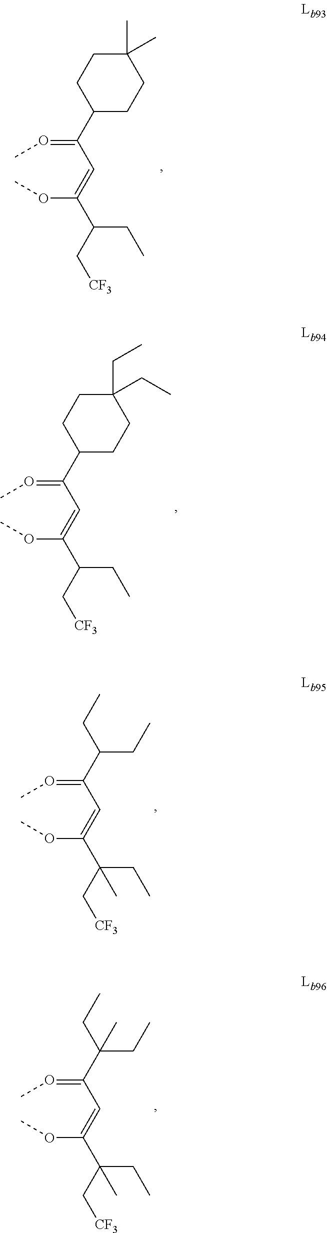 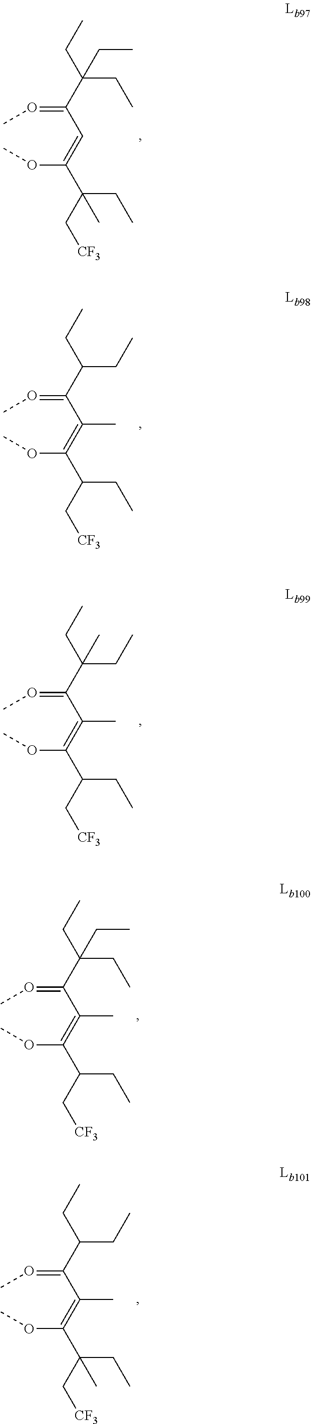 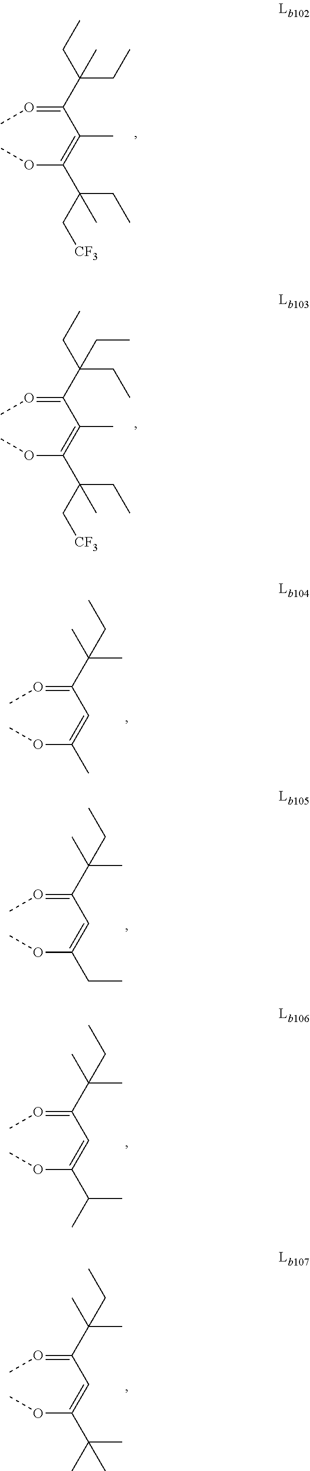 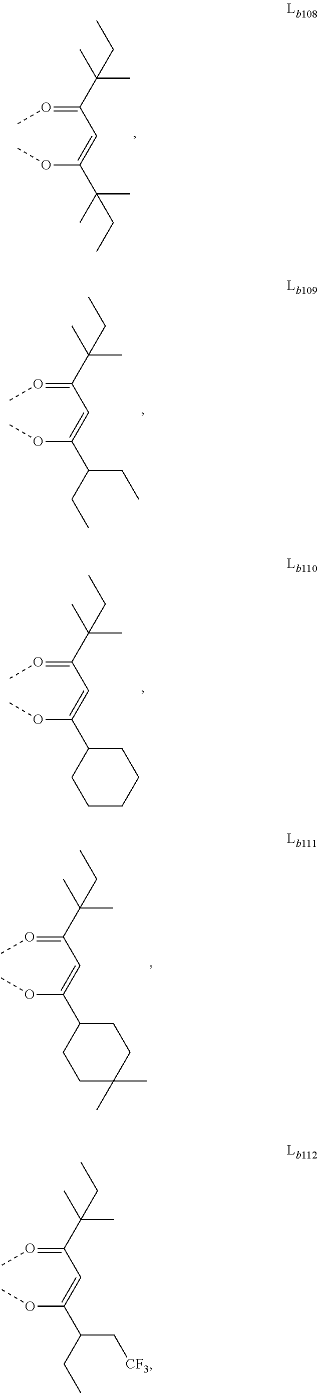 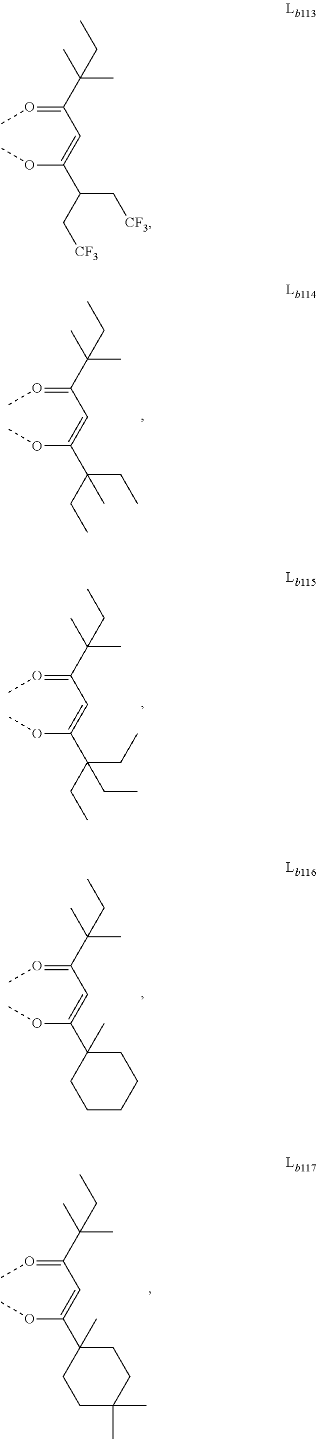 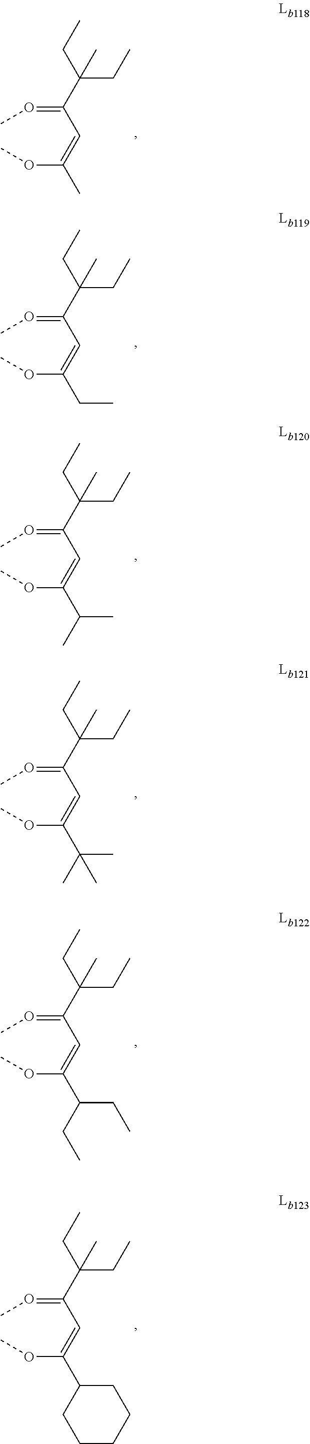 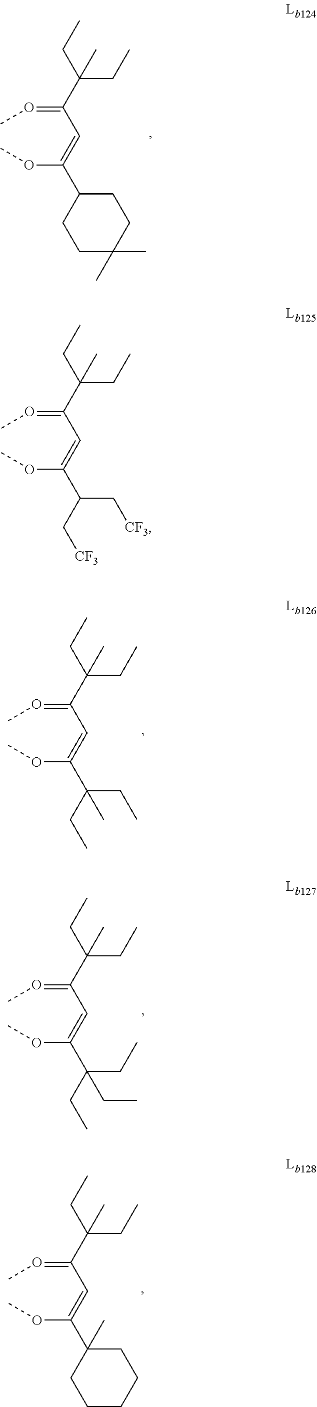 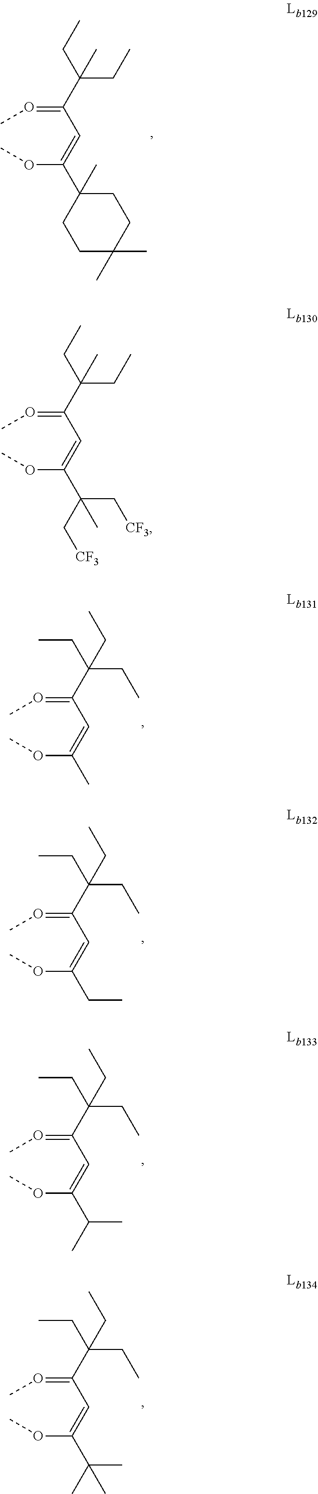 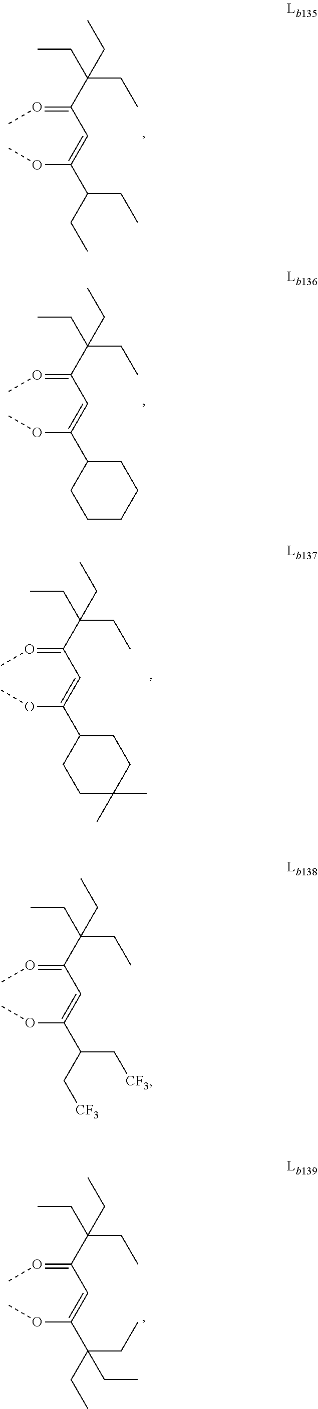 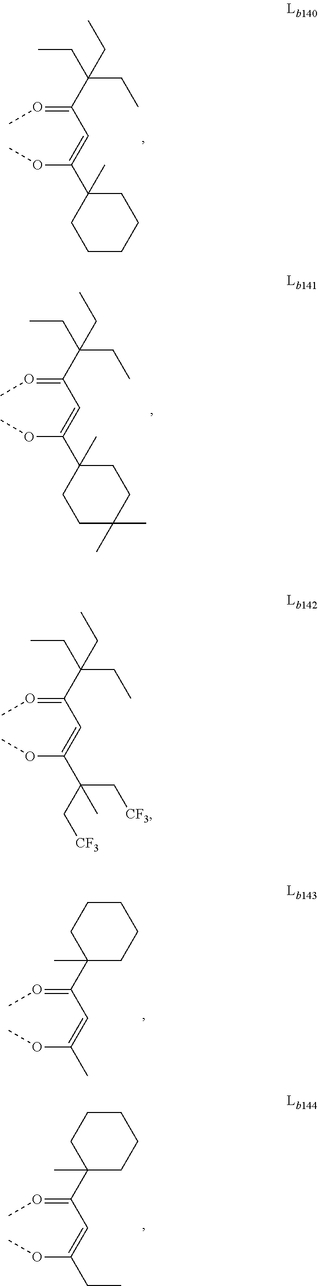 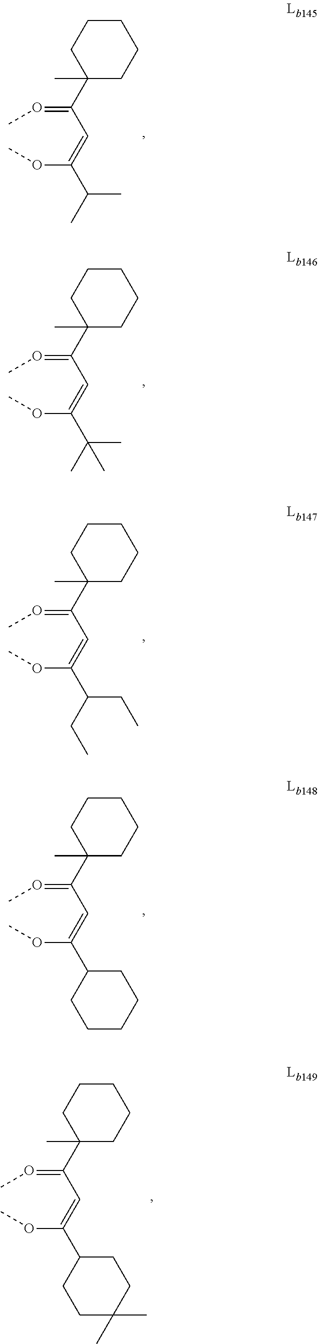 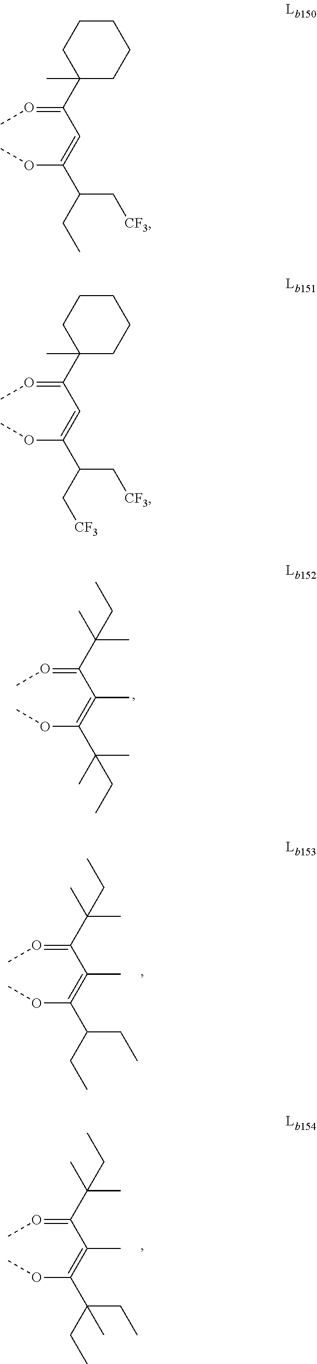 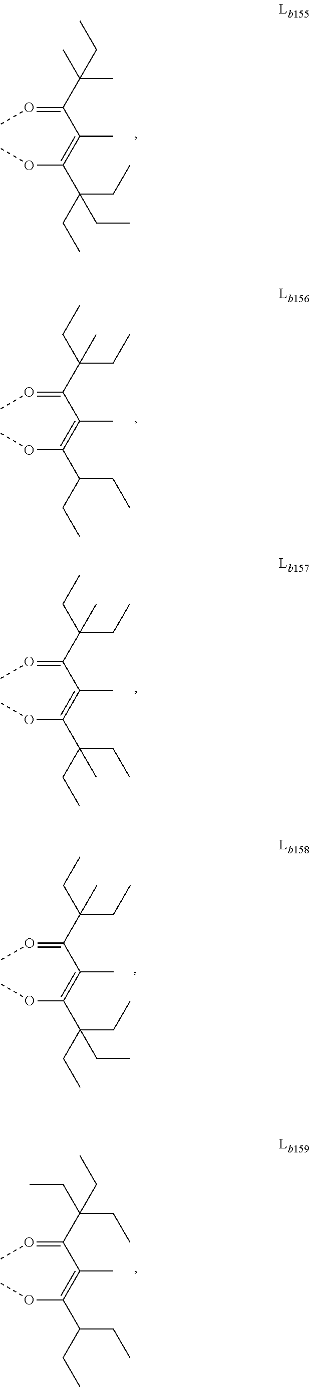 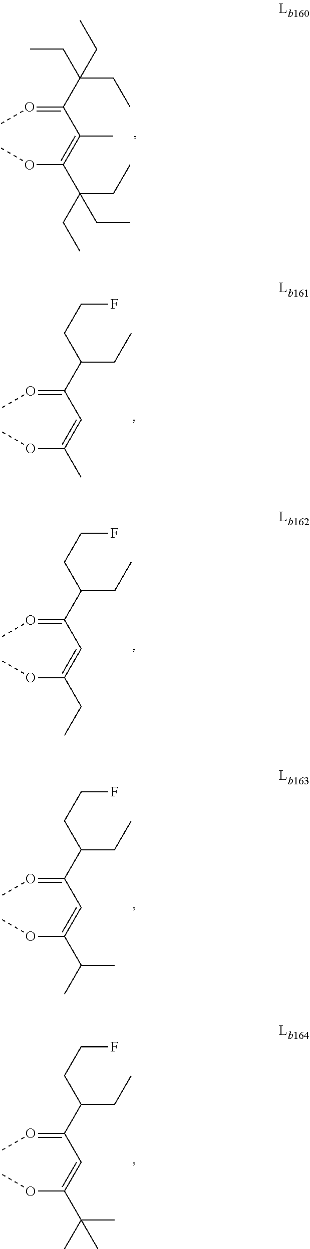 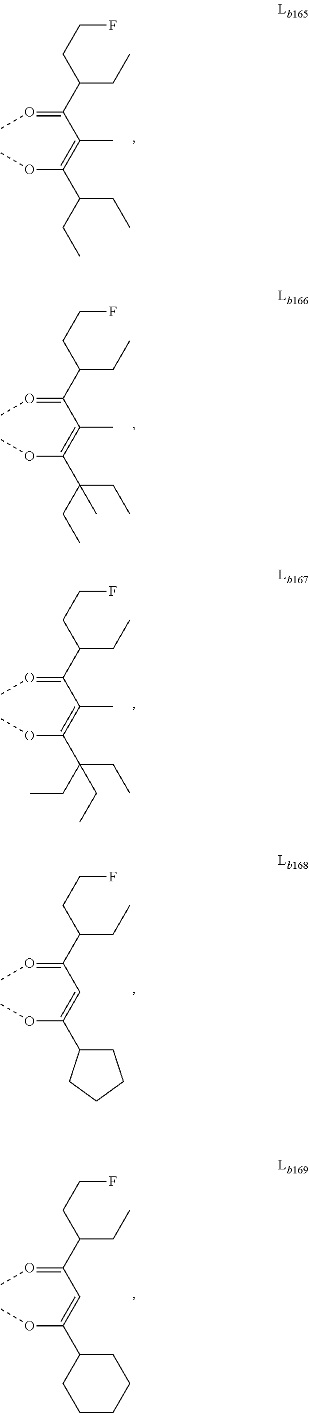 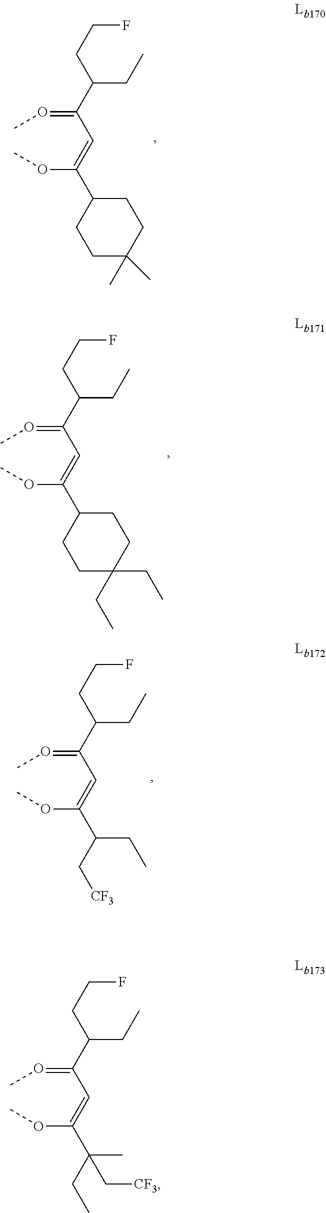 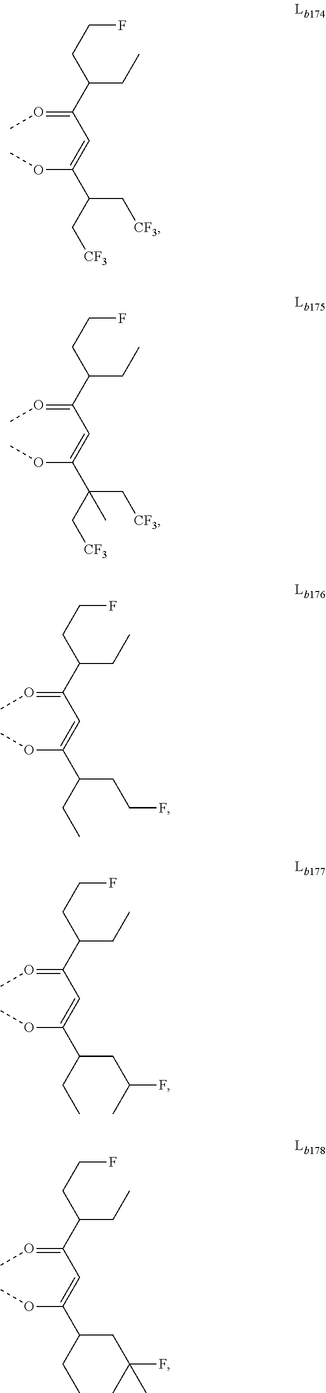 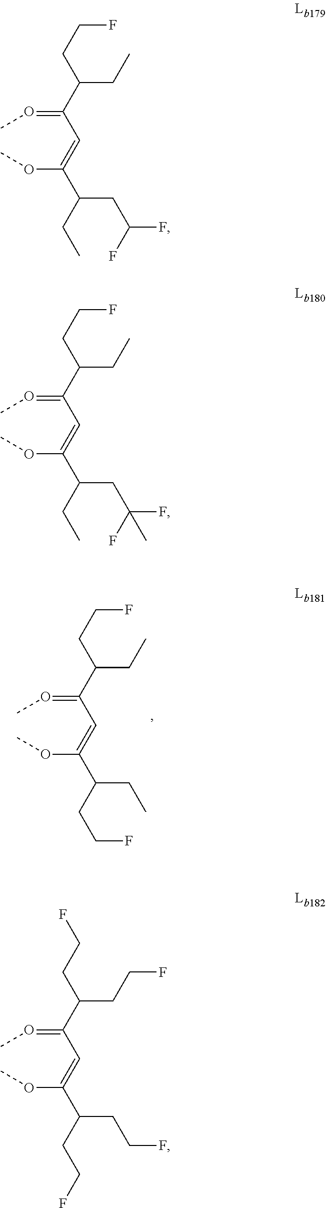 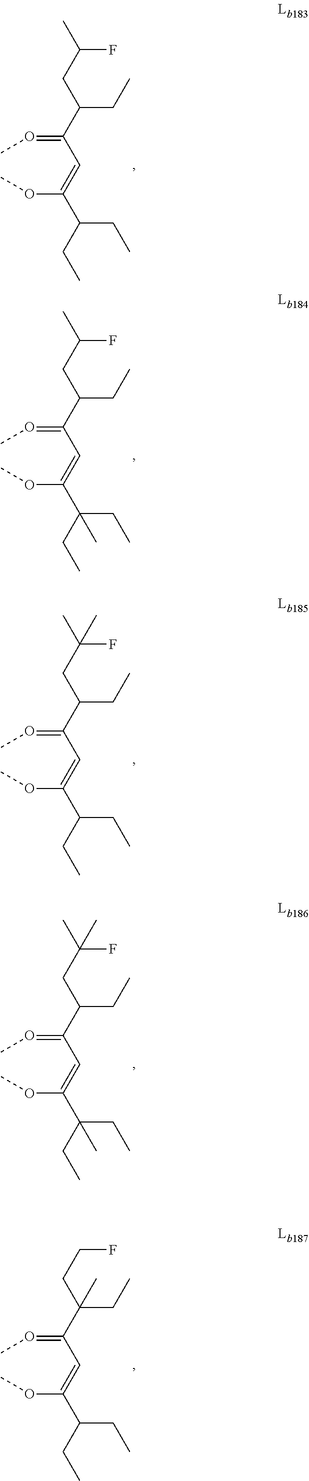 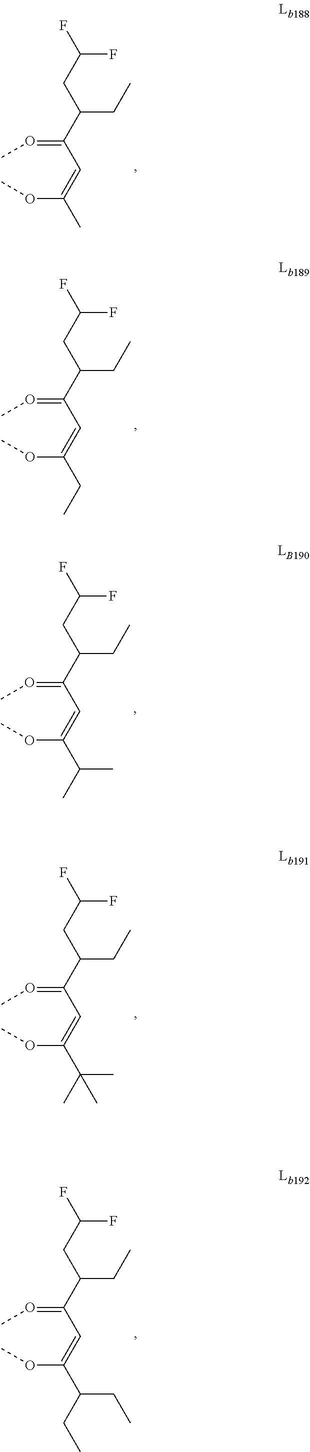 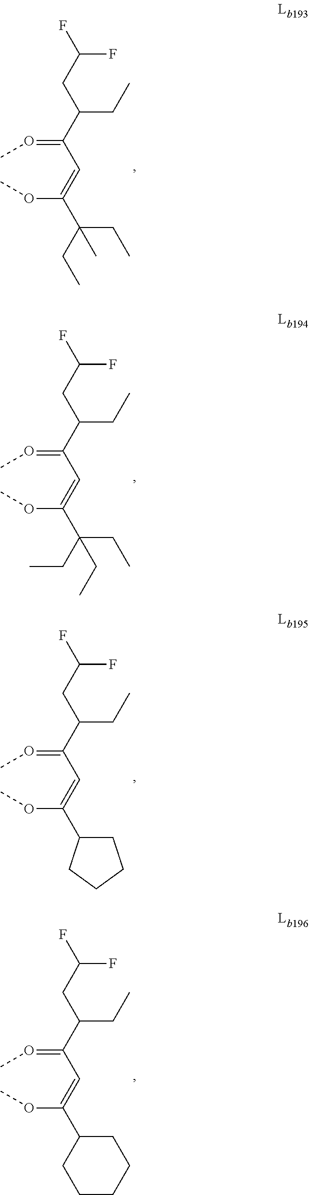 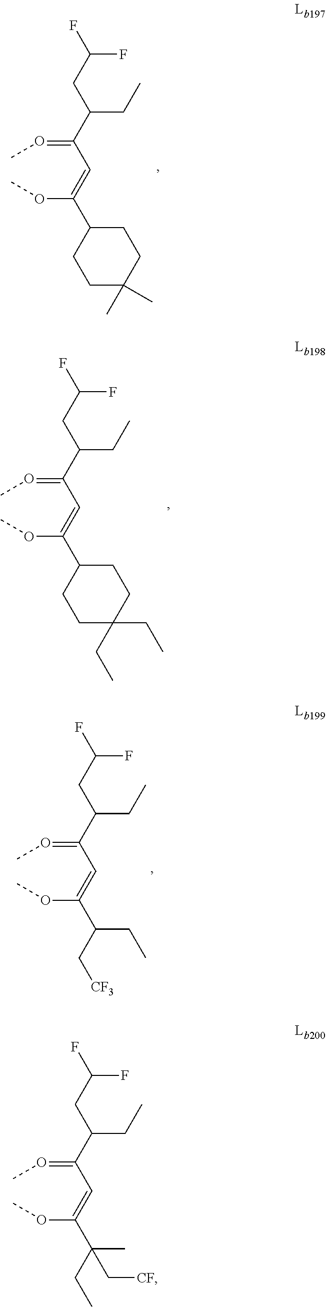 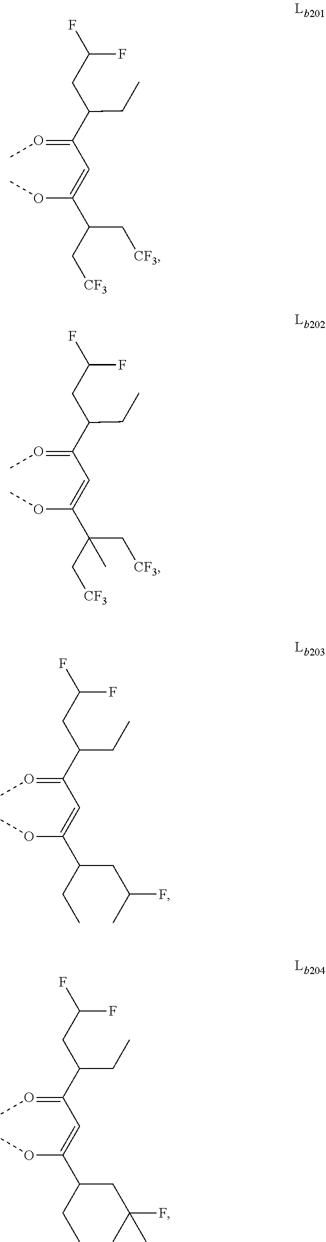 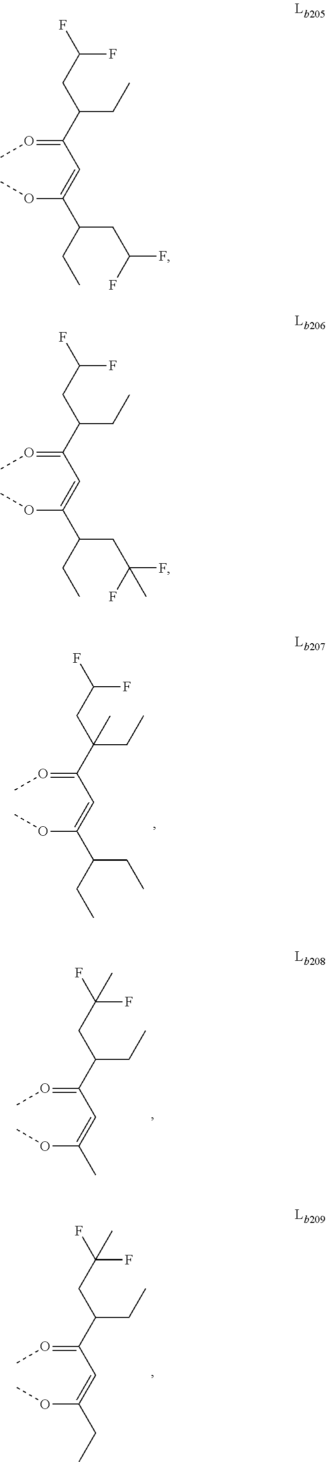 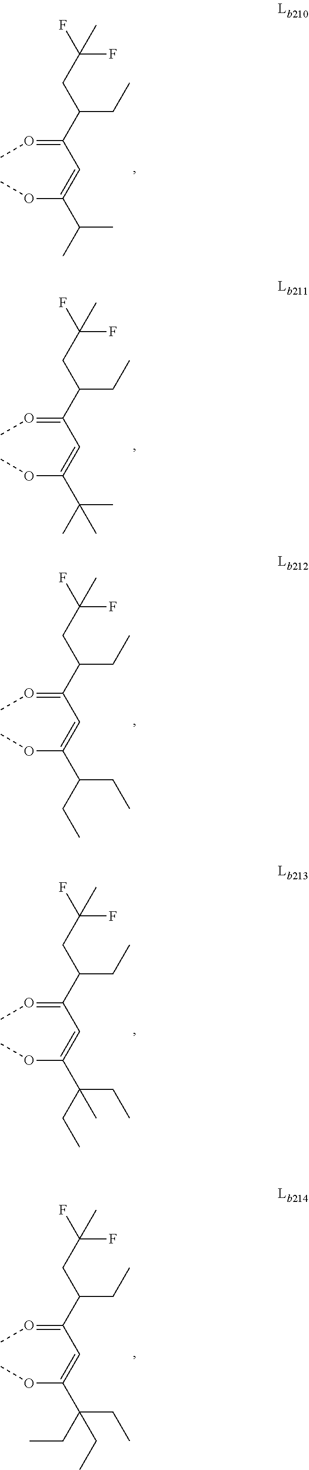 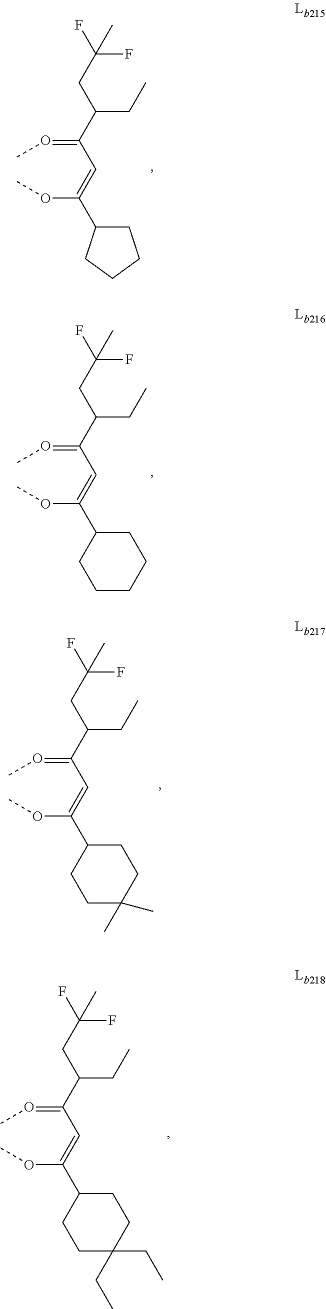 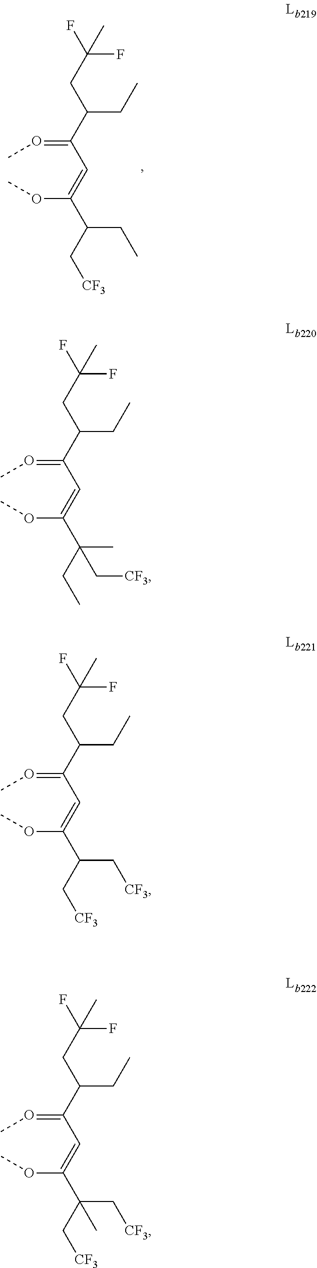 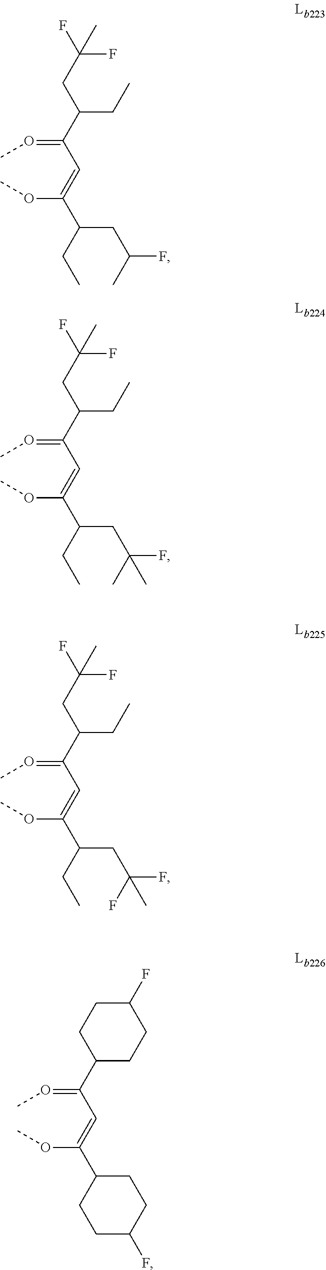 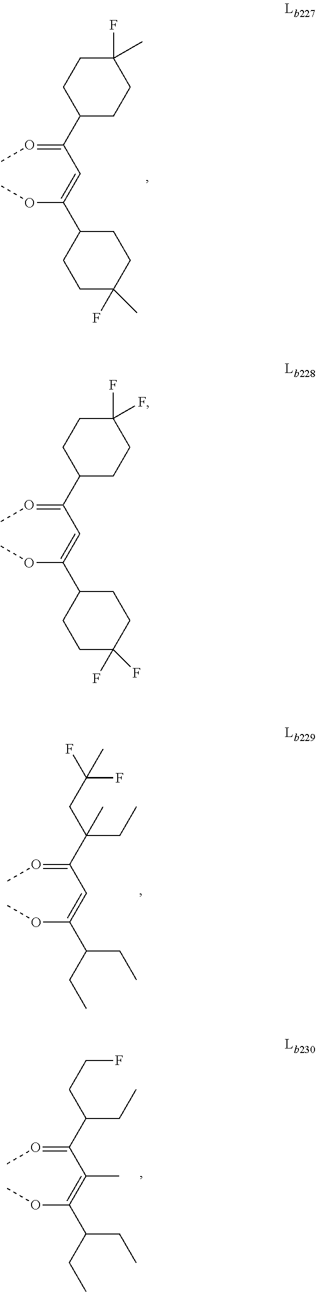 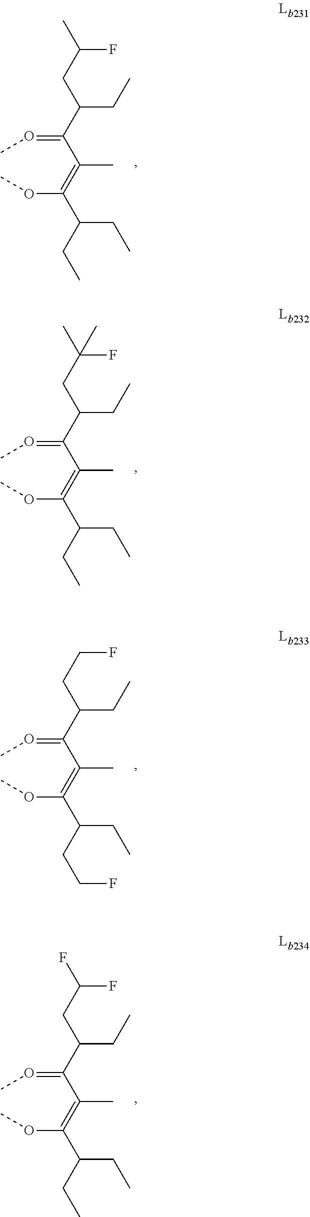 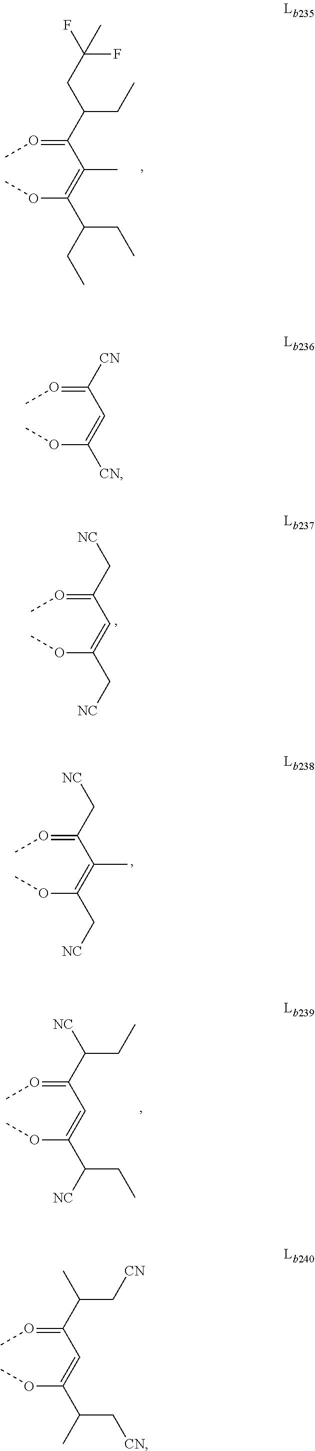 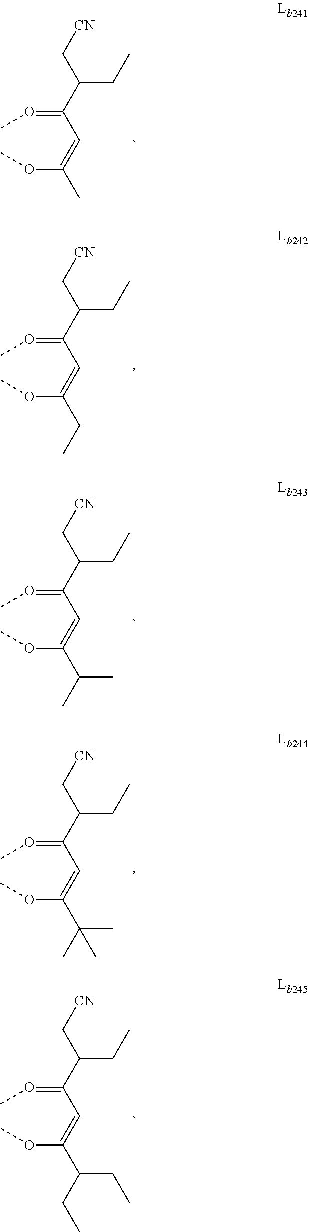 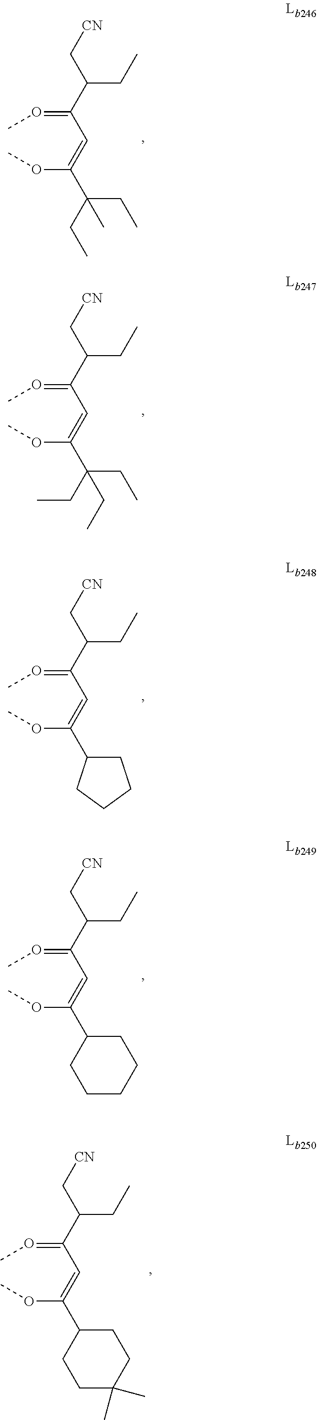 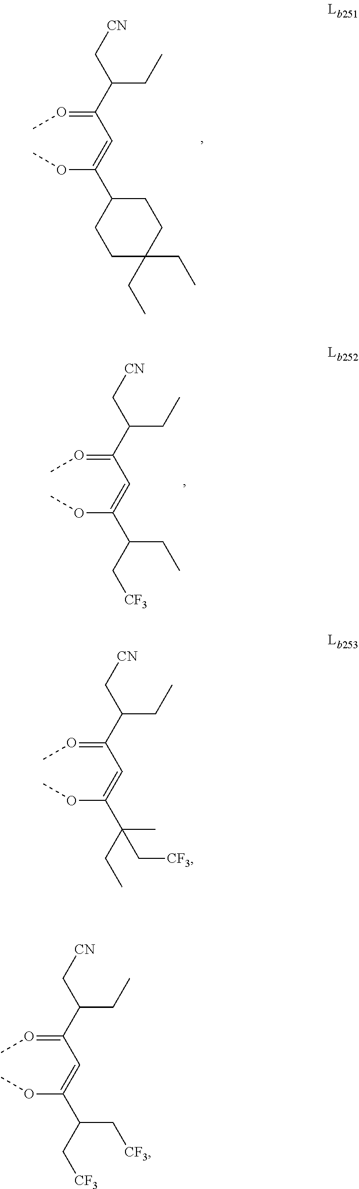 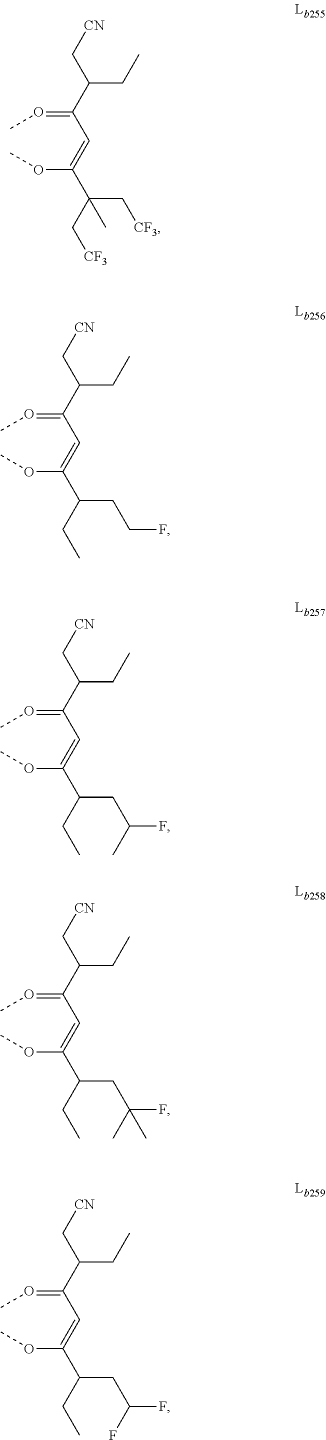 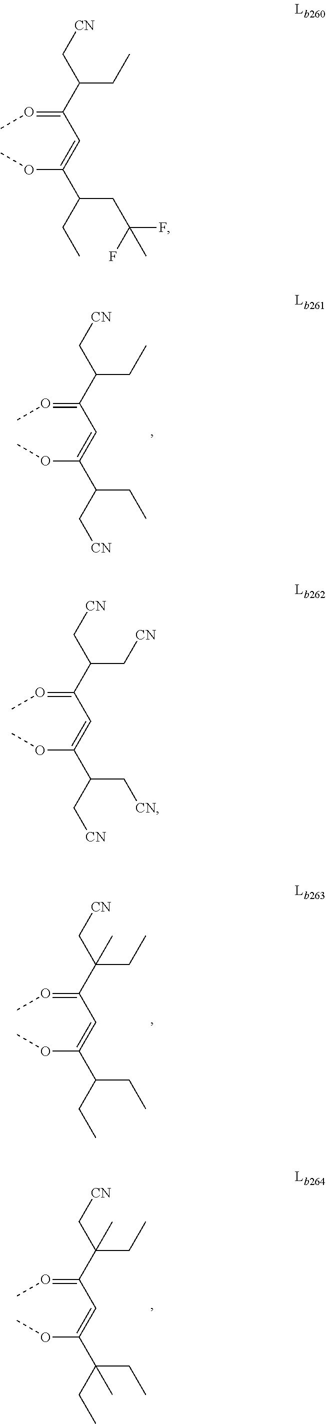 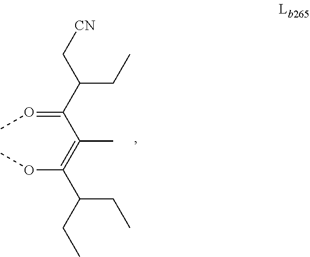 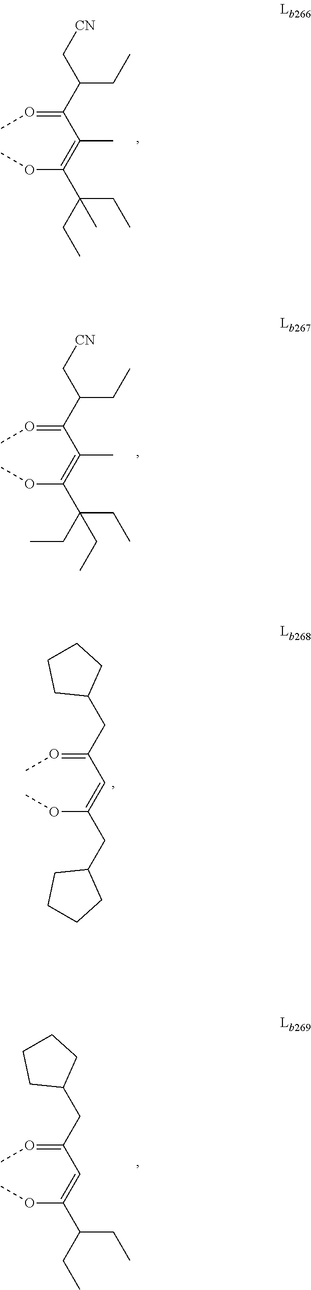 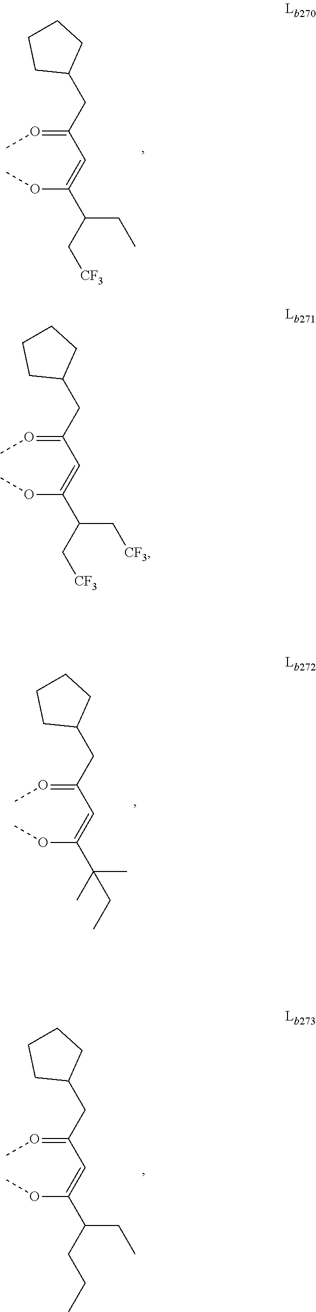 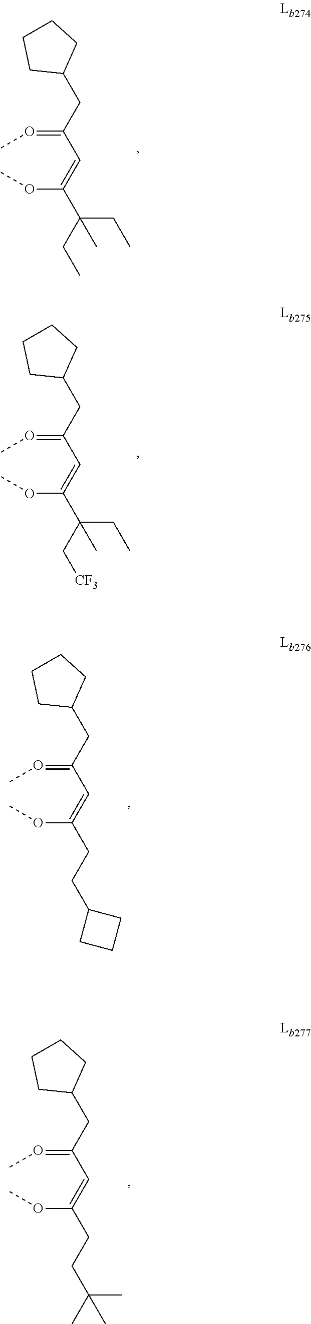 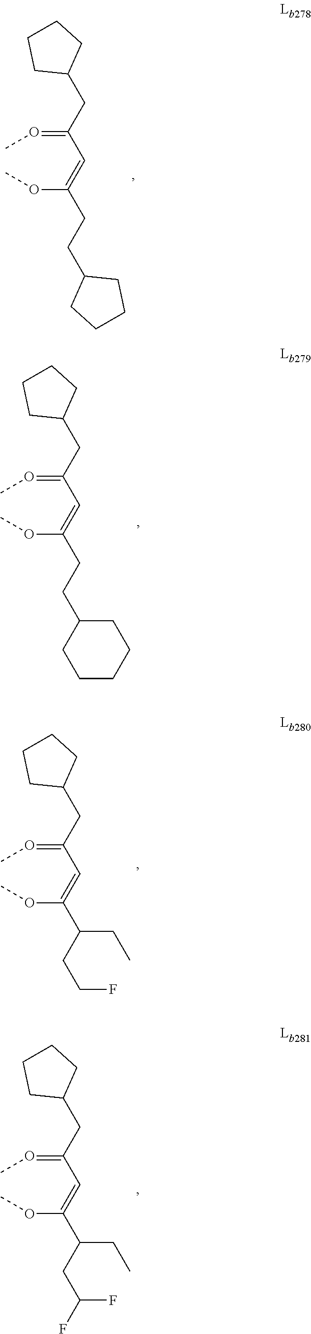 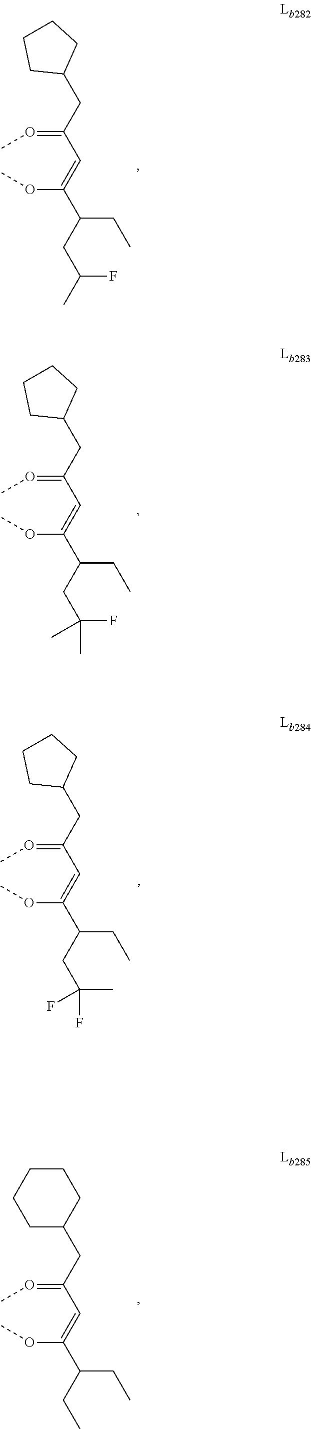 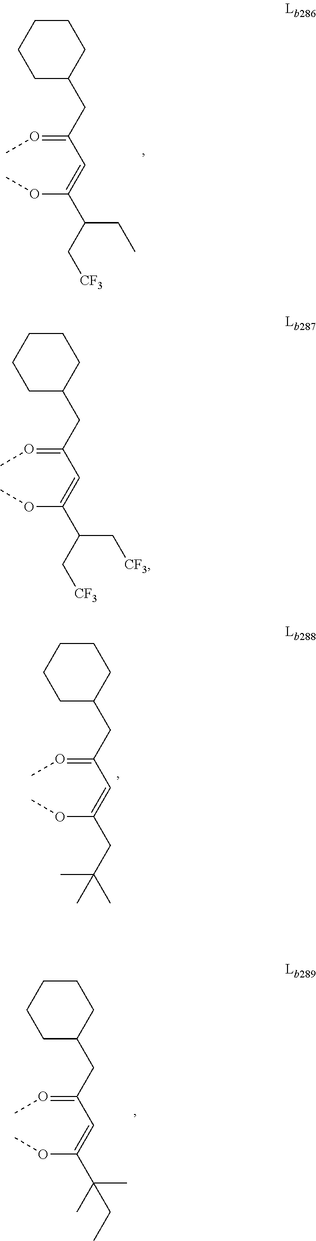 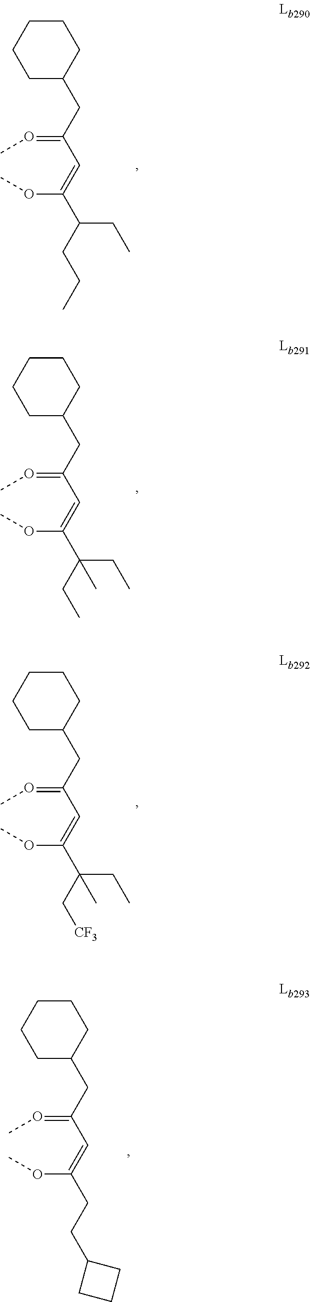 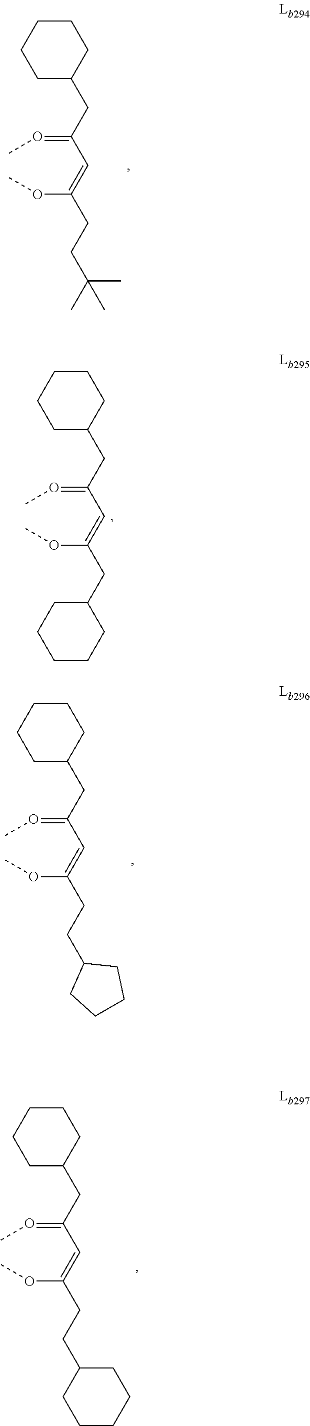 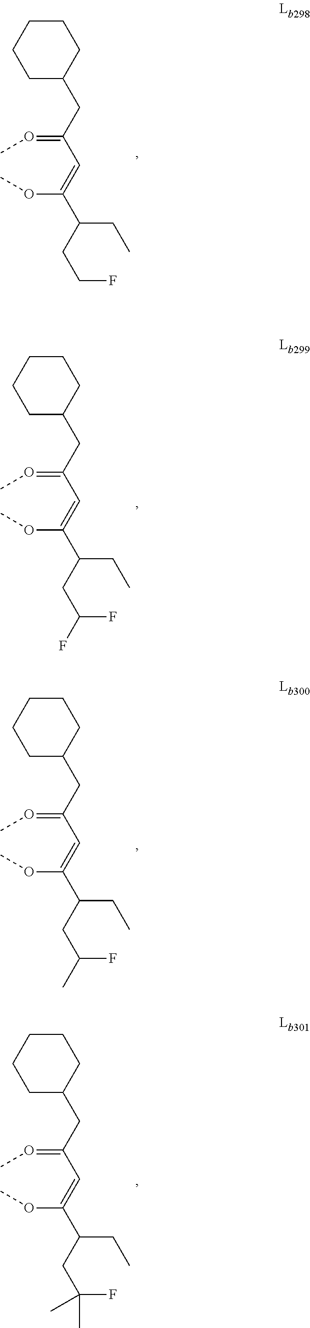 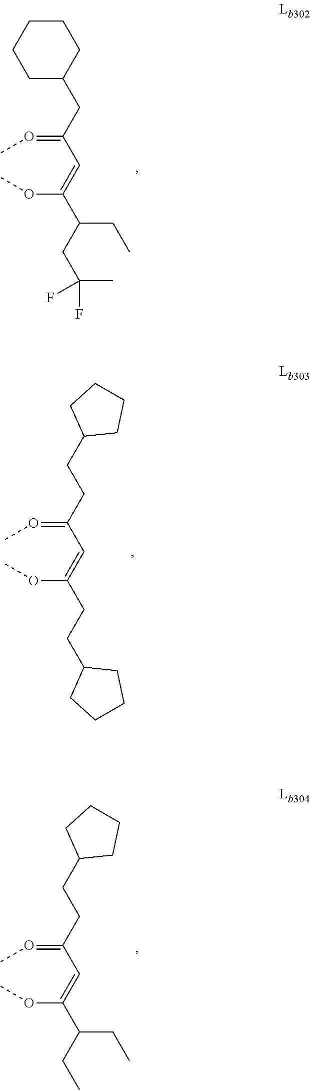 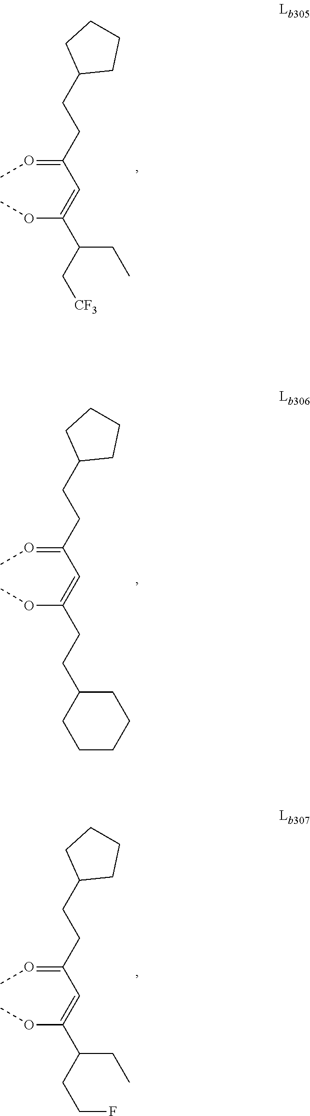 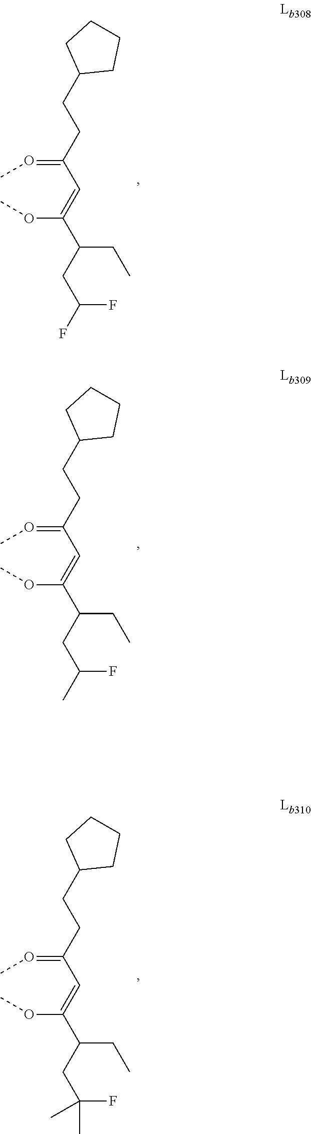 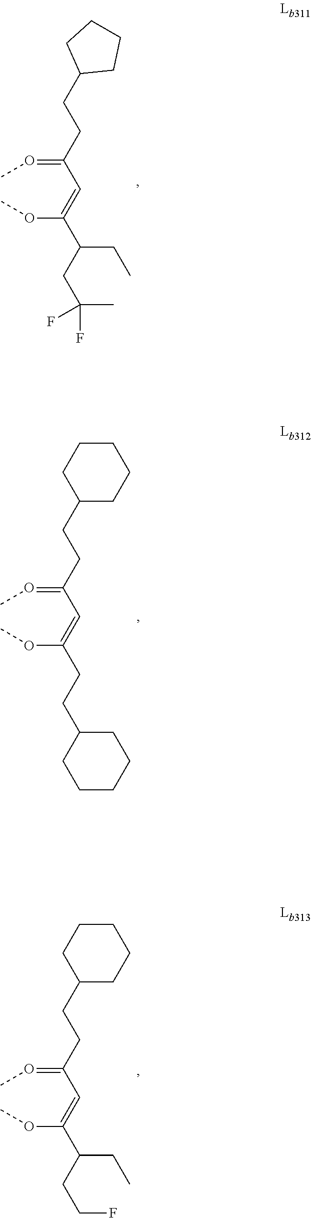 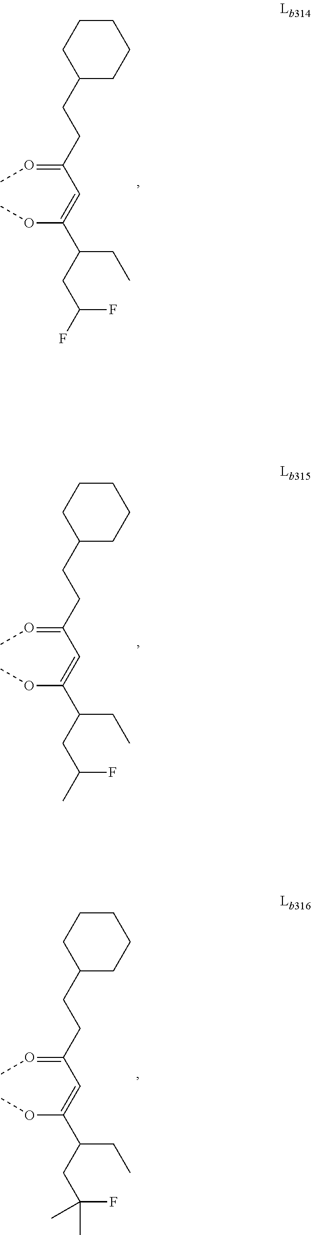 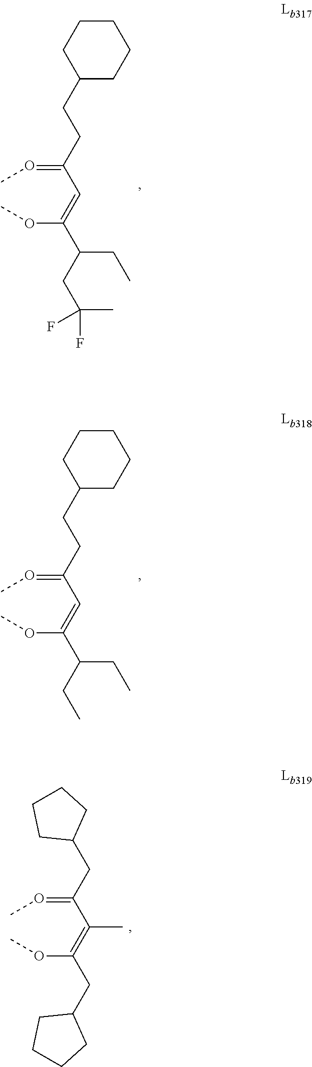 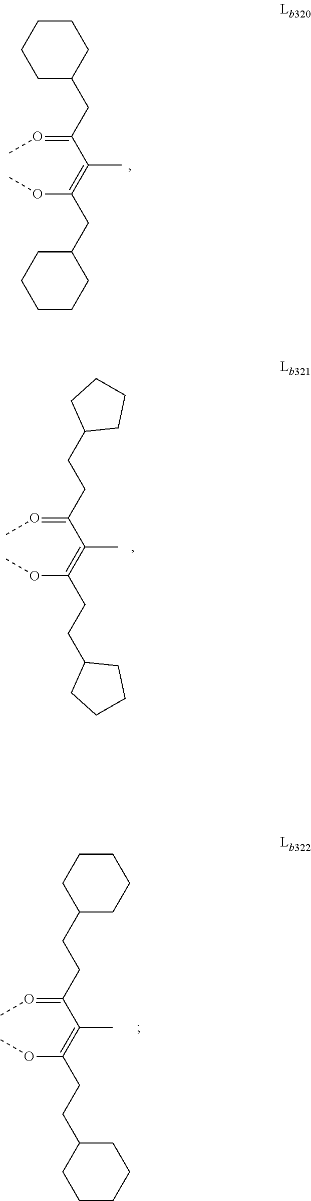
wherein L_{c} is, at each occurrence identically or differently, selected from the group consisting of the following structures:

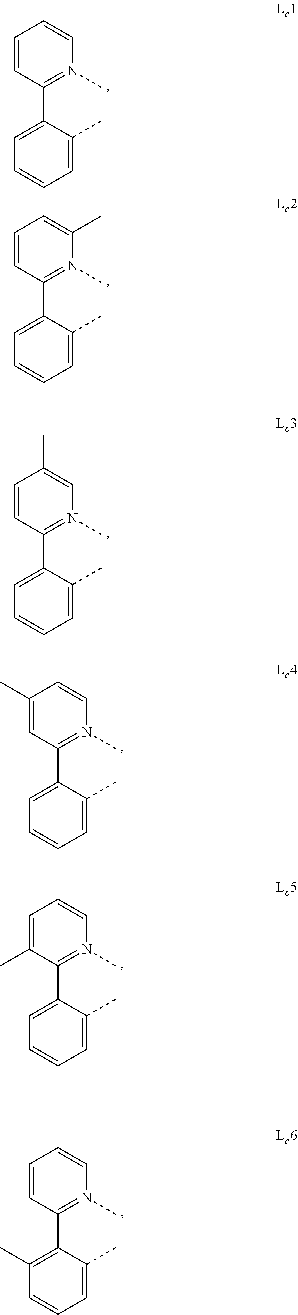

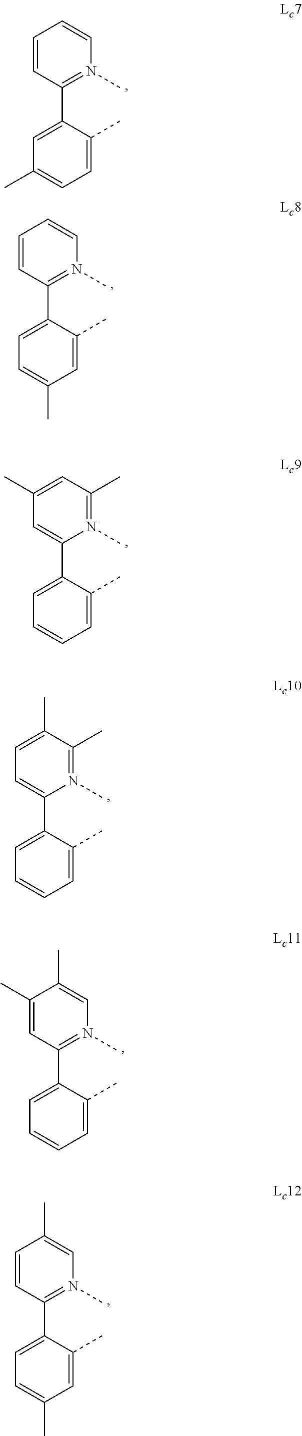

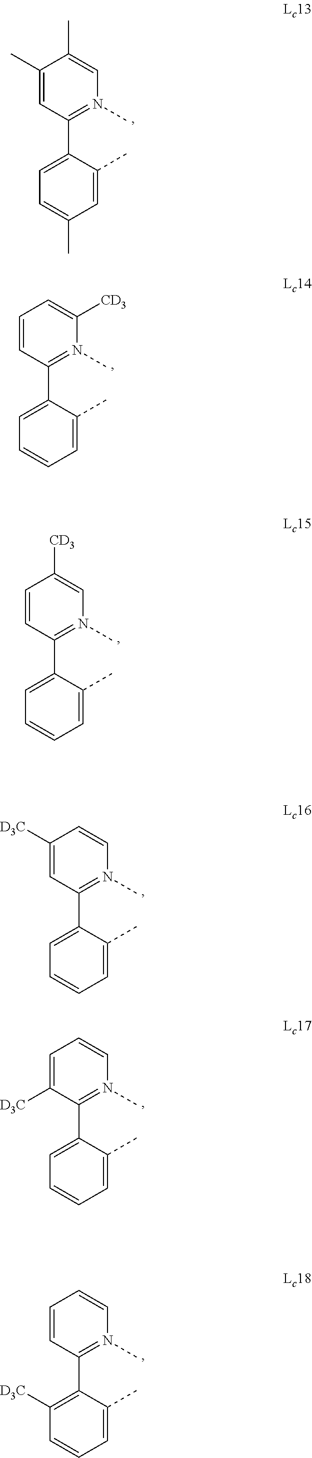

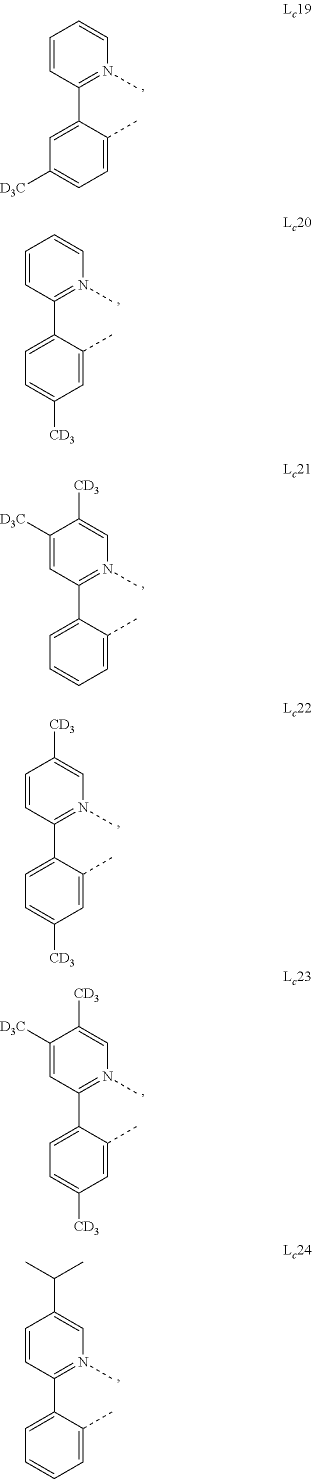

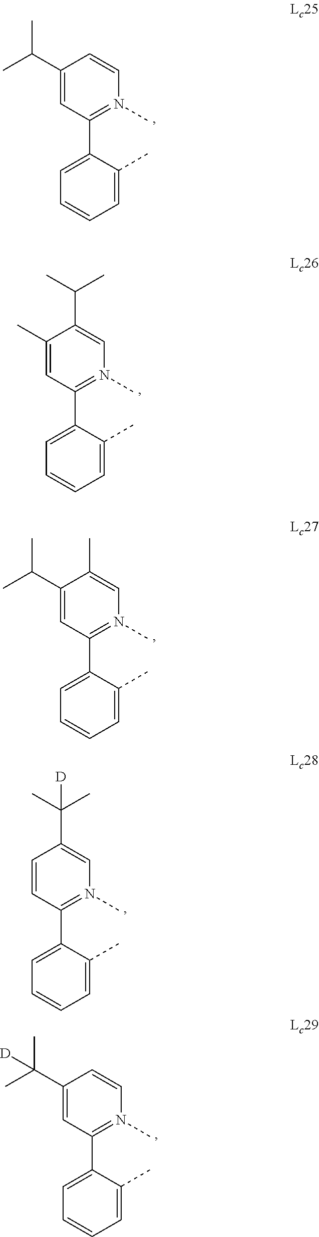

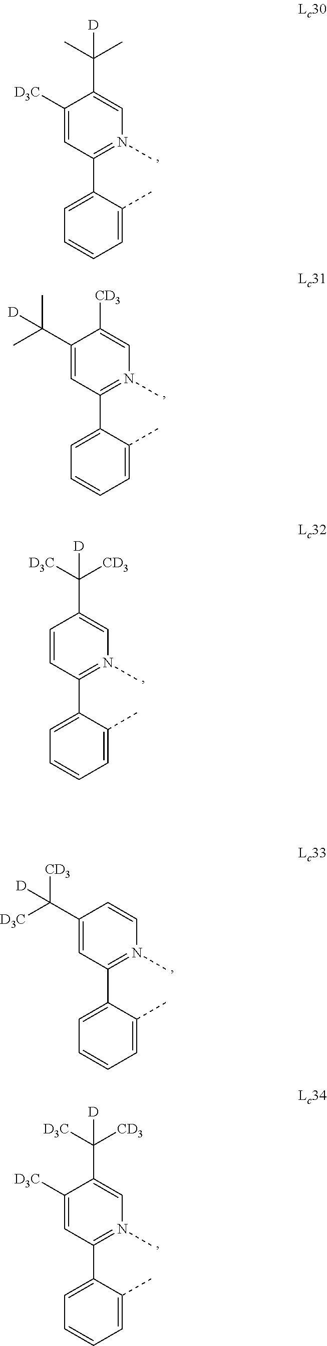

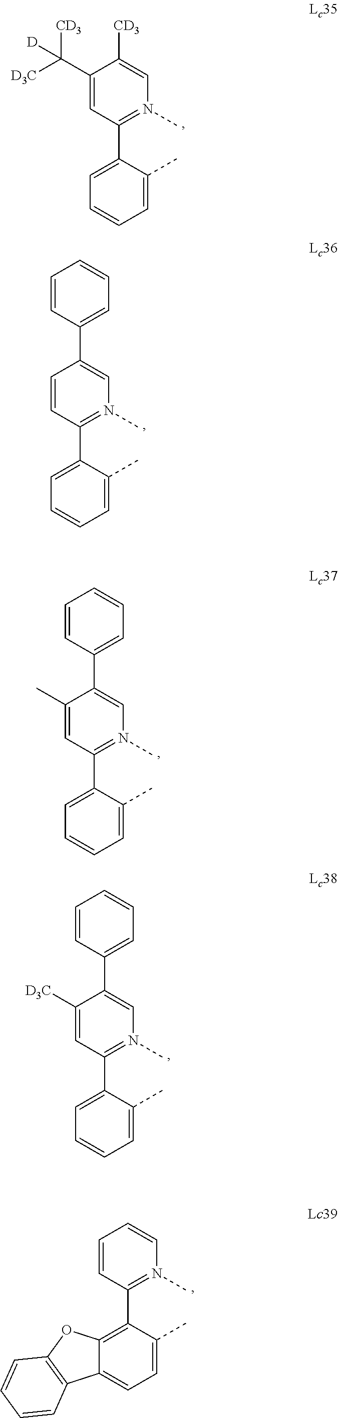

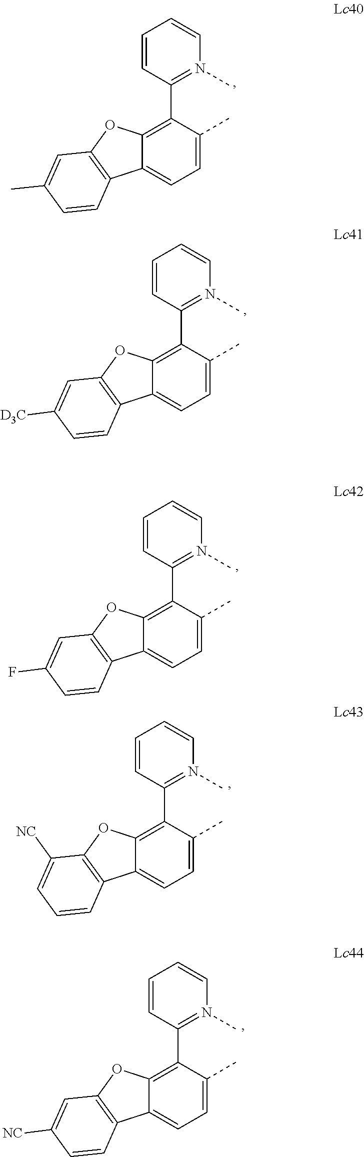

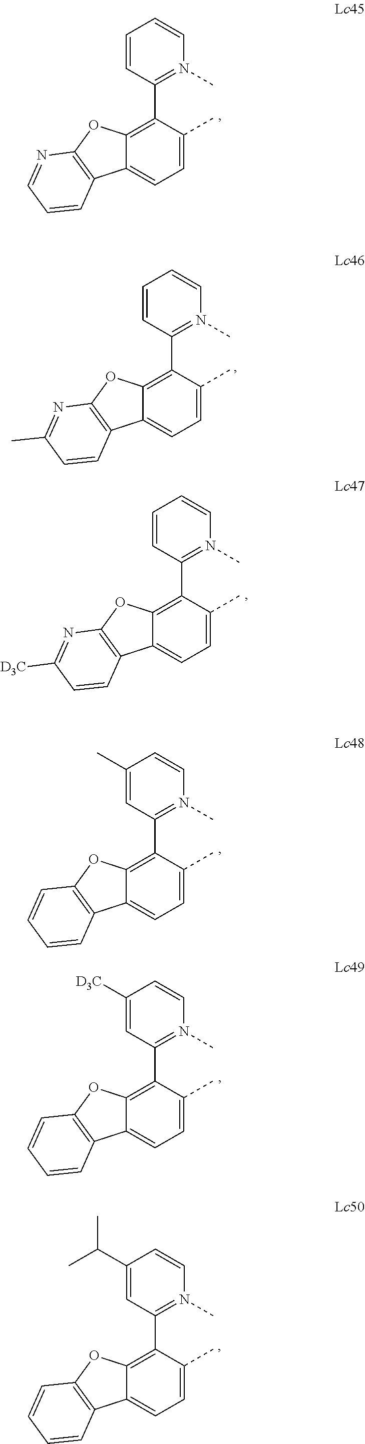

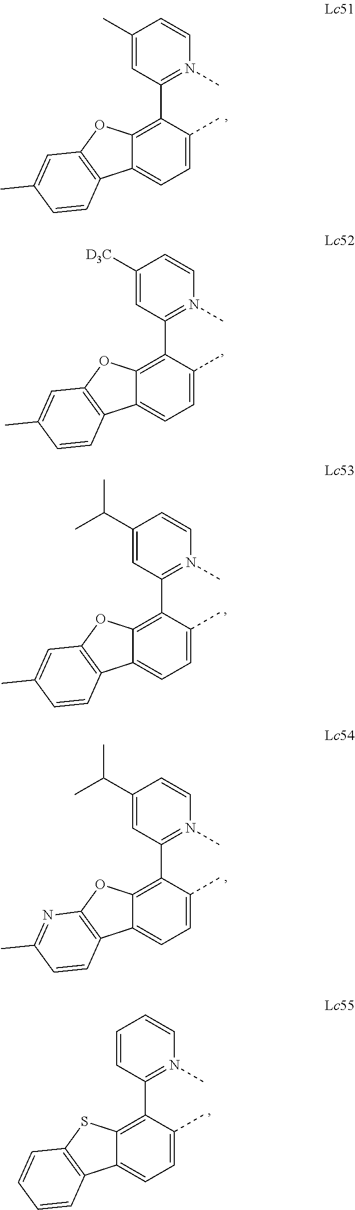

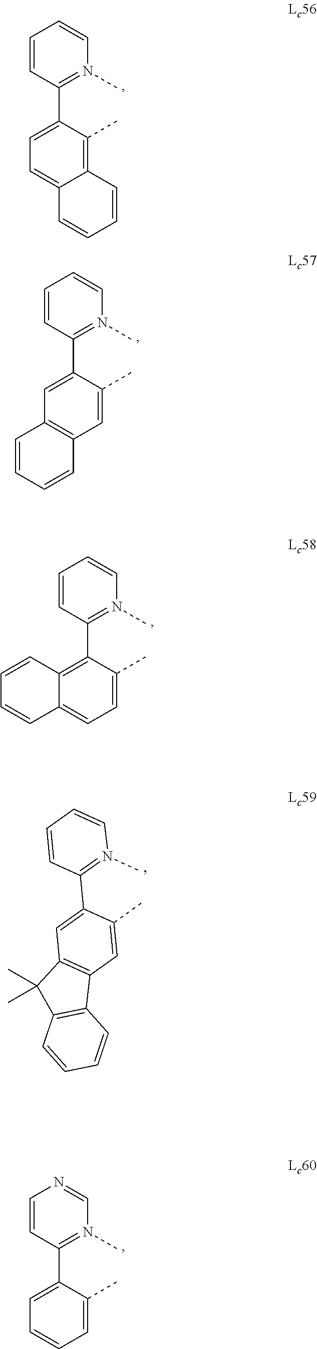

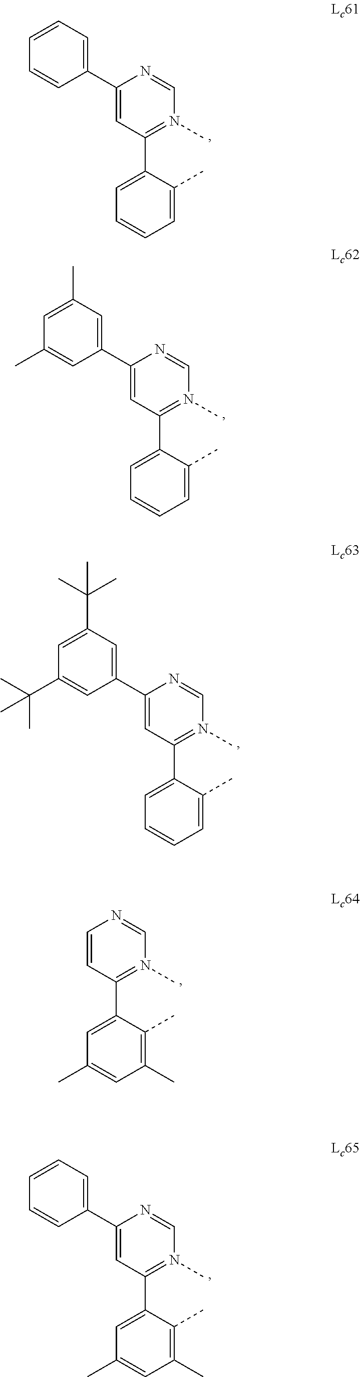

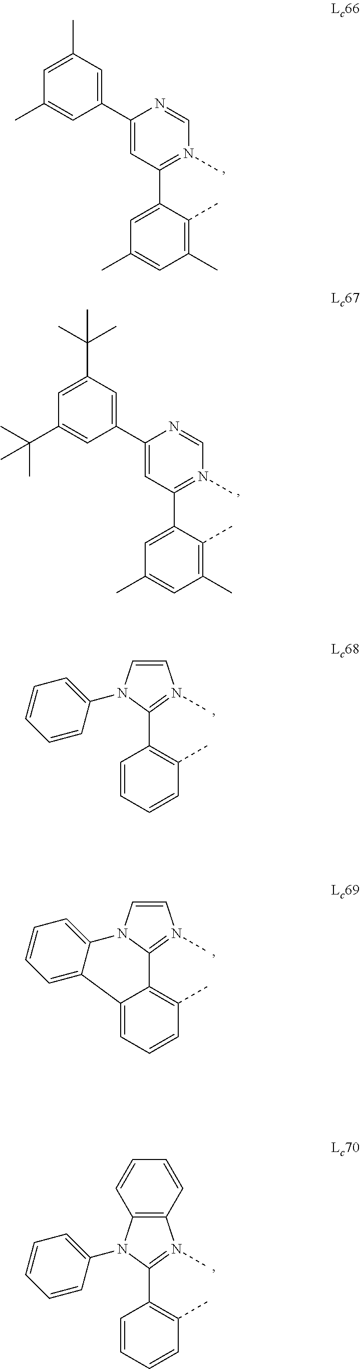

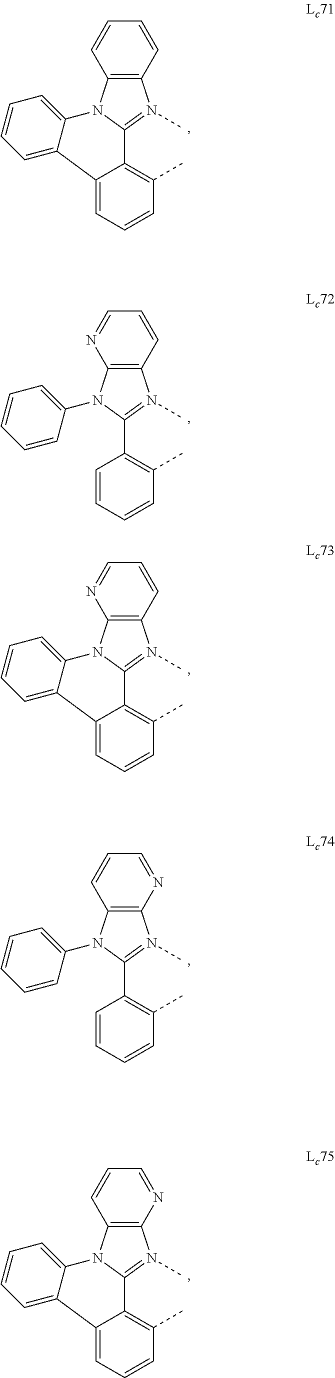

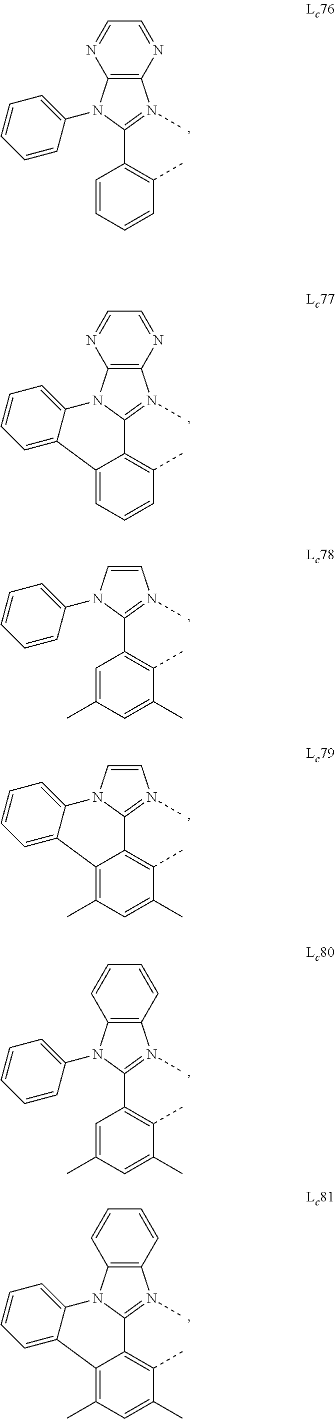

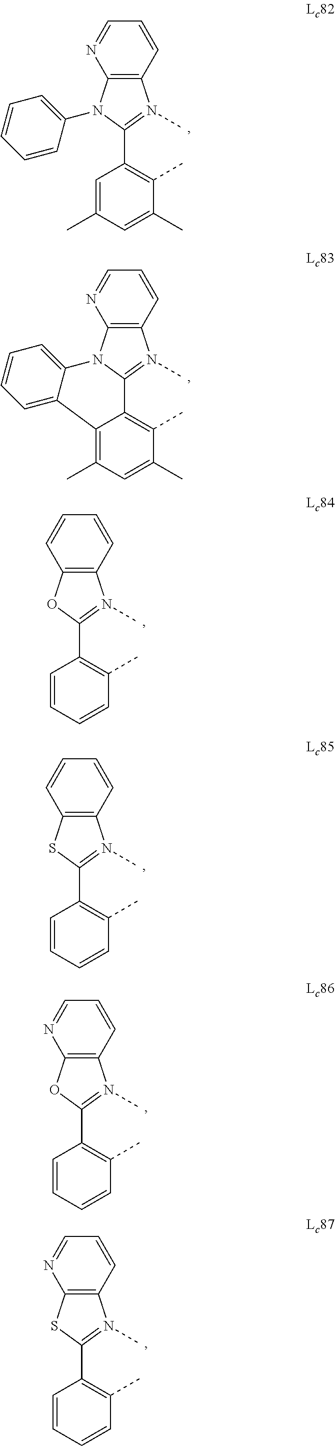

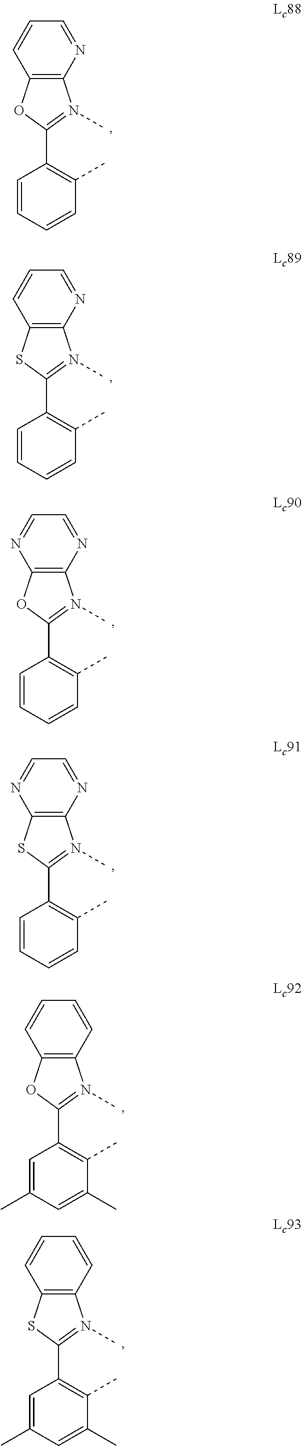

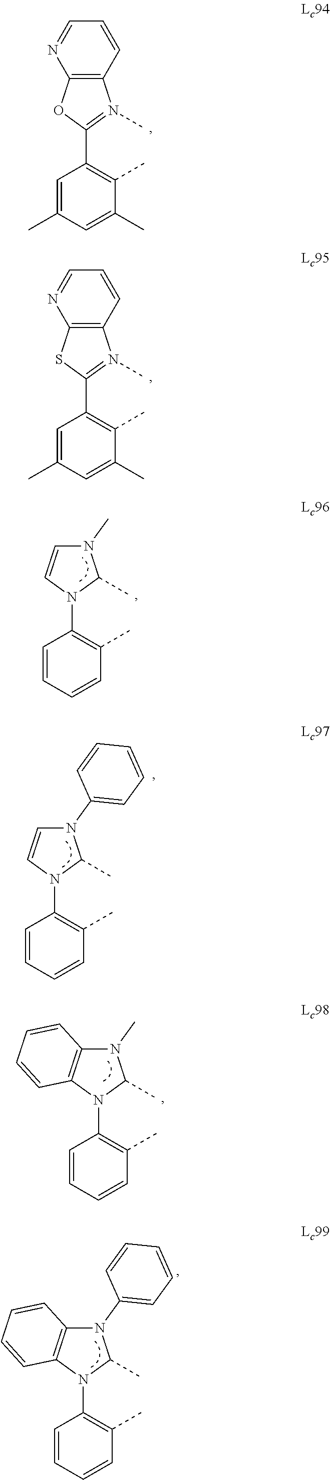

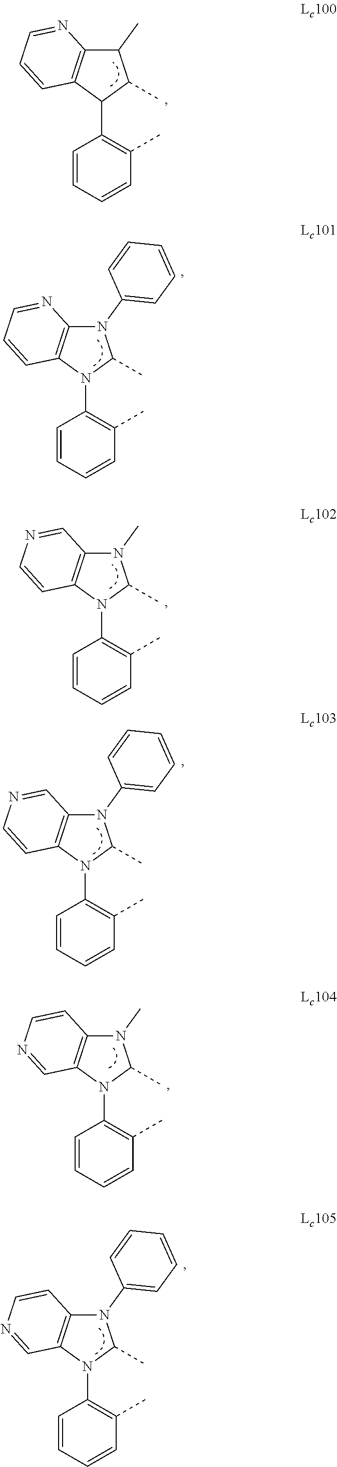

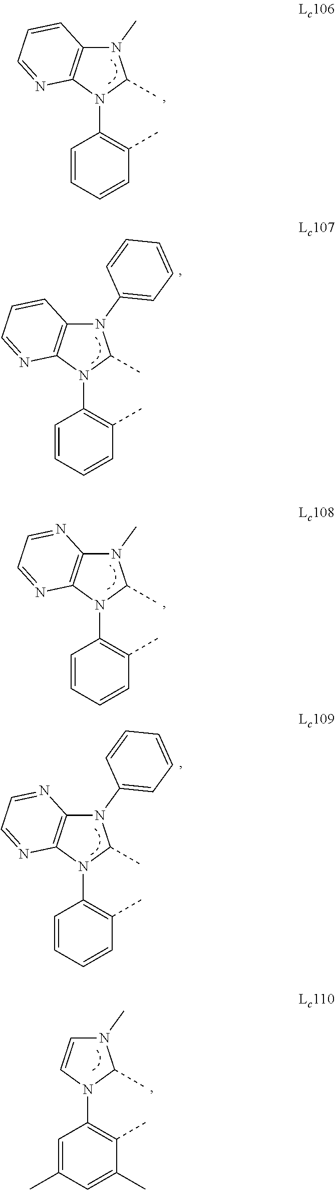

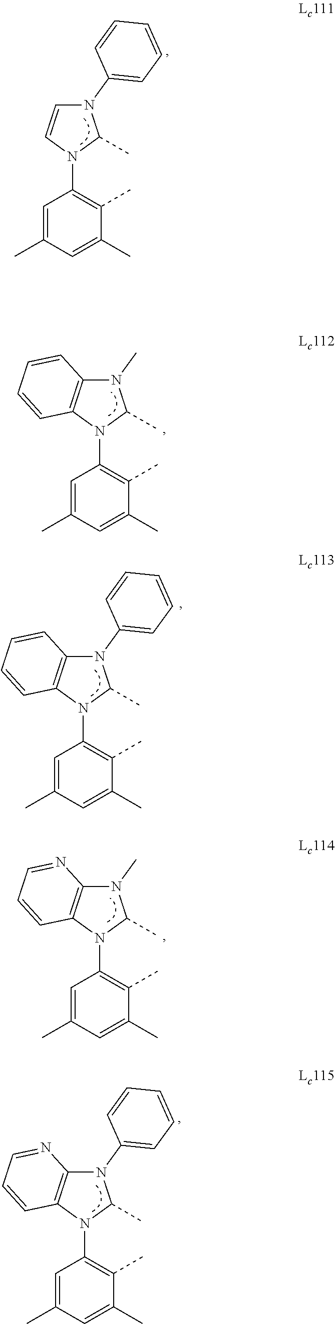

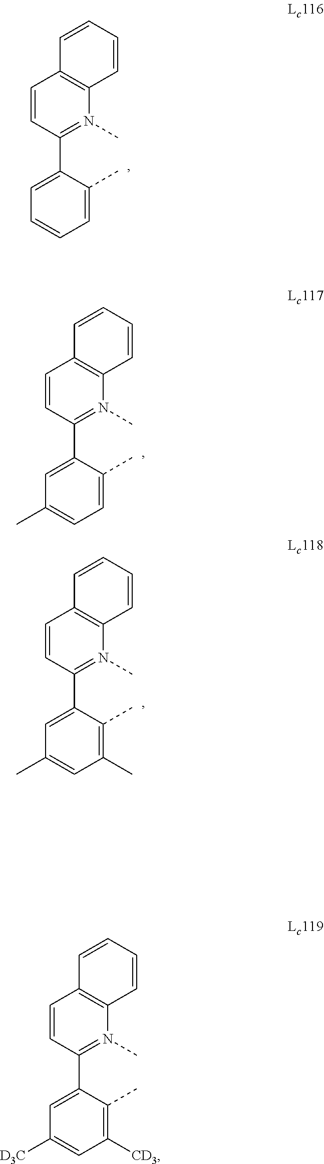

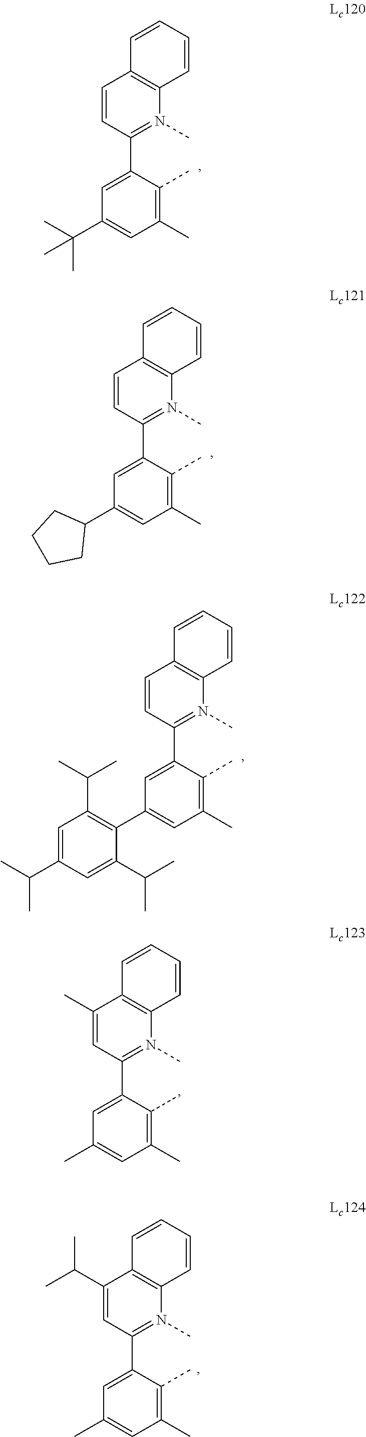

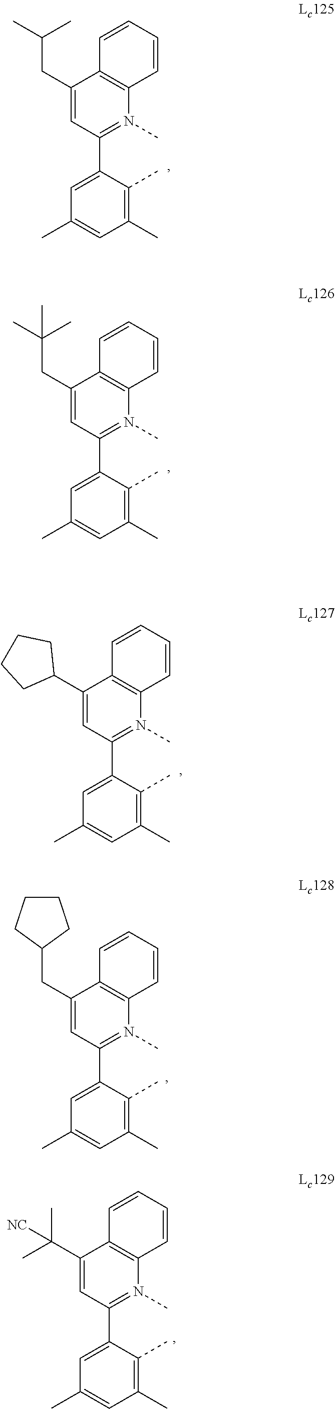

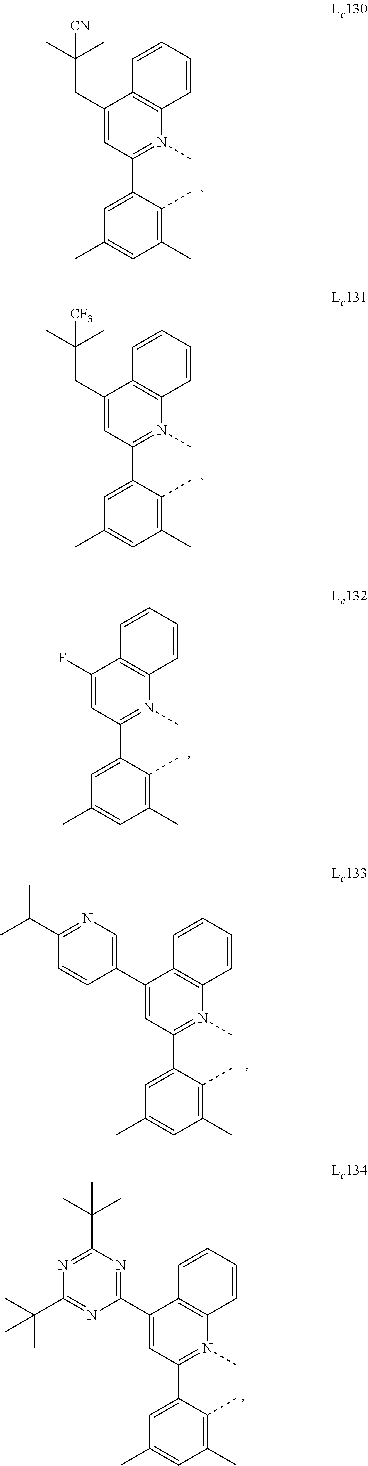

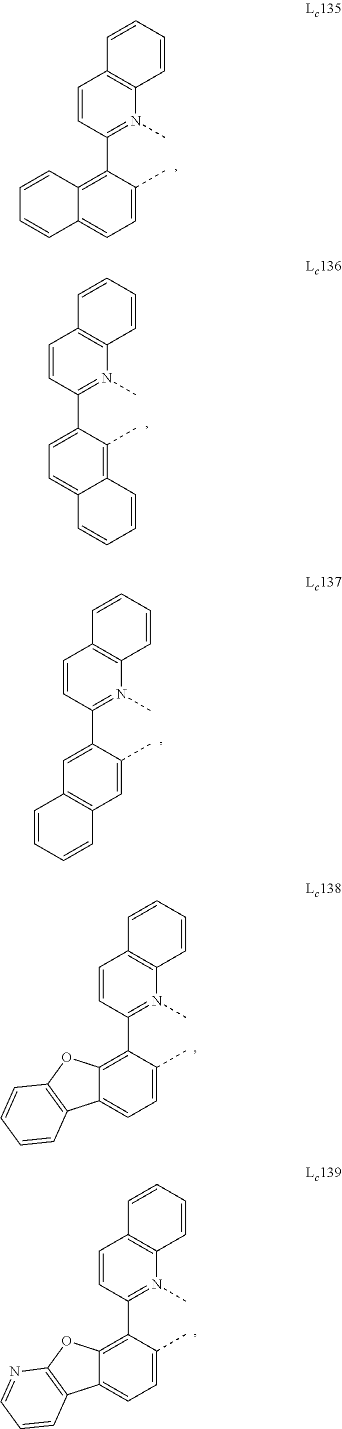

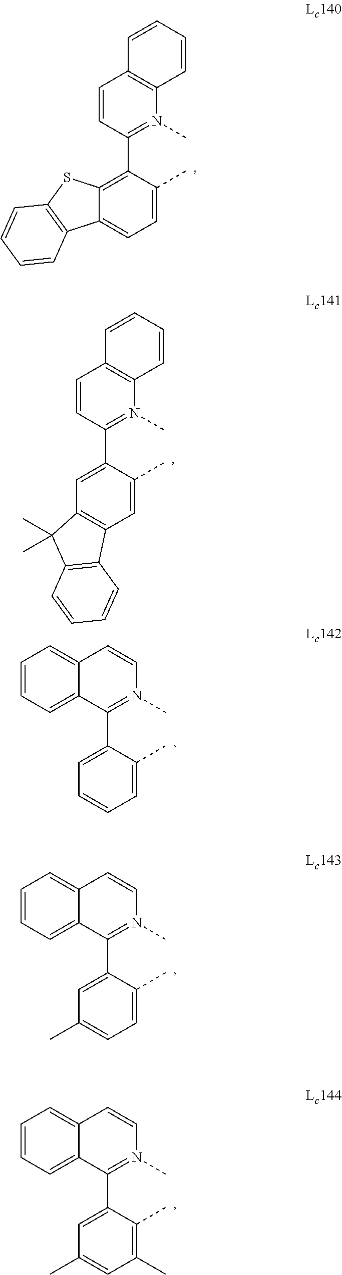

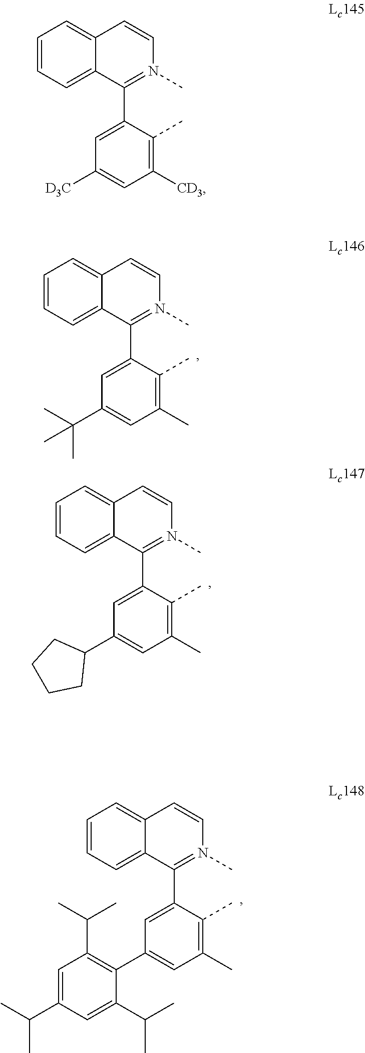

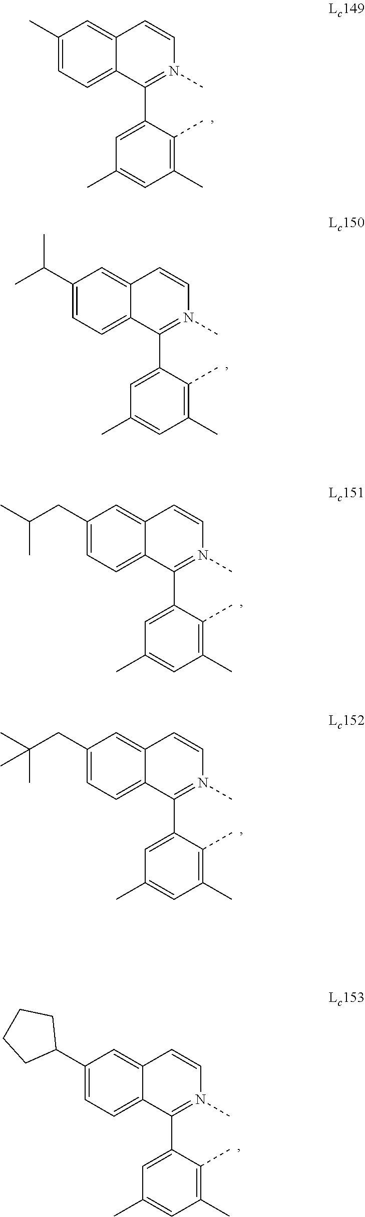

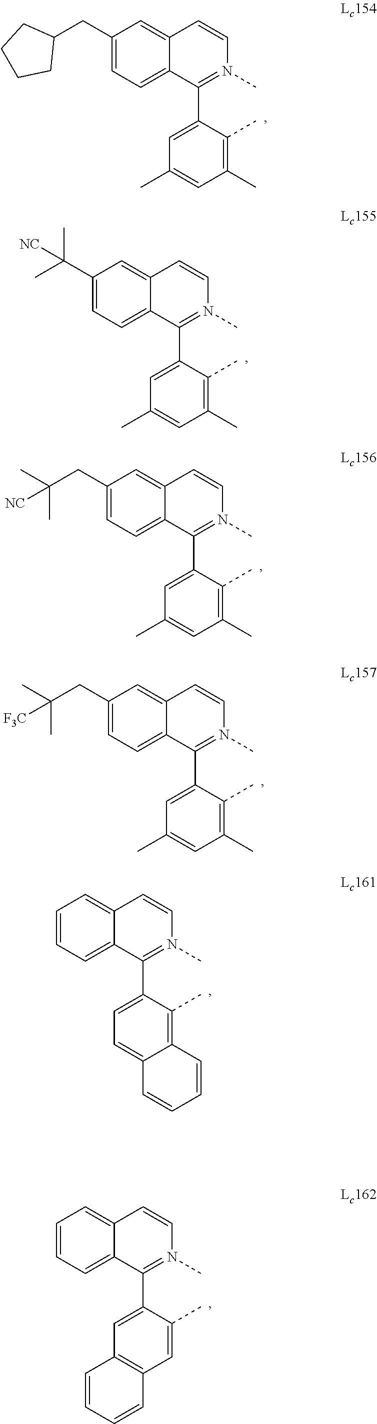

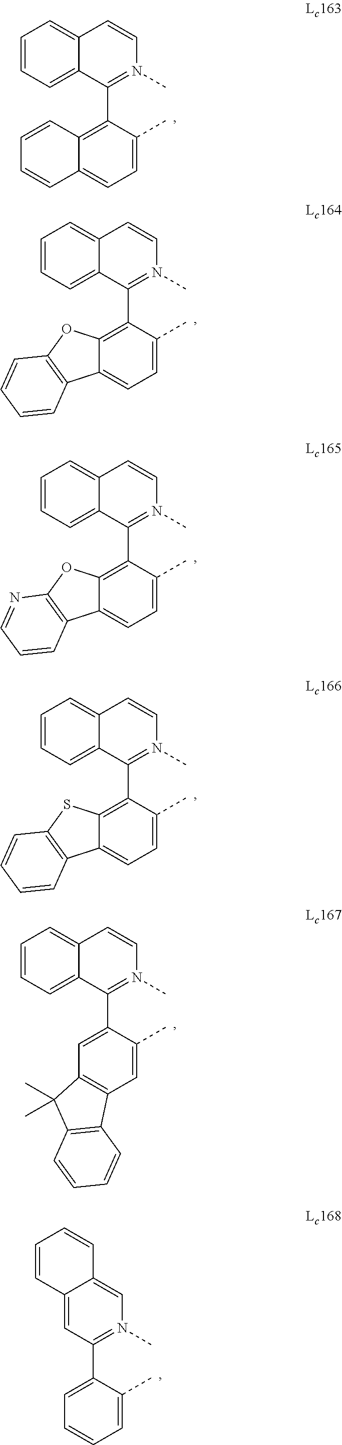

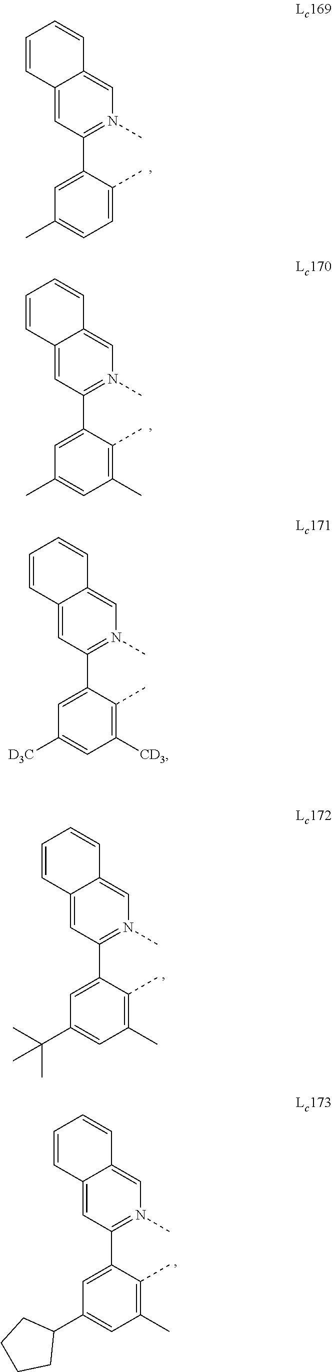

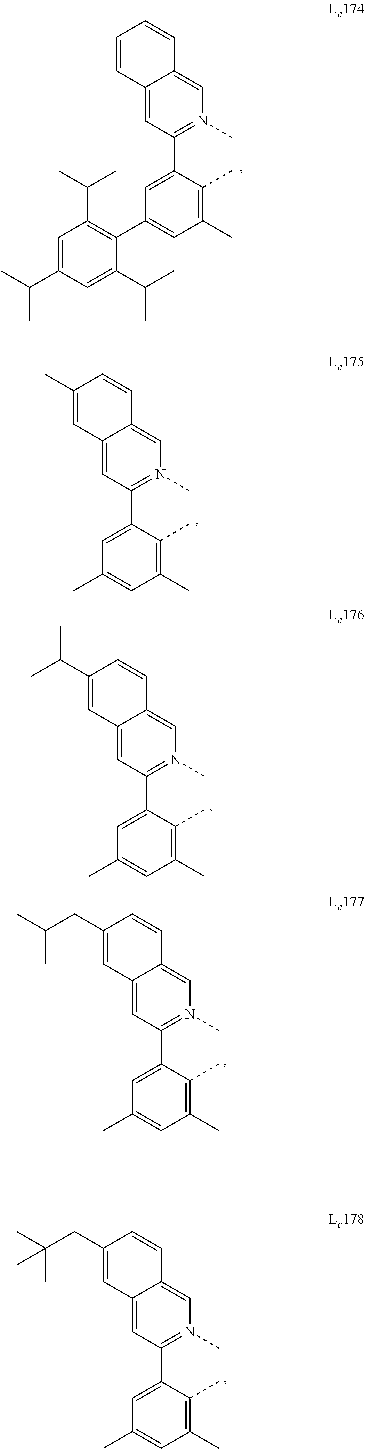

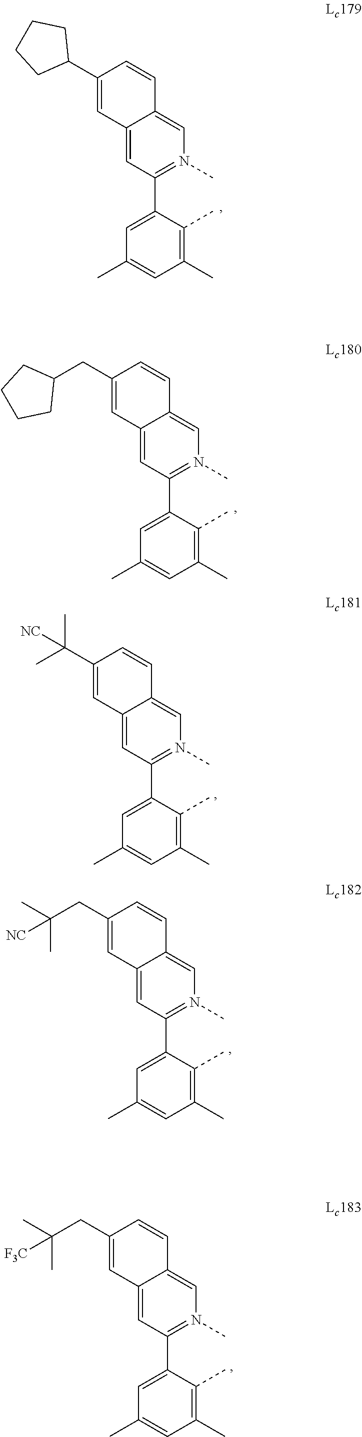

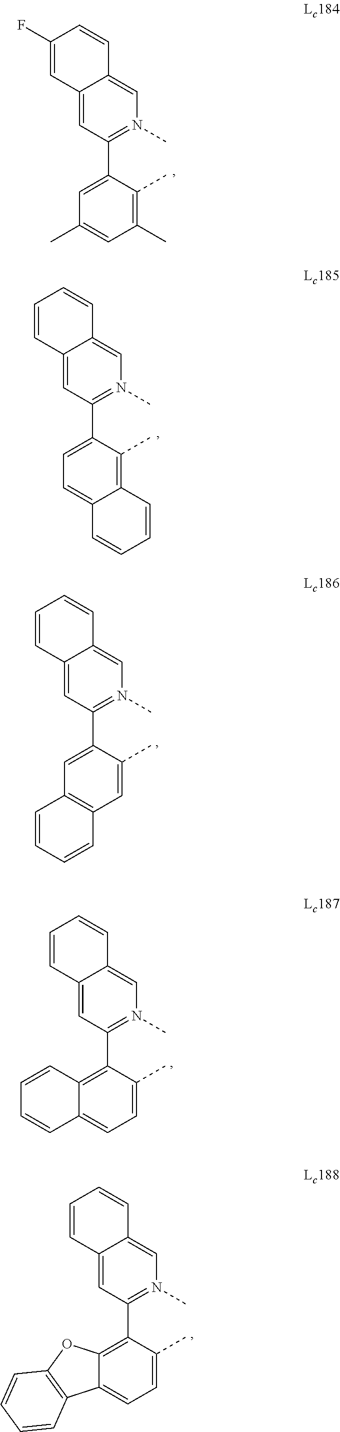

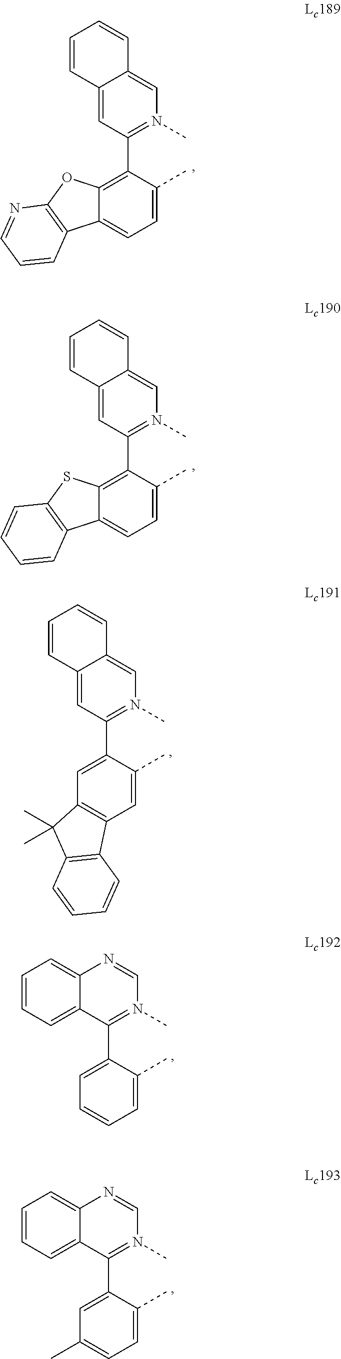

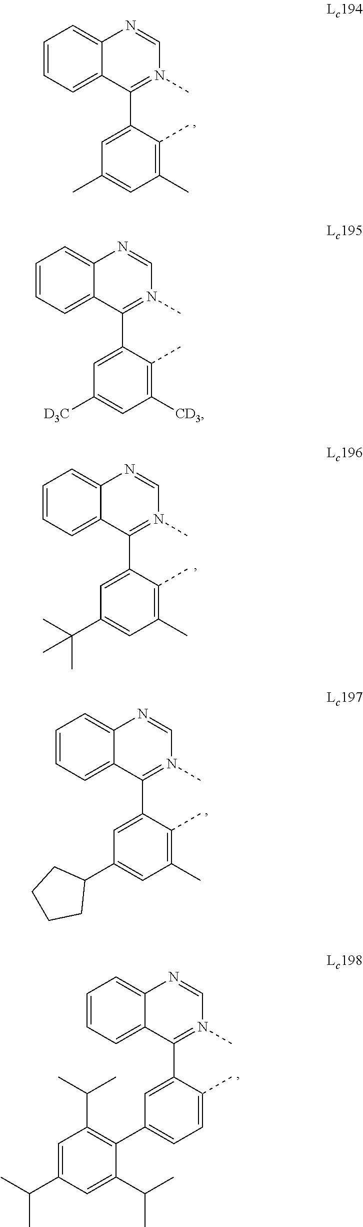

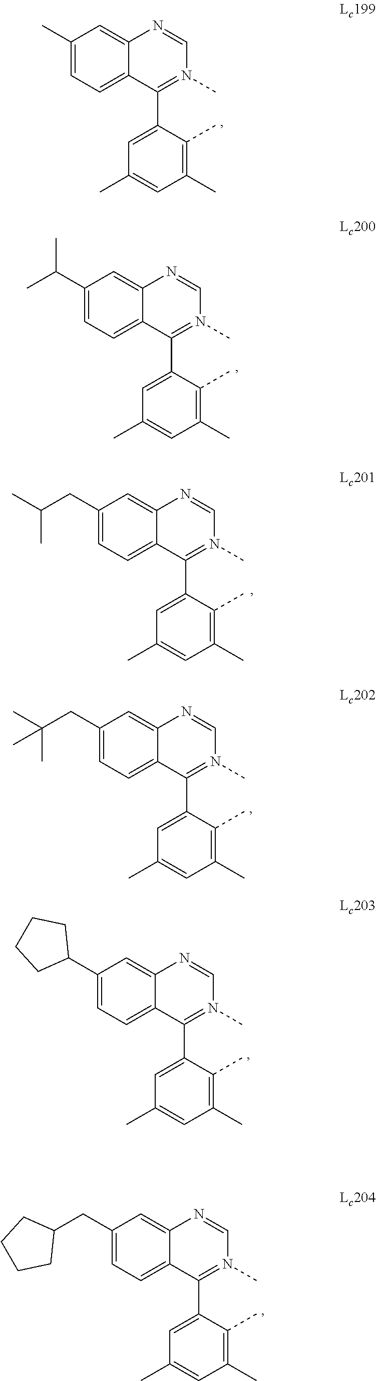

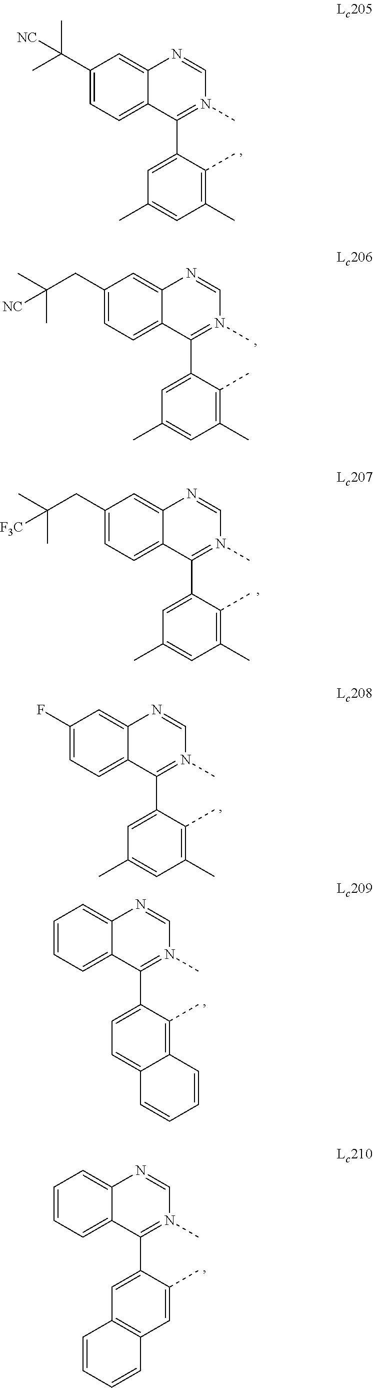

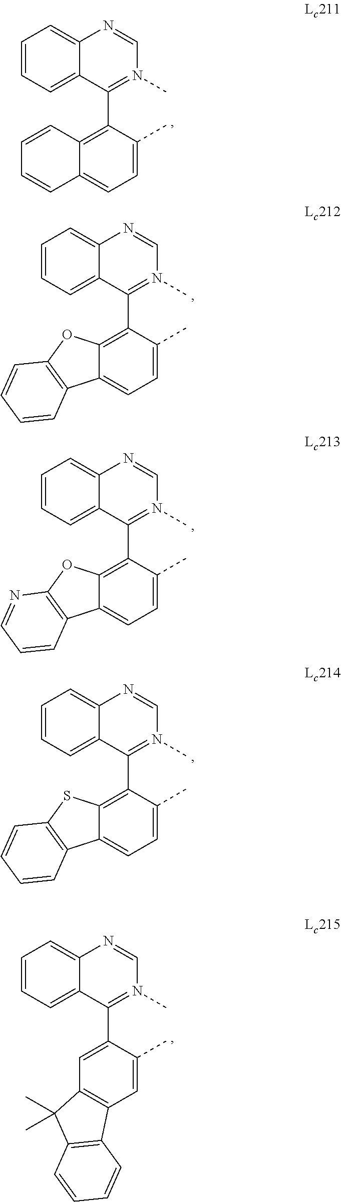

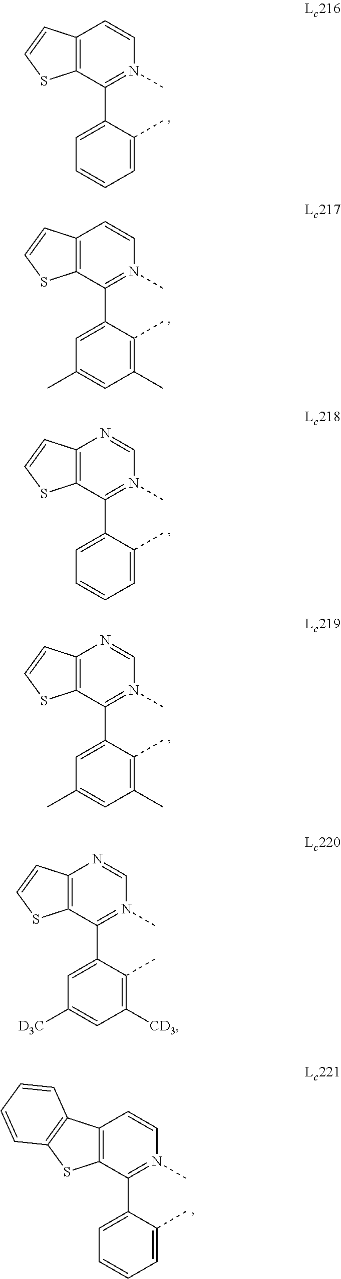

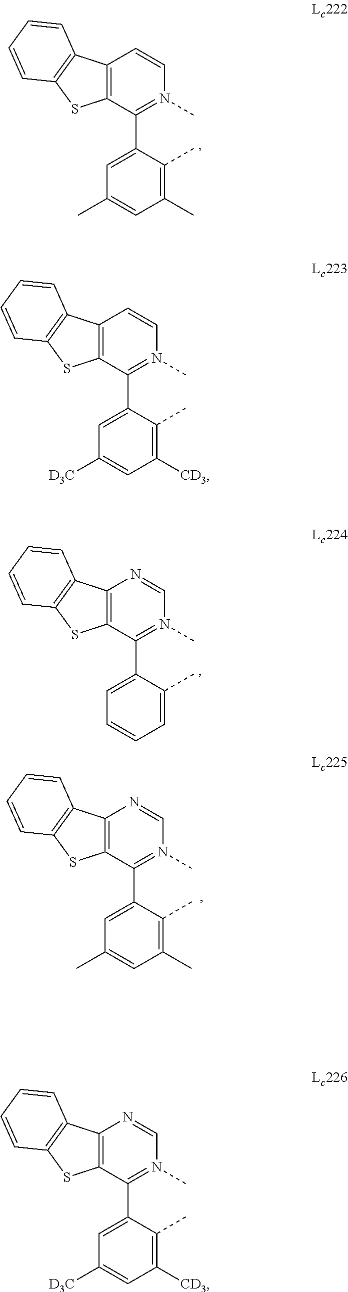

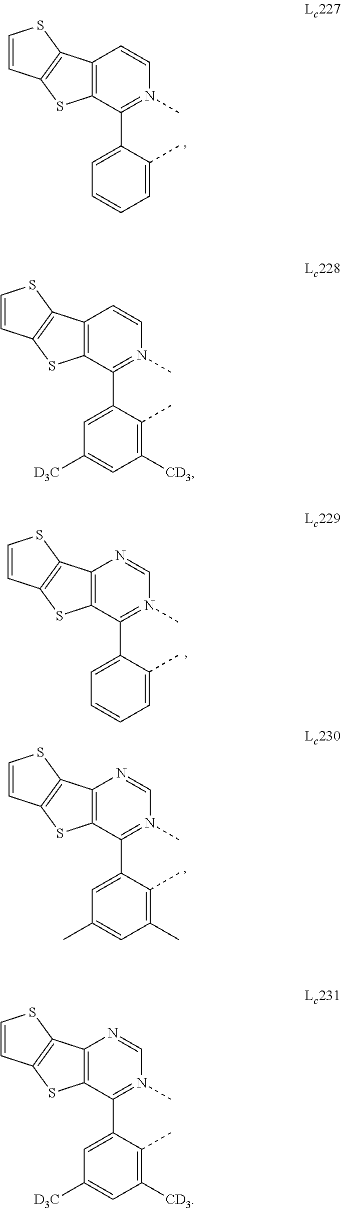

16. The organic electroluminescent device according to claim 15, wherein the first compound has a structure of Ir(Lₐ)₂(L_{b}) or Ir(Lₐ)₂(L_{c}) or Ir(Lₐ)(L_{c})₂;
wherein when the first compound has a structure of Ir(Lₐ)₂(L_{b}), Lₐ is, at each occurrence identically or differently, selected from any one or any two of the group consisting of Lₐ₁ to Lₐ₃₁₉ and L_{b} is selected from any one of the group consisting of L_{b1} to L_{b322}; when the first compound has a structure of Ir(Lₐ)₂(L_{c}), Lₐ is, at each occurrence identically or differently, selected from any one or any two of the group consisting of Lₐ₁ to Lₐ₃₁₉ and L_{c} is selected from any one of the group consisting of L_{c1} to L_{c231}; and when the first compound has a structure of Ir(Lₐ)(L_{c})₂, Lₐ is selected from any one of the group consisting of Lₐ₁ to Lₐ₃₁₉ and L_{c} is, at each occurrence identically or differently, selected from any one or any two of the group consisting of L_{c1} to L_{c231};
preferably, the first compound is selected from the group consisting of Compound C₁ to Compound C₁₃₉ and Compound RD-1 to Compound RD-90:

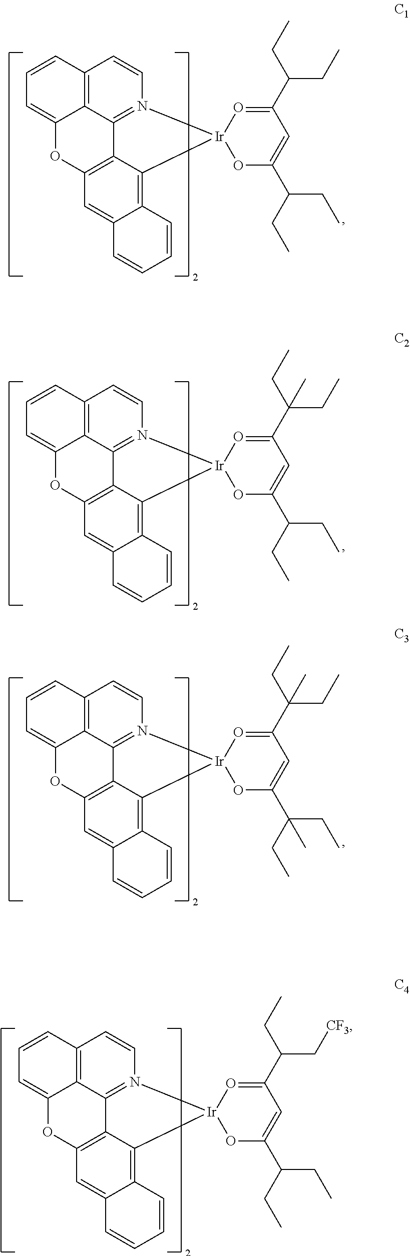

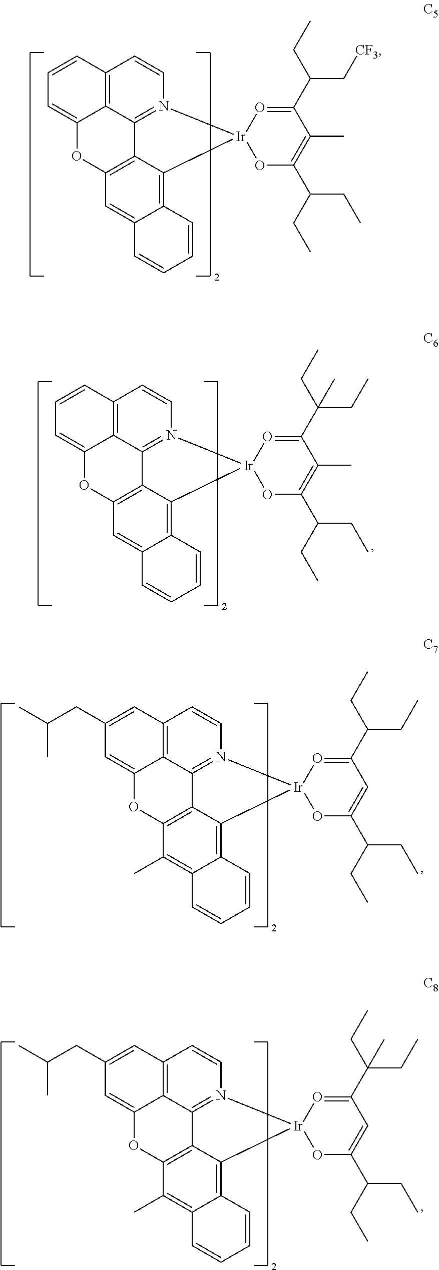

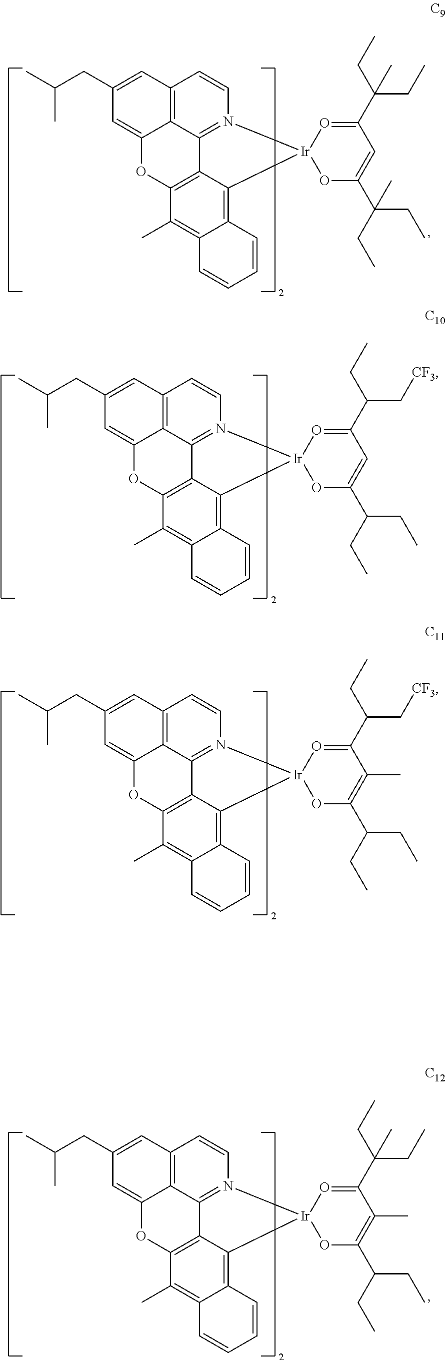

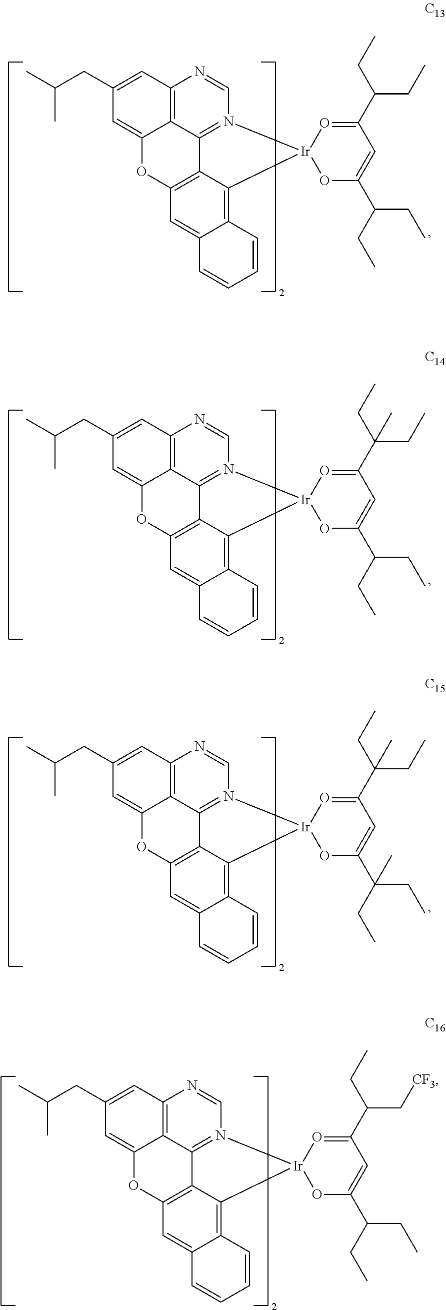

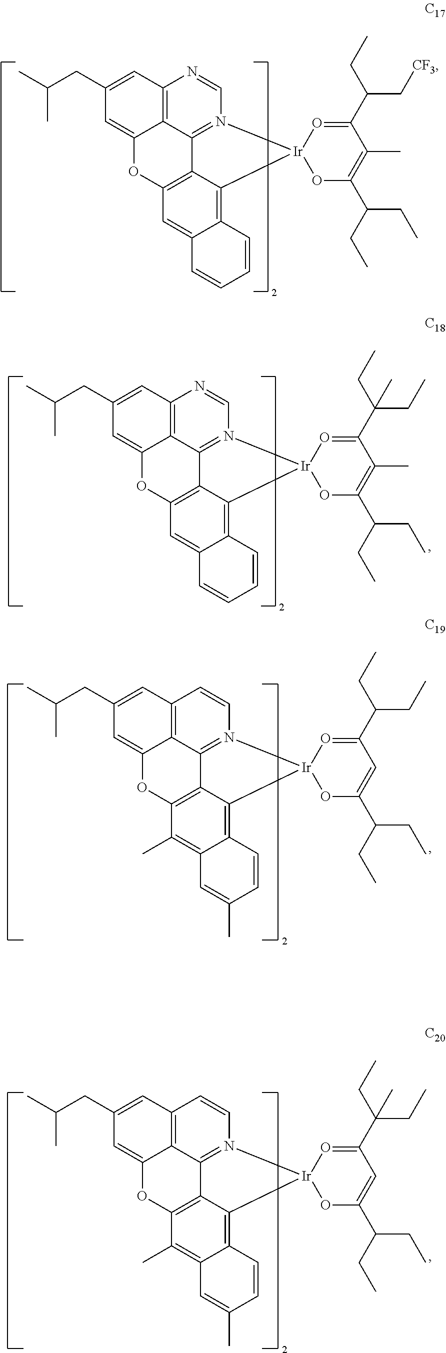

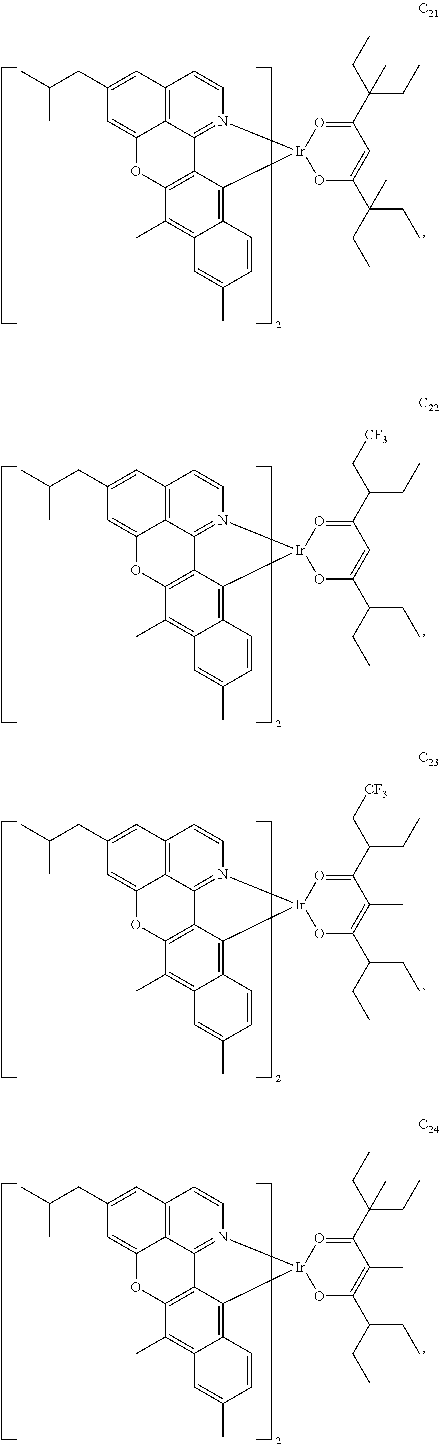

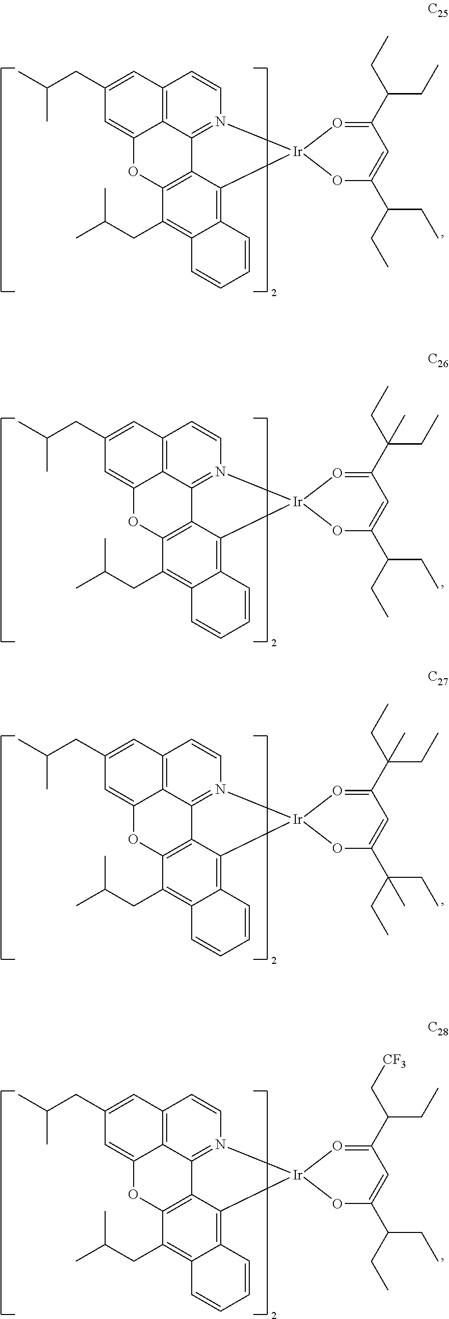

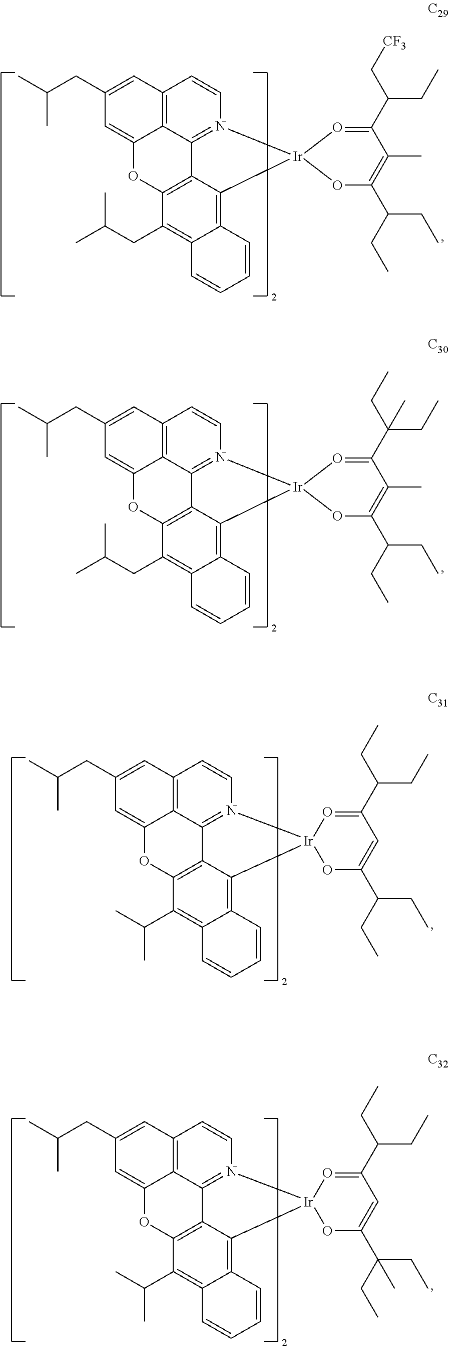

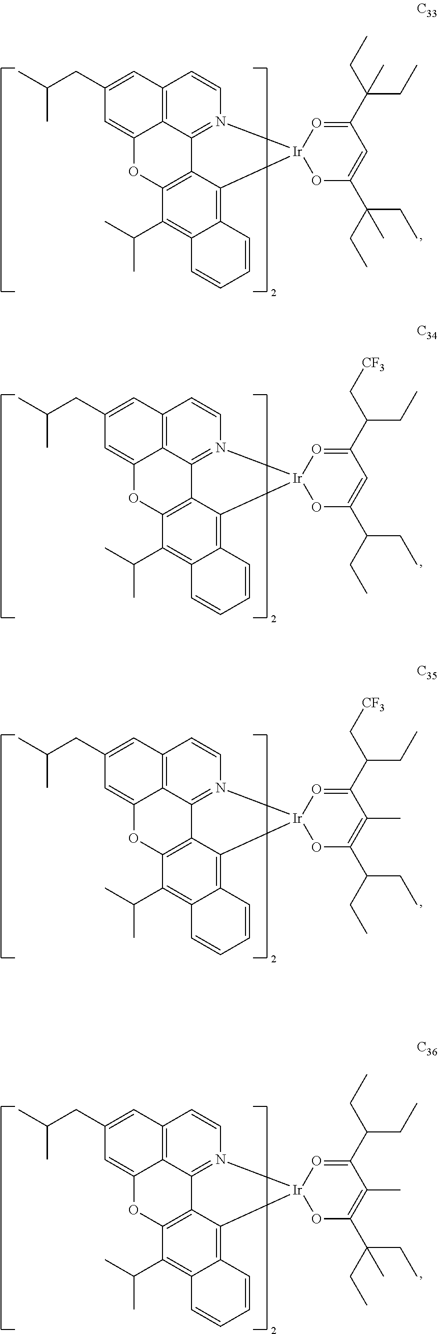

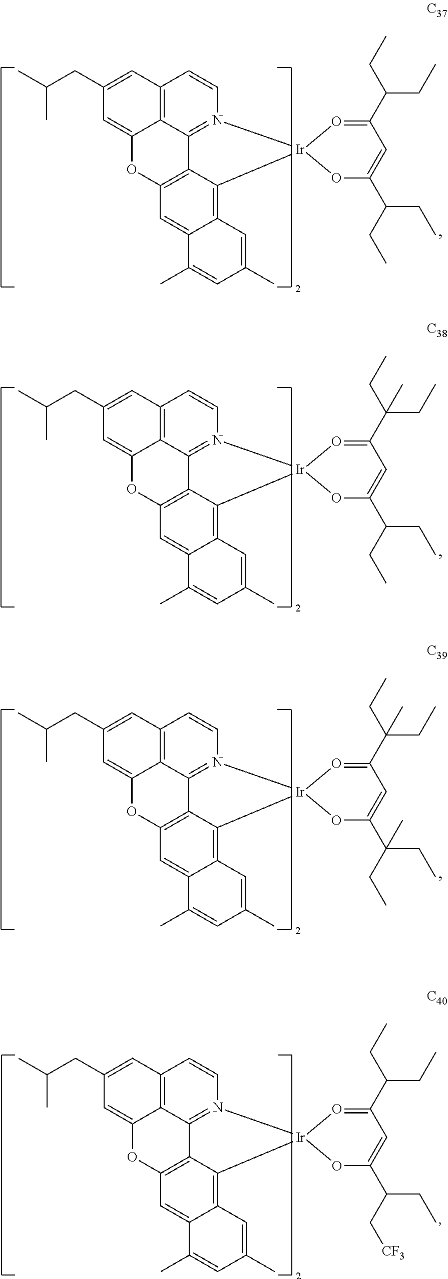

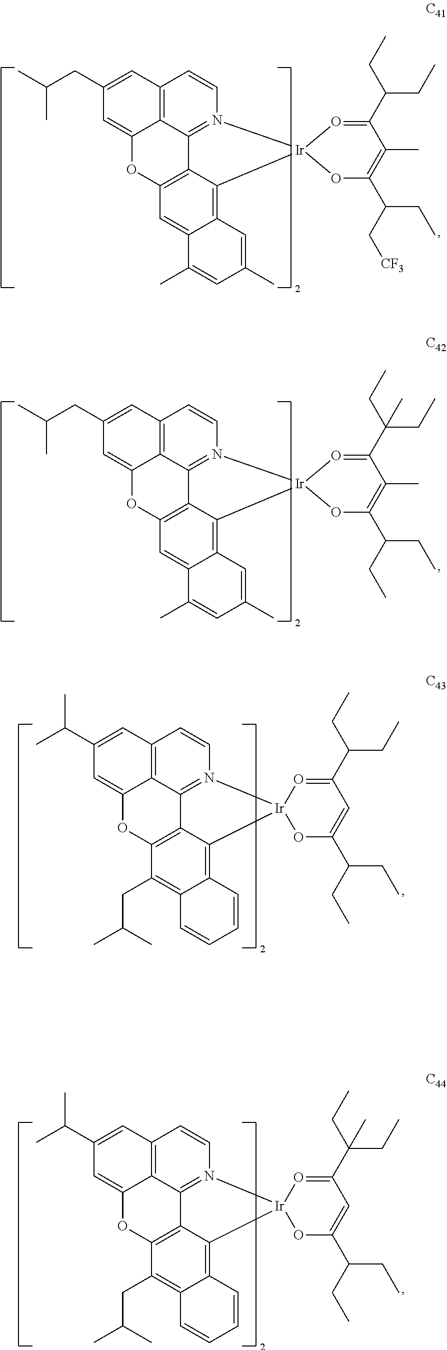

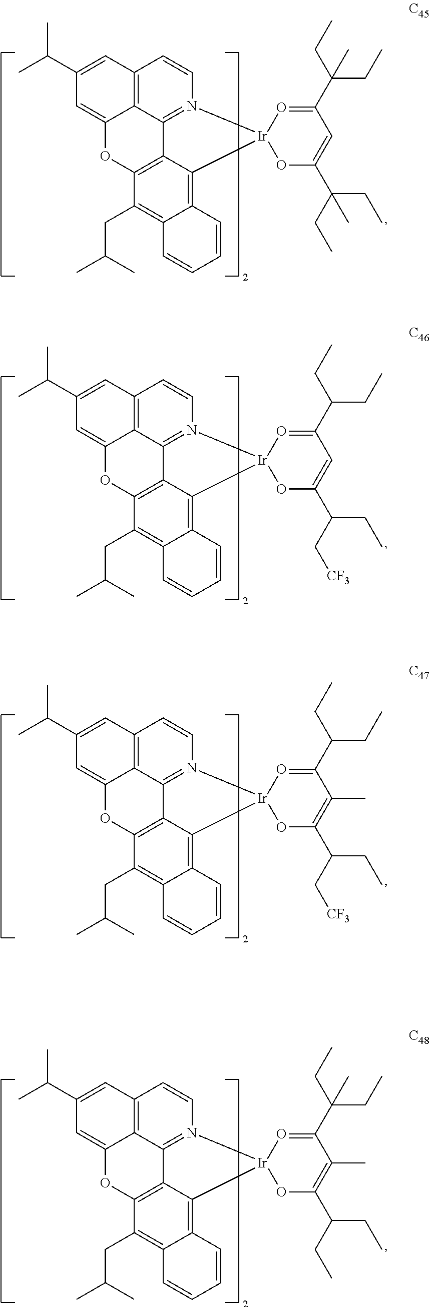

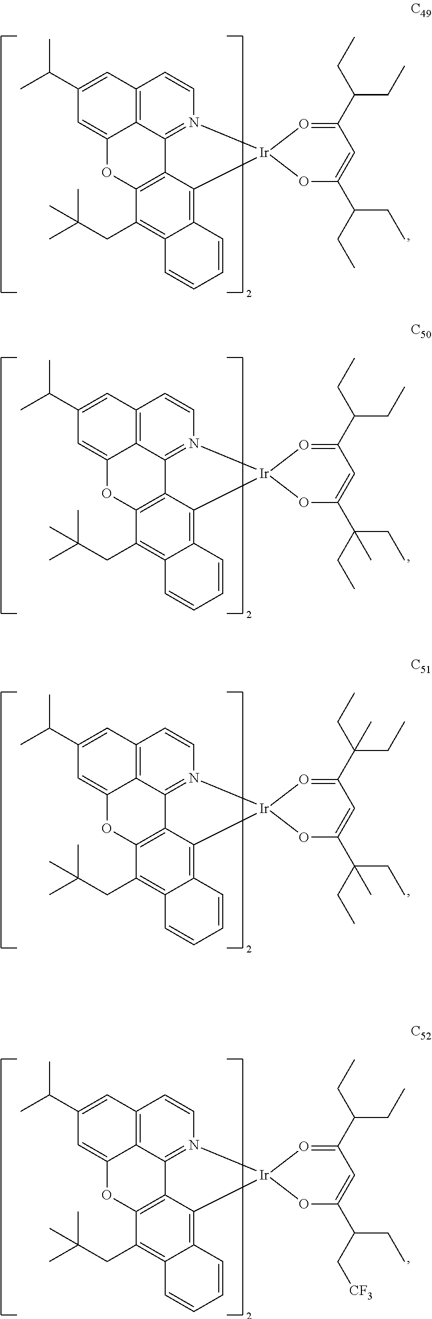

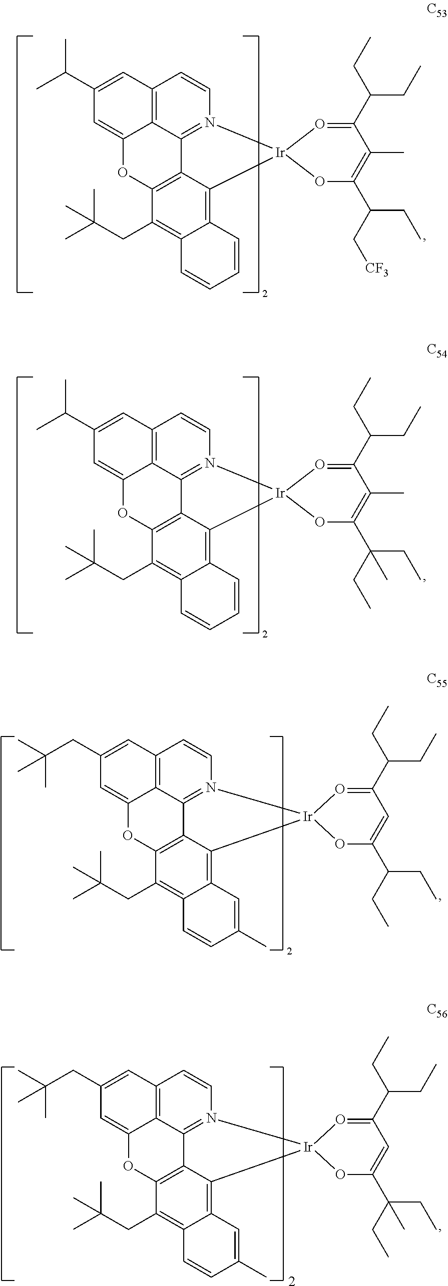

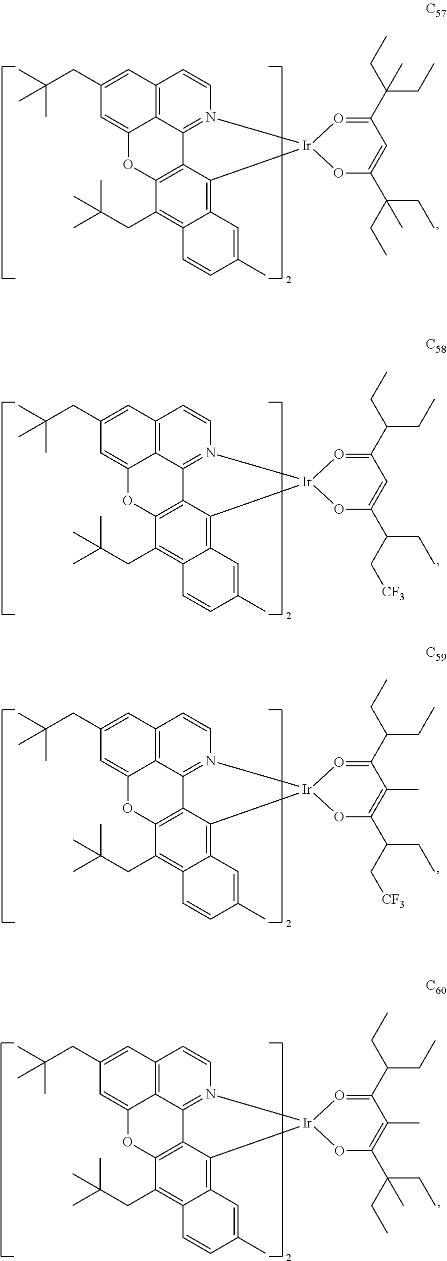

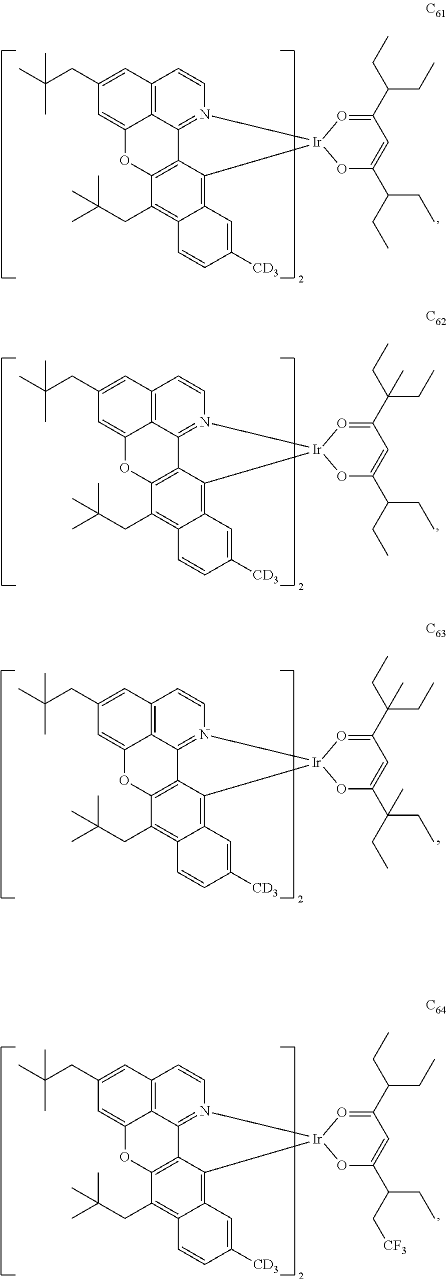

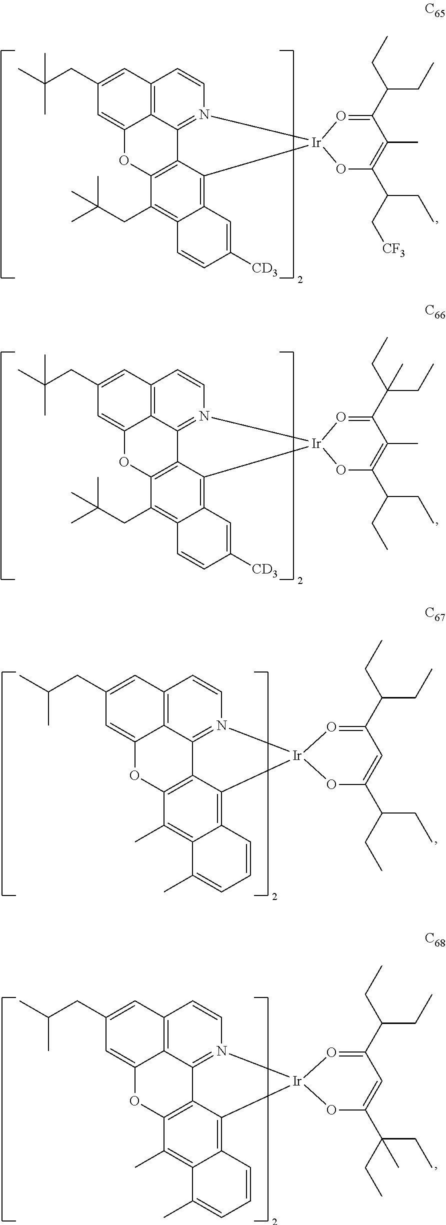

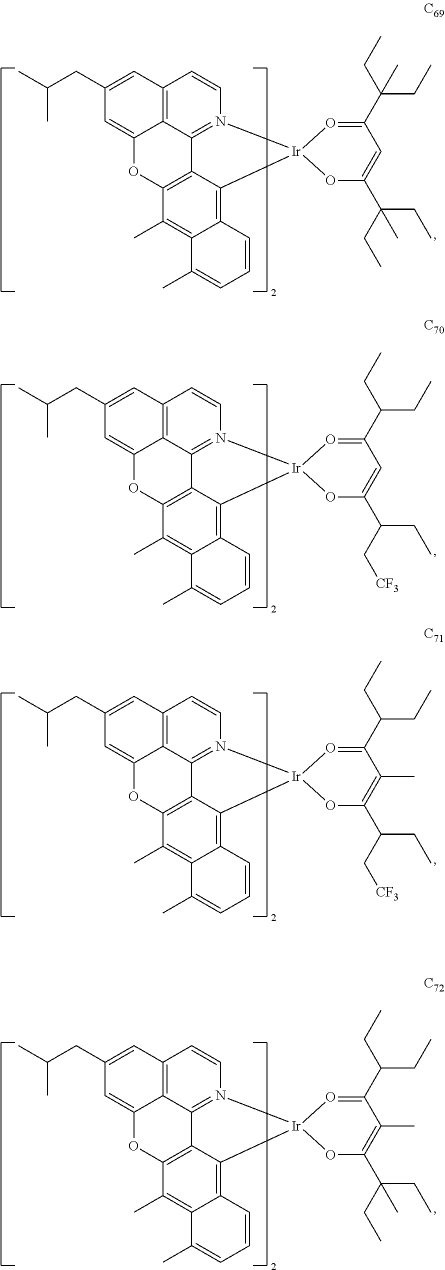

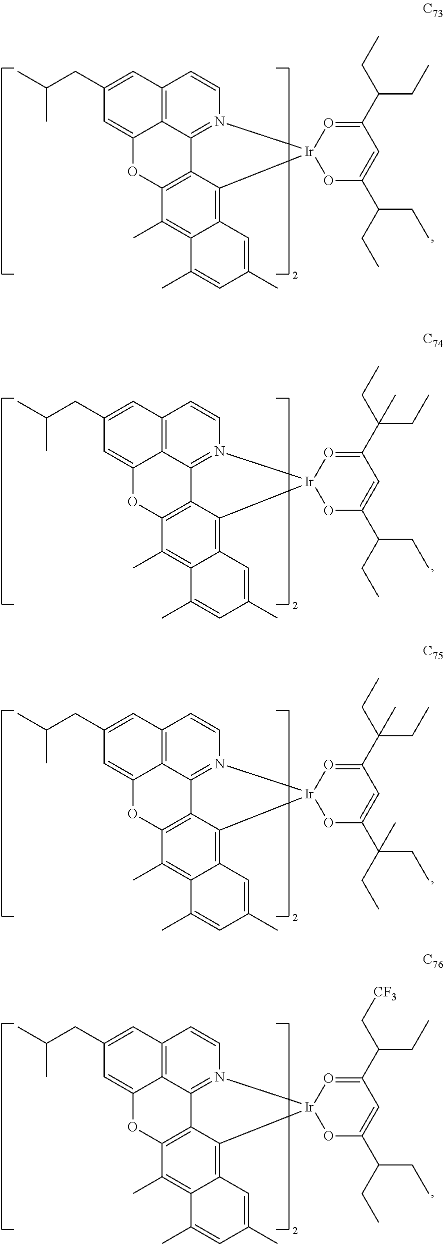

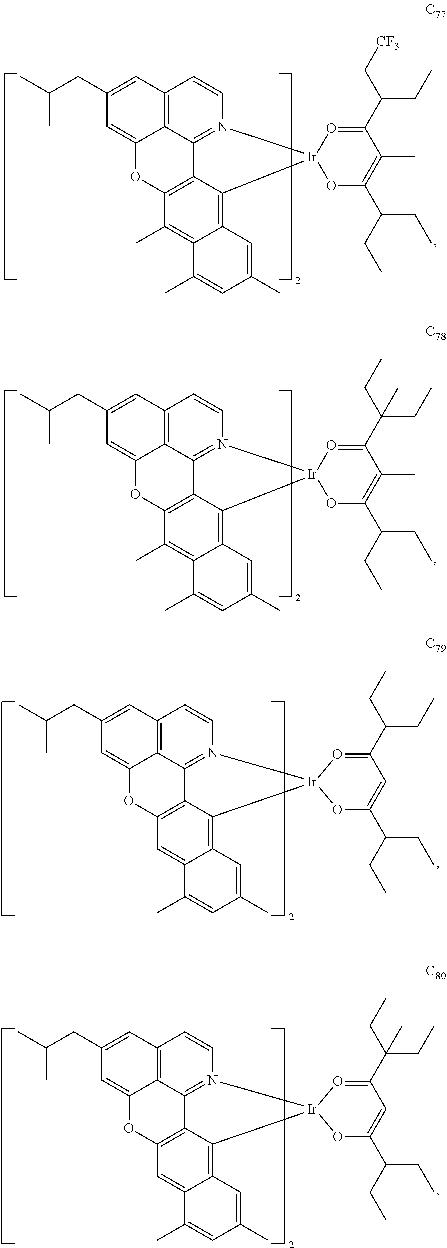

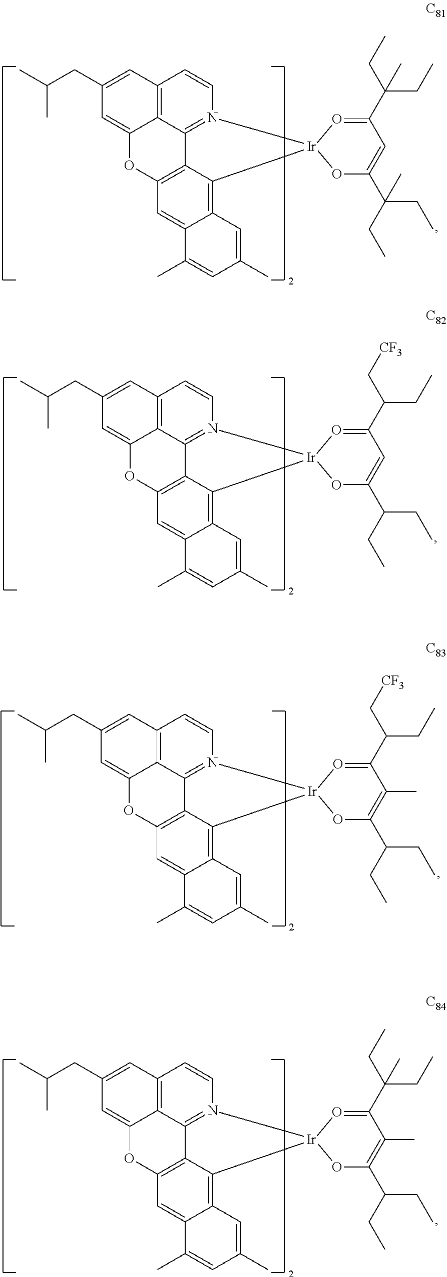

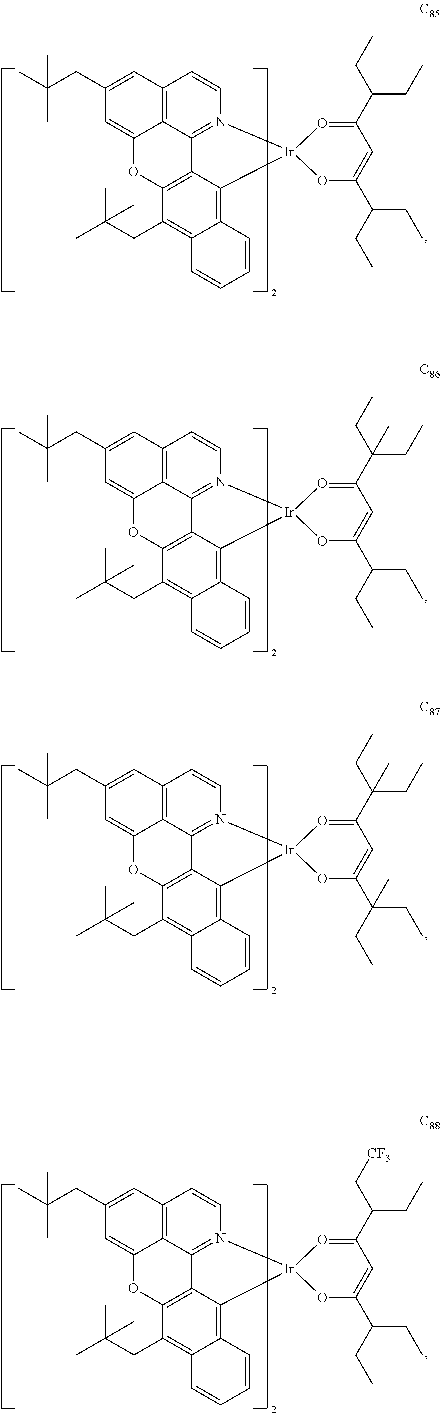

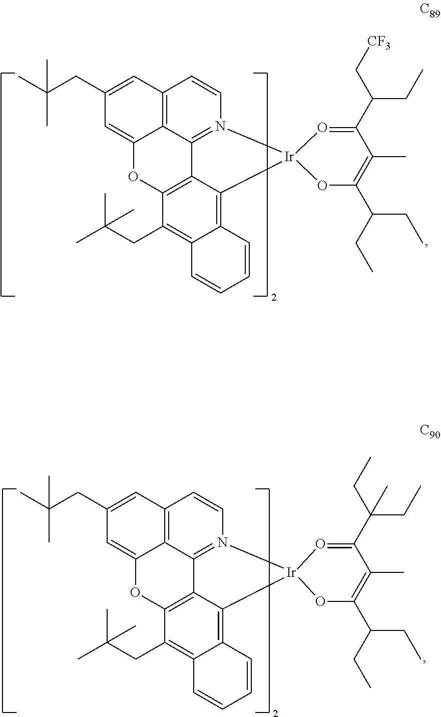

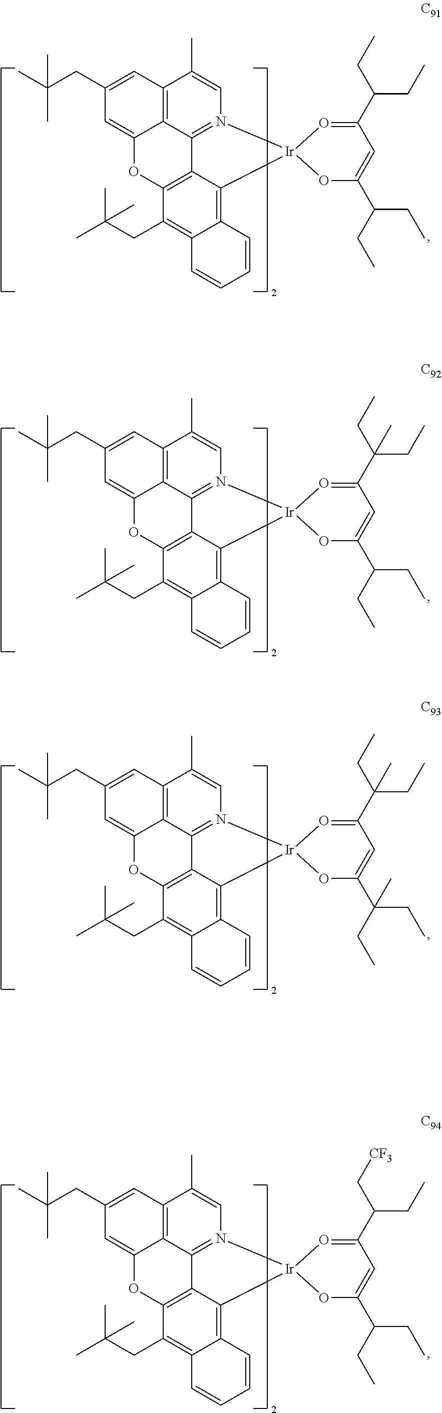

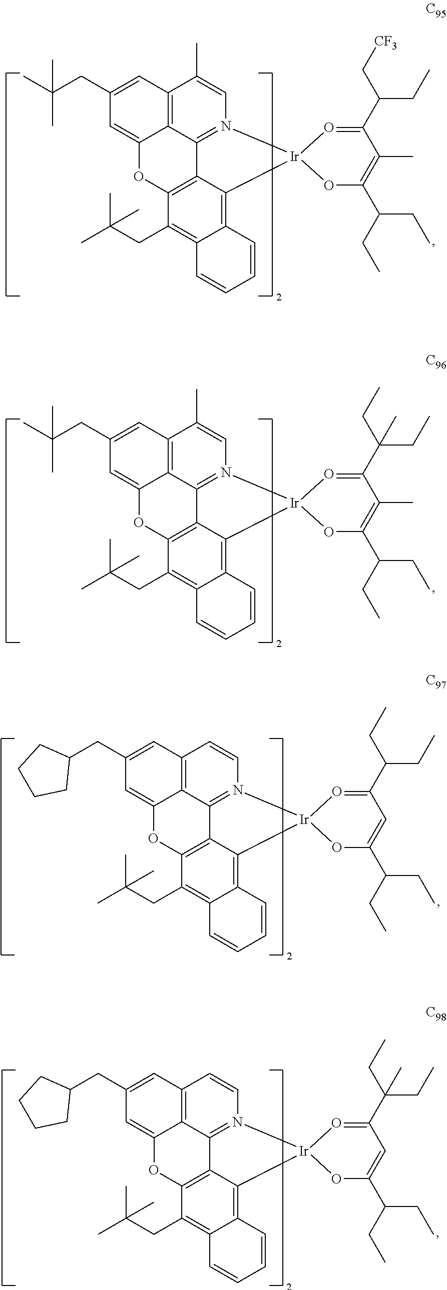

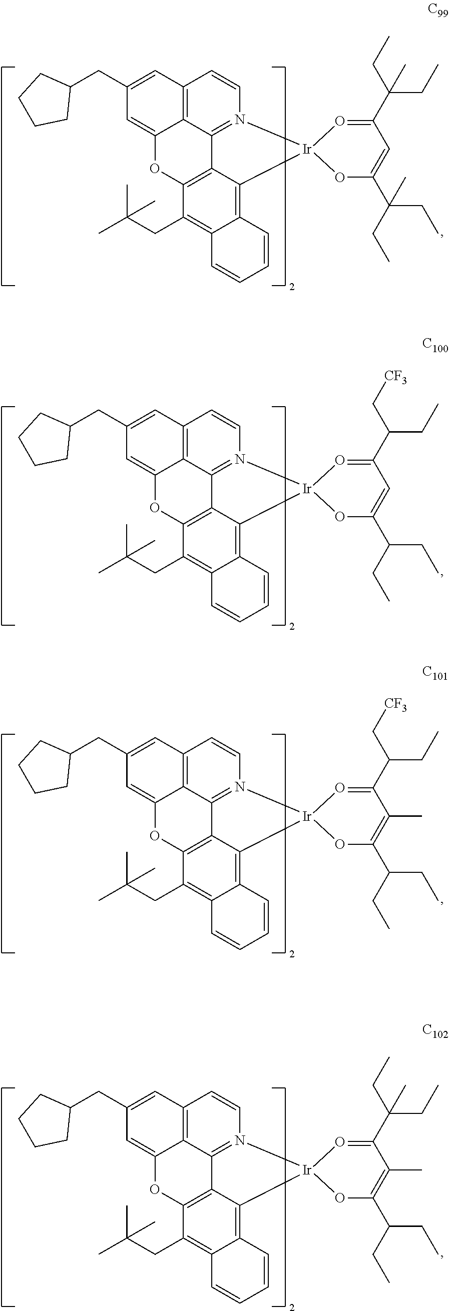

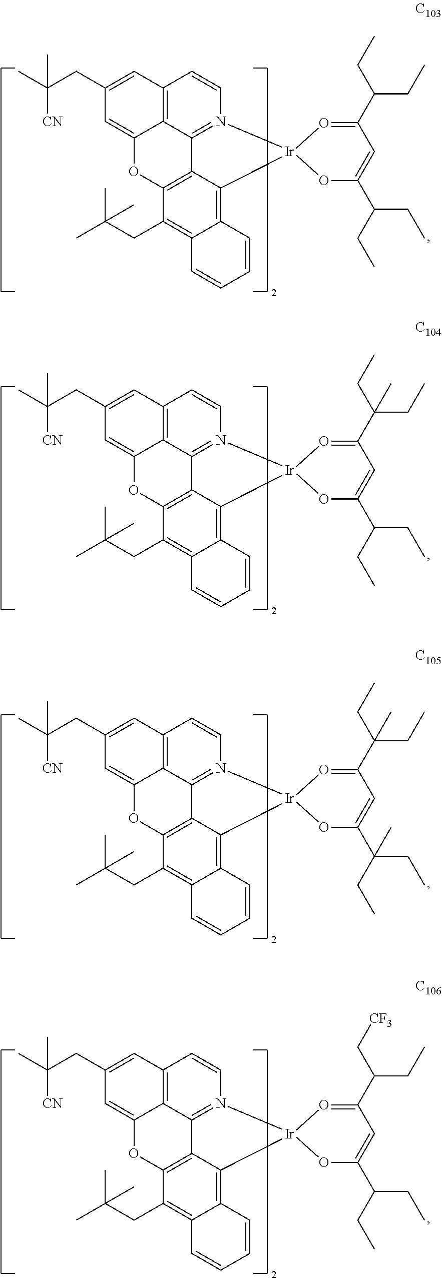

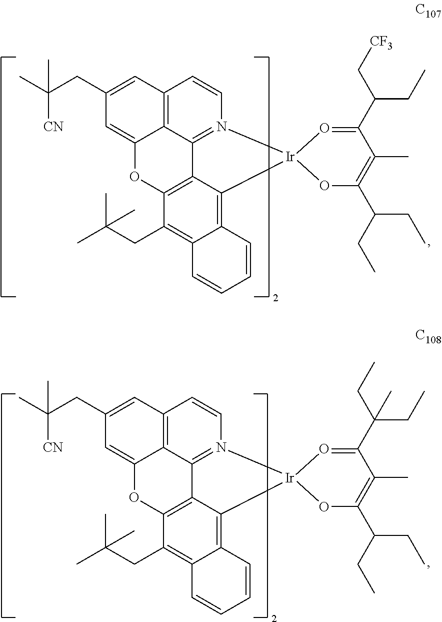

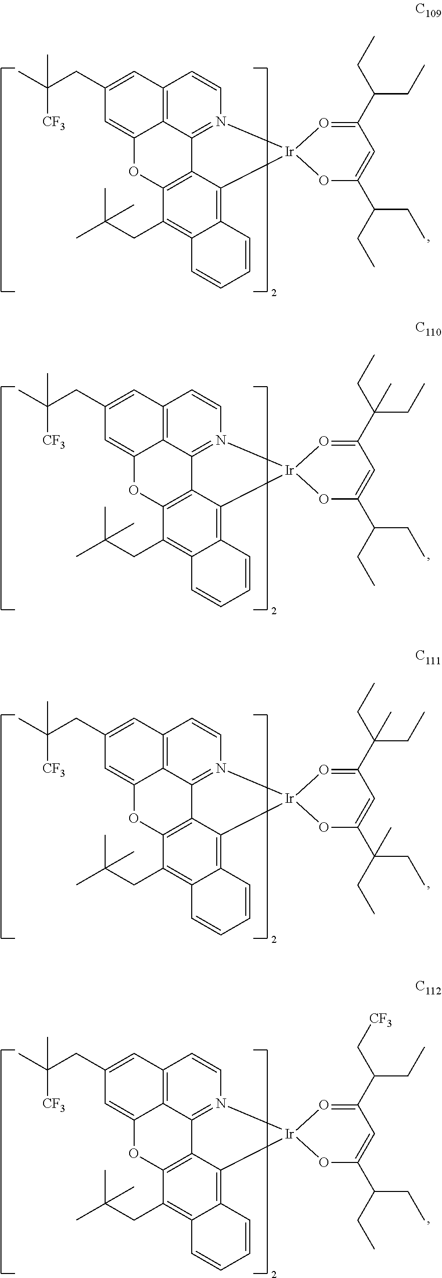

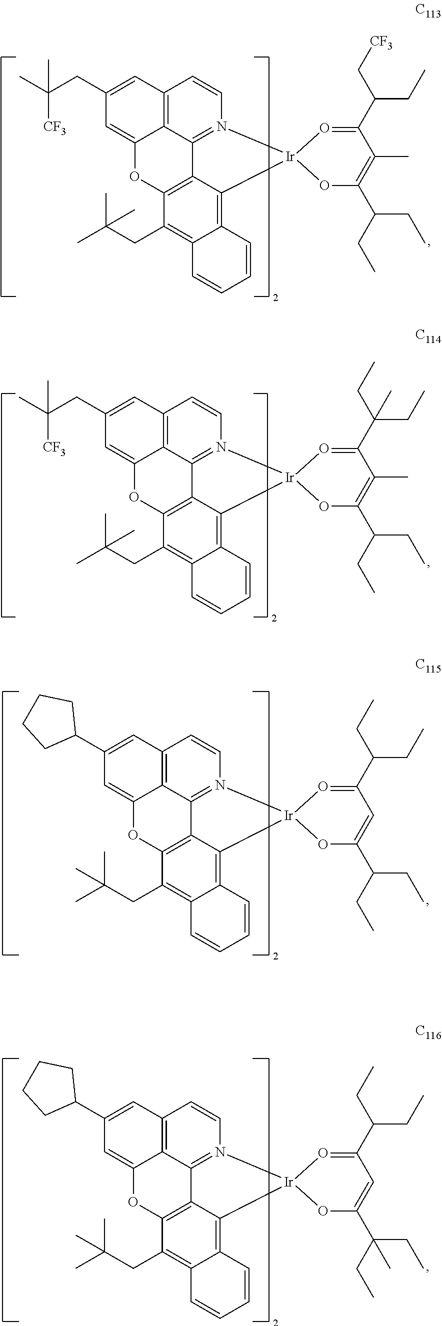

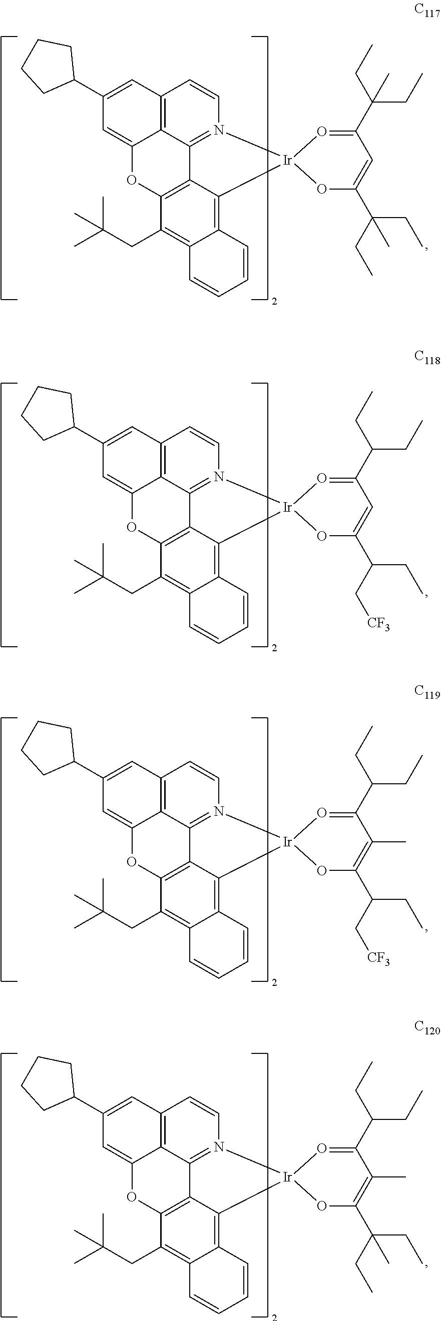

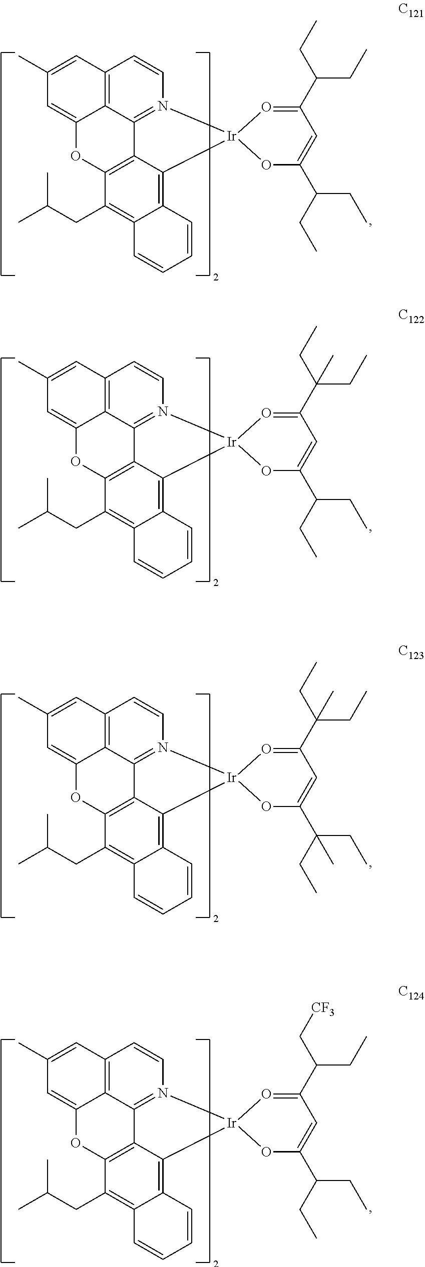

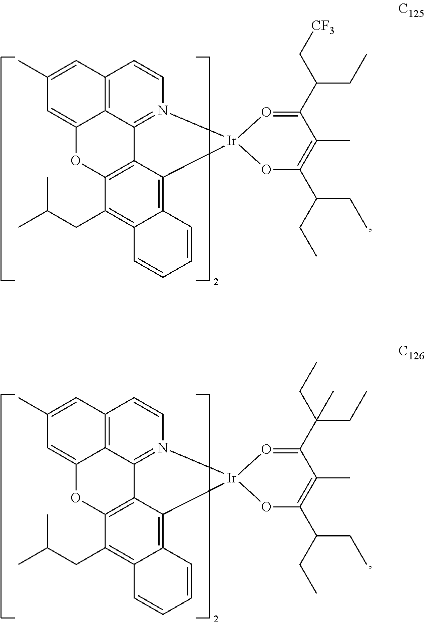

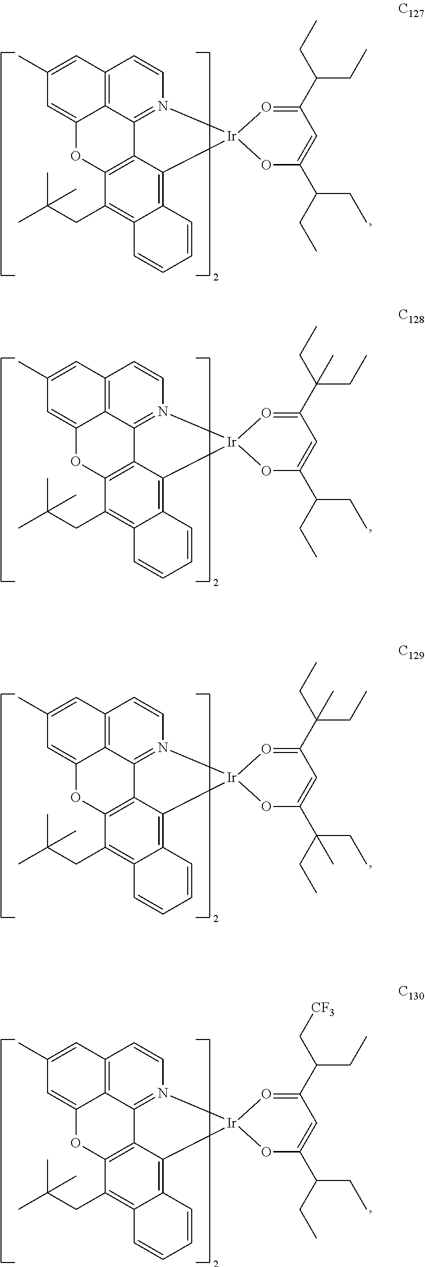

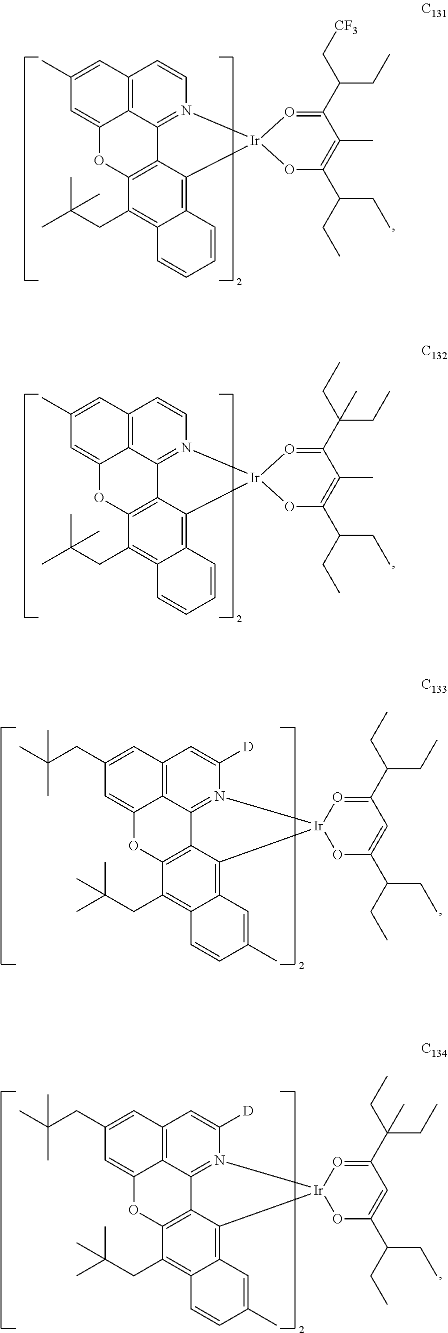

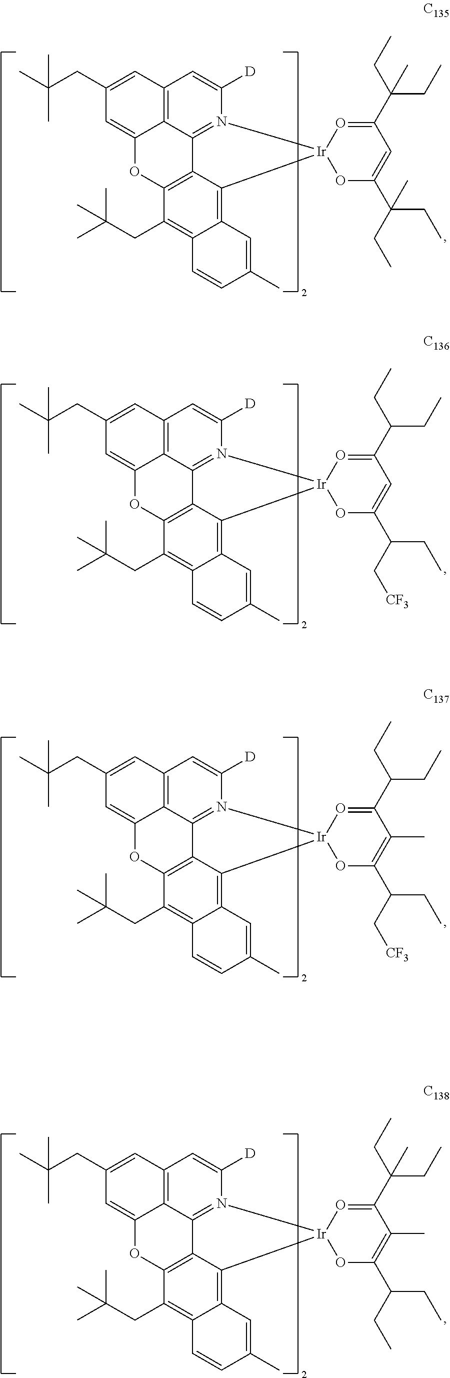

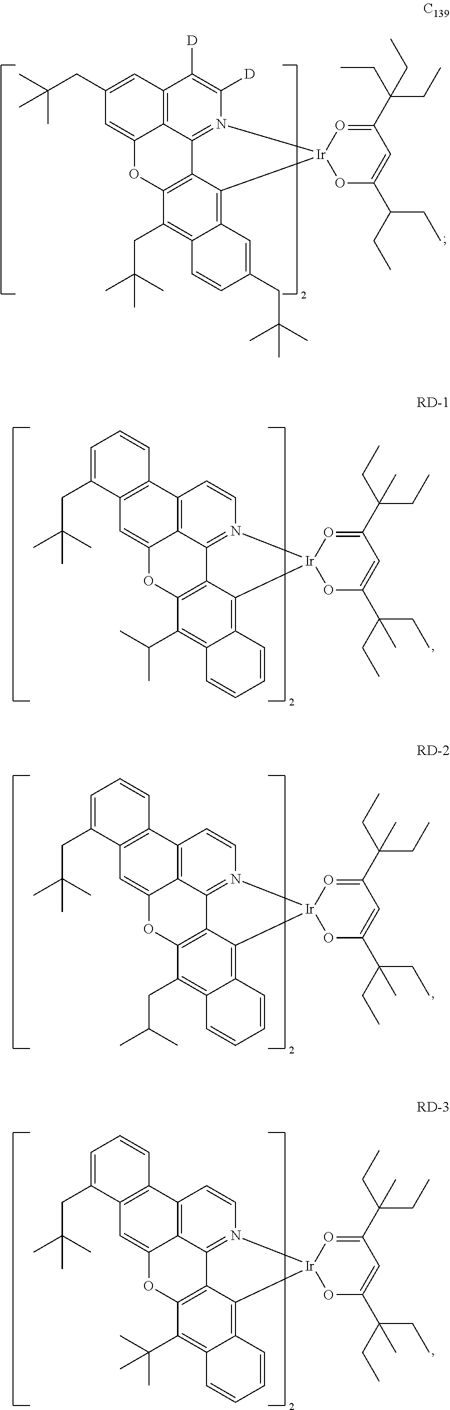

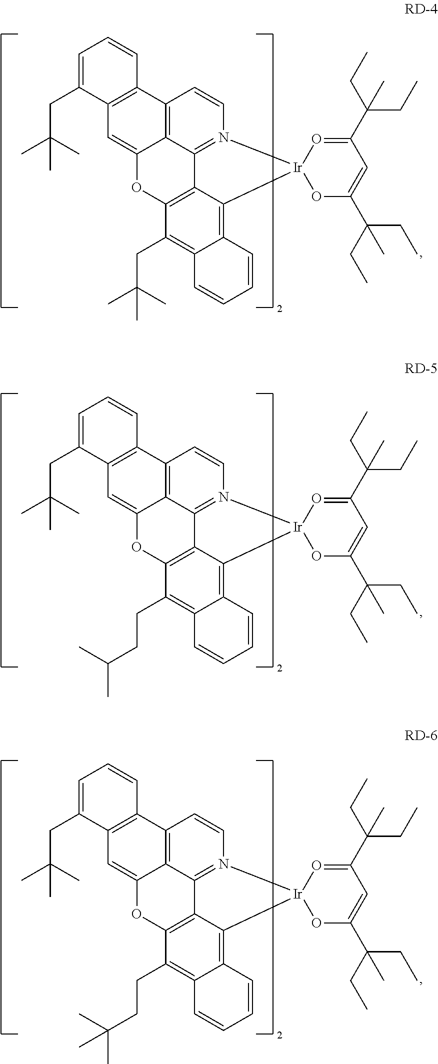

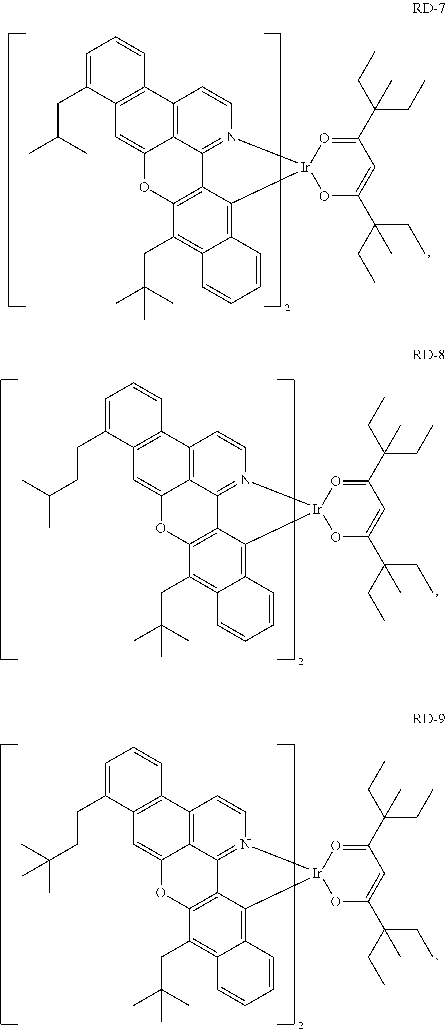

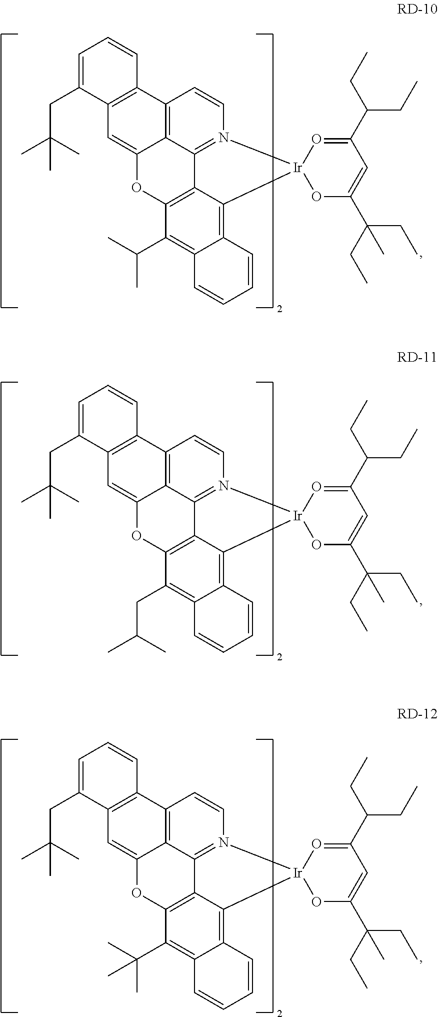

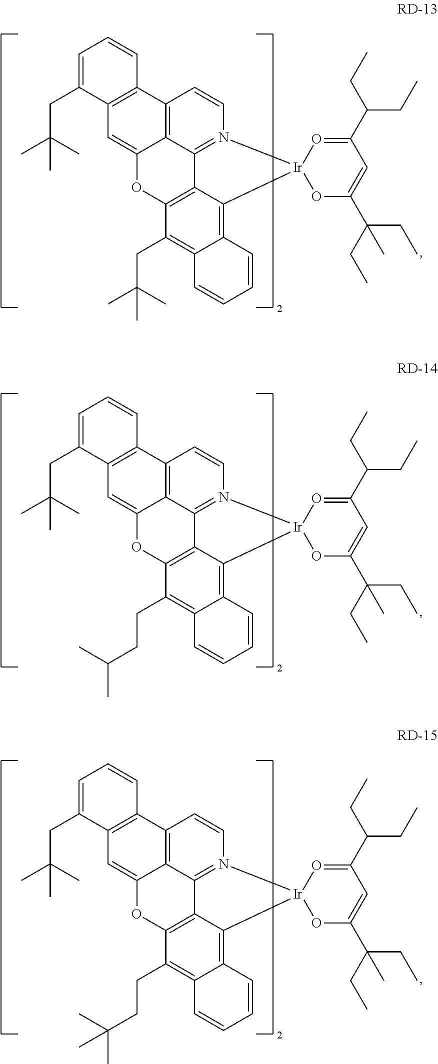

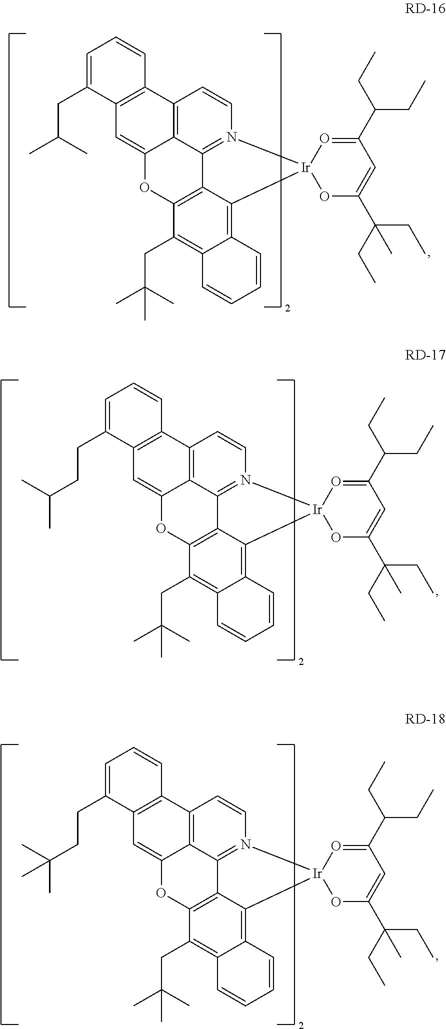

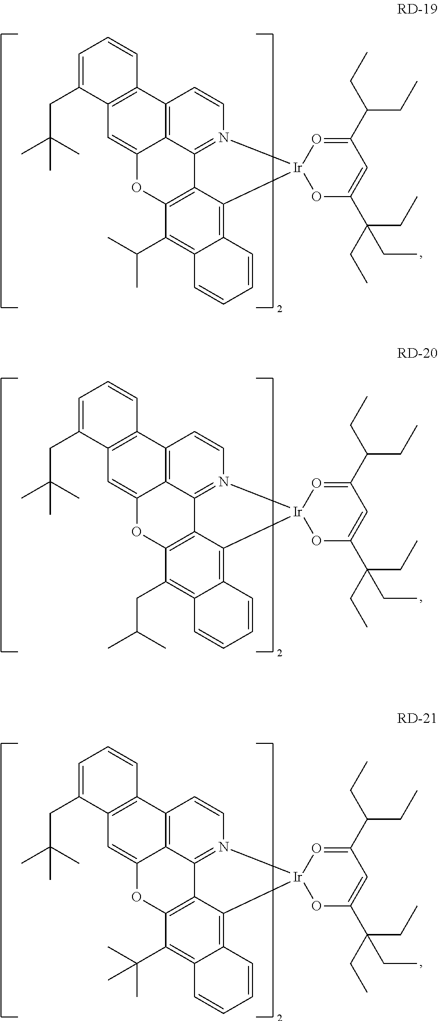

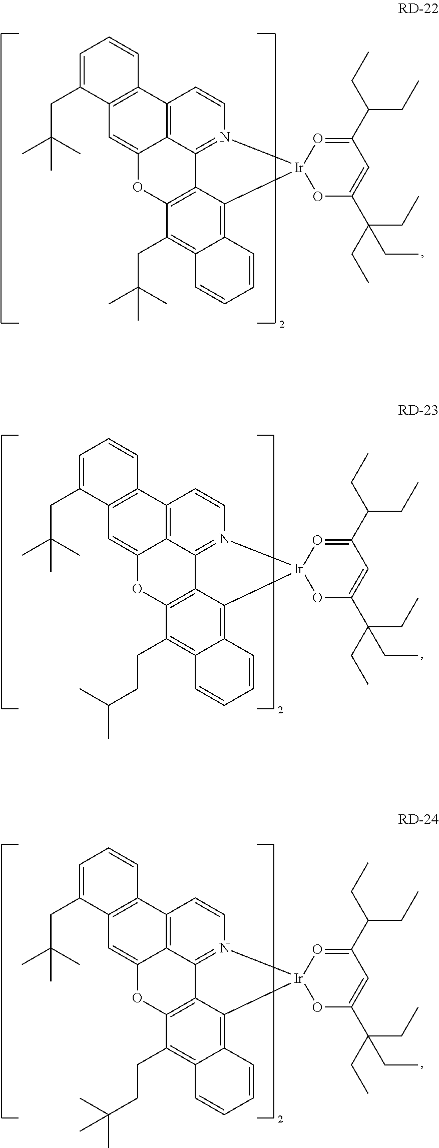

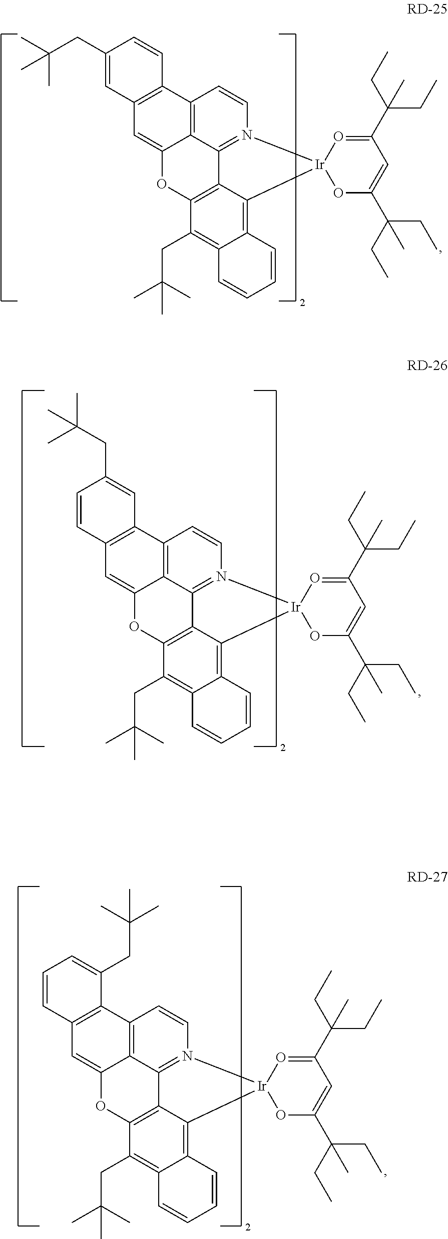

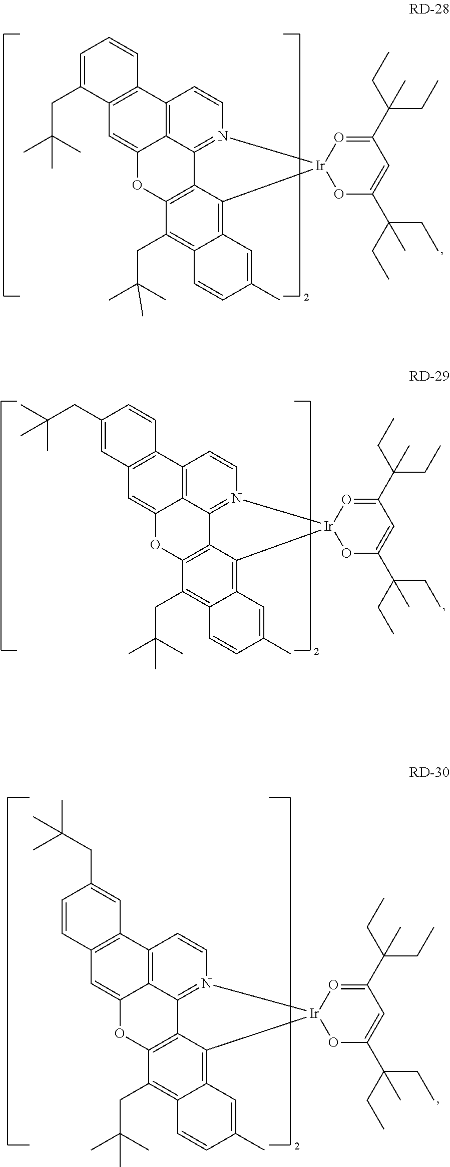

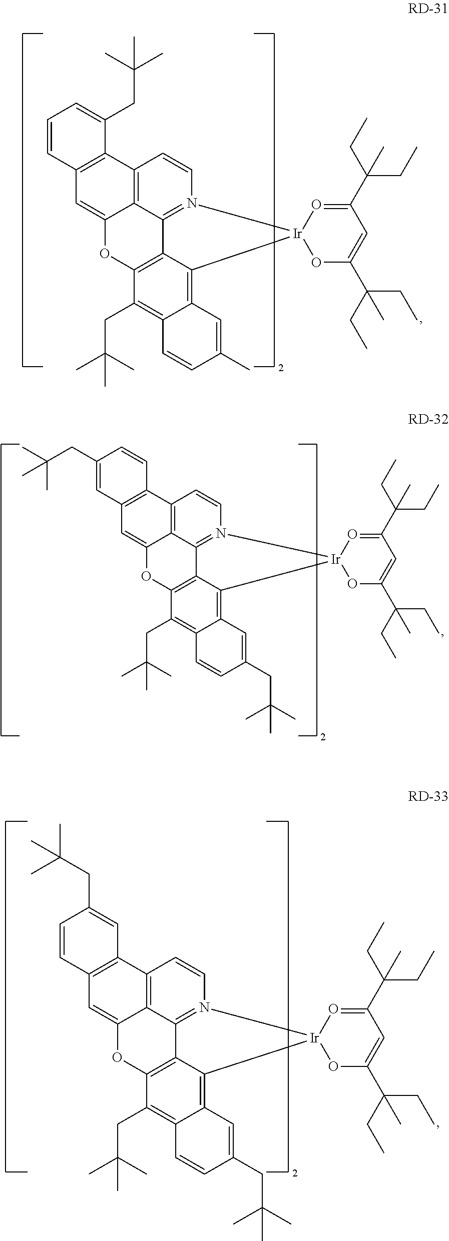

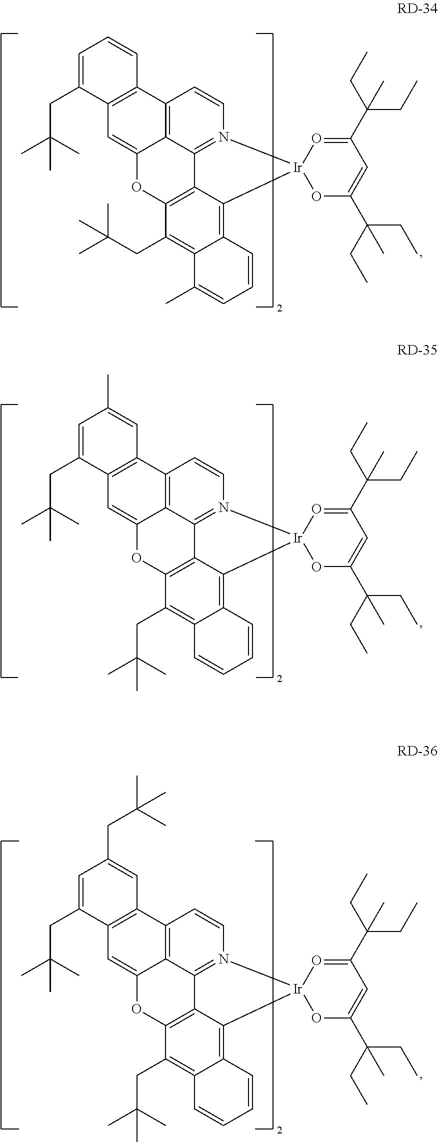

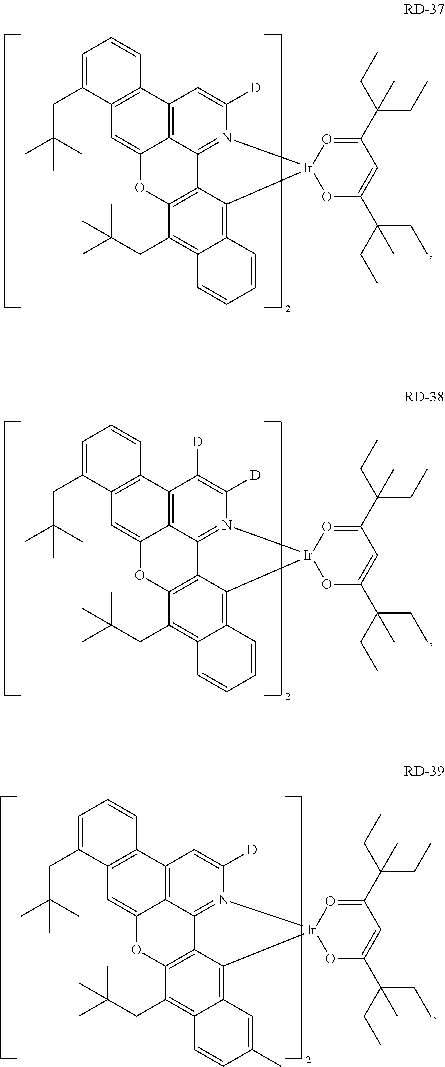

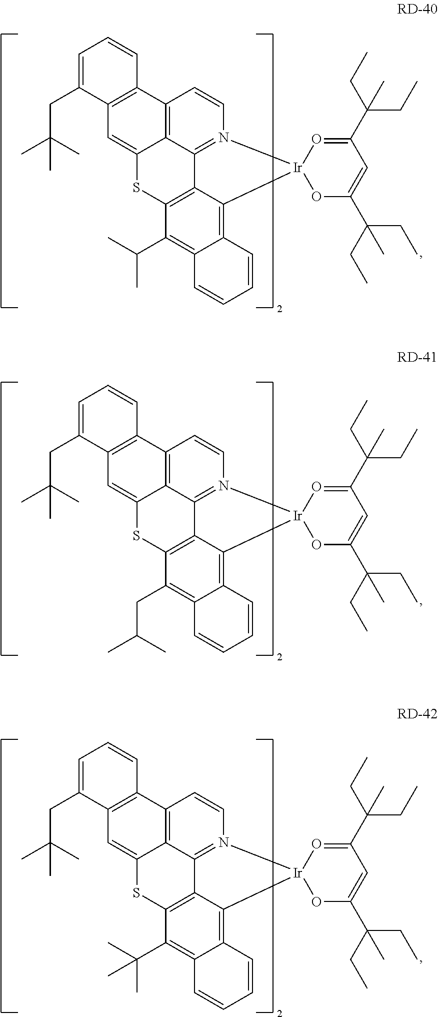

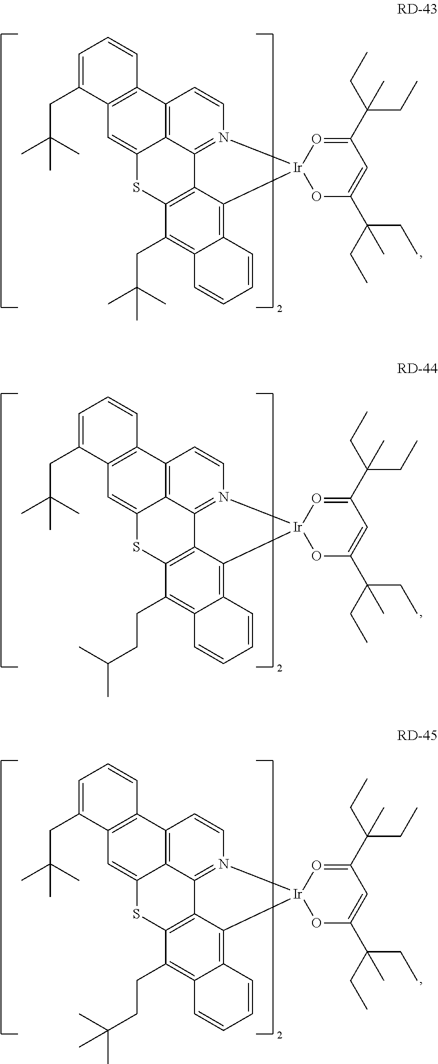

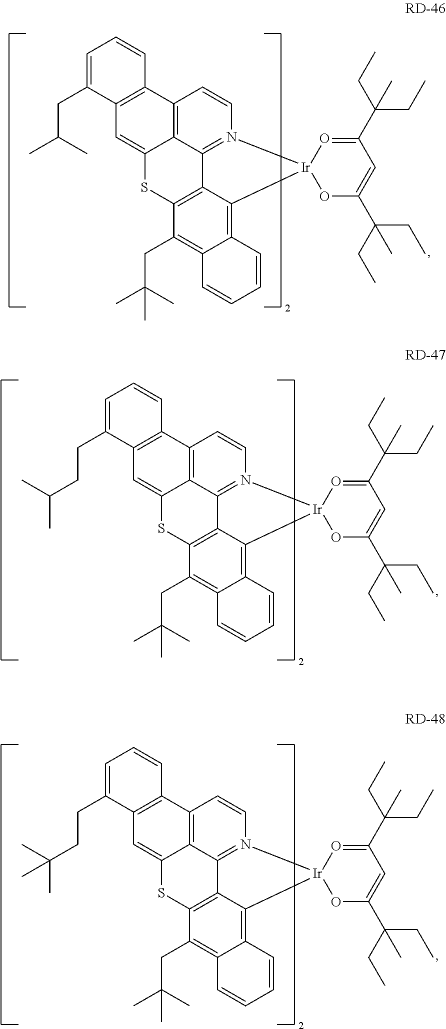

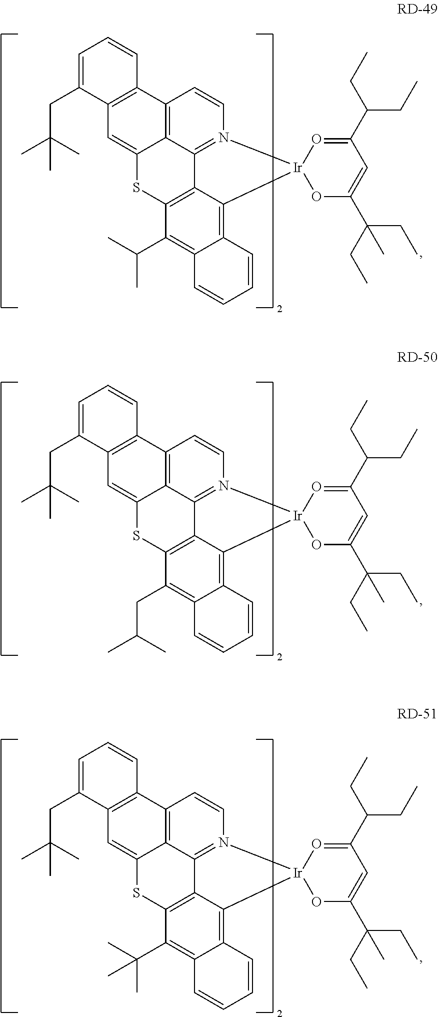

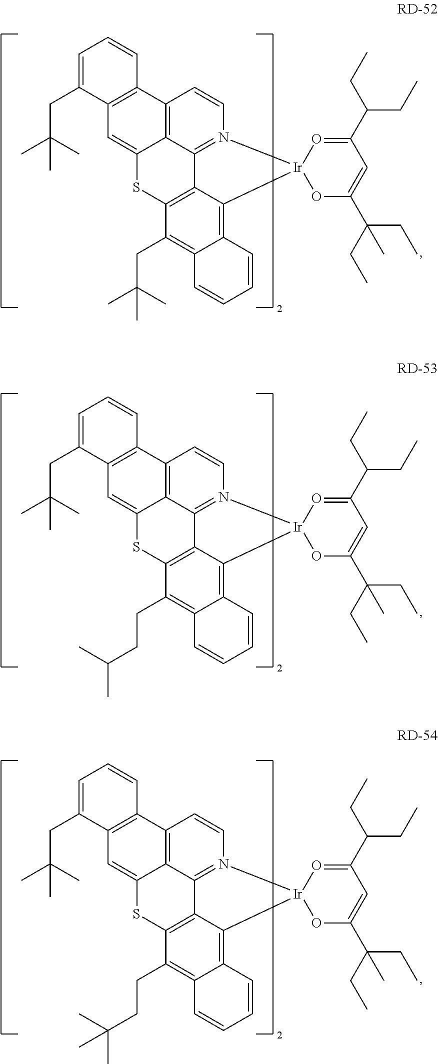

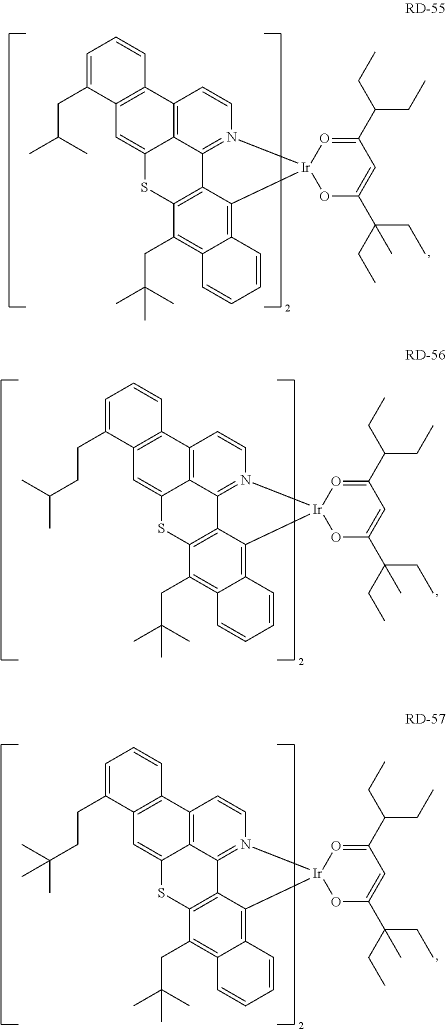

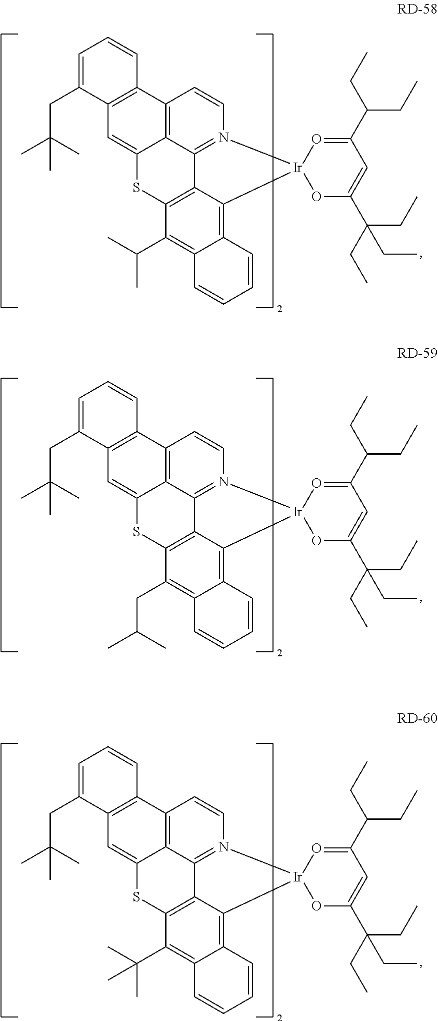

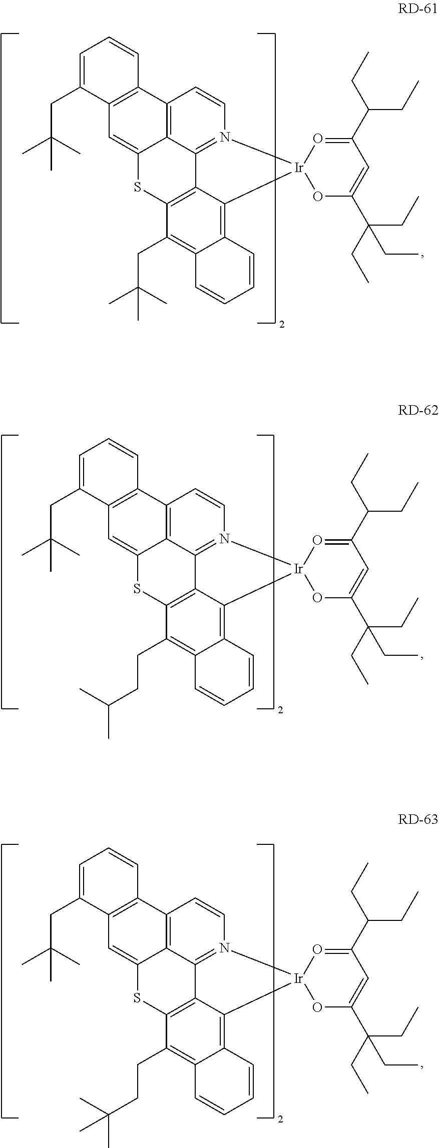

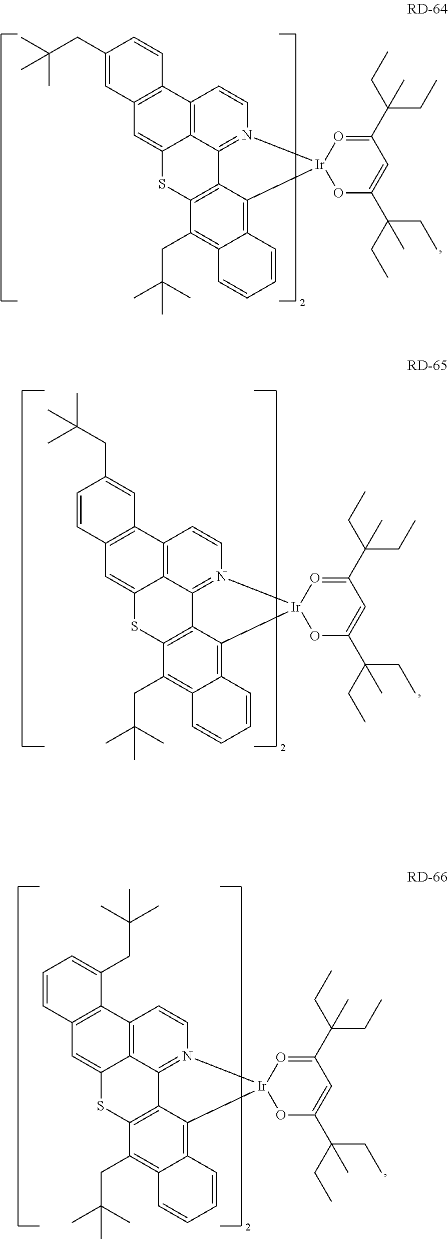

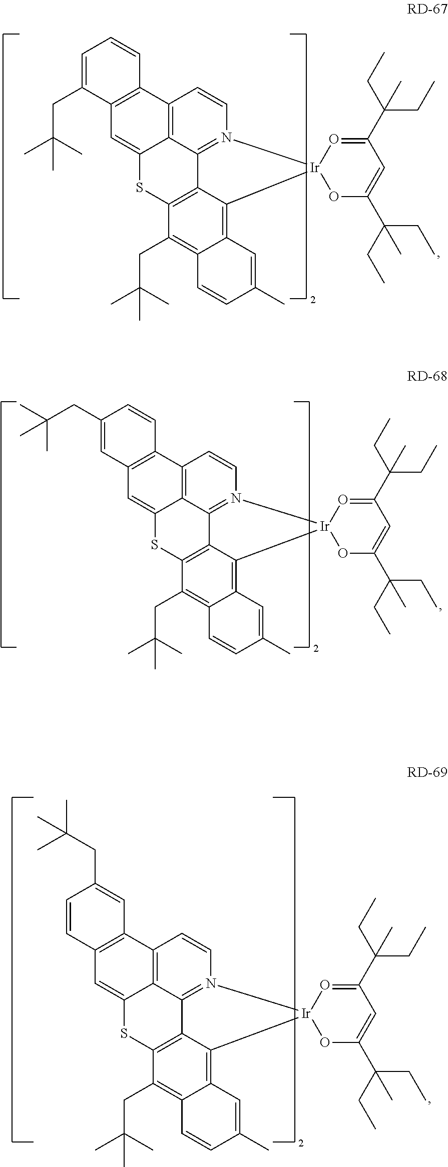

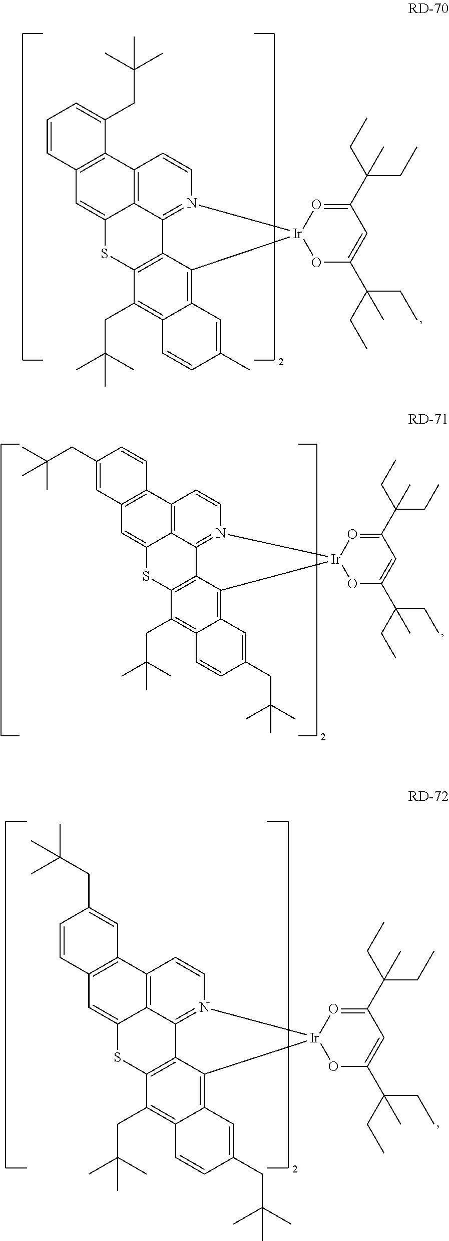

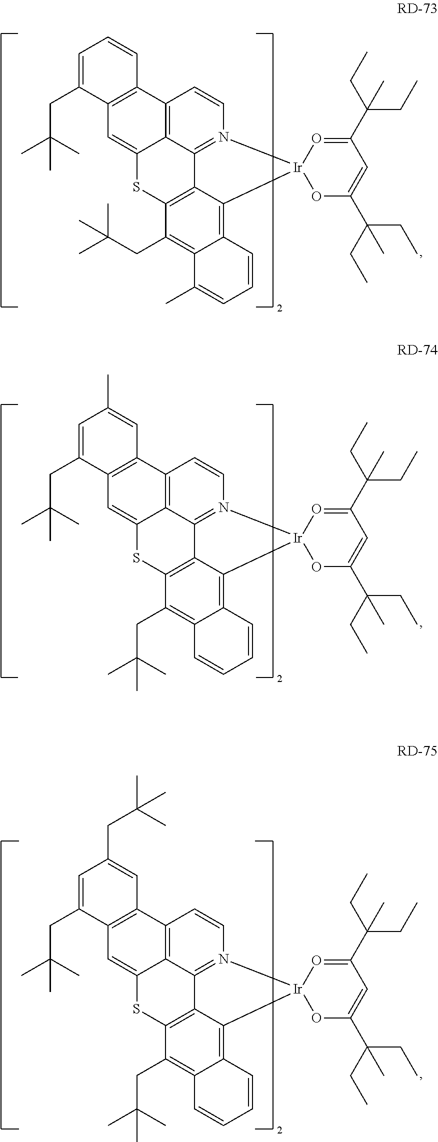

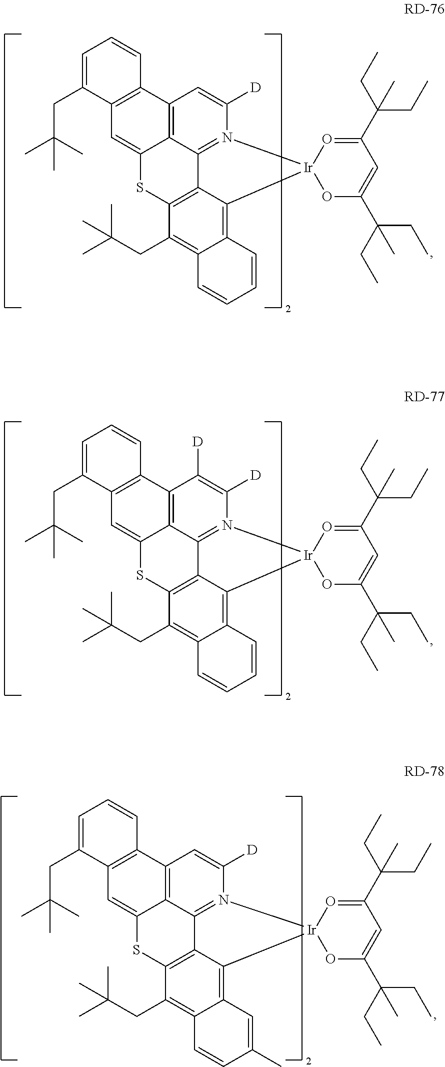

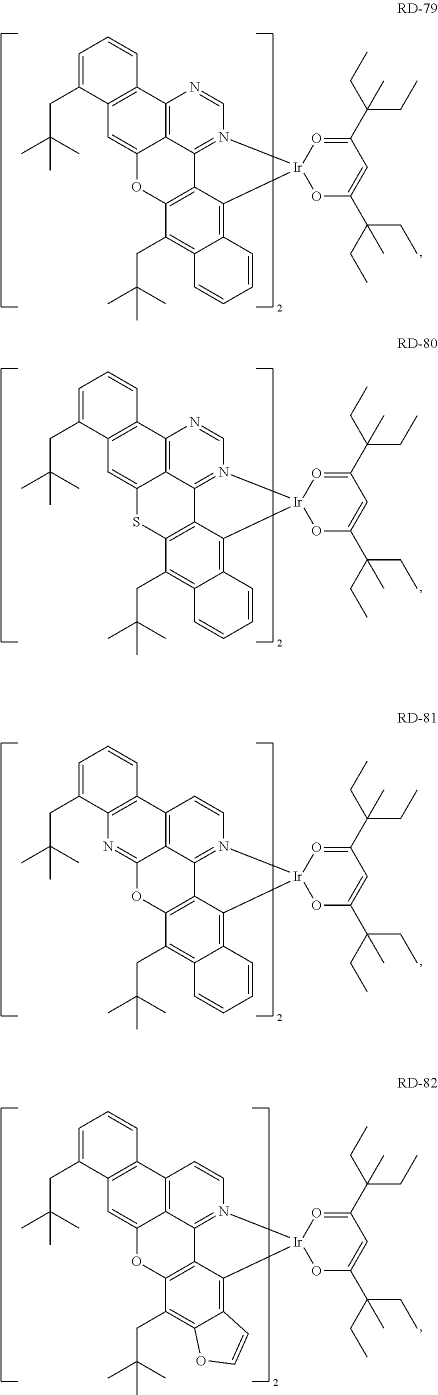

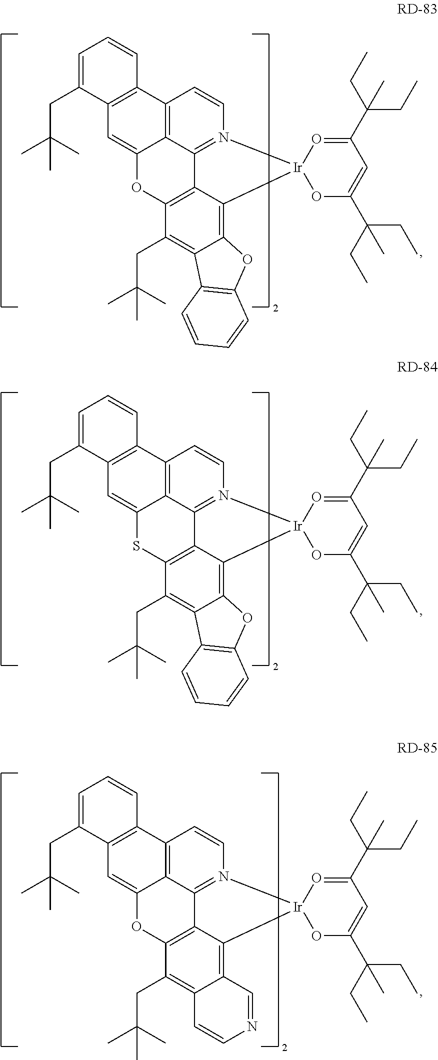

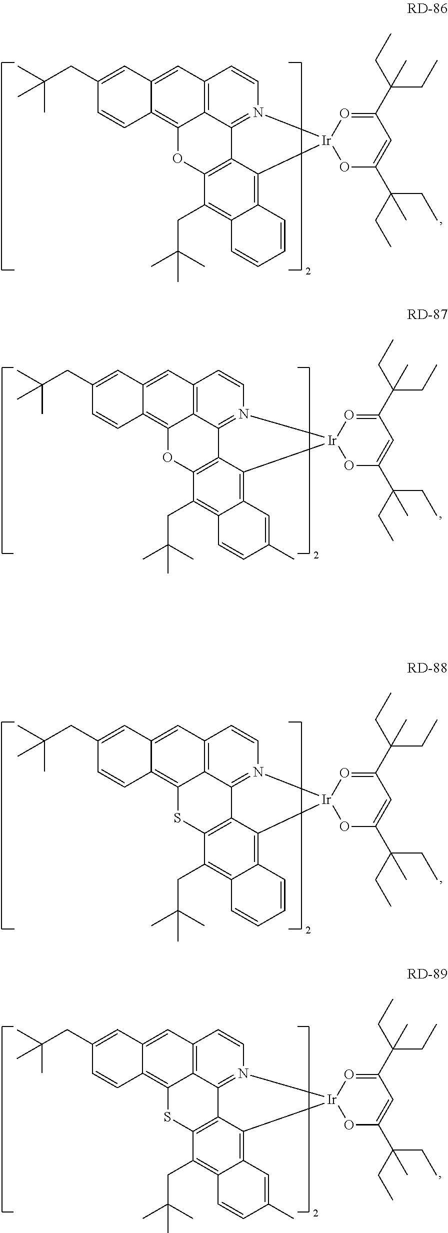

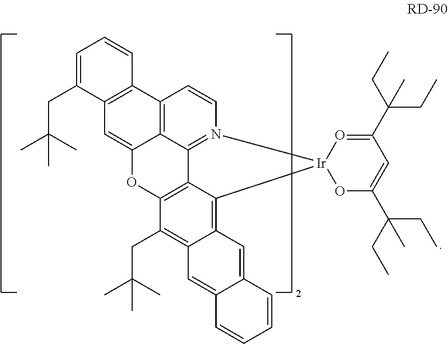

17. The organic electroluminescent device according to claim 1, wherein the electron blocking material is a second compound having a structure represented by Formula 2-1 or Formula 2-2: 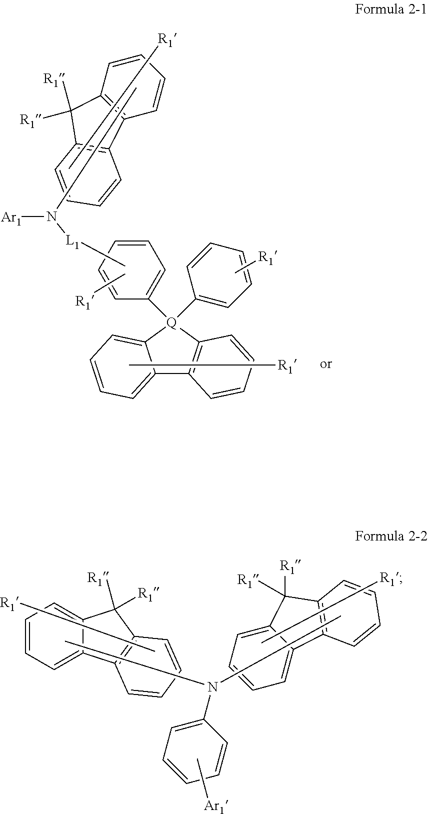
wherein Ar₁ and Ar₁′ are each independently selected from substituted or unsubstituted aryl having 6 to 30 carbon atoms, substituted or unsubstituted heteroaryl having 3 to 30 carbon atoms, or a combination thereof;
Ar₁′ and Rᵢ′ represent, at each occurrence identically or differently, mono-substitution, multiple substitutions, or non-substitution;
L₁ is, at each occurrence identically or differently, selected from a single bond, substituted or unsubstituted arylene having 6 to 30 carbon atoms, substituted or unsubstituted heteroarylene having 3 to 30 carbon atoms, or a combination thereof,
Q is selected from C or Si;
Rᵢ′ and Rᵢ″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents Rᵢ′ can be optionally joined to form a ring.

18. The organic electroluminescent device according to claim 17, wherein Q is selected from Si;
Rᵢ′ is, at each occurrence identically or differently, selected from hydrogen, deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, or a combination thereof,
Rᵢ″ is, at each occurrence identically or differently, selected from substituted or unsubstituted alkyl having 1 to 20 carbon atoms, substituted or unsubstituted aryl having 6 to 30 carbon atoms, substituted or unsubstituted heteroaryl having 3 to 30 carbon atoms, or a combination thereof, and
Ar₁ and Ar₁′ are, at each occurrence identically or differently, selected from substituted or unsubstituted phenyl, substituted or unsubstituted biphenyl, substituted or unsubstituted terphenyl, substituted or unsubstituted naphthyl, substituted or unsubstituted fluorenyl, substituted or unsubstituted spirofluorenyl, substituted or unsubstituted silafluorenyl, substituted or unsubstituted spirosilafluorenyl, substituted or unsubstituted dibenzofuryl, substituted or unsubstituted dibenzothienyl, substituted or unsubstituted dibenzoselenophenyl, substituted or unsubstituted phenanthryl, substituted or unsubstituted triphenylenyl, substituted or unsubstituted pyridyl, substituted or unsubstituted carbazolyl, substituted or unsubstituted anthryl, substituted or unsubstituted pyrenyl, or a combination thereof,
preferably, Rᵢ′ and Rᵢ″ are, at each occurrence identically or differently, selected from substituted or unsubstituted alkyl having 1 to 20 carbon atoms, substituted or unsubstituted aryl having 6 to 30 carbon atoms, or a combination thereof.

19. The organic electroluminescent device according to claim 17, wherein the second compound is selected from the group consisting of Compound C₁ to Compound C₁₈₄: 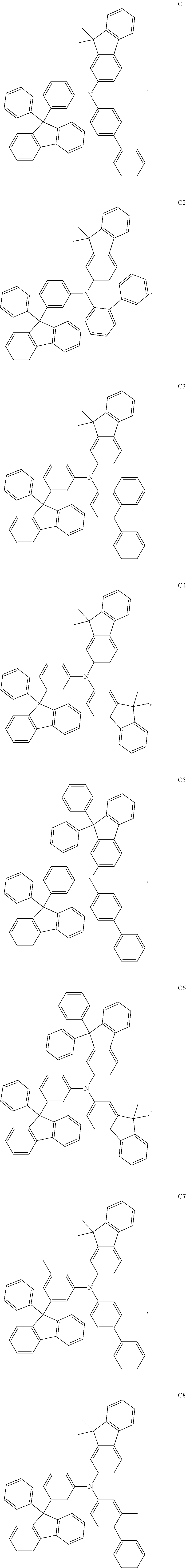 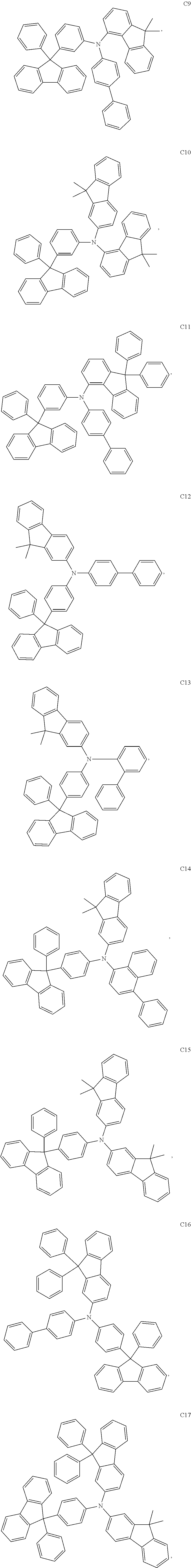 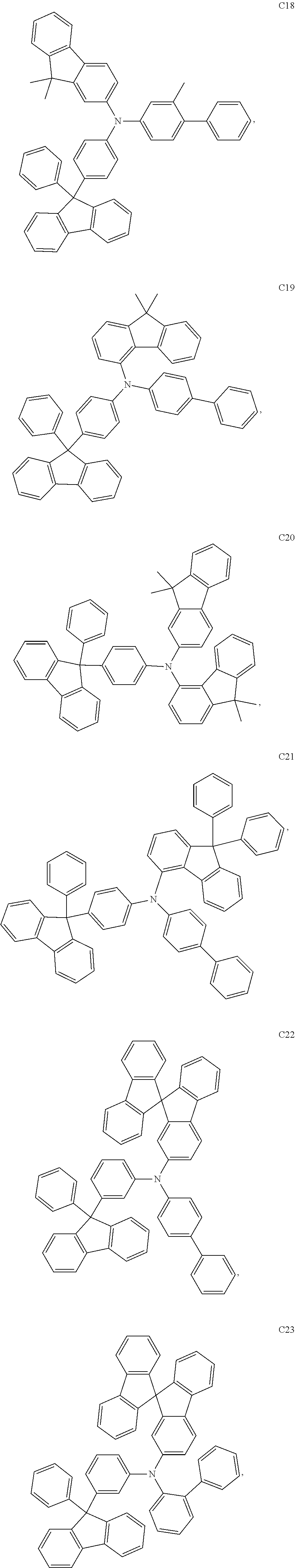 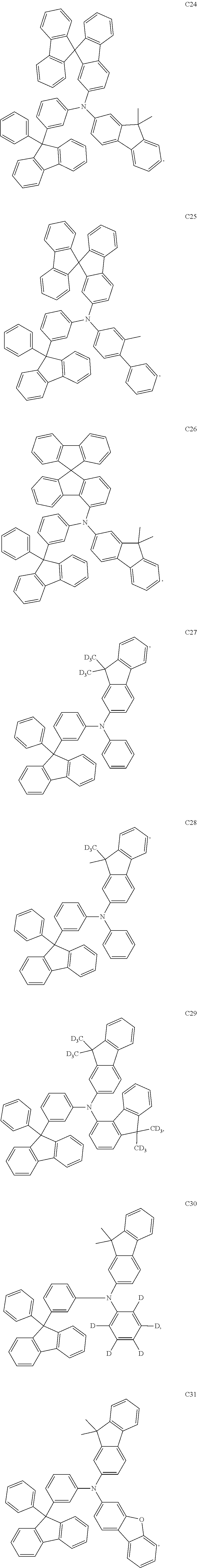 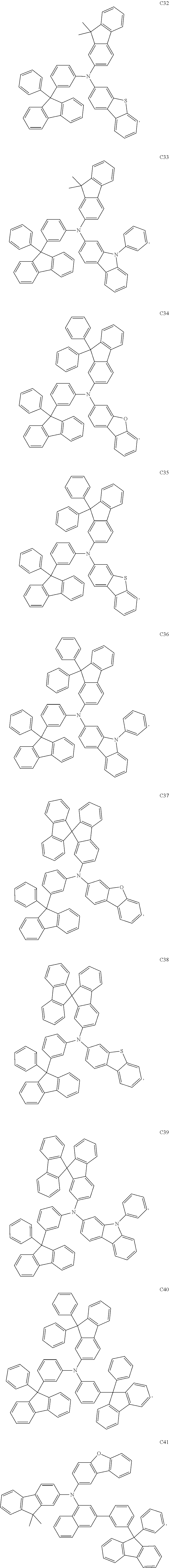 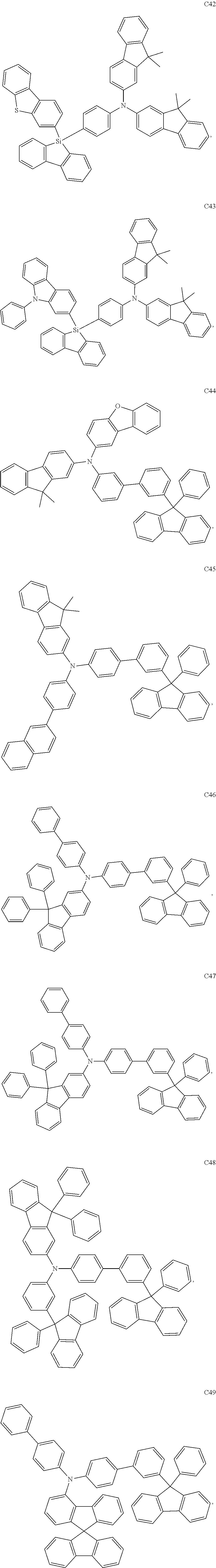 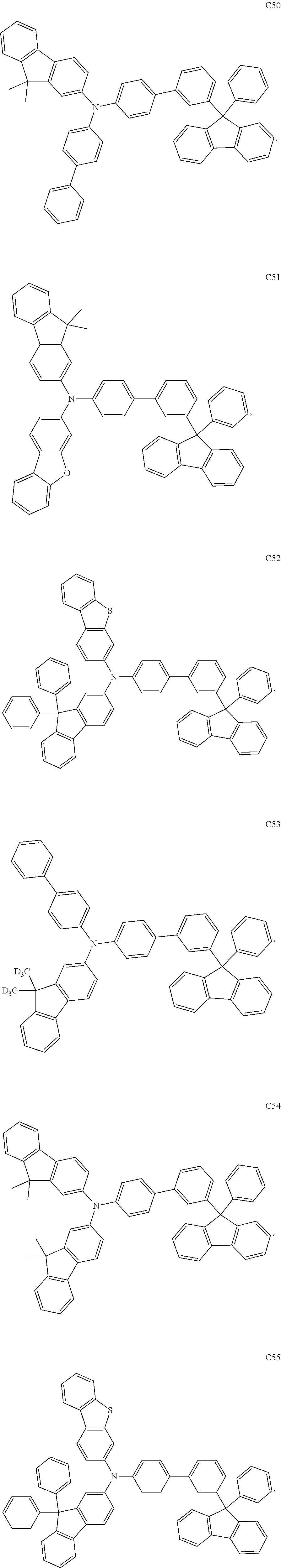 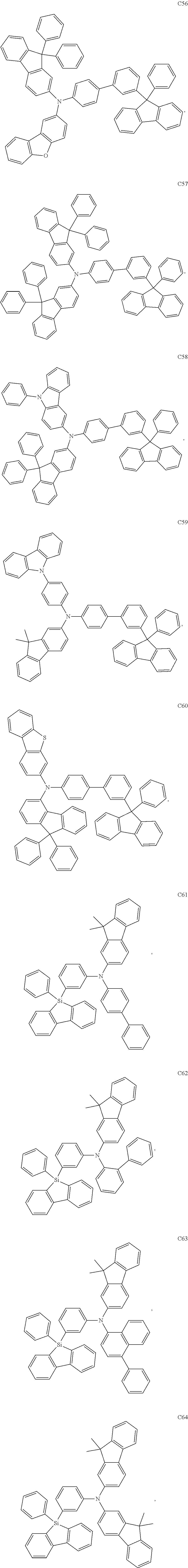 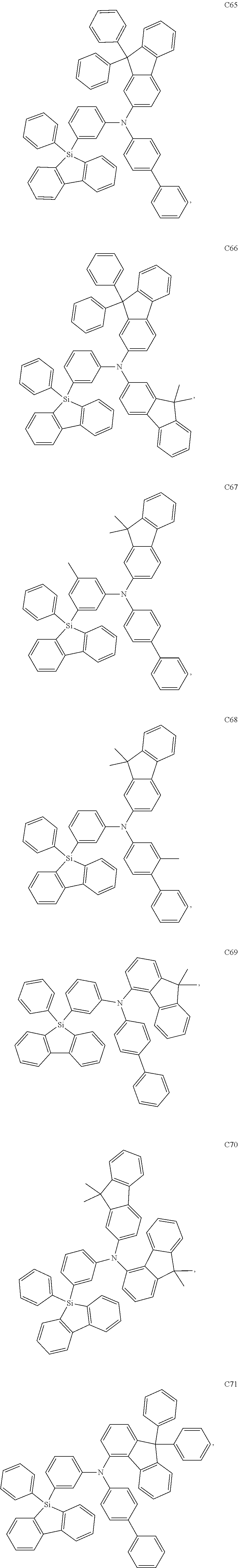 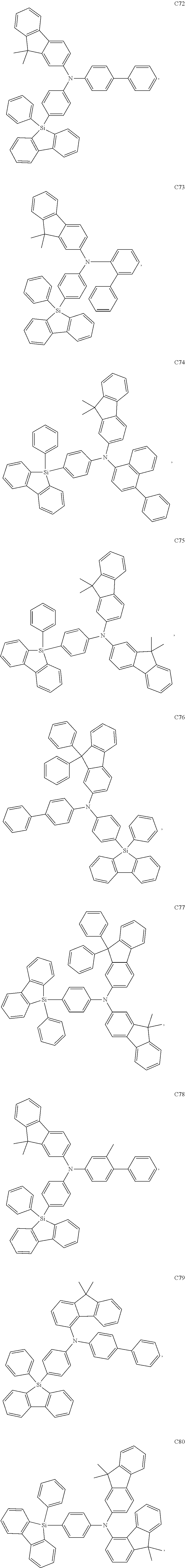 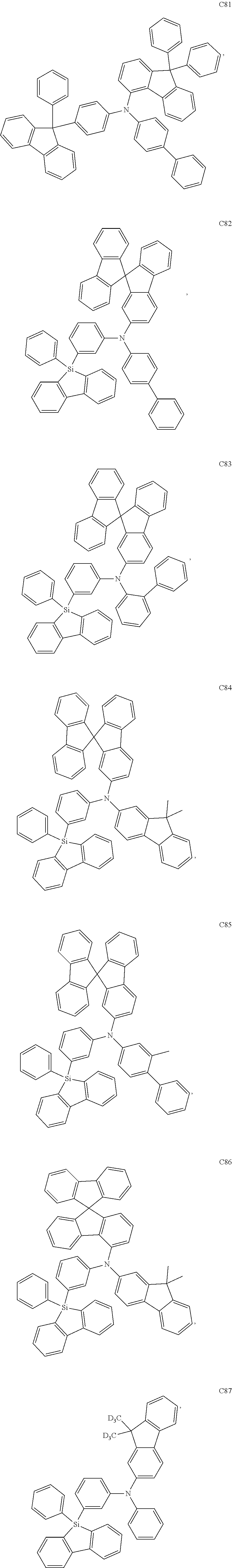 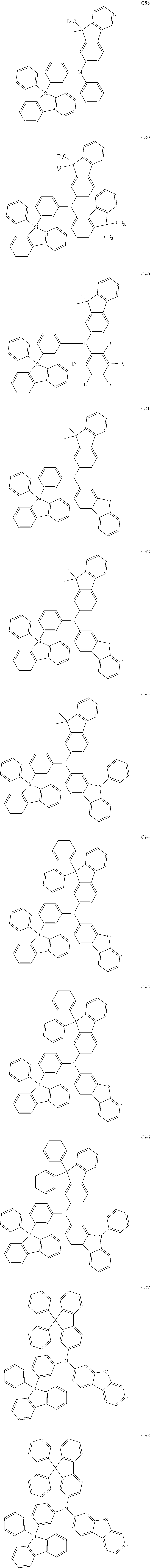 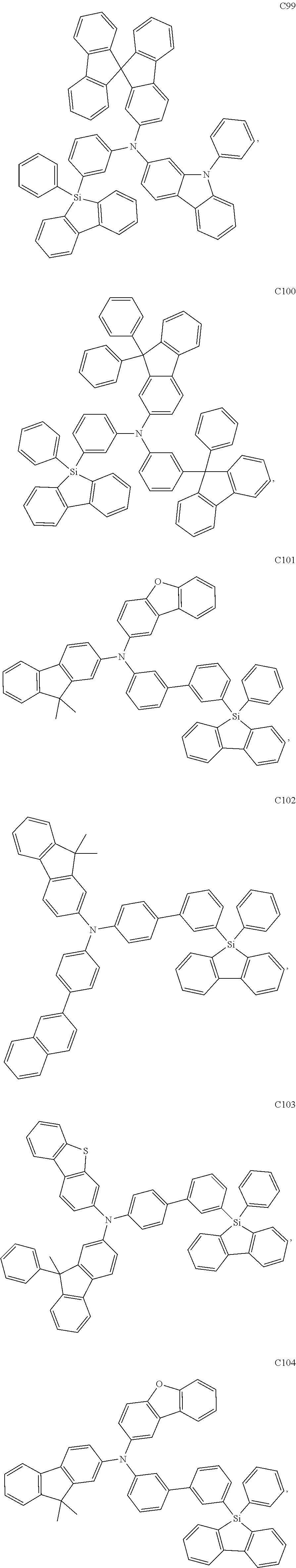 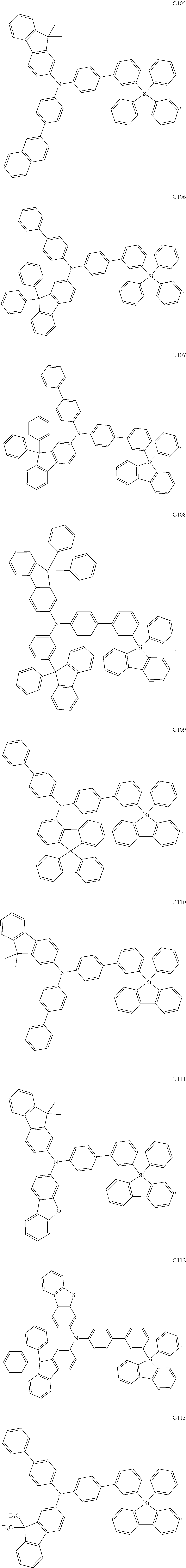 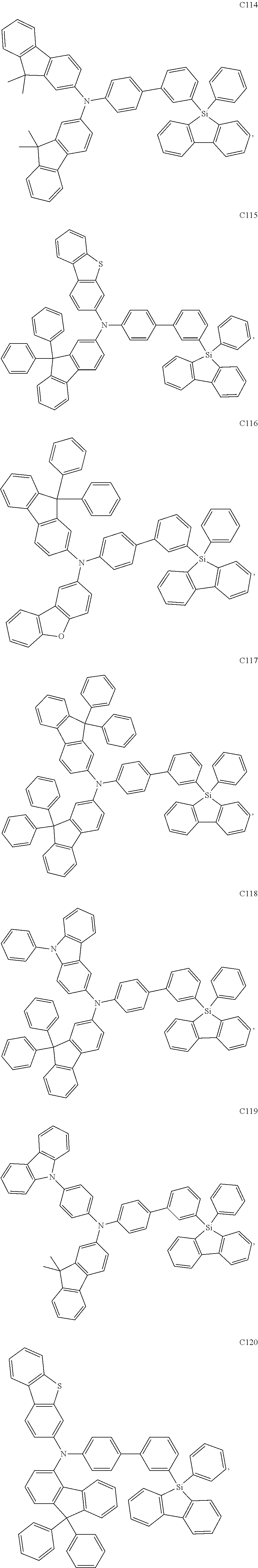 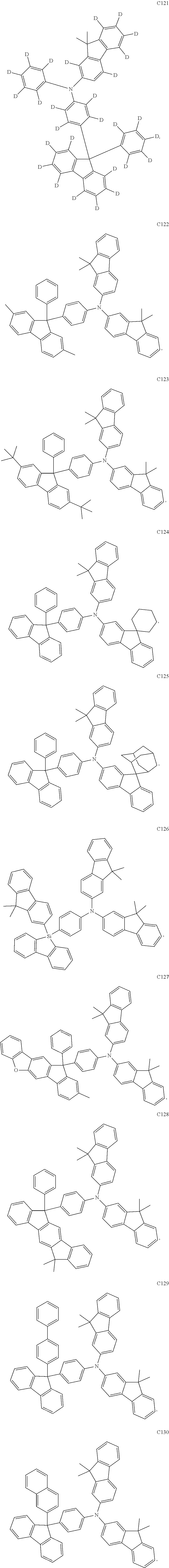 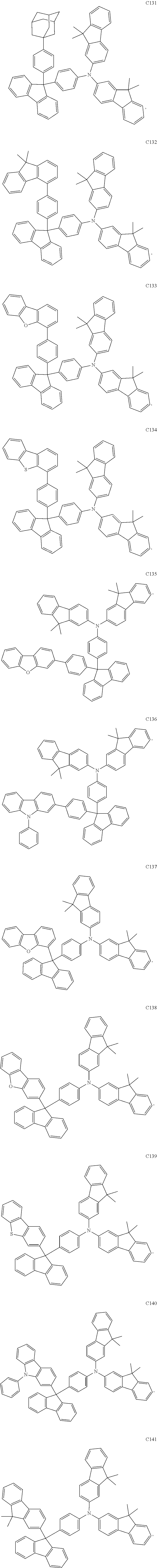 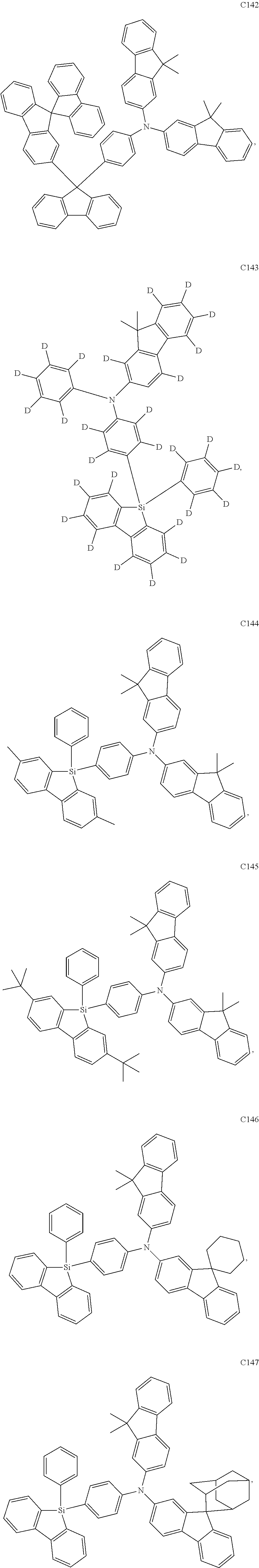 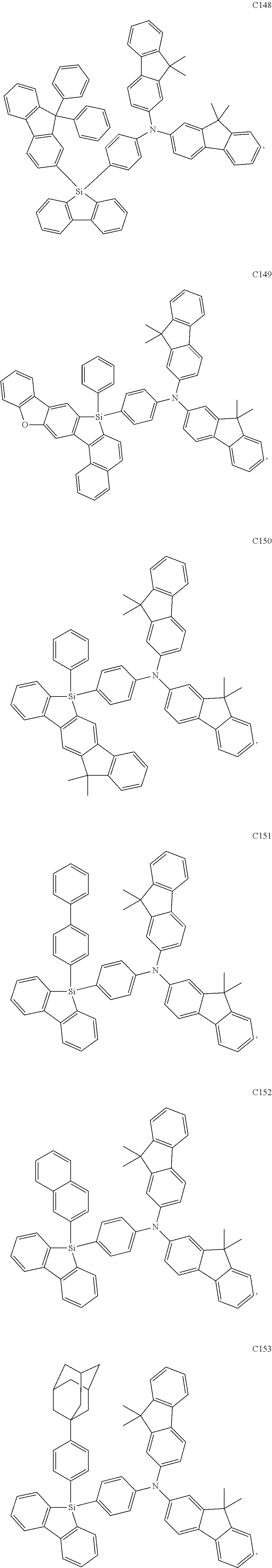 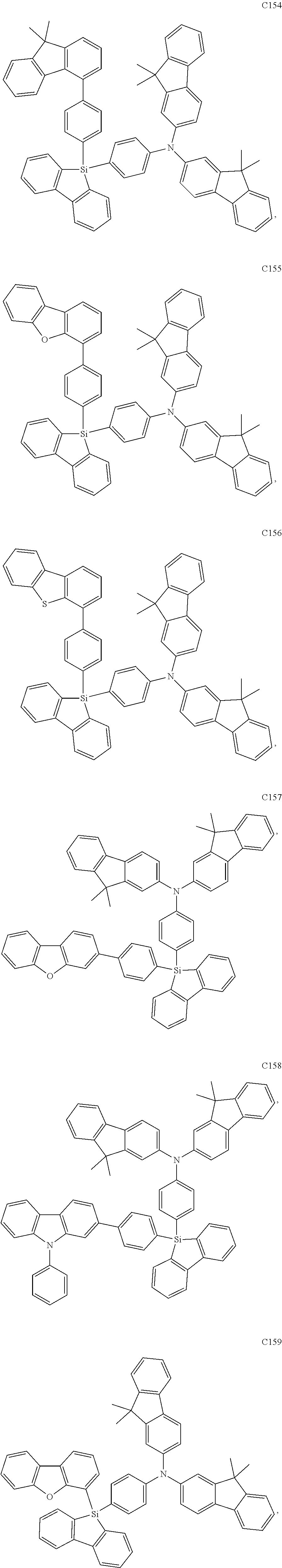 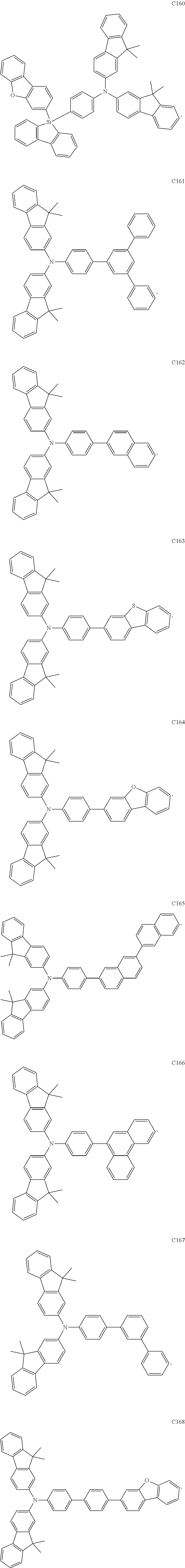 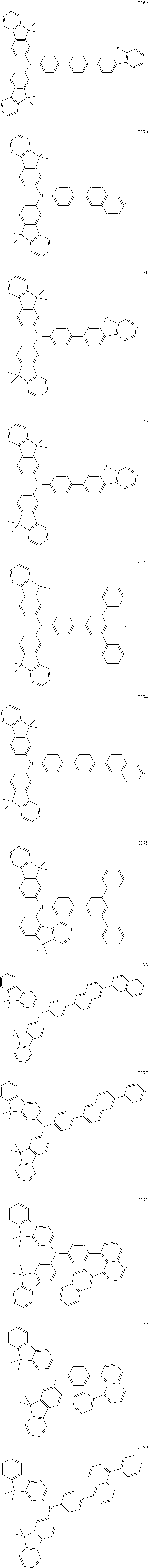 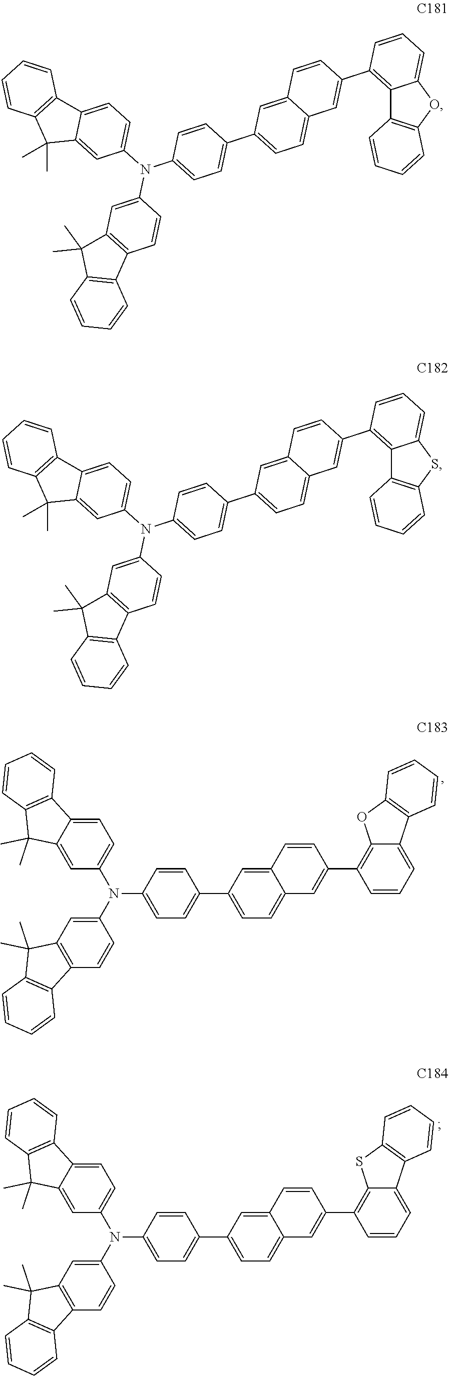 [SMILES: CC1(C)c2ccccc2-c2ccc(N(c3ccc(-c4ccc5cc(-c6cccc7oc8ccccc8c67)ccc5c4)cc3)c3ccc4c(c3)C(C)(C)c3ccccc3-4)cc21 ; CC1(C)c2ccccc2-c2ccc(N(c3ccc(-c4ccc5cc(-c6cccc7sc8ccccc8c67)ccc5c4)cc3)c3ccc4c(c3)C(C)(C)c3ccccc3-4)cc21 ; CC1(C)c2ccccc2-c2ccc(N(c3ccc(-c4ccc5cc(-c6cccc7c6oc6ccccc67)ccc5c4)cc3)c3ccc4c(c3)C(C)(C)c3ccccc3-4)cc21 ; CC1(C)c2ccccc2-c2ccc(N(c3ccc(-c4ccc5cc(-c6cccc7c6sc6ccccc67)ccc5c4)cc3)c3ccc4c(c3)C(C)(C)c3ccccc3-4)cc21]
wherein optionally, hydrogens in Compound C₁ to Compound C₁₈₄ can be partially or fully substituted with deuterium.

20. The organic electroluminescent device according to claim 1, wherein the emissive layer is in direct contact with the electron blocking layer.

21. The organic electroluminescent device according to claim 1, wherein the capacitance of the organic electroluminescent device satisfies the following condition:
at 500 Hz, a maximum capacitance value per unit of emissive area of the organic electroluminescent device is Cₘₐₓ₋ₛ, and ΔCₛ=C₀₋ₛ−Cₘₐₓ₋ₛ≥10 nF/cm²;
wherein C₀₋ₛ denotes a maximum capacitance value per unit of emissive area of an organic electroluminescent device A at 500 Hz, and the organic electroluminescent device A is the same as the organic electroluminescent device except that the electron blocking material in the electron blocking layer of the organic electroluminescent device is replaced with Compound HT;
preferably, ΔCₛ≥12.5 nF/cm²;
more preferably, ΔCₛ≥20 nF/cm²;
most preferably, ΔCₛ≥25 nF/cm².

22. A display assembly, comprising the organic electroluminescent device according to claim 1.
